(19) United States
(12) Patent Application Publication
(10) Pub. No.: US 2024/0063278 A1
(43) Pub. Date: Feb. 22, 2024

(54) TRANSISTOR CIRCUITS INCLUDING FRINGELESS TRANSISTORS AND METHOD OF MAKING THE SAME

(71) Applicant: SANDISK TECHNOLOGIES LLC, ADDISON, TX (US)

(72) Inventors: Dai IWATA, Yokkaichi (JP); Hokuto KODATE, Yokkaichi (JP)

(21) Appl. No.: 18/500,623

(22) Filed: Nov. 2, 2023

Related U.S. Application Data
(63) Continuation-in-part of application No. 17/501,163, filed on Oct. 14, 2021.
Application No. 17/501,163 is a continuation-in-part of application No. 17/316,015, filed on May 10, 2021.

(51) Int. Cl. H01L 29/423; H01L 27/06; H01L 29/66; H01L 29/06

(52) U.S. Cl. CPC H01L 29/42364; H01L 27/0617; H01L 29/6656; H01L 29/0653

(57) ABSTRACT

A lateral extent of a gate electrode of a field effect transistor along a gate electrode direction that is perpendicular to a channel direction can be the same as a width of an underlying active region. A gate electrode of an additional field effect transistor may extend over a trench isolation structure that laterally surrounds the additional field effect transistor. Different types of electrodes may be formed by patterning a lower gate material layer and by patterning an upper gate material layer with different patterns such that patterned portions of the lower gate material layer are confined within areas of active regions, while patterned portions of the upper gate material layer extends outside of the areas of the active regions.

### RELATED APPLICATIONS

This application is a continuation-in-part (CIP) application of U.S. application Ser. No. 17/501,163 filed on Oct. 14, 2021, which is a CIP application of U.S. application Ser. No. 17/316,015 filed on May 10, 2021, the entire contents of which are incorporated herein by reference.

### FIELD

The present disclosure relates generally to the field of semiconductor devices and specifically to transistor circuits including fringeless transistors and methods of making the same.

### BACKGROUND

Peripheral (i.e., driver) circuitry for a memory device includes multiple types of field effect transistors configurated to operate at different operating voltages. Providing field effect transistors that operate at different operating voltages at a high device density is a challenge.

### SUMMARY

According to an aspect of the present disclosure, a semiconductor structure comprises: a first field effect transistor comprising a first active region and a first gate electrode that comprises a first semiconductor gate electrode portion; a first trench isolation structure laterally surrounding the first active region; a second field effect transistor comprising a second active region and a second gate electrode that comprises a stack of a lower semiconductor gate electrode portion and an upper semiconductor gate electrode portion; a second trench isolation structure laterally surrounding the second active region; and at least one dielectric material layer overlying the first field effect transistor and the second field effect transistor, wherein: the first semiconductor gate electrode portion contacts sidewall surface segments of the first trench isolation structure and comprises a top surface contacting the at least one dielectric material layer; the lower semiconductor gate electrode portion has a same material composition and a same thickness as the first semiconductor gate electrode portion, and contacts sidewall surface segments of the second trench isolation structure; and the upper semiconductor gate electrode portion comprises a bottom surface contacting the lower semiconductor gate electrode and top surface segments of the second shallow trench isolation structure.

According to another aspect of the present disclosure, a method of forming a semiconductor structure comprises: forming a first patterned stack including a first gate dielectric layer and a first gate semiconductor material portion and a second patterned stack including a second gate dielectric layer and a second gate semiconductor material portion over a semiconductor substrate, wherein the first gate semiconductor material portion and the second gate semiconductor material portion comprise patterned portions of a first semiconductor material layer; forming shallow trench isolation structures around the first patterned stack and the second patterned stack, and into an upper portion of the semiconductor substrate; forming a dielectric capping layer directly on the first gate semiconductor material portion; forming a second semiconductor material layer directly on the second gate semiconductor material portion; patterning the second semiconductor material layer, the dielectric capping layer, the first gate dielectric layer, and the second gate dielectric layer to form a first gate electrode comprising a portion of the first gate semiconductor material portion and a second gate electrode comprising a portion of the second gate semiconductor material portion and a patterned portion of the second semiconductor material layer; forming a first field effect transistor by forming a first source region and a first drain region in portions of the semiconductor substrate adjacent to the first gate electrode; and forming a second field effect transistor by forming a second source region and a second drain region in portions of the semiconductor substrate adjacent to the second gate electrode.

According to yet another aspect of the present disclosure, a semiconductor structure comprises: a first field effect transistor comprising a first active region and a first gate electrode that comprises a first semiconductor gate electrode portion and a first metallic gate electrode portion; and a second field effect transistor comprising a second active region and a second gate electrode that comprises a second semiconductor gate electrode portion and a second metallic gate electrode portion, wherein: the first active region comprises a first source region and a first drain region that are laterally spaced from each other by a first channel along a first channel direction; the first gate electrode laterally extends along a first gate electrode direction that is perpendicular to the first channel direction; and a maximum lateral extent of the first metallic gate electrode portion along the first gate electrode direction is greater than a maximum lateral extent of the first semiconductor gate electrode portion along the first gate electrode direction.

According to still another aspect of the present disclosure, a method of forming a semiconductor structure comprises: forming a first patterned stack including a first gate dielectric layer, a first gate semiconductor material portion, and a first hardmask plate over a first portion of a semiconductor substrate; forming a first trench isolation structure around the first patterned stack and into the first portion of the semiconductor substrate; forming a peripheral recess region around the first patterned stack in a portion of the first trench isolation structure that is proximal to the first hardmask plate by vertically recessing a portion of the first trench isolation structure; forming a stepped cavity by removing the first hardmask plate, wherein the stepped cavity comprises a volume from which the first hardmask plate is removed and a volume of the peripheral recess region; forming a stepped metallic plate in the stepped cavity, wherein the stepped metallic plate comprise a first region having a first thickness and a second region having a second thickness that is less than the first thickness; patterning the stepped metallic plate and the first semiconductor gate semiconductor material portion into a first gate electrode; and forming a first field effect transistor by forming a first source region and a first drain region in the first portion of the semiconductor substrate adjacent to the first gate electrode.

According to another aspect of the present disclosure, a semiconductor structure comprises: a first field effect transistor; a second field effect transistor; and a third field effect transistor. The second field effect transistor and the third field effect transistor comprise a shared source/drain region, and are located in a same second active region; the second field effect transistor comprises a second gate electrode which comprises only one semiconductor layer; the third field effect transistor comprises a third gate electrode which comprises two different semiconductor layers; a gate length of the second gate electrode along a gate length direction that is perpendicular to a channel direction of the second field effect transistor is the same as a width of the second active region along the gate length direction; and a gate length of the third gate electrode along the gate length direction that is perpendicular to the channel direction of the third field effect transistor is greater than the width of the second active region along the gate length direction and is greater than the gate length of the second gate electrode.

According to yet another aspect of the present disclosure, a method of forming a semiconductor structure is provided. The method comprises: depositing and patterning a first semiconductor material layer including a first semiconductor material over a semiconductor substrate, wherein patterned portions of the first semiconductor material layer comprise a lower semiconductor plate, a first-transistor lower gate material portion, and a second-transistor gate material portion; forming a dielectric plate over the lower semiconductor plate; depositing and patterning a second semiconductor material layer including a second semiconductor material, wherein patterned portions of the second semiconductor material layer comprises a middle semiconductor plate that is formed on the dielectric plate; depositing a third semiconductor material layer including a third semiconductor material over the patterned portions of the second semiconductor material layer; forming a first-transistor upper gate material portion by patterning a first portion of the third semiconductor material layer; patterning a second portion of the third semiconductor material layer and the first-transistor lower gate electrode portion into a first gate electrode of a first field effect transistor; and patterning the second-transistor gate material portion into a second gate electrode of a second field effect transistor.

According to another aspect of the present disclosure, a semiconductor structure comprises: a first field effect transistor; a second field effect transistor; and a third field effect transistor. The second field effect transistor and the third field effect transistor comprise a shared source/drain region, and are located in a same second active region; the second field effect transistor comprises a second gate electrode which comprises a second lower semiconductor gate electrode portion and a second upper semiconductor gate electrode portion; the third field effect transistor comprises a third gate electrode which comprises a third lower semiconductor gate electrode portion and a third upper semiconductor gate electrode portion; the third gate electrode is thicker than the second gate electrode; a gate length of the second gate electrode along a gate length direction that is perpendicular to a second channel direction of the second field effect transistor is the same as a width of the second active region along the gate length direction; and a gate length of the third gate electrode along the gate length direction that is perpendicular to the second channel direction is greater than the width of the second active region along the gate length direction and is greater than the gate length of the second gate electrode.

According to even further another aspect of the present disclosure, a method of forming a semiconductor structure is provided. The method comprises: depositing and patterning a first semiconductor material layer including a first semiconductor material over a semiconductor substrate, wherein patterned portions of the first semiconductor material layer comprises a first-transistor lower gate material portion and a second-transistor lower gate material portion; forming a first trench isolation structure around the first-transistor lower gate material portion and forming a second trench isolation structure around the second-transistor lower gate material portion; depositing and patterning a second semiconductor material layer including a second semiconductor material over the first-transistor lower gate material portion and the second-transistor lower gate material portion; thinning a first portion of the second semiconductor material layer overlying a first segment of the second-transistor lower gate material portion without thinning a second portion of the second semiconductor material layer overlying the first-transistor lower gate material portion, wherein a thinned portion of the second semiconductor material layer has a top surface that is formed entirely below a horizontal plane including a top surface of the second trench isolation structure; and patterning the second semiconductor material layer, the first-transistor lower gate material portion, and a second-transistor lower gate material portion to form a first gate electrode that comprises a patterned portion of the second portion of the second semiconductor material layer and a patterned portion of the first-transistor lower gate material portion, and to form a second gate electrode that comprises a patterned portion of the thinned portion of the second semiconductor material layer and a patterned portion of the second-transistor lower gate material portion.

### BRIEF DESCRIPTION OF THE DRAWINGS

FIG. 1A is a top-down view of a first exemplary structure after formation of various doped wells according to a first embodiment of the present disclosure. FIG. 1B is a vertical cross-sectional view of the first exemplary structure along the hinged vertical plane B-B′ of FIG. 1A. FIG. 1C is a vertical cross-sectional view of the first exemplary structure along the vertical plane C-C′ of FIG. 1A. FIG. 1D is a vertical cross-sectional view of the first exemplary structure along the vertical plane D-D′ of FIG. 1A. FIG. 1E is a vertical cross-sectional view of the first exemplary structure along the vertical plane E-E′ of FIG. 1A. FIG. 1F is a vertical cross-sectional view of the first exemplary structure along the vertical plane F-F′ of FIG. 1A.

FIG. 2A is a top-down view of the first exemplary structure after formation of gate dielectric layers and semiconductor material layers according to the first embodiment of the present disclosure. FIG. 2B is a vertical cross-sectional view of the first exemplary structure along the hinged vertical plane B-B′ of FIG. 2A. FIG. 2C is a vertical cross-sectional view of the first exemplary structure along the vertical plane C-C′ of FIG. 2A. FIG. 2D is a vertical cross-sectional view of the first exemplary structure along the vertical plane D-D′ of FIG. 2A. FIG. 2E is a vertical cross-sectional view of the first exemplary structure along the vertical plane E-E′ of FIG. 2A. FIG. 2F is a vertical cross-sectional view of the first exemplary structure along the vertical plane F-F′ of FIG. 2A.

FIG. 3A is a top-down view of the first exemplary structure after formation of a patterned mask layer, shallow trenches, and deep trenches according to the first embodiment of the present disclosure. FIG. 3B is a vertical cross-sectional view of the first exemplary structure along the hinged vertical plane B-B′ of FIG. 3A. FIG. 3C is a vertical cross-sectional view of the first exemplary structure along the vertical plane C-C′ of FIG. 3A. FIG. 3D is a vertical cross-sectional view of the first exemplary structure along the vertical plane D-D′ of FIG. 3A. FIG. 3E is a vertical cross-sectional view of the first exemplary structure along the vertical plane E-E′ of FIG. 3A. FIG. 3F is a vertical cross-sectional view of the first exemplary structure along the vertical plane F-F′ of FIG. 3A.

FIG. 4 is a vertical cross-sectional of the first exemplary structure after formation of the trench fill material layer according to the first embodiment of the present disclosure.

FIG. 5A is a top-down view of the first exemplary structure after forming trench isolation structures according to the first embodiment of the present disclosure. FIG. 5B is a vertical cross-sectional view of the first exemplary structure along the hinged vertical plane B-B′ of FIG. 5A. FIG. 5C is a vertical cross-sectional view of the first exemplary structure along the vertical plane C-C′ of FIG. 5A. FIG. 5D is a vertical cross-sectional view of the first exemplary structure along the vertical plane D-D′ of FIG. 5A. FIG. 5E is a vertical cross-sectional view of the first exemplary structure along the vertical plane E-E′ of FIG. 5A. FIG. 5F is a vertical cross-sectional view of the first exemplary structure along the vertical plane F-F′ of FIG. 5A.

FIG. 6A is a top-down view of the first exemplary structure after formation of a planar semiconductor spacer layer according to the first embodiment of the present disclosure. FIG. 6B is a vertical cross-sectional view of the first exemplary structure along the hinged vertical plane B-B′ of FIG. 6A. FIG. 6C is a vertical cross-sectional view of the first exemplary structure along the vertical plane C-C′ of FIG. 6A. FIG. 6D is a vertical cross-sectional view of the first exemplary structure along the vertical plane D-D′ of FIG. 6A. FIG. 6E is a vertical cross-sectional view of the first exemplary structure along the vertical plane E-E′ of FIG. 6A. FIG. 6F is a vertical cross-sectional view of the first exemplary structure along the vertical plane F-F′ of FIG. 6A.

FIG. 7A is a top-down view of the first exemplary structure after patterning the planar semiconductor spacer layer according to the first embodiment of the present disclosure. FIG. 7B is a vertical cross-sectional view of the first exemplary structure along the hinged vertical plane B-B′ of FIG. 7A. FIG. 7C is a vertical cross-sectional view of the first exemplary structure along the vertical plane C-C′ of FIG. 7A. FIG. 7D is a vertical cross-sectional view of the first exemplary structure along the vertical plane D-D′ of FIG. 7A. FIG. 7E is a vertical cross-sectional view of the first exemplary structure along the vertical plane E-E′ of FIG. 7A. FIG. 7F is a vertical cross-sectional view of the first exemplary structure along the vertical plane F-F′ of FIG. 7A.

FIG. 8A is a top-down view of the first exemplary structure after deposition of a conductive gate cap layer and a gate cap dielectric layer according to the first embodiment of the present disclosure. FIG. 8B is a vertical cross-sectional view of the first exemplary structure along the hinged vertical plane B-B′ of FIG. 8A. FIG. 8C is a vertical cross-sectional view of the first exemplary structure along the vertical plane C-C′ of FIG. 8A. FIG. 8D is a vertical cross-sectional view of the first exemplary structure along the vertical plane D-D′ of FIG. 8A. FIG. 8E is a vertical cross-sectional view of the first exemplary structure along the vertical plane E-E′ of FIG. 8A. FIG. 8F is a vertical cross-sectional view of the first exemplary structure along the vertical plane F-F′ of FIG. 8A.

FIG. 9A is a top-down view of the first exemplary structure after patterning the gate cap dielectric layer, the conductive gate cap layer, and the planar semiconductor spacer layer according to the first embodiment of the present disclosure. FIG. 9B is a vertical cross-sectional view of the first exemplary structure along the hinged vertical plane B-B′ of FIG. 9A. FIG. 9C is a vertical cross-sectional view of the first exemplary structure along the vertical plane C-C′ of FIG. 9A. FIG. 9D is a vertical cross-sectional view of the first exemplary structure along the vertical plane D-D′ of FIG. 9A. FIG. 9E is a vertical cross-sectional view of the first exemplary structure along the vertical plane E-E′ of FIG. 9A. FIG. 9F is a vertical cross-sectional view of the first exemplary structure along the vertical plane F-F′ of FIG. 9A.

FIG. 10A is a top-down view of the first exemplary structure after applying and patterning a photoresist layer for patterning the semiconductor material layers according to the first embodiment of the present disclosure. FIG. 10B is a vertical cross-sectional view of the first exemplary structure along the hinged vertical plane B-B′ of FIG. 10A. FIG. 10C is a vertical cross-sectional view of the first exemplary structure along the vertical plane C-C′ of FIG. 10A. FIG. 10D is a vertical cross-sectional view of the first exemplary structure along the vertical plane D-D′ of FIG. 10A. FIG. 10E is a vertical cross-sectional view of the first exemplary structure along the vertical plane E-E′ of FIG. 10A. FIG. 10F is a vertical cross-sectional view of the first exemplary structure along the vertical plane F-F′ of FIG. 10A.

FIG. 11A is a top-down view of the first exemplary structure after applying and patterning the semiconductor material layers and the gate dielectric layers according to the first embodiment of the present disclosure. FIG. 11B is a vertical cross-sectional view of the first exemplary structure along the hinged vertical plane B-B′ of FIG. 11A. FIG. 11C is a vertical cross-sectional view of the first exemplary structure along the vertical plane C-C′ of FIG. 11A. FIG. 11D is a vertical cross-sectional view of the first exemplary structure along the vertical plane D-D′ of FIG. 11A. FIG. 11E is a vertical cross-sectional view of the first exemplary structure along the vertical plane E-E′ of FIG. 11A. FIG. 11F is a vertical cross-sectional view of the first exemplary structure along the vertical plane F-F′ of FIG. 11A. FIG. 11G is a vertical cross-sectional view of the first exemplary structure along the vertical plane G-G′ of FIG. 11A.

FIG. 12A is a top-down view of the first exemplary structure after formation of dielectric gate spacers according to the first embodiment of the present disclosure. FIG. 12B is a vertical cross-sectional view of the first exemplary structure along the hinged vertical plane B-B′ of FIG. 12A. FIG. 12C is a vertical cross-sectional view of the first exemplary structure along the vertical plane C-C′ of FIG. 12A. FIG. 12D is a vertical cross-sectional view of the first exemplary structure along the vertical plane D-D′ of FIG. 12A. FIG. 12E is a vertical cross-sectional view of the first exemplary structure along the vertical plane E-E′ of FIG. 12A. FIG. 12F is a vertical cross-sectional view of the first exemplary structure along the vertical plane F-F′ of FIG. 12A. FIG. 12G is a vertical cross-sectional view of the first exemplary structure along the vertical plane G-G′ of FIG. 12A.

FIG. 13A is a top-down view of the first exemplary structure after formation of source regions and drain regions according to the first embodiment of the present disclosure. FIG. 13B is a vertical cross-sectional view of the first exemplary structure along the hinged vertical plane B-B′ of FIG. 13A. FIG. 13C is a vertical cross-sectional view of the first exemplary structure along the vertical plane C-C′ of FIG. 13A. FIG. 13D is a vertical cross-sectional view of the first exemplary structure along the vertical plane D-D′ of FIG. 13A. FIG. 13E is a vertical cross-sectional view of the first exemplary structure along the vertical plane E-E′ of FIG. 13A. FIG. 13F is a vertical cross-sectional view of the first exemplary structure along the vertical plane F-F′ of FIG. 13A. FIG. 13G is a vertical cross-sectional view of the first exemplary structure along the vertical plane G-G′ of FIG. 13A.

FIG. 14A is a top-down view of the first exemplary structure after formation of a contact-level dielectric layer and various contact via structures according to the first embodiment of the present disclosure. FIG. 14B is a vertical cross-sectional view of the first exemplary structure along the hinged vertical plane B-B′ of FIG. 14A. FIG. 14C is a vertical cross-sectional view of the first exemplary structure along the vertical plane C-C′ of FIG. 14A. FIG. 14D is a vertical cross-sectional view of the first exemplary structure along the vertical plane D-D′ of FIG. 14A. FIG. 14E is a vertical cross-sectional view of the first exemplary structure along the vertical plane E-E′ of FIG. 14A. FIG. 14F is a vertical cross-sectional view of the first exemplary structure along the vertical plane F-F′ of FIG. 14A.

FIG. 15A is a top-down view of a second exemplary structure after formation of trench isolation structures according to the second embodiment of the present disclosure. FIG. 15B is a vertical cross-sectional view of the second exemplary structure along the hinged vertical plane B-B′ of FIG. 15A. FIG. 15C is a vertical cross-sectional view of the second exemplary structure along the vertical plane C-C′ of FIG. 15A. FIG. 15D is a vertical cross-sectional view of the second exemplary structure along the vertical plane D-D′ of FIG. 15A. FIG. 15E is a vertical cross-sectional view of the second exemplary structure along the vertical plane E-E′ of FIG. 15A. FIG. 15F is a vertical cross-sectional view of the second exemplary structure along the vertical plane F-F′ of FIG. 15A.

FIG. 16A is a top-down view of a second exemplary structure after implanting electrical dopants into a subset of the lower semiconductor material layers according to the second embodiment of the present disclosure. FIG. 16B is a vertical cross-sectional view of the second exemplary structure along the hinged vertical plane B-B′ of FIG. 16A. FIG. 16C is a vertical cross-sectional view of the second exemplary structure along the vertical plane C-C′ of FIG. 16A. FIG. 16D is a vertical cross-sectional view of the second exemplary structure along the vertical plane D-D′ of FIG. 16A. FIG. 16E is a vertical cross-sectional view of the second exemplary structure along the vertical plane E-E′ of FIG. 16A. FIG. 16F is a vertical cross-sectional view of the second exemplary structure along the vertical plane F-F′ of FIG. 16A.

FIG. 17A is a top-down view of the second exemplary structure after formation of a planar semiconductor spacer layer according to the second embodiment of the present disclosure. FIG. 17B is a vertical cross-sectional view of the second exemplary structure along the hinged vertical plane B-B′ of FIG. 17A. FIG. 17C is a vertical cross-sectional view of the second exemplary structure along the vertical plane C-C′ of FIG. 17A. FIG. 17D is a vertical cross-sectional view of the second exemplary structure along the vertical plane D-D′ of FIG. 17A. FIG. 17E is a vertical cross-sectional view of the second exemplary structure along the vertical plane E-E′ of FIG. 17A. FIG. 17F is a vertical cross-sectional view of the second exemplary structure along the vertical plane F-F′ of FIG. 17A.

FIG. 18A is a top-down view of the second exemplary structure after patterning the planar semiconductor spacer layer according to the second embodiment of the present disclosure. FIG. 18B is a vertical cross-sectional view of the second exemplary structure along the hinged vertical plane B-B′ of FIG. 18A. FIG. 18C is a vertical cross-sectional view of the second exemplary structure along the vertical plane C-C′ of FIG. 18A. FIG. 18D is a vertical cross-sectional view of the second exemplary structure along the vertical plane D-D′ of FIG. 18A. FIG. 18E is a vertical cross-sectional view of the second exemplary structure along the vertical plane E-E′ of FIG. 18A. FIG. 18F is a vertical cross-sectional view of the second exemplary structure along the vertical plane F-F′ of FIG. 18A.

FIG. 19A is a top-down view of the second exemplary structure after deposition of a conductive gate cap layer and a planar dielectric spacer layer according to the second embodiment of the present disclosure. FIG. 19B is a vertical cross-sectional view of the second exemplary structure along the hinged vertical plane B-B′ of FIG. 19A. FIG. 19C is a vertical cross-sectional view of the second exemplary structure along the vertical plane C-C′ of FIG. 19A. FIG. 19D is a vertical cross-sectional view of the second exemplary structure along the vertical plane D-D′ of FIG. 19A. FIG. 19E is a vertical cross-sectional view of the second exemplary structure along the vertical plane E-E′ of FIG. 19A. FIG. 19F is a vertical cross-sectional view of the second exemplary structure along the vertical plane F-F′ of FIG. 19A.

FIG. 20A is a top-down view of the second exemplary structure after patterning the gate cap dielectric layer, the conductive gate cap layer, and the planar semiconductor spacer layer according to the second embodiment of the present disclosure. FIG. 20B is a vertical cross-sectional view of the second exemplary structure along the hinged vertical plane B-B′ of FIG. 20A. FIG. 20C is a vertical cross-sectional view of the second exemplary structure along the vertical plane C-C′ of FIG. 20A. FIG. 20D is a vertical cross-sectional view of the second exemplary structure along the vertical plane D-D′ of FIG. 20A. FIG. 20E is a vertical cross-sectional view of the second exemplary structure along the vertical plane E-E′ of FIG. 20A. FIG. 20F is a vertical cross-sectional view of the second exemplary structure along the vertical plane F-F′ of FIG. 20A.

FIG. 21A is a top-down view of the second exemplary structure after applying and patterning a photoresist layer for patterning the lower semiconductor material layers according to the second embodiment of the present disclosure. FIG. 21B is a vertical cross-sectional view of the second exemplary structure along the hinged vertical plane B-B′ of FIG. 21A. FIG. 21C is a vertical cross-sectional view of the second exemplary structure along the vertical plane C-C′ of FIG. 21A. FIG. 21D is a vertical cross-sectional view of the second exemplary structure along the vertical plane D-D′ of FIG. 21A. FIG. 21E is a vertical cross-sectional view of the second exemplary structure along the vertical plane E-E′ of FIG. 21A. FIG. 21F is a vertical cross-sectional view of the second exemplary structure along the vertical plane F-F′ of FIG. 21A.

FIG. 22A is a top-down view of the second exemplary structure after applying and patterning the lower semiconductor material layers and the gate dielectric layers according to the second embodiment of the present disclosure. FIG. 22B is a vertical cross-sectional view of the second exemplary structure along the hinged vertical plane B-B′ of FIG. 22A. FIG. 22C is a vertical cross-sectional view of the second exemplary structure along the vertical plane C-C′ of FIG. 22A. FIG. 22D is a vertical cross-sectional view of the second exemplary structure along the vertical plane D-D′ of FIG. 22A. FIG. 22E is a vertical cross-sectional view of the second exemplary structure along the vertical plane E-E′ of FIG. 22A. FIG. 22F is a vertical cross-sectional view of the second exemplary structure along the vertical plane F-F′ of FIG. 22A. FIG. 22G is a vertical cross-sectional view of the second exemplary structure along the vertical plane G-G′ of FIG. 22A.

FIG. 23A is a top-down view of the second exemplary structure after formation of dielectric gate spacers according to the second embodiment of the present disclosure. FIG. 23B is a vertical cross-sectional view of the second exemplary structure along the hinged vertical plane B-B′ of FIG. 23A. FIG. 23C is a vertical cross-sectional view of the second exemplary structure along the vertical plane C-C′ of FIG. 23A. FIG. 23D is a vertical cross-sectional view of the second exemplary structure along the vertical plane D-D′ of FIG. 23A. FIG. 23E is a vertical cross-sectional view of the second exemplary structure along the vertical plane E-E′ of FIG. 23A. FIG. 23F is a vertical cross-sectional view of the second exemplary structure along the vertical plane F-F′ of FIG. 23A. FIG. 23G is a vertical cross-sectional view of the second exemplary structure along the vertical plane G-G′ of FIG. 23A.

FIG. 24A is a top-down view of the second exemplary structure after formation of source regions and drain regions according to the second embodiment of the present disclosure. FIG. 24B is a vertical cross-sectional view of the second exemplary structure along the hinged vertical plane B-B′ of FIG. 24A. FIG. 24C is a vertical cross-sectional view of the second exemplary structure along the vertical plane C-C′ of FIG. 24A. FIG. 24D is a vertical cross-sectional view of the second exemplary structure along the vertical plane D-D′ of FIG. 24A. FIG. 24E is a vertical cross-sectional view of the second exemplary structure along the vertical plane E-E′ of FIG. 24A. FIG. 24F is a vertical cross-sectional view of the second exemplary structure along the vertical plane F-F′ of FIG. 24A. FIG. 24G is a vertical cross-sectional view of the second exemplary structure along the vertical plane G-G′ of FIG. 24A.

FIG. 25A is a top-down view of the second exemplary structure after formation of a contact-level dielectric layer and various contact via structures according to the second embodiment of the present disclosure. FIG. 25B is a vertical cross-sectional view of the second exemplary structure along the hinged vertical plane B-B′ of FIG. 25A. FIG. 25C is a vertical cross-sectional view of the second exemplary structure along the vertical plane C-C′ of FIG. 25A. FIG. 25D is a vertical cross-sectional view of the second exemplary structure along the vertical plane D-D′ of FIG. 25A. FIG. 25E is a vertical cross-sectional view of the second exemplary structure along the vertical plane E-E′ of FIG. 25A. FIG. 25F is a vertical cross-sectional view of the second exemplary structure along the vertical plane F-F′ of FIG. 25A.

FIG. 26A is a top-down view of a third exemplary structure after formation of trench isolation structures according to the third embodiment of the present disclosure. FIG. 26B is a vertical cross-sectional view of the third exemplary structure along the hinged vertical plane B-B′ of FIG. 26A.

FIG. 27A is a top-down view of the third exemplary structure after formation of a planar semiconductor spacer layer according to the third embodiment of the present disclosure. FIG. 27B is a vertical cross-sectional view of the third exemplary structure along the hinged vertical plane B-B′ of FIG. 27A.

FIG. 28A is a top-down view of the third exemplary structure after patterning the planar semiconductor spacer layer according to the third embodiment of the present disclosure. FIG. 28B is a vertical cross-sectional view of the third exemplary structure along the hinged vertical plane B-B′ of FIG. 28A.

FIG. 29A is a top-down view of the third exemplary structure after deposition of an upper semiconductor material layer and a conductive gate cap layer according to the third embodiment of the present disclosure. FIG. 29B is a vertical cross-sectional view of the third exemplary structure along the hinged vertical plane B-B′ of FIG. 29A.

FIG. 30A is a top-down view of the third exemplary structure after patterning the conductive gate cap layer and the upper semiconductor material layer according to the third embodiment of the present disclosure. FIG. 30B is a vertical cross-sectional view of the third exemplary structure along the hinged vertical plane B-B′ of FIG. 30A.

FIG. 31A is a top-down view of the third exemplary structure after applying and patterning a photoresist layer for patterning the planar semiconductor spacer layer and the lower semiconductor material layers according to the third embodiment of the present disclosure. FIG. 31B is a vertical cross-sectional view of the third exemplary structure along the hinged vertical plane B-B′ of FIG. 31A.

FIG. 32A is a top-down view of the third exemplary structure after applying and patterning the planar semiconductor spacer layer and the lower semiconductor material layers according to the third embodiment of the present disclosure. FIG. 32B is a vertical cross-sectional view of the third exemplary structure along the hinged vertical plane B-B′ of FIG. 32A. FIG. 32C is a vertical cross-sectional view of the third exemplary structure along the vertical plane C-C′ of FIG. 32A. FIG. 32D is a vertical cross-sectional view of the third exemplary structure along the vertical plane D-D′ of FIG. 32A.

FIG. 33A is a top-down view of the third exemplary structure after formation of dielectric gate spacers according to the third embodiment of the present disclosure. FIG. 33B is a vertical cross-sectional view of the third exemplary structure along the hinged vertical plane B-B′ of FIG. 33A.

FIG. 34A is a top-down view of the third exemplary structure after formation of source regions and drain regions according to the third embodiment of the present disclosure.

FIG. 34B is a vertical cross-sectional view of the third exemplary structure along the hinged vertical plane B-B′ of FIG. 34A. FIG. 34C is a vertical cross-sectional view of the third exemplary structure along the vertical plane C-C′ of FIG. 34A. FIG. 34D is a vertical cross-sectional view of the third exemplary structure along the vertical plane D-D′ of FIG. 34A.

FIG. 35A is a top-down view of the third exemplary structure after formation of a contact-level dielectric layer and various contact via structures according to the third embodiment of the present disclosure. FIG. 35B is a vertical cross-sectional view of the third exemplary structure along the hinged vertical plane B-B′ of FIG. 35A.

FIG. 36A is a top-down view of a comparative sense amplifier transistor structure. FIG. 36B is a vertical cross-sectional view of the comparative sense amplifier transistor structure along the vertical plane B-B′ of FIG. 36A.

FIG. 37A is a top-down view of a fourth exemplary sense amplifier transistor structure according to the fourth embodiment of the present disclosure. FIG. 37B is a vertical cross-sectional view of the fourth exemplary sense amplifier transistor structure along the vertical plane B-B′ of FIG. 37A.

FIG. 38 is a top-down view of two adjacent comparative sense amplifier transistor structures of FIG. 36A.

FIG. 39 is a top-down view of two adjacent fourth exemplary sense amplifier transistor structures of FIG. 37A according to the fourth embodiment of the present disclosure.

FIG. 40A is a top-down view of a first exemplary transistor structure according to the first embodiment of the present disclosure. FIG. 40B is a vertical cross-sectional view of the first exemplary transistor structure along the vertical plane B-B′ of FIG. 40A.

FIG. 41 is a top-down view of two adjacent comparative transistor structures.

FIG. 42 is a top-down view of two adjacent first exemplary transistor structures according to the first embodiment of the present disclosure.

FIG. 43 is a top-down view of two adjacent second exemplary transistor structures according to the second embodiment of the present disclosure.

FIG. 44 is a top-down view of an alternative configuration of the second exemplary transistor structure according to the second embodiment of the present disclosure.

FIG. 45A is a top-down view of third exemplary transistor structures according to the third embodiment of the present disclosure. FIG. 45B is a vertical cross-sectional view of the third exemplary transistor structures along the vertical plane B-B′ of FIG. 45A.

FIG. 46A is another top-down view of third exemplary transistor structures according to the third embodiment of the present disclosure. FIGS. 46B and 46C are vertical cross-sectional views of the third exemplary transistor structures along the vertical planes B-B′ and C-C′, respectively, of FIG. 46A.

FIG. 47A is a top-down view of a fifth exemplary structure after formation of shallow trenches according to a fifth embodiment of the present disclosure. FIGS. 47B, 47C, and 47D are vertical cross-sectional views of the fifth exemplary structure along the vertical planes B-B′, C-C′, and D-D′, respectively, of FIG. 47A.

FIG. 48A is a top-down view of the fifth exemplary structure after formation of a shallow trench isolation structure according to the fifth embodiment of the present disclosure. FIGS. 48B, 48C, and 48D are vertical cross-sectional views of the fifth exemplary structure along the vertical planes B-B′, C-C′, and D-D′, respectively, of FIG. 48A.

FIG. 49A is a top-down view of the fifth exemplary structure after vertically recessing a gap region of the shallow trench isolation structure according to the fifth embodiment of the present disclosure. FIGS. 49B, 49C, and 49D are vertical cross-sectional views of the fifth exemplary structure along the vertical planes B-B′, C-C′, and D-D′, respectively, of FIG. 49A.

FIG. 50A is a top-down view of the fifth exemplary structure after removal of hardmask plates and formation of gate dielectric layers according to the fifth embodiment of the present disclosure. FIGS. 50B, 50C, and 50D are vertical cross-sectional views of the fifth exemplary structure along the vertical planes B-B′, C-C′, and D-D′, respectively, of FIG. 50A.

FIG. 51A is a top-down view of the fifth exemplary structure after formation of gate electrode material portions according to the fifth embodiment of the present disclosure.

FIGS. 51B, 51C, and 51D are vertical cross-sectional views of the fifth exemplary structure along the vertical planes B-B′, C-C′, and D-D′, respectively, of FIG. 51A.

FIG. 52A is a top-down view of the fifth exemplary structure after formation of gate dielectrics and gate electrodes according to the fifth embodiment of the present disclosure. FIGS. 52B, 52C, and 52D are vertical cross-sectional views of the fifth exemplary structure along the vertical planes B-B′, C-C′, and D-D′, respectively, of FIG. 52A.

FIG. 53A is a top-down view of the fifth exemplary structure after formation of a dielectric liner layer and source/drain extension regions according to the fifth embodiment of the present disclosure. FIGS. 53B, 53C, and 53D are vertical cross-sectional views of the fifth exemplary structure along the vertical planes B-B′, C-C′, and D-D′, respectively, of FIG. 53A.

FIG. 54A is a top-down view of the fifth exemplary structure after formation of main dielectric spacers and deep source/drain regions according to the fifth embodiment of the present disclosure. FIGS. 54B, 54C, and 54D are vertical cross-sectional views of the fifth exemplary structure along the vertical planes B-B′, C-C′, and D-D′, respectively, of FIG. 54A.

FIG. 55A is a top-down view of the fifth exemplary structure after formation of metal-semiconductor alloy regions according to the fifth embodiment of the present disclosure. FIGS. 55B, 55C, and 55D are vertical cross-sectional views of the fifth exemplary structure along the vertical planes B-B′, C-C′, and D-D′, respectively, of FIG. 55A.

FIG. 56A is a top-down view of the fifth exemplary structure after formation of a planarization dielectric layer according to the fifth embodiment of the present disclosure. FIGS. 56B, 56C, and 56D are vertical cross-sectional views of the fifth exemplary structure along the vertical planes B-B′, C-C′, and D-D′, respectively, of FIG. 56A.

FIG. 57A is a top-down view of the fifth exemplary structure after formation of various contact via structures according to the fifth embodiment of the present disclosure. FIGS. 57B, 57C, and 57D are vertical cross-sectional views of the fifth exemplary structure along the vertical planes B-B′, C-C′, and D-D′, respectively, of FIG. 57A.

FIG. 58A is a top-down view of a sixth exemplary structure after formation of various doped wells according to a sixth embodiment of the present disclosure. FIG. 58B is a vertical cross-sectional view of the sixth exemplary structure along the vertical plane B-B′ of FIG. 58A.

FIG. 59A is a top-down view of the sixth exemplary structure after formation of gate dielectric layers, a first semiconductor material layer, and a patterned hardmask layer according to the sixth embodiment of the present disclosure. FIG. 59B is a vertical cross-sectional view of the sixth exemplary structure along the vertical plane B-B′ of FIG. 59A.

FIG. 60A is a top-down view of the sixth exemplary structure after formation of shallow trenches according to the sixth embodiment of the present disclosure. FIG. 60B is a vertical cross-sectional view of the sixth exemplary structure along the vertical plane B-B′ of FIG. 60A.

FIG. 61A is a vertical cross-sectional of the sixth exemplary structure after formation of the trench fill material layer according to the sixth embodiment of the present disclosure. FIG. 61B is a vertical cross-sectional view of the sixth exemplary structure along the vertical plane B-B′ of FIG. 61A.

FIG. 62A is a top-down view of the sixth exemplary structure after forming shallow trench isolation structures according to the sixth embodiment of the present disclosure. FIG. 62B is a vertical cross-sectional view of the sixth exemplary structure along the vertical plane B-B′ of FIG. 62A.

FIG. 63A is a top-down view of the sixth exemplary structure after removal of the patterned hardmask layer according to the sixth embodiment of the present disclosure. FIG. 63B is a vertical cross-sectional view of the sixth exemplary structure along the vertical plane B-B′ of FIG. 63A.

FIG. 64A is a top-down view of the sixth exemplary structure after formation of a dielectric capping layer according to the sixth embodiment of the present disclosure. FIG. 64B is a vertical cross-sectional view of the sixth exemplary structure along the vertical plane B-B′ of FIG. 64A.

FIG. 65A is a top-down view of the sixth exemplary structure after patterning the dielectric capping layer according to the sixth embodiment of the present disclosure. FIG. 65B is a vertical cross-sectional view of the sixth exemplary structure along the vertical plane B-B′ of FIG. 65A.

FIG. 66A is a top-down view of the sixth exemplary structure after formation of a second semiconductor material layer according to the sixth embodiment of the present disclosure. FIG. 66B is a vertical cross-sectional view of the sixth exemplary structure along the vertical plane B-B′ of FIG. 66A.

FIG. 67A is a top-down view of the sixth exemplary structure after patterning of the second semiconductor material layer according to the sixth embodiment of the present disclosure. FIG. 67B is a vertical cross-sectional view of the sixth exemplary structure along the vertical plane B-B′ of FIG. 67A.

FIG. 68A is a top-down view of the sixth exemplary structure after formation of a dielectric cover layer according to the sixth embodiment of the present disclosure. FIG. 68B is a vertical cross-sectional view of the sixth exemplary structure along the vertical plane B-B′ of FIG. 68A.

FIG. 69A is a top-down view of the sixth exemplary structure after patterning the dielectric cover layer employing a gate photoresist layer according to the sixth embodiment of the present disclosure. FIG. 69B is a vertical cross-sectional view of the sixth exemplary structure along the vertical plane B-B′ of FIG. 69A.

FIG. 70A is a top-down view of the sixth exemplary structure after patterning the semiconductor capping plate and the first semiconductor material layer into various semiconductor gate electrode portions according to the sixth embodiment of the present disclosure. FIG. 70B is a vertical cross-sectional view of the sixth exemplary structure along the vertical plane B-B′ of FIG. 70A.

FIG. 71A is a top-down view of the sixth exemplary structure after removal of the gate photoresist layer according to the sixth embodiment of the present disclosure. FIG. 71B is a vertical cross-sectional view of the sixth exemplary structure along the vertical plane B-B′ of FIG. 71A.

FIG. 72A is a top-down view of the sixth exemplary structure after formation of source/drain extension regions according to the sixth embodiment of the present disclosure. FIG. 72B is a vertical cross-sectional view of the sixth exemplary structure along the vertical plane B-B′ of FIG. 72A. FIG. 72C is a vertical cross-sectional view of the sixth exemplary structure along the vertical plane C-C′ of FIG. 72A. FIG. 72D is a vertical cross-sectional view of the sixth exemplary structure along the vertical plane D-D′ of FIG. 72A. FIG. 72E is a vertical cross-sectional view of the sixth exemplary structure along the vertical plane E-E′ of FIG. 72A. FIG. 72F is a vertical cross-sectional view of the sixth exemplary structure along the vertical plane F-F′ of FIG. 72A.

FIG. 73A is a top-down view of the sixth exemplary structure after formation of a dielectric gate spacer layer according to the sixth embodiment of the present disclosure. FIG. 73B is a vertical cross-sectional view of the sixth exemplary structure along the vertical plane B-B′ of FIG. 73A.

FIG. 74A is a top-down view of the sixth exemplary structure after formation of dielectric gate spacers according to the sixth embodiment of the present disclosure. FIG. 74B is a vertical cross-sectional view of the sixth exemplary structure along the vertical plane B-B′ of FIG. 74A. FIG. 74C is a vertical cross-sectional view of the sixth exemplary structure along the vertical plane C-C′ of FIG. 74A. FIG. 74D is a vertical cross-sectional view of the sixth exemplary structure along the vertical plane D-D′ of FIG. 74A. FIG. 74E is a vertical cross-sectional view of the sixth exemplary structure along the vertical plane E-E′ of FIG. 74A. FIG. 74F is a vertical cross-sectional view of the sixth exemplary structure along the vertical plane F-F′ of FIG. 74A.

FIG. 75A is a top-down view of the sixth exemplary structure after formation of source regions and drain regions according to the sixth embodiment of the present disclosure.

FIG. 75B is a vertical cross-sectional view of the sixth exemplary structure along the vertical plane B-B′ of FIG. 75A. FIG. 75C is a vertical cross-sectional view of the sixth exemplary structure along the vertical plane C-C′ of FIG. 75A. FIG. 75D is a vertical cross-sectional view of the sixth exemplary structure along the vertical plane D-D′ of FIG. 75A. FIG. 75E is a vertical cross-sectional view of the sixth exemplary structure along the vertical plane E-E′ of FIG. 75A. FIG. 75F is a vertical cross-sectional view of the sixth exemplary structure along the vertical plane F-F′ of FIG. 75A.

FIG. 76A is a top-down view of the sixth exemplary structure after formation of a contact-level dielectric layer and various contact via structures according to the sixth embodiment of the present disclosure. FIG. 76B is a vertical cross-sectional view of the sixth exemplary structure along the vertical plane B-B′ of FIG. 76A. FIG. 76C is a vertical cross-sectional view of the sixth exemplary structure along the vertical plane C-C′ of FIG. 76A. FIG. 76D is a vertical cross-sectional view of the sixth exemplary structure along the vertical plane D-D′ of FIG. 76A. FIG. 76E is a vertical cross-sectional view of the sixth exemplary structure along the vertical plane E-E′ of FIG. 76A. FIG. 76F is a vertical cross-sectional view of the sixth exemplary structure along the vertical plane F-F′ of FIG. 76A.

FIG. 77A is a top-down view of a seventh exemplary structure after formation of a gate dielectric layer, a semiconductor gate electrode material layer, and a hardmask layer according to a seventh embodiment of the present disclosure. FIG. 77B is a vertical cross-sectional view of the seventh exemplary structure along the vertical planes B-B′ of FIG. 77A.

FIG. 78A is a top-down view of a seventh exemplary structure after formation of shallow trenches according to the seventh embodiment of the present disclosure. FIGS. 78B, 78C, and 78D are vertical cross-sectional views of the seventh exemplary structure along the vertical planes B-B′, C-C′, and D-D′, respectively, of FIG. 78A.

FIG. 79A is a top-down view of the seventh exemplary structure after formation of a shallow trench isolation structure according to the seventh embodiment of the present disclosure. FIGS. 79B, 79C, and 79D are vertical cross-sectional views of the seventh exemplary structure along the vertical planes B-B′, C-C′, and D-D′, respectively, of FIG. 79A.

FIG. 80A is a top-down view of the seventh exemplary structure after vertically recessing a gap region of the shallow trench isolation structure according to the seventh embodiment of the present disclosure. FIGS. 80B, 80C, and 80D are vertical cross-sectional views of the seventh exemplary structure along the vertical planes B-B′, C-C′, and D-D′, respectively, of FIG. 80A.

FIG. 81A is a top-down view of the seventh exemplary structure after removal of hardmask plates and formation of gate dielectric layers according to the seventh embodiment of the present disclosure. FIGS. 81B, 81C, and 81D are vertical cross-sectional views of the seventh exemplary structure along the vertical planes B-B′, C-C′, and D-D′, respectively, of FIG. 81A.

FIG. 82A is a top-down view of the seventh exemplary structure after formation of a metallic gate electrode material layer according to the seventh embodiment of the present disclosure. FIGS. 82B, 82C, and 82D are vertical cross-sectional views of the seventh exemplary structure along the vertical planes B-B′, C-C′, and D-D′, respectively, of FIG. 82A.

FIG. 83A is a top-down view of the seventh exemplary structure after formation of metallic plates according to the seventh embodiment of the present disclosure. FIGS. 83B, 83C, and 83D are vertical cross-sectional views of the seventh exemplary structure along the vertical planes B-B′, C-C′, and D-D′, respectively, of FIG. 83A.

FIG. 84A is a top-down view of the seventh exemplary structure after formation of a patterned photoresist layer according to the seventh embodiment of the present disclosure. FIGS. 84B, 84C, and 84D are vertical cross-sectional views of the seventh exemplary structure along the vertical planes B-B′, C-C′, and D-D′, respectively, of FIG. 84A.

FIG. 85A is a top-down view of the seventh exemplary structure after formation of gate electrodes and gate dielectrics according to the seventh embodiment of the present disclosure. FIGS. 85B, 85C, and 85D are vertical cross-sectional views of the seventh exemplary structure along the vertical planes B-B′, C-C′, and D-D′, respectively, of FIG. 85A.

FIG. 86A is a top-down view of the seventh exemplary structure after formation of source/drain extension regions according to the seventh embodiment of the present disclosure. FIGS. 86B, 86C, and 86D are vertical cross-sectional views of the seventh exemplary structure along the vertical planes B-B′, C-C′, and D-D′, respectively, of FIG. 86A.

FIG. 87A is a top-down view of the seventh exemplary structure after formation of dielectric spacers and deep source/drain regions according to the seventh embodiment of the present disclosure. FIGS. 87B, 87C, and 87D are vertical cross-sectional views of the seventh exemplary structure along the vertical planes B-B′, C-C′, and D-D′, respectively, of FIG. 87A.

FIG. 88A is a top-down view of the seventh exemplary structure after formation of dielectric liners according to the seventh embodiment of the present disclosure. FIGS. 88B, 88C, and 88D are vertical cross-sectional views of the seventh exemplary structure along the vertical planes B-B′, C-C′, and D-D′, respectively, of FIG. 88A.

FIG. 89A is a top-down view of the seventh exemplary structure after formation of a planarization dielectric layer according to the seventh embodiment of the present disclosure. FIGS. 89B, 89C, and 89D are vertical cross-sectional views of the seventh exemplary structure along the vertical planes B-B′, C-C′, and D-D′, respectively, of FIG. 89A.

FIG. 90A is a top-down view of the seventh exemplary structure after formation of various contact via structures according to the seventh embodiment of the present disclosure. FIGS. 90B, 90C, and 90D are vertical cross-sectional views of the seventh exemplary structure along the vertical planes B-B′, C-C′, and D-D′, respectively, of FIG. 90A.

FIG. 91A is a top-down view of an eighth exemplary structure after formation of various doped wells, a gate dielectric layer, a first semiconductor material layer, and a hardmask layer, and a patterned photoresist layer according to an eighth embodiment of the present disclosure. FIG. 91B is a vertical cross-sectional view of the eighth exemplary structure along the vertical plane B-B′ of FIG. 91A.

FIG. 92A is a top-down view of the eighth exemplary structure after formation of shallow trenches according to the eighth embodiment of the present disclosure. FIGS. 92B, 92C, 92D, and 92E are vertical cross-sectional views of the eighth exemplary structure along the vertical planes B-B′, C-C′, D-D′, and E-E′, respectively, of FIG. 92A.

FIG. 93A is a vertical cross-sectional of the eighth exemplary structure after formation of shallow trench isolation structures according to the eighth embodiment of the present disclosure. FIGS. 93B, 93C, 93D, and 93E are vertical cross-sectional views of the eighth exemplary structure along the vertical planes B-B′, C-C′, D-D′, and E-E′, respectively, of FIG. 93A.

FIG. 94A is a top-down view of the eighth exemplary structure after formation of a node dielectric layer and a second semiconductor material layer according to the eighth embodiment of the present disclosure. FIGS. 94B, 94C, 94D, and 94E are vertical cross-sectional views of the eighth exemplary structure along the vertical planes B-B′, C-C′, D-D′, and E-E′, respectively, of FIG. 94A.

FIG. 95A is a top-down view of the eighth exemplary structure after patterning the second semiconductor material layer and the node dielectric layer according to the eighth embodiment of the present disclosure. FIGS. 95B, 95C, 95D, and 95E are vertical cross-sectional views of the eighth exemplary structure along the vertical planes B-B′, C-C′, D-D′, and E-E′, respectively, of FIG. 95A.

FIG. 96A is a top-down view of the eighth exemplary structure after formation of a third semiconductor material layer and a dielectric capping layer according to the eighth embodiment of the present disclosure. FIGS. 96B, 96C, 96D, and 96E are vertical cross-sectional views of the eighth exemplary structure along the vertical planes B-B′, C-C′, D-D′, and E-E′, respectively, of FIG. 96A.

FIG. 97A is a top-down view of the eighth exemplary structure after formation and patterning of a gate-level photoresist layer according to the eighth embodiment of the present disclosure. FIGS. 97B, 97C, 97D, and 97E are vertical cross-sectional views of the eighth exemplary structure along the vertical planes B-B′, C-C′, D-D′, and E-E′, respectively, of FIG. 97A.

FIG. 98A is a top-down view of the eighth exemplary structure after patterning the dielectric capping layer according to the eighth embodiment of the present disclosure. FIGS. 98B, 98C, 98D, and 98E are vertical cross-sectional views of the eighth exemplary structure along the vertical planes B-B′, C-C′, D-D′, and E-E′, respectively, of FIG. 98A.

FIG. 99A is a top-down view of the eighth exemplary structure after formation of a first block-level photoresist layer according to the eighth embodiment of the present disclosure. FIGS. 99B, 99C, 99D, and 99E are vertical cross-sectional views of the eighth exemplary structure along the vertical planes B-B′, C-C′, D-D′, and E-E′, respectively, of FIG. 99A.

FIG. 100A is a top-down view of the eighth exemplary structure after transfer of a gate pattern in regions that are not masked by the first block-level photoresist layer according to the eighth embodiment of the present disclosure. FIGS. 100B, 100C, 100D, and 100E are vertical cross-sectional views of the eighth exemplary structure along the vertical planes B-B′, C-C′, D-D′, and E-E′, respectively, of FIG. 100A.

FIG. 101A is a top-down view of the eighth exemplary structure after formation of a second block-level photoresist layer and transfer of the gate pattern in regions that are not masked by the second block-level photoresist layer through the node dielectric layer according to the eighth embodiment of the present disclosure. FIGS. 101B, 101C, 101D, and 101E are vertical cross-sectional views of the eighth exemplary structure along the vertical planes B-B′, C-C′, D-D′, and E-E′, respectively, of FIG. 101A.

FIG. 102A is a top-down view of the eighth exemplary structure after formation of a third block-level photoresist layer according to the eighth embodiment of the present disclosure. FIGS. 102B, 102C, 102D, and 102E are vertical cross-sectional views of the eighth exemplary structure along the vertical planes B-B′, C-C′, D-D′, and E-E′, respectively, of FIG. 102A.

FIG. 103A is a top-down view of the eighth exemplary structure after transfer of the gate pattern into the first semiconductor material layer according to the eighth embodiment of the present disclosure. FIGS. 103B, 103C, 103D, 103E, 103F, and 103G are vertical cross-sectional views of the eighth exemplary structure along the vertical planes B-B′, C-C′, D-D′, E-E′, F-F′, and G-G′, respectively, of FIG. 103A.

FIG. 104A is a top-down view of the eighth exemplary structure after formation of source/drain extension regions according to the eighth embodiment of the present disclosure.

FIGS. 104B, 104C, 104D, 104E, 104F, and 104G are vertical cross-sectional views of the eighth exemplary structure along the vertical planes B-B′, C-C′, D-D′, E-E′, F-F′, and G-G′, respectively, of FIG. 104A.

FIG. 105A is a top-down view of the eighth exemplary structure after formation of dielectric gate spacers and source regions and drain regions according to the eighth embodiment of the present disclosure. FIGS. 105B, 105C, 105D, 105E, 105F, and 105G are vertical cross-sectional views of the eighth exemplary structure along the vertical planes B-B′, C-C′, D-D′, E-E′, F-F′, and G-G′, respectively, of FIG. 105A.

FIG. 106A is a top-down view of the eighth exemplary structure after formation of a contact-level dielectric layer and various contact via structures according to the eighth embodiment of the present disclosure. FIGS. 106B, 106C, 106D, 106E, 106F, and 106G are vertical cross-sectional views of the eighth exemplary structure along the vertical planes B-B′, C-C′, D-D′, E-E′, F-F′, and G-G′, respectively, of FIG. 106A.

FIG. 107A is a top-down view of a ninth exemplary structure after formation of various doped wells, a gate dielectric layer, a first semiconductor material layer, a hardmask layer, and shallow trenches according to a ninth embodiment of the present disclosure. FIGS. 107B, 107C, and 107D are vertical cross-sectional views of the ninth exemplary structure along the vertical planes B-B′, C-C′, and D-D′, respectively, of FIG. 107A.

FIG. 108A is a vertical cross-sectional of the ninth exemplary structure after formation of shallow trench isolation structures according to the ninth embodiment of the present disclosure. FIGS. 108B, 108C, and 108D are vertical cross-sectional views of the ninth exemplary structure along the vertical planes B-B′, C-C′, and D-D′, respectively, of FIG. 108A.

FIG. 109A is a vertical cross-sectional of the ninth exemplary structure after removal of hardmask plates according to the ninth embodiment of the present disclosure. FIGS. 109B, 109C, and 109D are vertical cross-sectional views of the ninth exemplary structure along the vertical planes B-B′, C-C′, and D-D′, respectively, of FIG. 109A.

FIG. 110A is a top-down view of the ninth exemplary structure after formation of a second semiconductor material layer according to the ninth embodiment of the present disclosure. FIGS. 110B, 110C, and 110D are vertical cross-sectional views of the ninth exemplary structure along the vertical planes B-B′, C-C′, and D-D′, respectively, of FIG. 110A.

FIG. 111A is a top-down view of the ninth exemplary structure after vertically recessing portions of the second semiconductor material layer according to the ninth embodiment of the present disclosure. FIGS. 111B, 111C, 111D, and 111E are vertical cross-sectional views of the ninth exemplary structure along the vertical planes B-B′, C-C′, D-D′, and E-E′, respectively, of FIG. 111A.

FIG. 112A is a top-down view of the ninth exemplary structure after formation and patterning of a gate-level photoresist layer according to the ninth embodiment of the present disclosure. FIGS. 112B, 112C, 112D, and 112E are vertical cross-sectional views of the ninth exemplary structure along the vertical planes B-B′, C-C′, D-D′, and E-E′, respectively, of FIG. 112A.

FIG. 113A is a top-down view of the ninth exemplary structure after patterning the second semiconductor material layer and the first semiconductor material layer into semiconductor gate electrode portions according to the ninth embodiment of the present disclosure. FIGS. 113B, 113C, 113D, 113E, 113F, and 113G are vertical cross-sectional views of the ninth exemplary structure along the vertical planes B-B′, C-C′, D-D′, E-E′, F-F′, and G-G′, respectively, of FIG. 113A.

FIG. 114A is a top-down view of the ninth exemplary structure after formation of source/drain extension regions according to the ninth embodiment of the present disclosure. FIGS. 114B, 114C, 114D, 114E, 114F, and 114G are vertical cross-sectional views of the ninth exemplary structure along the vertical planes B-B′, C-C′, D-D′, E-E′, F-F′, and G-G′, respectively, of FIG. 114A.

FIG. 115A is a top-down view of the ninth exemplary structure after formation of dielectric gate spacers and source regions and drain regions according to the ninth embodiment of the present disclosure. FIGS. 115B, 115C, 115D, 115E, 115F, and 115G are vertical cross-sectional views of the ninth exemplary structure along the vertical planes B-B′, C-C′, D-D′, E-E′, F-F′, and G-G′, respectively, of FIG. 115A.

FIG. 116A is a top-down view of the ninth exemplary structure after formation of a contact-level dielectric layer and various contact via structures according to the ninth embodiment of the present disclosure. FIGS. 116B, 116C, 116D, 116E, 116F, and 116G are vertical cross-sectional views of the ninth exemplary structure along the vertical planes B-B′, C-C′, D-D′, E-E′, F-F′, and G-G′, respectively, of FIG. 116A.

### DETAILED DESCRIPTION

Embodiments of the present disclosure provide transistor circuits including fringeless transistors and methods of making the same, the various aspects of which are described below. Such high density transistor circuits including fringeless transistors may be employed in various applications such as sense amplifier and peripheral low voltage driver circuits of memory device, such as a three-dimensional memory array.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element.

As used herein, a “layer” refers to a material portion including a region having a thickness. A layer may extend over the entirety of an underlying or overlying structure, or may have an extent less than the extent of an underlying or overlying structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material”, “insulating material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flows with a current density modulated by an external electrical field. As used herein, a “channel region” refers to a semiconductor region in which mobility of charge carriers is affected by an applied electrical field. A “gate electrode” refers to a conductive material portion that controls electron mobility in the channel region by application of an electrical field. A “source region” refers to a doped semiconductor region that supplies charge carriers that flow through the channel region. A “drain region” refers to a doped semiconductor region that receives charge carriers supplied by the source region and passes through the channel region. A “source/drain region” may be a source region or a drain region. An “active region” collectively refers to a source region, a drain region, and a channel region of a field effect transistor. A “source extension region” refers to a doped semiconductor region that is a portion of a source region and having a lesser dopant concentration than the rest of the source region. A “drain extension region” refers to a doped semiconductor region that is a portion of a drain region and having a lesser dopant concentration than the rest of the drain region. An “active region extension” refers to a source extension region or a drain extension region.

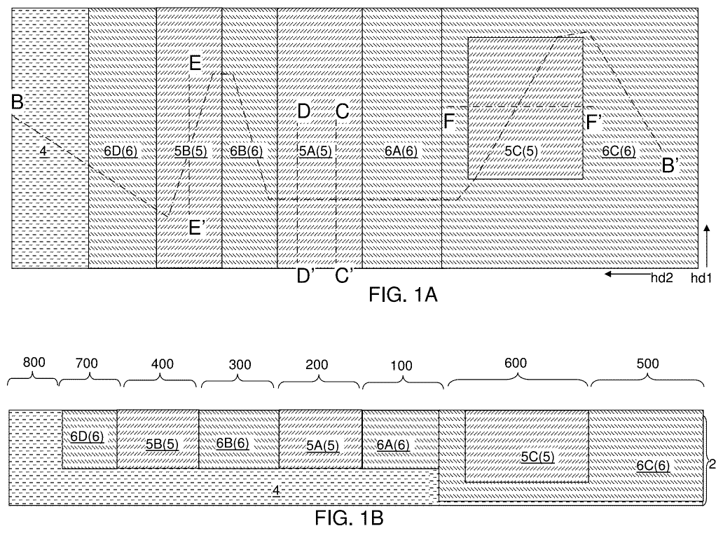

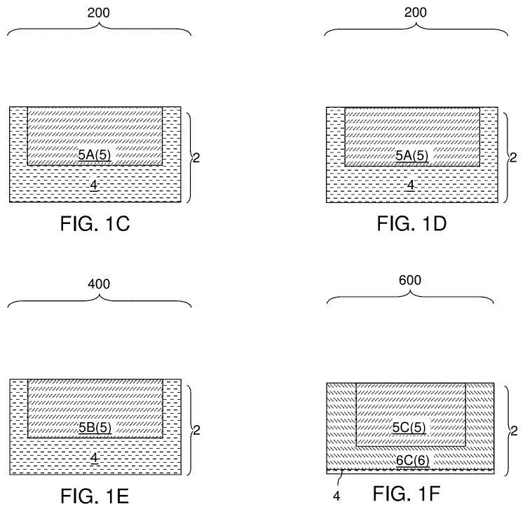

Referring to FIGS. 1A-1F, a first exemplary structure according to an embodiment of the present disclosure is illustrated. The first exemplary structure includes a semiconductor substrate 2. As used herein, a “semiconductor substrate” refers to a substrate that includes at least one semiconductor material portion, i.e., at least one portion of a semiconductor material. The semiconductor substrate 2 includes a semiconductor material at least at a top portion thereof. The semiconductor substrate 2 may optionally include at least one additional material layer at a bottom portion thereof. In one embodiment, the semiconductor substrate 2 can be a bulk semiconductor substrate consisting of a semiconductor material (e.g., single crystal silicon wafer), or can be a semiconductor-on-insulator (SOI) substrate including a buried insulator layer (such as a silicon oxide layer) underlying the semiconductor (e.g., silicon) material portion, and a handle substrate underlying the buried insulator layer.

The semiconductor substrate 2 can include a substrate semiconductor layer 4 that includes a lightly doped semiconductor material portion, on which at least one field effect transistor can be formed. In one embodiment, the entirety of the semiconductor substrate 2 may be the substrate semiconductor layer 4. In another embodiment, the substrate semiconductor layer 4 may comprise an upper portion of the semiconductor substrate 2, such as doped well in a silicon wafer. The substrate semiconductor layer 4 may include a lightly doped semiconductor material including electrical dopants at an atomic concentration in a range from 1.0×10¹⁴/cm³ to 1.0×10¹⁸/cm³, such as from 1.0×10¹⁵/cm³ to 1.0×10¹⁷/cm³, although lesser and greater atomic concentrations can also be employed.

The semiconductor material of the substrate semiconductor layer 4 can be an elemental semiconductor material (such as silicon) or an alloy of at least two elemental semiconductor materials (such as a silicon-germanium alloy), or can be a compound semiconductor material (such as a III-V compound semiconductor material or a II-VI compound semiconductor material), or can be an organic semiconductor material. The thickness of the substrate semiconductor layer 4 can be in a range from 0.5 mm to 2 mm in case the semiconductor substrate 2 is a bulk semiconductor substrate. In case the semiconductor substrate 2 is a semiconductor-on-insulator substrate, the thickness of the substrate semiconductor layer 4 may be in a range from 100 nm to 1,000 nm, although lesser and greater thicknesses can also be employed.

Various doped wells (5, 6) can be formed in an upper portion of the semiconductor substrate 2 (e.g., in the substrate semiconductor layer 4). The various doped wells (5, 6) may include p-type wells 5 having a respective p-type doping and n-type wells 6 having a respective n-type doping. For example, the p-type wells 5 may include a first p-type well 6A, a second p-type well 5B, a third p-type well 5C, etc. The n-type wells 6 may include a first n-type well 6A, a second n-type well 6B, a third n-type well 6C, a fourth n-type well 6D, etc. The regions including the various doped wells (5, 6) may be employed to form various semiconductor devices. For example, the region including the first n-type well 6A may comprise a first p-type field effect transistor region 100 in which first p-type field effect transistors including p-doped source and drain regions are to be subsequently formed; the region including the first p-type well 5A may comprise a first n-type field effect transistor region 200 in which first n-type field effect transistors including n-doped source and drain regions are to be subsequently formed; the region including the second n-type well 6B may comprise a second p-type field effect transistor region 300 in which second p-type field effect transistors including p-doped source and drain regions are to be subsequently formed; the region including the second p-type well 5B may comprise a second n-type field effect transistor region 400 in which second n-type field effect transistors including n-doped source and drain regions are to be subsequently formed; the region including the third n-type well 6C may comprise a third p-type field effect transistor region 500 in which third p-type field effect transistors including p-doped source and drain regions are to be subsequently formed; and the region including the third p-type well 5C may comprise a third n-type field effect transistor region 600 in which third n-type field effect transistors including n-doped source and drain regions are to be subsequently formed. Optionally, the region including the fourth n-doped well 6D may comprise a first passive device region 700 in which a first passive device such as a resistor is subsequently formed. Optionally, a region in which the substrate semiconductor layer 4 is physically exposed may be employed for a passive device region, such as a second passive device region 800, in which a second passive device such as a capacitor is subsequently formed. For example, regions 100 and 200 may contain low voltage transistors, regions 300 and 400 may contain very low voltage transistors which operate at a lower voltage than the low voltage transistors, and regions 500 and 600 may contain high voltage transistors which operate at a higher voltage than the low voltage transistors.

The various device regions may be arranged in any pattern on a top surface of the semiconductor substrate 2. While the present disclosure is described employing an embodiment in which the direction of semiconductor channels (i.e., the direction of current flow in the channel regions of the field effect transistors) is parallel to a first horizontal direction hd1 and perpendicular to a second horizontal direction hd2, it is understood that the direction of the semiconductor channel may be oriented along any direction for each field effect transistor to be subsequently formed. The depth of each doped well (5, 6) and the dopant concentration in each doped well (5, 6) may be suitably selected. For example, the dopant concentration in each doped well (5, 6) may be in a range from 1.0×10¹⁴/cm³ to 1.0×10¹⁸/cm³, such as from 1.0×10¹⁵/cm³ to 1.0×10¹¹/cm³, although lesser and greater atomic concentrations can also be employed. The depth of each well (5, 6) may be in a range from 50 nm to 2,000 nm, although lesser and greater depths may also be employed.

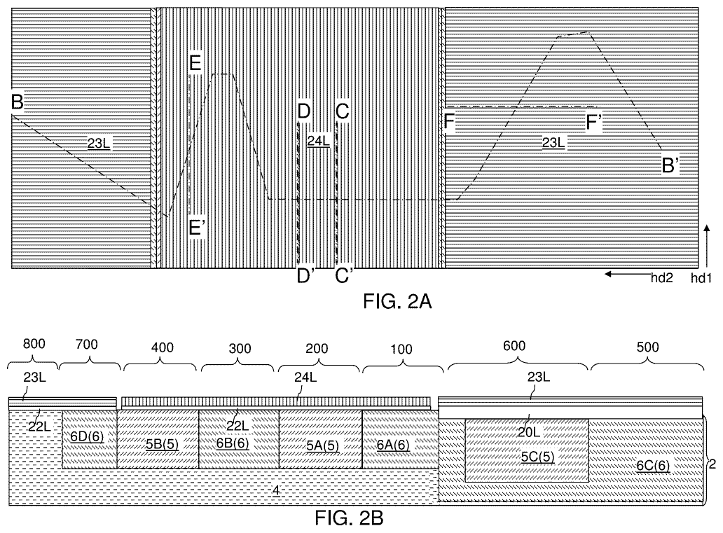

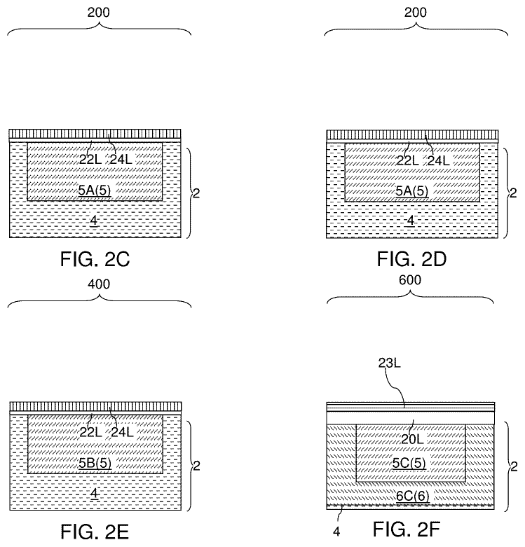

Referring to FIGS. 2A-2F, various gate dielectric layers (20L, 22L) can be formed on a top surface of the semiconductor substrate 2. For example, a first gate dielectric layer 22L can be formed in regions in which low and very low voltage field effect transistors employing thinner gate dielectrics are to be subsequently formed, and a second gate dielectric layer 20L can be formed in regions in which high voltage field effect transistors employing thicker gate dielectrics are to be subsequently formed. In an illustrative example, the first p-type field effect transistor region 100 may include low voltage p-type field effect transistors, the first n-type field effect transistor region 200 may include low voltage n-type field effect transistors, the second p-type field effect transistor region 300 may include very low voltage p-type field effect transistors, the second n-type field effect transistor region 400 may include very low voltage n-type field effect transistors, the third p-type field effect transistor region 500 may include high voltage p-type field effect transistors, and the third n-type field effect transistor region 600 may include high voltage n-type field effect transistors. The above transistors may be employed in a peripheral (e.g., driver) circuit for a memory device. Additional transistors may be employed in a sense amplifier circuit of the memory device. In this case, the first gate dielectric layer 22L may be formed in the first p-type field effect transistor region 100, the first n-type field effect transistor region 200, the second p-type field effect transistor region 300, and the second n-type field effect transistor region 400. The second gate dielectric layer 20L may be formed in the third p-type field effect transistor region 500 and in the third n-type field effect transistor region 600. The first passive device region 700 and the second passive device region 800 may include a portion of the first gate dielectric layer 22L and/or a portion of the second gate dielectric layer 20L as needed. In an illustrative example, the second gate dielectric layer 20L may be formed on the top surface of the semiconductor substrate 2 and can be patterned so that portions of the second gate dielectric layer 20L are removed from the first p-type field effect transistor region 100, the first n-type field effect transistor region 200, the second p-type field effect transistor region 300, and the second n-type field effect transistor region 400. Subsequently, the first gate dielectric layer 22L can be formed by thermal oxidation of physically exposed surface portions of the semiconductor substrate 2 and/or by deposition of a dielectric material such as silicon oxide. The thickness of the first gate dielectric layer 22L may be in a range from 1 nm to 6 nm, such as from 1.5 nm to 3 nm, although lesser and greater thicknesses may also be employed. The first gate dielectric layer 22L may be thicker in the low voltage transistor regions 100 and 200 than in the very low voltage transistor regions 300 and 400. The thickness of the second gate dielectric layer 20L may be thicker than that of the first gate dielectric layer 22L and may be in a range from 4 nm to 30 nm, such as from 6 nm to 15 nm, although lesser and greater thicknesses may also be employed.

A polish stop pad layer 23L and a semiconductor material layer 24L may be formed over the first and second gate dielectric layers (22L, 20L). The polish stop pad layer 23L may comprise any suitable sacrificial material, such as silicon nitride and/or a bilayer of silicon nitride and silicon oxide, which may be used as a polish stop. The semiconductor material layer 24L may comprise a heavily doped polysilicon layer. Optionally, the polish stop pad layer 23L may also be formed on top of the semiconductor material layer 24L. The thickness of layers (23L, 24L) may be in a range from 50 nm to 300 nm, such as from 100 nm to 200 nm, although lesser and greater thicknesses may also be employed.

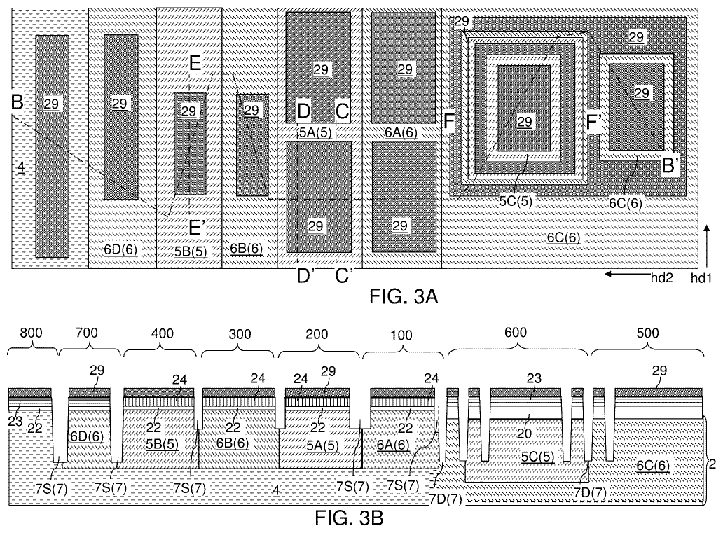

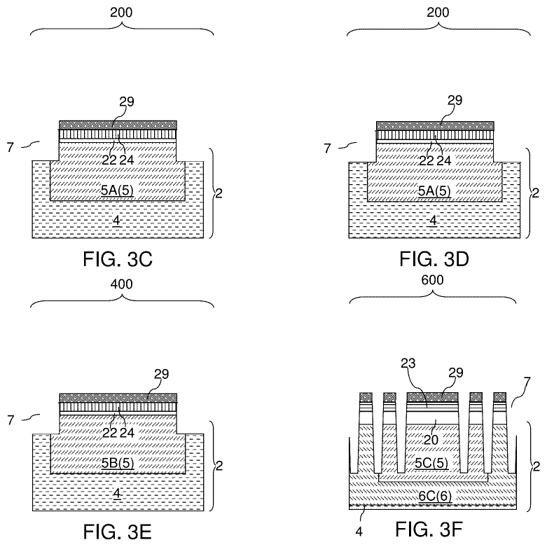

Referring to FIGS. 3A-3F, a mask layer 21 such as a photoresist layer or hardmask layer 21 can be deposited over the layers (23L, 24L). The mask layer 21 is patterned to form a pattern of openings around each area in which semiconductor devices are to be subsequently formed. For example, within the areas of the field effect transistor regions (100, 200, 300, 400, 500, 600), the areas of the openings in the mask layer 21 can be located outside the areas of active regions (i.e., outside the areas of the source regions, the drain regions, and the channel regions). Within the areas of the passive device regions (700, 800), the areas of the opening in each mask layer 21 can be located outside the areas of the passive devices to be subsequently formed. An anisotropic etch can be performed to transfer the pattern of the openings in the mask layer 21 through the underlying layers. For example, deep trenches 7D may be formed in regions 500, 600, 700 and 800 through the polish stop pad layer 23L into an upper portion of the semiconductor substrate 2. The depth of the deep trenches 7D may be in a range from 1,000 nm to 2,000 nm, although lesser and greater depths may also be employed. Shallow trenches 7C may be formed in regions 100, 200, 300 and 400 through the semiconductor material layer 24L (and optionally through any portion of the polish stop pad layer located on the semiconductor material layer 24L) into an upper portion of the semiconductor substrate 2. The depth of the shallow trenches 7S may be shallower than the depth of the deep trenches 7D. The depth of the shallow trenches 7S may be in a range from 150 nm to 500 nm, although lesser and greater depths may also be employed. The mask layer 21 can be subsequently removed. The combination of the deep trenches 7D and the shallow trenches 7S is collectively referred to as trenches 7. The trenches 7 divide the layers (23L, 24L) into polish stop plates 23 and gate electrode material plates 24. Further, the trenches divide the gate dielectric layers (22L, 20L) into gate dielectric plates (22, 20), which may include, for example, first gate dielectric plates 22 and second gate dielectric plates 20.

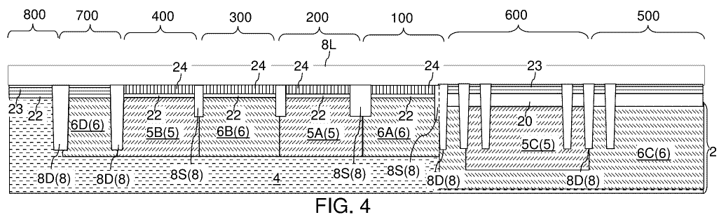

Referring to FIG. 4, at least one trench fill material layer 8L can be conformally deposited in the trenches 7 and over the polish stop plates 23 and the gate electrode material plates 24. The at least one trench fill material layer 8L may consist of at least one dielectric fill material such as silicon oxide, or may include a combination of a dielectric liner (such as a silicon oxide liner) and at least one semiconductor fill material (such as amorphous silicon or polysilicon).

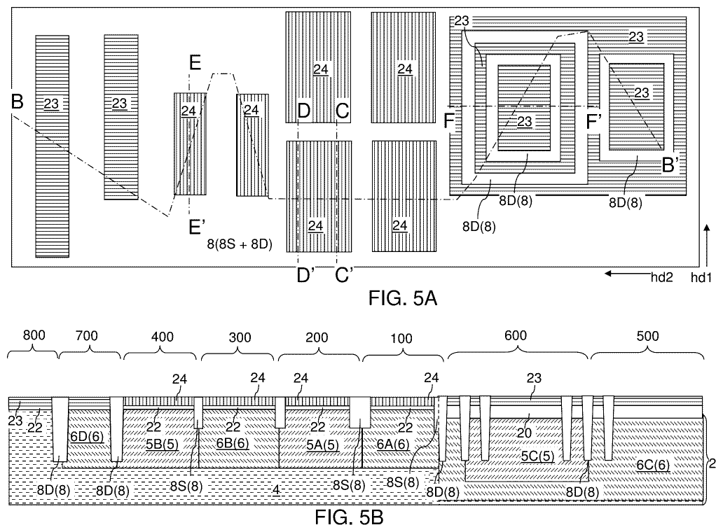

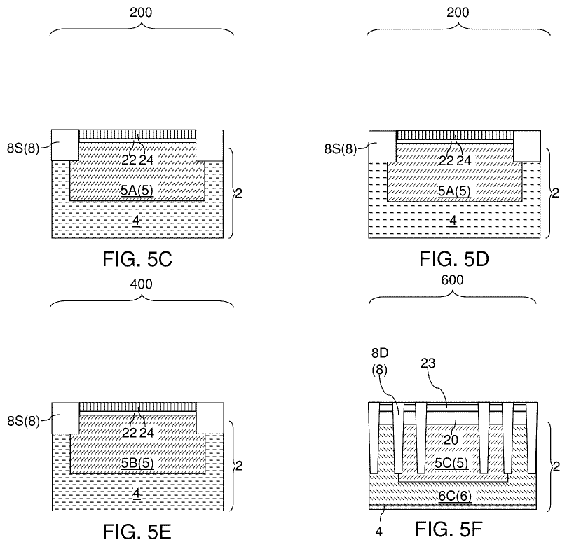

Referring to FIGS. 5A-5F, excess portions of the at least one trench fill material layer 8L can be removed from above the top surface of the polish stop plates 23 and the gate electrode material plates 24 by a planarization process, which may include a chemical mechanical polishing (CMP) process. The CMP process stops on the polish stop plates 23 and optionally on the gate electrode material plates 24 if they are exposed between the polish stop plates 23. The polish stop plates 23 located above the gate electrode material plates 24 may be removed during the CMP process, and the polish stop plates 23 located in other regions are thinned by the CMP process and/or completely or partially stripped by a selective etch, such as hot phosphoric acid etch.

The remaining portions of the at least one trench fill material layer 8L filling the trenches 7 constitute trench isolation structures 8, which may be a continuous structure contacting the semiconductor material of the semiconductor substrate 2 with dielectric surfaces and providing electrical isolation between adjacent semiconductor devices to be subsequently formed. The trench isolation structures 8 include deep trench isolation structures 8D located in the deep trenches 7D and shallow trench isolation structures 8S located in the shallow trenches 7S.

Generally, a trench isolation structure 8 can be formed through the plates (23L, 24L) and the gate dielectric layers (22L, 20L). Patterned portions of the semiconductor material layer 24L and the first gate dielectric layer 22L comprise stacks of a gate dielectric plate 22 and a gate electrode material plate 24 that is laterally surrounded by a respective portion of the trench isolation structure 8.

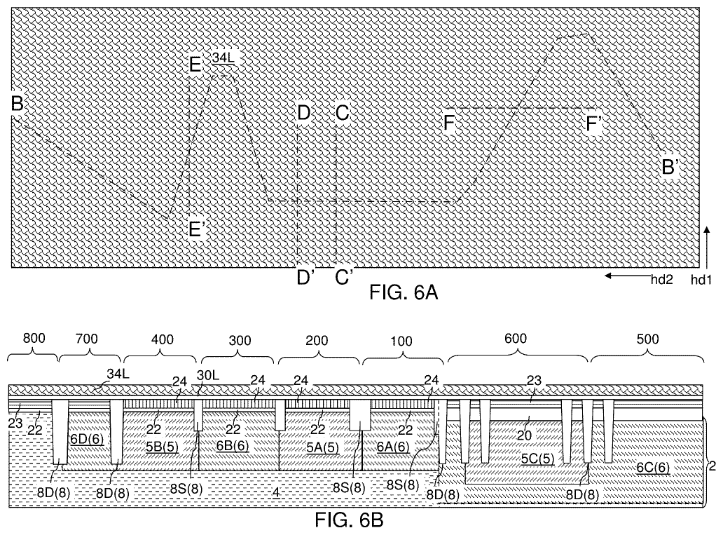

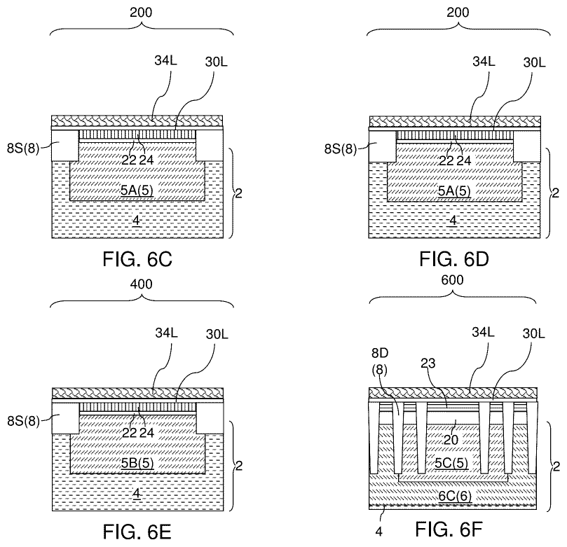

Referring to FIGS. 6A-6F, a planar dielectric spacer layer 30L and a planar semiconductor spacer layer 34L can be deposited over the gate electrode material plates (24, 23) and the trench isolation structure 8. The planar dielectric spacer layer 30L includes a dielectric material such as silicon oxide, and can be deposited by a conformal or non-conformal deposition process. The thickness of the planar dielectric spacer layer 30L may be in a range from 3 nm to 30 nm, although lesser and greater thicknesses may also be employed. The planar semiconductor spacer layer 34L includes a semiconductor material such as polysilicon, a silicon-germanium alloy, or a compound semiconductor material. The thickness of the planar semiconductor spacer layer 34L can be in a range from 30 nm to 300 nm, such as from 60 nm to 150 nm, although lesser and greater thicknesses may also be employed.

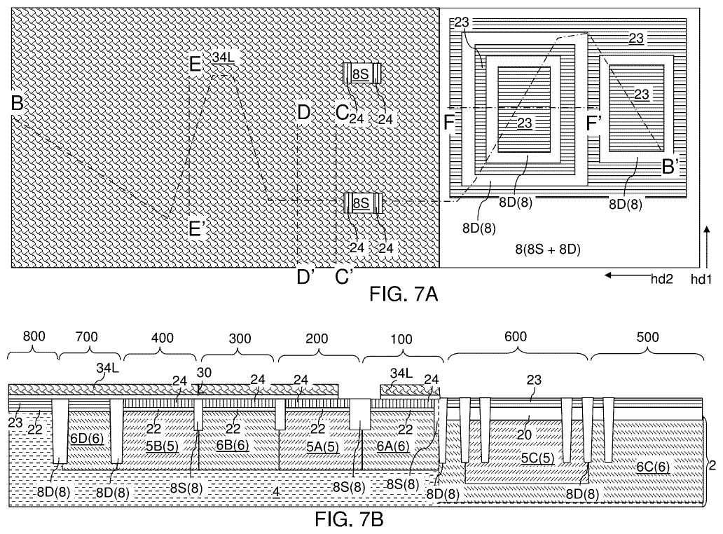

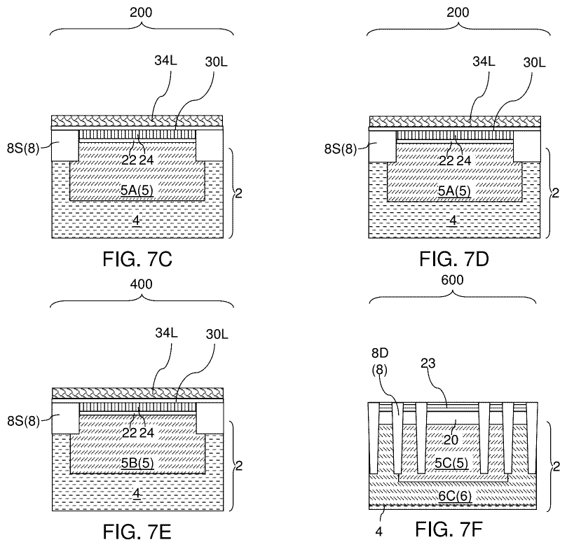

Referring to FIGS. 7A-7F, a photoresist layer (not shown) can be applied over the first exemplary structure, and can be lithographically patterned to form openings over areas of interfaces between the first p-type wells 5A and the trench isolation structure 8 and over areas of interfaces between the first n-type wells 6A and the trench isolation structure 8. Specifically, the openings in the photoresist layer can be formed in areas including interfaces between channel regions of the low voltage field effect transistors to be subsequently formed in the first p-type field effect transistor region 100 and in the first n-type field effect transistor region 200. Further, the photoresist layer can be removed from areas in which high voltage field effect transistors employing thick gate dielectrics are to be subsequently formed, such as the areas of the third p-type field effect transistor region 500 and the third n-type field effect transistor region 600.

An anisotropic etch process can be performed to remove unmasked portions of the planar semiconductor spacer layer 34L and the planar dielectric spacer layer 30L. Top surfaces of the plates 23 and the trench isolation structure 8 can be physically exposed in the third p-type field effect transistor region 500 and the third n-type field effect transistor region 600. In one embodiment, an opening through the planar semiconductor spacer layer 34L and the planar dielectric spacer layer 30L in the first p-type field effect transistor region 100 and in the first n-type field effect transistor region 200 may include an area of a portion of the shallow trench isolation structure 8S, an area of a portion of a first gate electrode material plate 24, and an area of a portion of another first gate electrode material plate 24.

Generally, the planar semiconductor spacer layer 34L and the planar dielectric spacer layer 30L can be patterned employing an etch process that employs an etch mask, such as a patterned photoresist layer. A portion of the top surface of the first semiconductor material layer 24L (comprising a portion of the top surface of a first semiconductor gate material plate 24) is physically exposed by patterning the planar semiconductor spacer layer 34L and the planar dielectric spacer layer 30L. The photoresist layer can be subsequently removed, for example, by ashing.

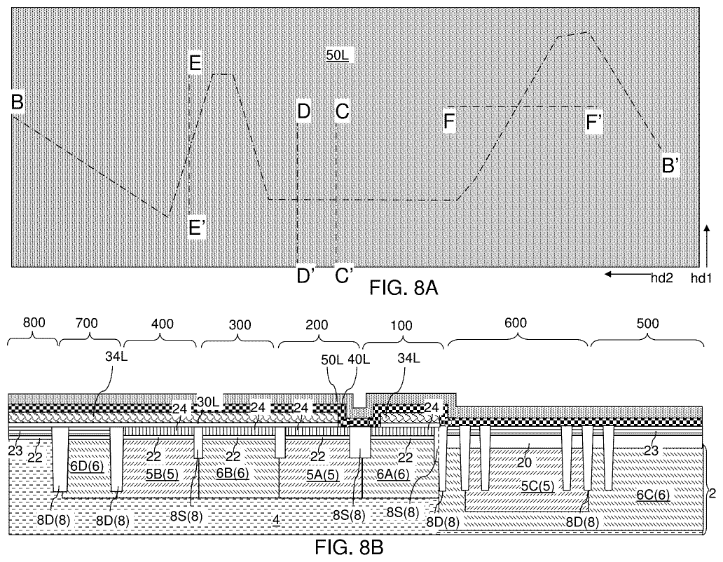

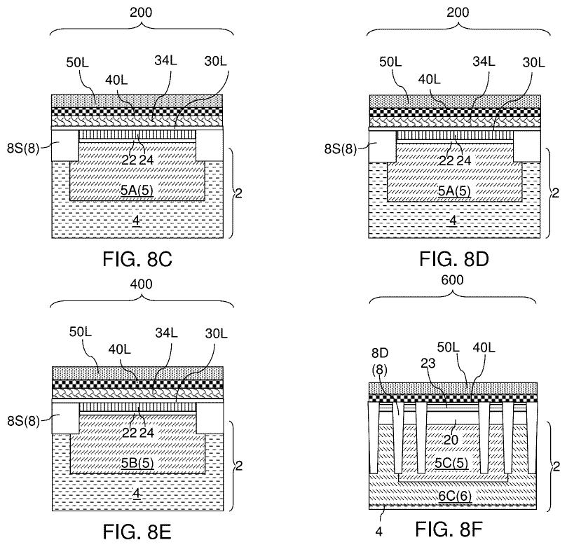

Referring to FIGS. 8A-8F, a conductive gate connection material layer comprising a metallic material can be deposited directly on physically exposed top surfaces plates (23, 24) and the trench isolation structure 8. In one embodiment, the conductive gate connection material layer may comprise a conductive gate cap layer 40L. The conductive gate cap layer 40L can include a metallic material such as an elemental metal (e.g., tungsten and/or titanium), an intermetallic alloy, a conductive metallic nitride (e.g., TiN or WN), a conducive metallic carbide, a heavily doped semiconductor (e.g., heavily doped polysilicon) and/or a conductive metal semiconductor alloy (such as a metal silicide). The thickness of the conductive gate cap layer 40L may be in a range from 20 nm to 200 nm, such as from 40 nm to 100 nm, although lesser and greater thicknesses may also be employed. Generally, the conductive gate cap layer 40L can be deposited over the planar semiconductor spacer layer 34L and directly on the top surfaces of remaining portions of the layers (23L, 24L), i.e., directly on the top surfaces of the plates (23, 24).

A gate cap dielectric layer 50L can be subsequently deposited over the conductive gate cap layer 40L. The gate cap dielectric layer 50L includes a dielectric material, such as silicon nitride. The thickness of the gate cap dielectric layer 50L can be in a range from 20 nm to 100 nm, such as from 30 nm to 50 nm, although lesser and greater thicknesses may also be employed.

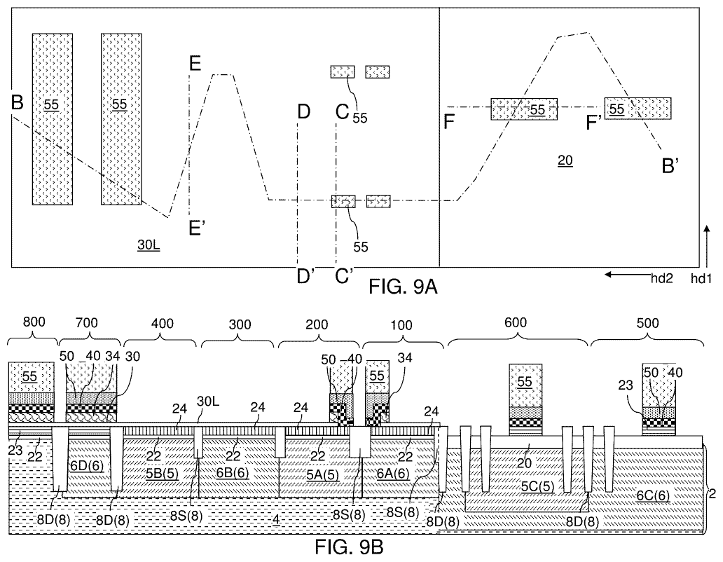

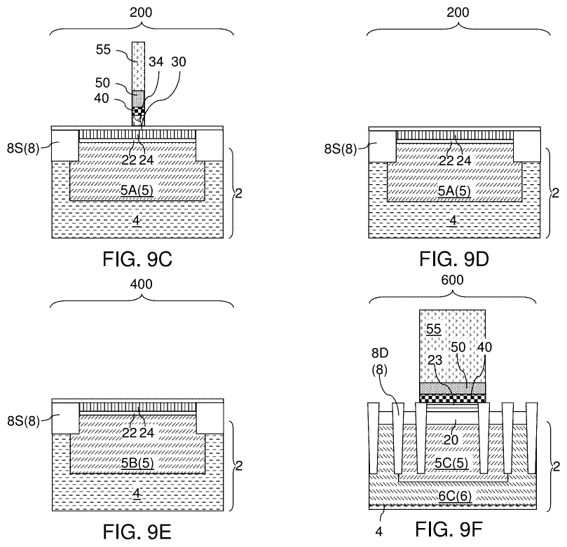

Referring to FIGS. 9A-9F, a first photoresist layer 53 can be applied over the first exemplary structure, and can be lithographically patterned to form discrete patterned photoresist material portions. The patterned portions of the first photoresist layer 53 can include first portions that overlie an edge of the planar semiconductor material layer 34L in the first p-type field effect transistor region 100 and in the first n-type field effect transistor region 200. The patterned portions of the first photoresist layer 53 can include second portions that define the shapes of gate electrodes to be formed in the third p-type field effect transistor region 500 and in the third n-type field effect transistor region 600. The patterned portions of the first photoresist layer 53 can include additional portions that cover a respective area within the first passive device region 700 and in the second passive device region 800.

A first anisotropic etch process can be performed to transfer the pattern in the first photoresist layer 53 through the gate cap dielectric layer 50L, the conductive gate cap layer 40L, the planar semiconductor spacer layer 34L, and portions of the plates 23 located outside the areas of the planar dielectric spacer layer 30L, which include portions of plates 23 located within the third p-type field effect transistor region 500 and the third n-type field effect transistor region 600. The planar dielectric spacer layer 30L, the second gate dielectric plate 20, and the trench isolation structure 8 can function as etch stop structures for the first anisotropic etch process. In case the planar dielectric spacer layer 30L, the second gate dielectric plate 20, and the trench isolation structure 8 comprise silicon oxide, the etch chemistry of the terminal step of the first anisotropic etch process can etch the semiconductor materials of the planar semiconductor spacer layer 34L and the plates 23 selective to silicon oxide.

Each patterned portion of the gate cap dielectric layer 50L comprises a gate cap dielectric 50. Each patterned portion of the conductive gate cap layer 40L comprises a conductive gate cap structure 40. Each patterned portion of the planar semiconductor spacer layer 34L comprises a planar semiconductor spacer plate 34.

A contiguous combination of a first gate cap dielectric 50, a first conductive gate cap structure 40, and a first planar semiconductor spacer plate 34 can be formed on a top surface of each gate electrode material plate 24 in the first p-type field effect transistor region 100 and/or in the first n-type field effect transistor region 200. In this case, the first conductive gate cap structure 40 can be formed on the physically exposed top surface of a portion of the first gate electrode material plate 24. According to an aspect of the present disclosure, a first conductive gate cap structure 40 in the first p-type field effect transistor region 100 or in the first n-type field effect transistor region 200 comprises a first segment that contacts portion of the top surface of an underlying gate electrode material plate 24; a second segment that overlies the first planar dielectric spacer layer 34L; and a connecting segment that contacts a first sidewall of the first planar dielectric spacer layer 34L and connecting the first segment and the second segment.

According to an aspect of the present disclosure, a portion of the first conductive gate cap structure 40 covers a portion of a top surface of an underlying portion of the shallow trench isolation structure 8, and a portion of a bottom surface of the first conductive gate cap structure 40 contacts the portion of the top surface of the underlying portion of the shallow trench isolation structure 8. A first sidewall of the first planar semiconductor spacer plate 34 overlies, and is vertically coincident with, the first sidewall of the planar dielectric spacer layer 30L, and contacts the connecting segment of the first conductive gate cap structure 40. The first planar semiconductor spacer plate 34 can be formed on a top surface of the planar dielectric spacer layer 30L while a semiconductor gate plate 24 (i.e., a portion of the semiconductor material layer 24L) is covered with the planar dielectric spacer layer 30L. The first conductive gate cap structure 40 is formed directly on the first planar semiconductor spacer plate 34. The first photoresist layer 53 can be subsequently removed, for example, by ashing.

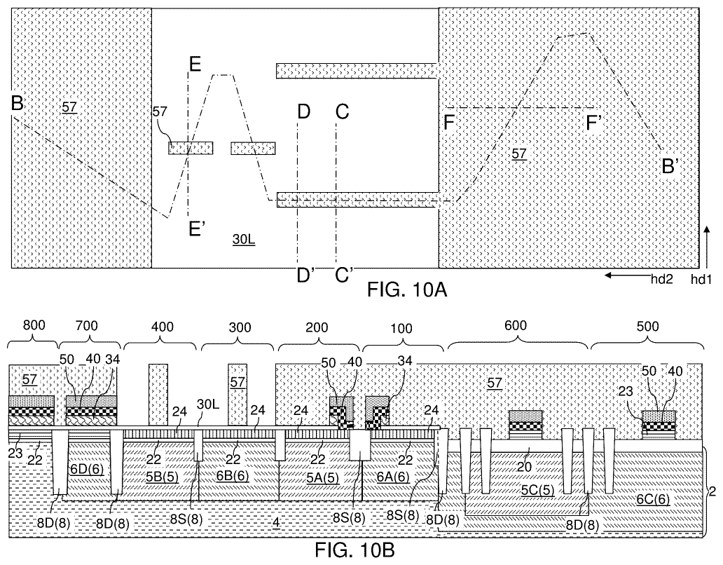

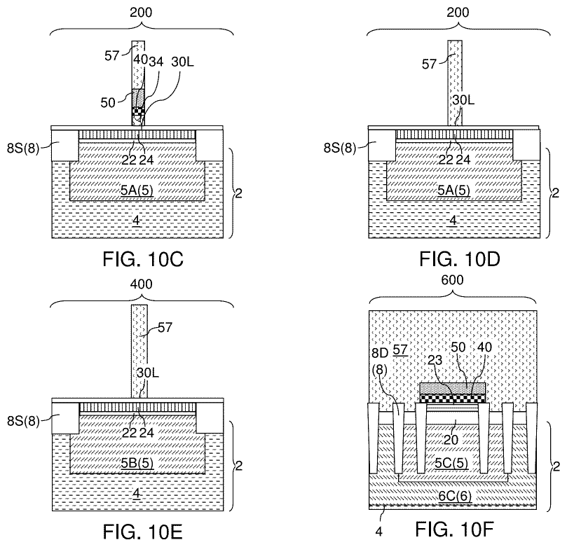

Referring to FIGS. 10A-10F, a second photoresist layer 57 can be applied over the first exemplary structure, and can be lithographically patterned to provide patterned photoresist material portions having the shapes of gate electrodes to be subsequently formed in the first p-type field effect transistor region 100, the first n-type field effect transistor region 200, the second p-type field effect transistor region 300, and the second n-type field effect transistor region 400. In one embodiment, the areas of the patterned portions of the second photoresist layer 57 may include the entirety of the areas of the patterned portions of the first photoresist layer 53 that is employed at the processing steps of FIGS. 9A-9F. The second photoresist layer 57 may cover the entirety of the areas of the third p-type field effect transistor region 500, the third n-type field effect transistor region 600, and the passive device regions (700, 800).

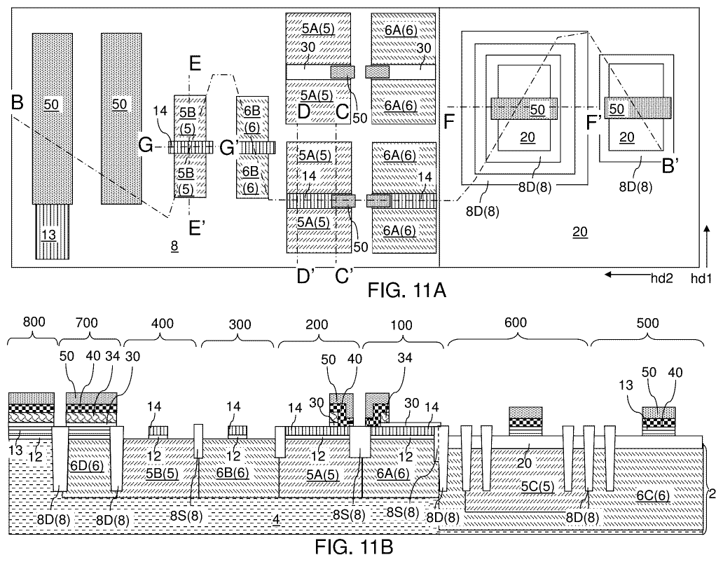

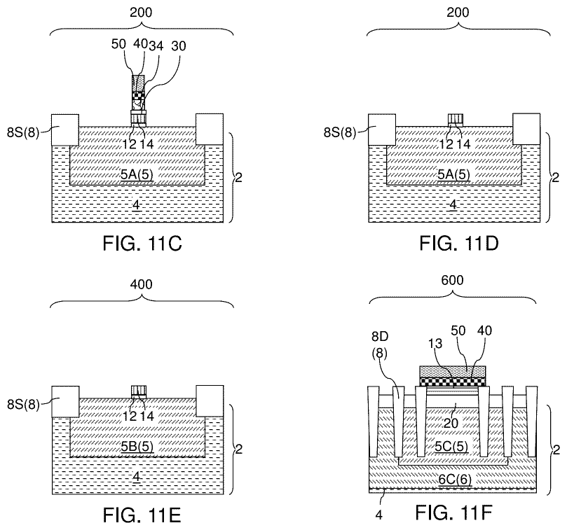

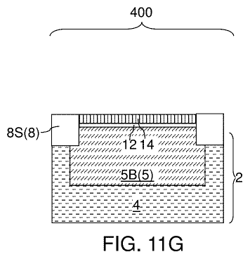

Referring to FIGS. 11A-11G, a second anisotropic etch process can be performed to transfer the pattern of the second photoresist layer 57 through the planar dielectric spacer layer 30L, the polish stop plates 23, the gate electrode material plates 24, and the first gate dielectric plates 22. Each patterned portion of the planar dielectric spacer layer 30L constitutes a planar dielectric spacer plate 30. Each patterned portion of the polish stop plates 23 constitutes dielectric portion 13. The dielectric portions 13 may comprise silicon nitride portions, which function as part of a composite silicon nitride/silicon oxide gate dielectric (13, 20) in the high voltage transistors in regions 500 and 600. Each patterned portion of the gate electrode material plates 24 constitutes a gate electrode 14. Each patterned portion of the first gate dielectric plates 22 constitutes a first gate dielectric 12. The terminal portion of the second anisotropic etch process may be selective to the to the semiconductor material of the semiconductor substrate 2. The second photoresist layer 57 can be subsequently removed, for example, by ashing.

Generally, stacks of a first gate dielectric plate 22 and a gate electrode material plate 24 can be patterned into a stack of a first gate dielectric 12 and a first gate electrode 14. The gate electrode material plate 24 is patterned into the gate electrode 14 by the second anisotropic etch process employing the photoresist layer 57 as a patterned etch mask. The first gate dielectric plate 22 and the planar dielectric spacer layer 30L can be patterned into the first gate dielectric 12 and a first planar dielectric spacer plate 30, respectively, by a same etch process such as the second anisotropic etch process.

A first planar dielectric spacer plate 30 covers a first portion of a top surface of the gate electrode 14 upon patterning the first gate electrode material plate 24 into the first gate electrode 14. A first portion of a top surface of the gate electrode 14 contacts a bottom surface of the first planar dielectric spacer plate 30. A first conductive gate cap structure 40 comprises a first segment that contacts a second portion of the top surface of the gate electrode 14 a second segment that overlies the first planar dielectric spacer plate 30, and a connecting segment that contacts a first sidewall of the first planar dielectric spacer plate 30 and connecting the first segment and the second segment.

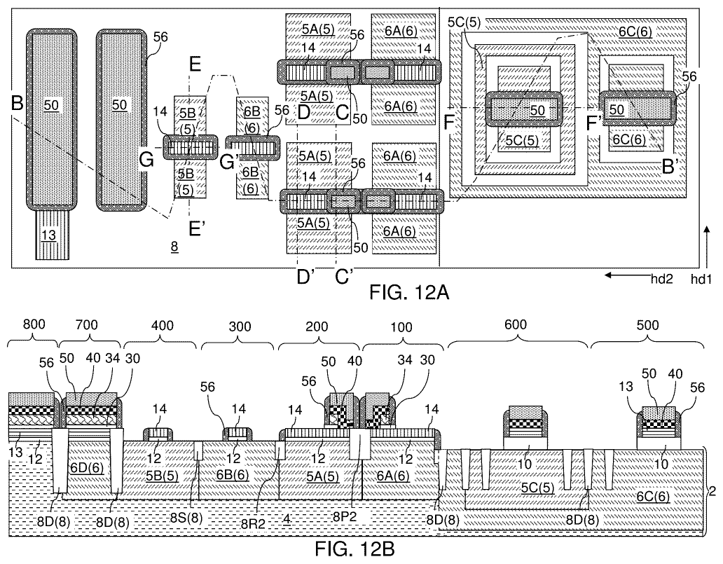

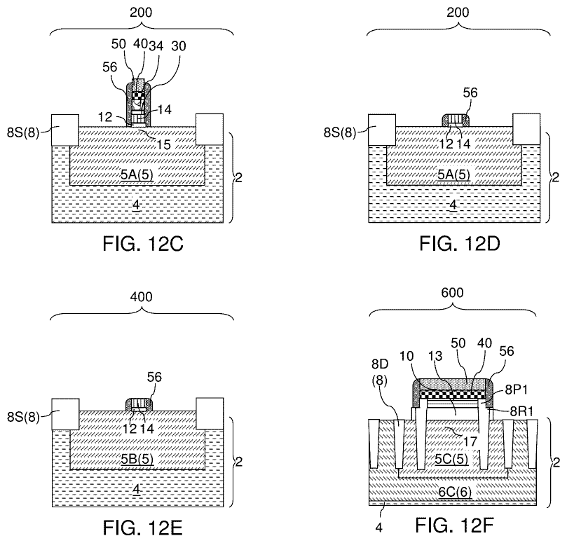

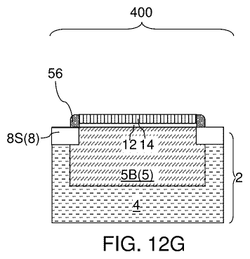

Referring to FIGS. 12A-12G, source/drain extension regions (not shown) can be optionally formed by implantation of p-type dopants and n-type dopants employing a respective patterned implantation mask layer (such as a patterned photoresist layer) and a respective ion implantation process. A dielectric gate spacer material layer including a dielectric material can be deposited by a conformal deposition process such as a chemical vapor deposition process. The dielectric material of the dielectric gate spacer material layer may include, for example, silicon nitride and/or silicon oxide. An anisotropic etch process can be performed to etch horizontally-extending portions of the dielectric gate spacer material layer. Remaining vertically-extending portions of the dielectric gate spacer material layer constitute dielectric gate spacers 56.

The anisotropic etch process may be extended to etch unmasked portions of the dielectric materials of the second gate dielectric plates 20 and the trench isolation structures 8 selective to the materials of the gate electrodes 14. In this case, the second gate dielectric plates 20 can be patterned into second gate dielectrics 10 (which may comprise portions of a composite silicon nitride/silicon oxide gate dielectrics (10, 13) for the high voltage transistors in regions 500 and 600), and the physically exposed top surfaces of the trench isolation structures 8 can be vertically recessed. In one embodiment, an outer sidewall of each second gate dielectric 10 can be vertically coincident with an outer sidewall of a respective one of the dielectric gate spacers 56. As used herein, a first surface and a second surface are vertically coincident with each other if the first surface and the second surface overlie or underlie each other, and are located within a same vertical plane. In one embodiment, the recessed portions of the top surfaces of the trench isolation structure 8 may be at, or about, the height of the top surfaces of the third doped wells (5C, 5D) in the third field effect transistor regions (500, 600).

In one embodiment, a first dielectric gate spacer 56 located within a first field effect transistor region (100 or 200) comprises an upper portion that laterally surrounds and contacts a first conductive gate cap structure 40 and the planar semiconductor spacer plate 34, and contacts a portion of a top surface of the first planar dielectric spacer plate 30. The first dielectric gate spacer 56 contacts a first sidewall of the first semiconductor spacer plate 34 that is vertically coincident with a first sidewall of the first planar dielectric spacer plate 30, and a second sidewall of the first planar semiconductor spacer plate 34 that is laterally offset from a second sidewall of the first planar dielectric spacer plate 34. An outer sidewall of the first dielectric gate spacer 56 can be vertically coincident with the second sidewall of the first planar dielectric spacer plate 30.

The first planar semiconductor spacer plate 34 can contact a top surface of the first planar dielectric spacer plate 30, can have a lesser area than the first planar dielectric spacer plate 30, and can contact a bottom surface of the second segment of the first conductive gate cap structure 40 that overlies the stack of the first planar dielectric spacer plate 30 and the first planar semiconductor spacer plate 34. A portion of the first conductive gate cap structure 40 covers a top surface of a first portion of the shallow trench isolation structure 8 that surrounds a portion of a first doped well (5A or 6A) that underlies a gate structure (12, 14, 30, 34, 40, 50) and the first dielectric gate spacer 56. As shown in FIG. 12F, a segment 8P1 of the first portion of the deep trench isolation structure 8D that underlies the first conductive gate cap structure 40 protrudes above a horizontal top surface of a recessed region 8R1 of the first portion of the deep trench isolation structure 8D because the first conductive gate cap structure 40 masks the protruding segment 8P of the first portion of the deep trench isolation structure 8D during the anisotropic etch process that vertically recesses unmasked portions of the trench isolation structure 8. Likewise, as shown in FIG. 12B, a segment 8P2 of the first portion of the shallow trench isolation structure 8S that underlies the first conductive gate cap structure 40 protrudes above a horizontal top surface of a recessed region 8R2 of the first portion of the shallow trench isolation structure 8S.

A first gate structure (12, 14, 30, 34, 40, 50) including a first gate dielectric 12, a first gate electrode 14, a first planar dielectric spacer plate 30, and a first conductive gate cap structure 40 overlies a first channel region 15 of a first (e.g., low voltage or very low voltage) field effect transistor in regions 100 and 200, as shown in FIG. 12C. The first channel region 15 can be a surface portion of a doped well (5, 6) that has an areal overlap with the first gate structure (12, 14, 30, 34, 40, 50) in a plan view. In one embodiment, the first gate dielectric 12 and the first gate electrode 14 comprise sidewalls that laterally extend along the first horizontal direction hd1, are vertically coincident with each other, and are laterally spaced from the sidewall of a recessed region 8R2 of a portion of the trench isolation structure 8 that laterally surrounds a portion of a doped well (5, 6), and are vertically coincident with a sidewall of another region of the portion of the trench isolation structure 8.

In one embodiment, the first gate dielectric 12 and the first gate electrode 14 contact a sidewall of a protruding region (i.e., a protruding segment) 8P2 of the portion of the trench isolation structure 8. The sidewall laterally extends along a first horizontal direction hd1. The first planar dielectric spacer plate 30 contacts a first portion of a top surface of the first gate electrode 14, and the first conductive gate cap structure 40 comprises a first segment that contacts a second portion of the top surface of the first gate electrode 14, a second segment that overlies the first planar dielectric spacer plate 30, and a connecting segment that contacts a first sidewall of the first planar dielectric spacer plate 30 and connecting the first segment and the second segment.

In one embodiment, the first gate dielectric 12 comprises a first sidewall that contacts the sidewall of the protruding region 8P2 of the first portion of the trench isolation structure 8. The first gate electrode 14 comprises a first sidewall that contacts the sidewall of the protruding region 8P2 of the first portion of the trench isolation structure 8. A second sidewall of the first gate dielectric 12 and a second sidewall of the first gate electrode 14 that laterally extend along the first horizontal direction hd1 contacts a sidewall of a lower portion of the first dielectric gate spacer 56. Additional sidewalls of the first gate dielectric 12 and the first gate electrode 14 contact additional sidewalls of the lower portion of the first dielectric gate spacer 56 that laterally extends along a second horizontal direction hd2 that is perpendicular to the first horizontal direction hd1.

A second gate structure (10, 13, 40, 50) including a second composite silicon nitride/silicon oxide gate dielectric (13, 10), a second gate electrode 40 (which comprises a second conductive gate cap structure 40) overlies a second channel region 17 of a second (e.g., high voltage) field effect transistor in regions 500 and 600, as shown in FIG. 12F.

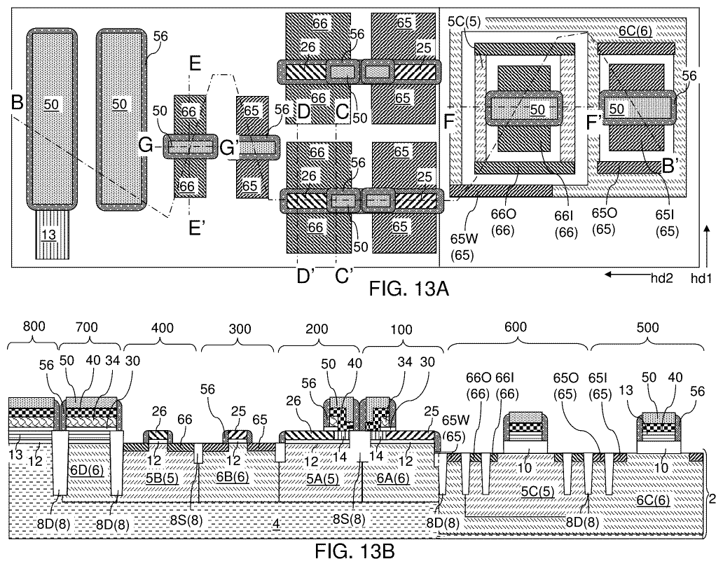

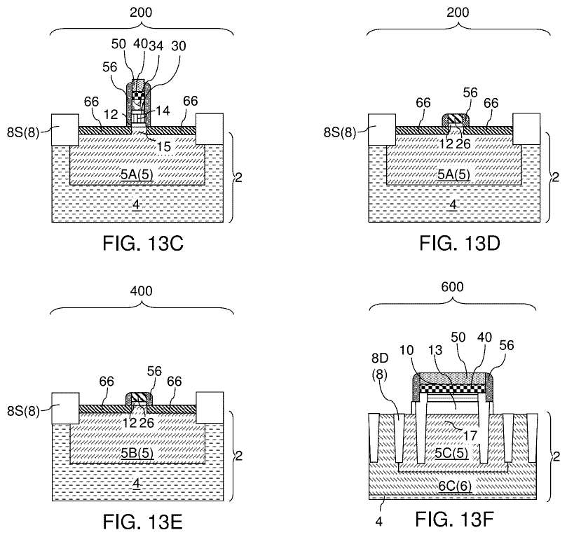

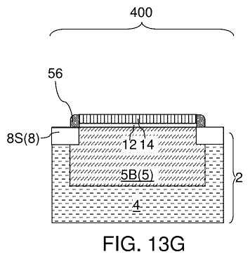

Referring to FIGS. 13A-13G, masked ion implantation processes can be performed to implant p-type dopants within unmasked surface portions of the n-type wells 6, and to implant n-type dopants within unmasked surface portions of the p-type wells 5. A combination of a patterned photoresist layer, the gate structures {(12, 10, 14, 13, 30, 34, 40, 50) and (10, 13, 40, 50)} and the dielectric gate spacers 56 can be employed as a composite implantation mask during each ion implantation process. Source regions and drain regions are formed within the implanted surface portions of the p-doped wells 5 and the n-doped wells 6. The source regions and the drain regions are collectively referred to as source/drain regions (65, 66), which include p-doped source/drain regions 65 that are formed within a respective one of the n-doped wells 6, and n-doped source/drain regions 66 that are formed within a respective one of the p-doped wells 5.

In one embodiment, configurations for increasing the breakdown voltage of field effect transistors may be employed in device regions in which high-voltage field effect transistors are formed such as the third field effect transistor regions (500, 600). In this case, the p-doped source/drain regions 65 may include inner p-doped source/drain regions 651 and outer p-doped source/drain regions 650 that are laterally spaced apart by an additional trench isolation structure 8 (e.g., deep trench isolation structure 8D), which may be disjoined from the trench isolation structure 8 (e.g., shallow trench isolation structure 8S) in the first field effect transistor regions (100, 200). Further, the n-doped source/drain regions 66 may include inner n-doped source/drain regions 661 and outer n-doped source/drain regions 660 that are laterally spaced apart by another additional trench isolation structure 8. Optionally, a well contact source/drain region 65W may be employed to facilitate biasing of a doped well.

In one embodiment, gate electrodes 14 located within the low and very low voltage field effect transistor regions (100, 200, 300, 400) may be doped with p-type dopants or n-type dopants to form doped gate electrodes (25, 26) that are doped with p-type dopants or n-type dopants. The doped gate electrodes (25, 26) include p-doped second gate electrodes 25 formed in the p-type field effect transistor regions (100, 300) and n-doped second gate electrodes 26 formed in the n-type field effect transistor regions (200, 400). Alternatively or in addition, the polysilicon gate electrodes 14 and/or heavily doped semiconductor (e.g., heavily doped polysilicon) conductive gate cap structures 40 may be silicided by forming a metal on the polysilicon 14 and annealing the metal to form a metal silicide on the exposed top surfaces of the polysilicon.

Generally, various field effect transistors having different gate dielectric thicknesses, different gate lengths (i.e., different lateral distances between a source region and a drain region), and different configurations can be formed in the various field effect transistor regions (100, 200, 300, 400, 500, 600).

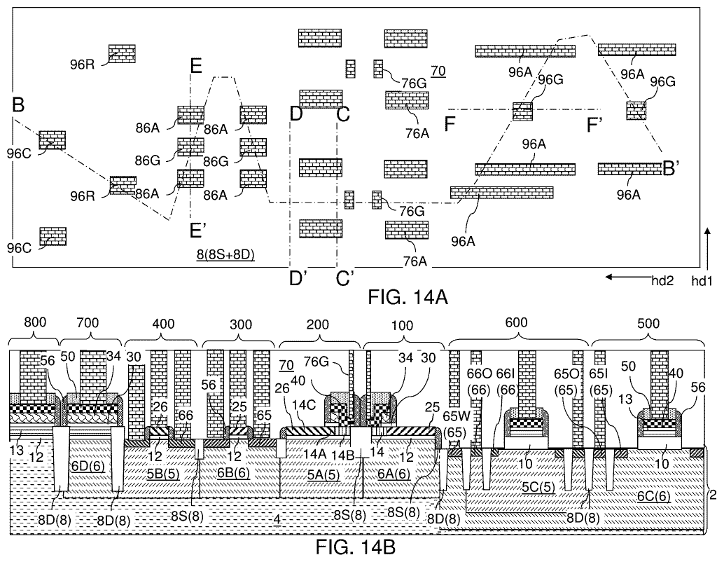

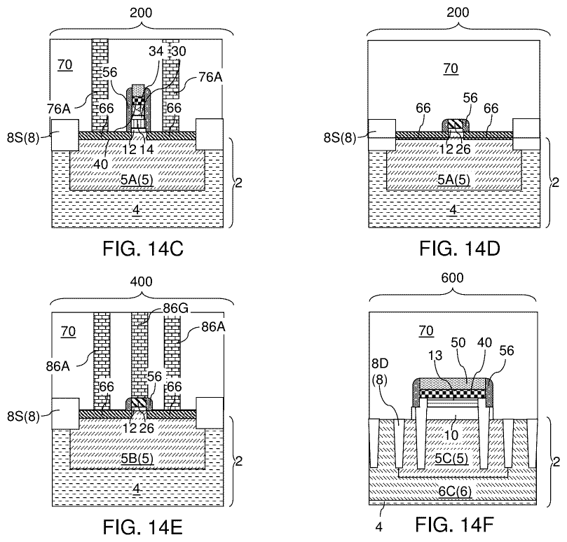

Referring to FIGS. 14A-14F, a contact-level dielectric layer 70 and various contact via structures (76A, 76G, 86A, 86G, 96A, 96G, 96R, 96C) can be subsequently formed. The contact-level dielectric layer 70 includes a dielectric material such as silicon oxide, and can be formed by a conformal or non-conformal deposition process. The top surface of the contact-level dielectric layer 70 can be planarized by a planarization process such as a chemical mechanical polishing (CMP) process. The vertical distance between the topmost surfaces of the gate cap dielectrics 50 and the top surface of the contact-level dielectric layer 70 can be in a range from 30 nm to 500 nm, although lesser and greater vertical distances may also be employed.

The contact-level dielectric layer 70 overlies and laterally surrounds each of the field effect transistors. In one embodiment shown in FIG. 13B, a first portion 14A of the top surface of a first gate electrode (14, 26) of a first field effect transistor in a first transistor region (100, 200) contacts a first planar dielectric spacer plate 30, a second portion 14B of the top surface of a first gate electrode 14 contacts a lower portion of the conductive gate cap structure 40, and the contact-level dielectric layer 70 can contact a third portion 14C of the top surface of the first gate electrode (14, 26). The third portion 14C of the top surface of the first gate electrode 14 can be laterally spaced from the second portion 14B of the top surface of the first gate electrode 14 by the first portion 14A of the top surface of the first gate electrode 14.

The contact via structures (76A, 76G, 86A, 86G, 96A, 96G, 96R, 96C) comprise first source/drain region contact via structures 76A contacting source/drain regions (65, 66) within the first field effect transistor regions (100, 200), as shown in FIG. 14C, first gate contact via structures 76G contacting top surfaces of the lower portions of the conductive gate cap structures 40 which are laterally offset from the semiconductor plates 34 within the first field effect transistor regions (100, 200), second source/drain region contact via structures 86A contacting source/drain regions (65, 66) within the second field effect transistor regions (300, 400), second gate contact via structures 86G contacting the second gate electrodes (25, 26) within the second field effect transistor regions (300, 400), third source/drain region contact via structures 96A contacting source/drain regions (65, 66) within the third field effect transistor regions (500, 600), and third gate contact via structures 96G contacting top surfaces of conductive gate cap structures 40 within the third field effect transistor regions (500, 600). Further, the contact via structures (76A, 76G, 86A, 86G, 96A, 96G, 96R, 96C) can comprise first passive device contact via structures 96R that contact first passive devices such as resistors, and second passive device contact via structures 96C that contact second passive devices such as capacitors.

Generally, a first field effect transistor can be formed in a first field effect transistor region (100 or 200). The first field effect transistor comprises a first active region having a pair of lengthwise sidewalls and a pair of widthwise sidewalls that contact sidewalls of and are laterally surrounded by a first portion of a trench isolation structure 8. The first active region comprises a first source region, a first drain region, and a first channel region located between the first source region and the first drain region. The first field effect transistor can comprise a first gate structure (12, 14, 25 or 26, 30, 34, 40, 50).

A second field effect transistor can be formed in a second field effect transistor region (300 or 400). The second field effect transistor comprises a second active region having a pair of lengthwise sidewalls and a pair of widthwise sidewalls that contact sidewalls of and are laterally surrounded by a second portion of the trench isolation structure 8. A second gate structure (12, 25 or 26) including a second gate dielectric 12 and a second gate electrode (25 or 26) overlies the second active region. The contact-level dielectric layer 70 overlies the first gate structure (12, 14, 25 or 26, 30, 34, 40, 50) and the second gate structure (12, 25 or 26). At least one gate contact structure (such as a second gate contact via structures 86G) is in contact with a portion of a top surface of the second gate electrode (25 or 26). An entirety of the top surface of the second gate electrode (25 or 26) that is not in contact with the at least one gate contact structure 86G is in contact with the contact-level dielectric layer 70.

The first exemplary structure can comprise an additional field effect transistor such as a third field effect transistor formed in a third field effect transistor region (500 or 600). The additional field effect transistor comprises an additional active region having a pair of lengthwise sidewalls and a pair of widthwise sidewalls that contact sidewalls of and are laterally surrounded by an additional portion of the trench isolation structure 8. The additional field effect transistor comprises an additional gate structure (10, 13, 40, 50) overlies the additional active region. The additional gate structure (10, 13, 40, 50) can include an additional composite gate dielectric comprising a silicon oxide sublayer 10 having a greater thickness than the first gate dielectric 12, and a silicon nitride sublayer 13, and an additional conductive gate cap structure 40 having a same thickness and a same material composition as the first segment of the first conductive gate cap structure 40. An entirety of a top surface of the silicon nitride portion 13 is in contact with a bottom surface of the additional conductive gate cap structure 40.

In one embodiment, the first exemplary structure may further comprise a passive device, which may be selected from a capacitor, a resistor, or any other passive device known in the art. The passive device comprises a layer stack including, from bottom to top, a first dielectric layer (such as another instance of a silicon oxide gate dielectric 12 and a silicon nitride portion 13), a second dielectric layer (such as a planar dielectric spacer plate 30), a semiconductor plate (such as a planar semiconductor spacer plate 34), and a metallic plate (such as a conductive gate cap structure 40). The second dielectric layer has a same material composition and a same thickness as the first planar dielectric spacer plate 30. The metallic plate has a same material composition and a same thickness as the first segment of the first conductive gate cap structure 40.

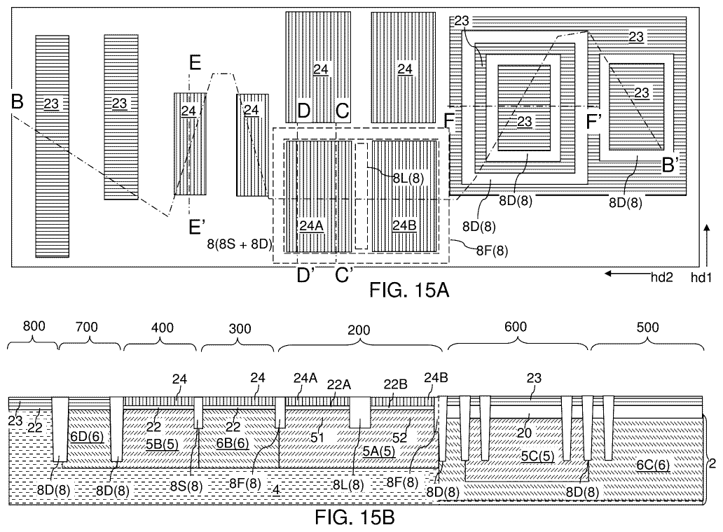

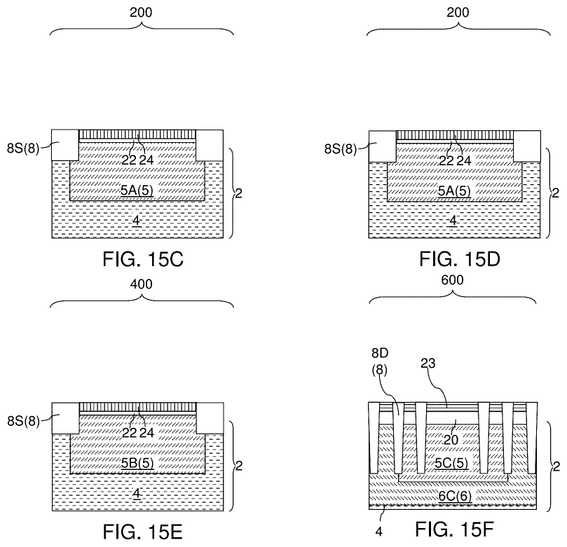

Referring to FIGS. 15A-15F, a second exemplary structure according to a second embodiment of the present disclosure may be derived from the first exemplary structure of FIGS. 5A-5F by rearranging and/or omitting a subset of the doped wells (5, 6). For example, the first p-doped wells 5A may extend into areas occupied by the first n-doped wells 6A in region 100 in the first embodiment. Alternatively, the first n-doped wells 6A may extend into areas occupied by the first p-doped wells 5A in region 200 in the first embodiment. In the configuration shown in FIG. 15B, the first p-doped wells 5A can be formed such that a plurality of active regions laterally surrounded by a respective portion of the trench isolation structure 8 is provided within the first n-type field effect transistor region 200. The first p-type field effect transistor region 100 is not illustrated for the drawings of the second exemplary structure, but may be present within the second exemplary structure. While the present disclosure is described employing an embodiment in which pairs of active regions are present within the first n-type field effect transistor region 200, embodiments are expressly contemplated herein in which pairs of active regions are present within the first p-type field effect transistor region 100 and field effect transistors having the same geometrical features are formed in the first p-type field effect transistor region 100. In other words, the devices of the present disclosure may be formed with opposite conductivity types.

Generally, at least one gate dielectric layer and at least one semiconductor material layer over a semiconductor material layer within the semiconductor substrate 2, and a trench isolation structure 8 can be formed through the at least one semiconductor material layer and the at least one gate dielectric layer. As shown in FIGS. 15A and 15B, patterned portions of the at least one semiconductor material layer and the at least one gate dielectric layer comprise a first stack (22A, 24A) of a first gate dielectric plate 22A and a first gate electrode material plate 24A overlying a first active region 51 of the semiconductor material layer, and a second stack (22B, 24B) of a second gate dielectric plate 22B and a second gate electrode material plate 24B overlying a second active region 52 of the semiconductor material layer.

The first stack (22A, 24A) and the second stack (22B, 24B) can be located within a same field effect transistor region such as the first n-type field effect transistor region 200. The trench isolation structure 8 comprises a frame portion 8F that laterally surrounds the first active region 51 and the second active region 52 continuously. A laterally-extending portion 8L of the trench isolation structure 8 can be located between the first active region 51 and the second active region 52.

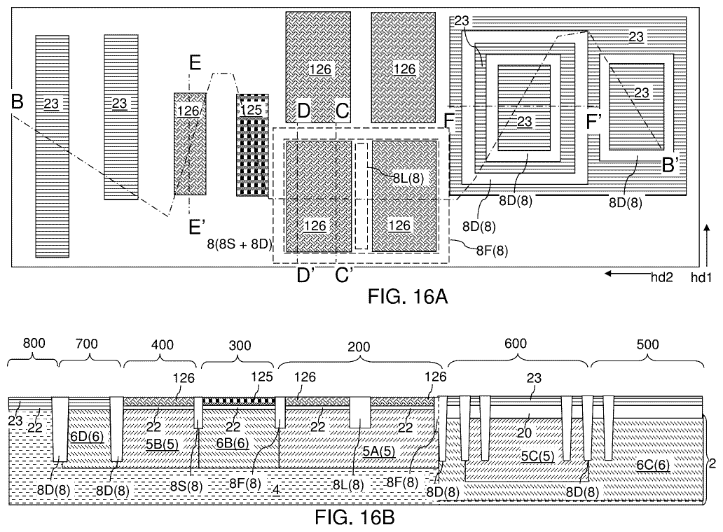

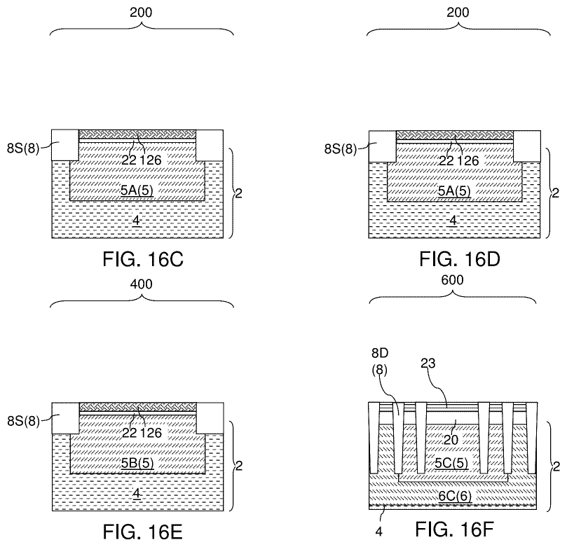

Referring to FIGS. 16A-16F, masked ion implantation processes can be performed to dope any portion of the gate electrode material plates 24 with suitable conductivity types. In an illustrative example, n-doped gate electrode material plates 126 can be formed in the first and second n-type field effect transistor regions (200, 400) and p-doped gate electrode material plates 125 can be formed in the second p-type field effect transistor region 300 and in the first p-type field effect transistor region (not shown).

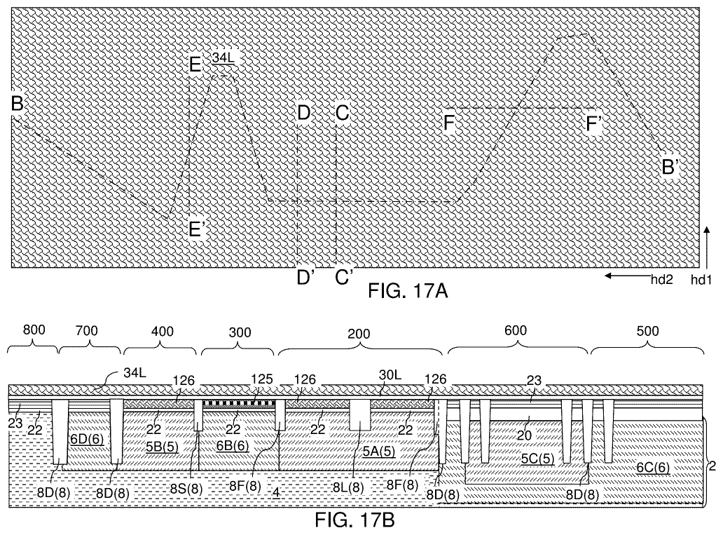

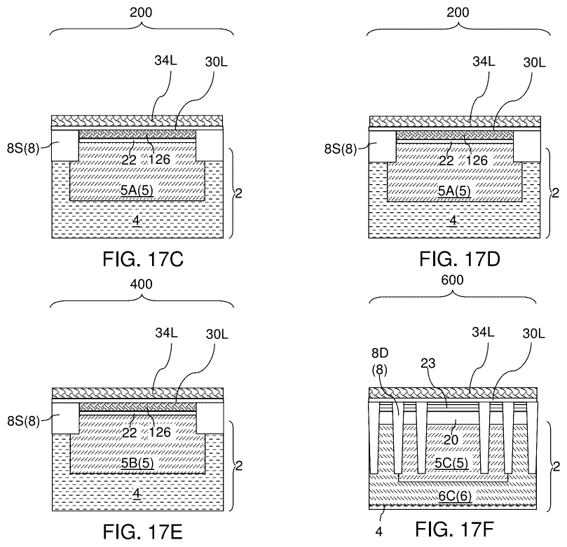

Referring to FIGS. 17A-17F, the processing steps of FIGS. 6A-6F can be performed to form a planar dielectric spacer layer 30L and a planar semiconductor spacer layer 34L over the top surfaces of the gate electrode material plates (125, 126), plates 23 and the trench isolation structure 8. The thickness and the material composition of each of the planar dielectric spacer layer 30L and the planar semiconductor spacer layer 34L may be the same as in the first exemplary structure.

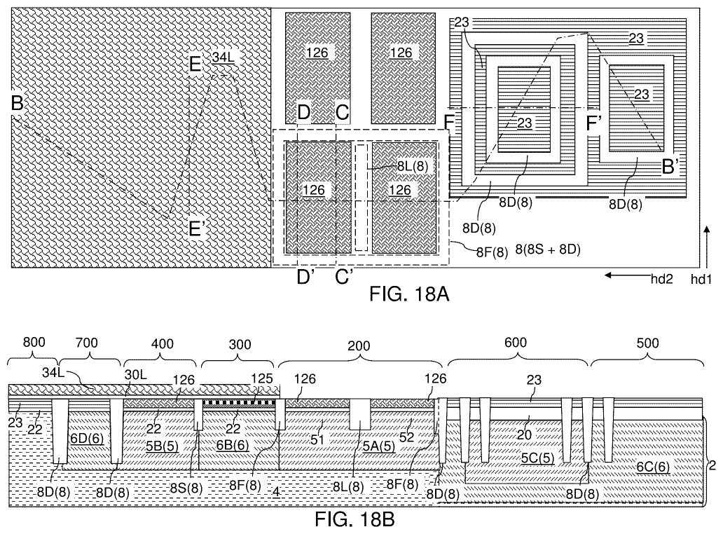

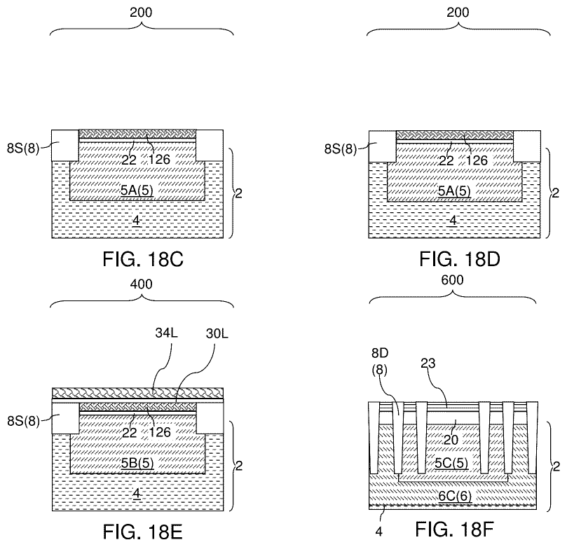

Referring to FIGS. 18A-18F, the processing steps of FIGS. 7A-7F can be performed to pattern the planar dielectric spacer layer 30L and the planar semiconductor spacer layer 34L. In the second embodiment, the planar dielectric spacer layer 30L and the planar semiconductor spacer layer 34L can be patterned such that the planar dielectric spacer layer 30L and the planar semiconductor spacer layer 34L remain in the second field effect transistor regions (300, 400) and in the passive device regions (700, 800), and are removed from the first field effect transistor regions (100, 200) and the third field effect transistor regions (500, 600). In this case, a first active region and a second active region may be provided within the first n-type field effect transistor region 200, and remaining portions of the planar dielectric spacer layer 30L and the planar semiconductor spacer layer 34L can be located outside areas of the first active region 51 and the second active region 52.

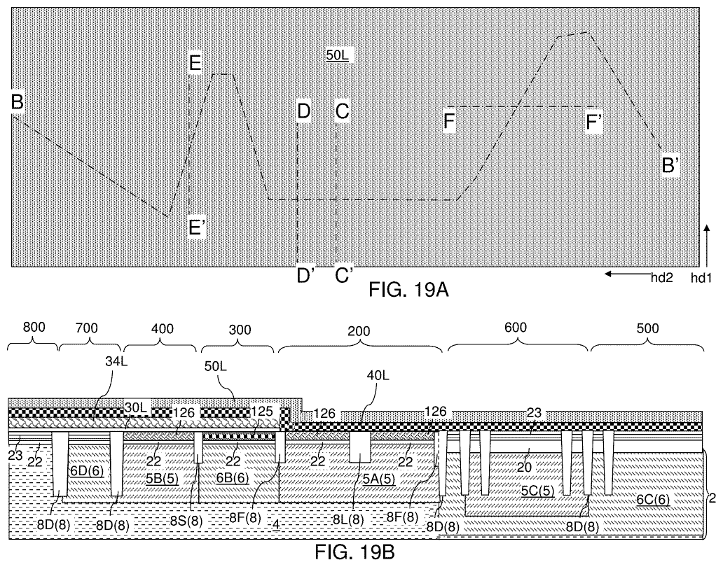

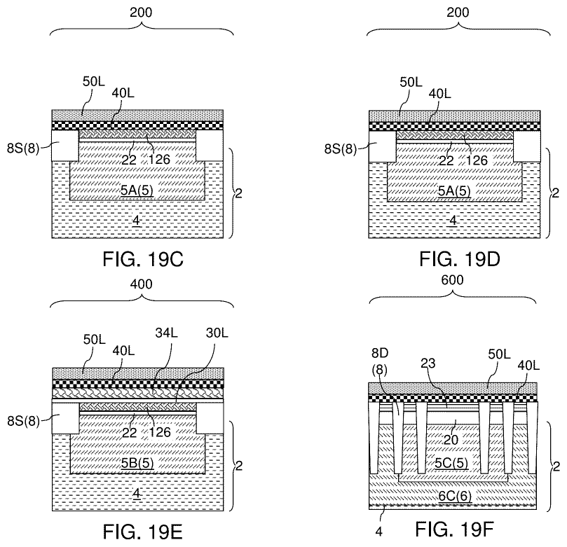

Referring to FIGS. 19A-19F, the processing steps of FIGS. 8A-8F can be performed to deposit a conductive gate connection material layer comprising a metallic material directly on physically exposed top surfaces of the gate electrode material plates 126, the plates 23 and the trench isolation structure 8 and over the planar semiconductor spacer layer 34. In one embodiment, the conductive gate connection material layer may comprise a conductive gate cap layer 40L, which can have the same material composition and the same thickness range as in the first exemplary structure. A gate cap dielectric layer 50L can be subsequently deposited over the conductive gate cap layer 40L. The gate cap dielectric layer 50L includes a dielectric material such as silicon nitride.

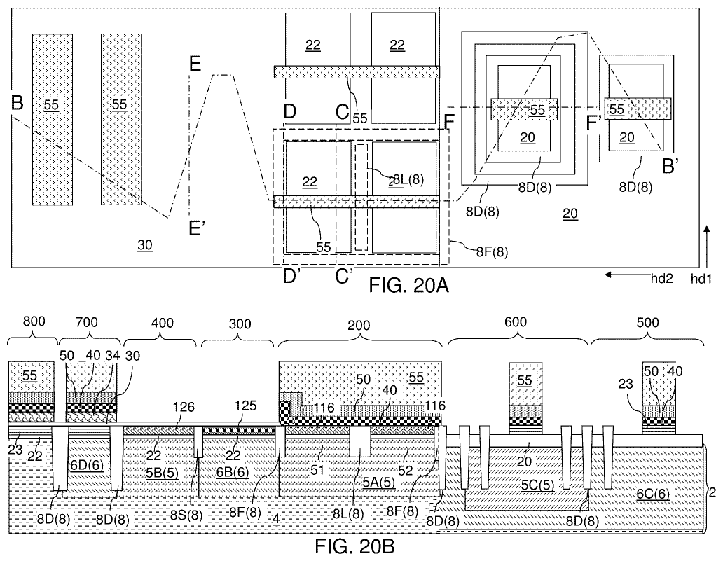

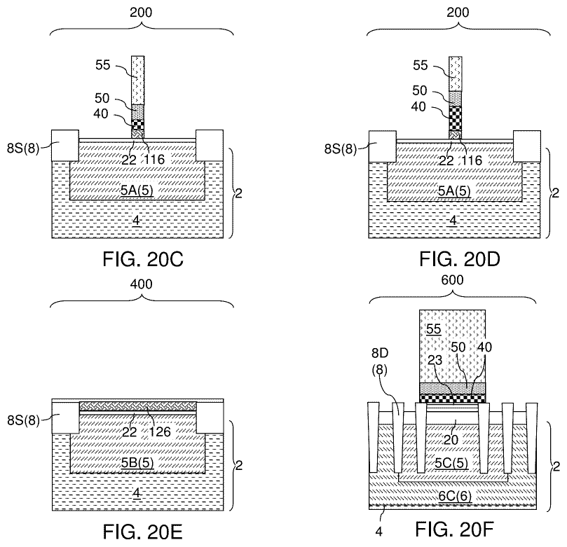

Referring to FIGS. 20A-20F, a first photoresist layer 53 can be applied over the second exemplary structure, and can be lithographically patterned to form discrete patterned photoresist material portions. The patterned portions of the first photoresist layer 53 can include first portions that define the shapes of gate structures to be subsequently formed in the first field effect transistor regions (100, 200). The patterned portions of the first photoresist layer 53 can include second portions that define the shapes of gate electrodes to be subsequently formed in the third p-type field effect transistor region 500 and in the third n-type field effect transistor region 600. The patterned portions of the first photoresist layer 53 can include additional portions that cover a respective area within the first passive device region 700 and in the second passive device region 800.

A first anisotropic etch process can be performed to transfer the pattern in the first photoresist layer 53 through the gate cap dielectric layer 50L, the conductive gate cap layer 40L, the planar semiconductor spacer layer 34L, and portions of the plates 23 located outside the areas of the planar dielectric spacer layer 30L located within the third p-type field effect transistor region 500 and the third n-type field effect transistor region 600. The planar dielectric spacer layer 30L, the second gate dielectric plate 20, and the trench isolation structure 8 can function as etch stop structures for the first anisotropic etch process. In case the planar dielectric spacer layer 30L, the second gate dielectric plate 20, and the trench isolation structure 8 comprise silicon oxide, the etch chemistry of the terminal step of the first anisotropic etch process can etch the semiconductor materials of the planar semiconductor spacer layer 34L and the silicon nitride plates 23 selective to silicon oxide.

Each patterned portion of the gate cap dielectric layer 50L comprises a gate cap dielectric 50. Each patterned portion of the conductive gate cap layer 40L comprises a conductive gate cap structure 40. Each patterned portion of the planar semiconductor spacer layer 34L comprises the planar semiconductor spacer plate 34. Each patterned portion of the gate electrode material plates 126 constitutes a gate electrode 116.

Generally, a first gate electrode material plate 126 can be provided over a first active region 51 and a second gate electrode material plate 126 can be provided over a second active region 52 that is spaced from the first active region by a portion 8L of the trench isolation structure 8. Portions of the first gate electrode material plate 126 and the second gate electrode material plate 126 can be anisotropically etched. Patterned portions of the first gate electrode material plate 126 and the second gate electrode material plate 126 comprise a first gate electrode 116 and a second gate electrode 116, respectively.

According to an aspect of the present disclosure, a sidewall of a conductive gate cap structure 40 can be formed adjacent to an sidewall of the planar semiconductor spacer layer 34L as formed at the processing steps of FIGS. 18A-18F such that a vertically-extending portion of the conductive gate cap structure 40 adjacent to the sidewall of the planar semiconductor spacer layer 34L is included within the conductive gate cap structure 40. Generally, conductive gate cap structures 40 formed within the first field effect transistor regions (100, 200) can be formed with a vertically-protruding portion, which is remnant of a vertically extending portion of the conductive gate cap layer 40L that is formed adjacent to a sidewall of the planar semiconductor spacer layer 34L as formed at the processing steps of FIGS. 18A-18F.

A contiguous combination of a first gate cap dielectric 50, a first conductive gate cap structure 40, a first planar semiconductor spacer plate 34, and a pair of first gate electrodes 116 can be formed across a pair of active regions (51, 52) in the first n-type field effect transistor region 200. Generally, each first conductive gate cap structure 40 constitutes a conductive gate connection structure that provide an electrically conductive path between an underlying pair of first gate electrodes 116 overlying the pair of active regions (51, 52) separated by the trench isolation structure 8L. Thus, the conductive gate connection material layer which comprises the conductive gate cap layer 40L can be patterned into conductive gate connection structure which comprises the first conductive gate cap structures 40. The first photoresist layer 53 can be subsequently removed, for example, by ashing.

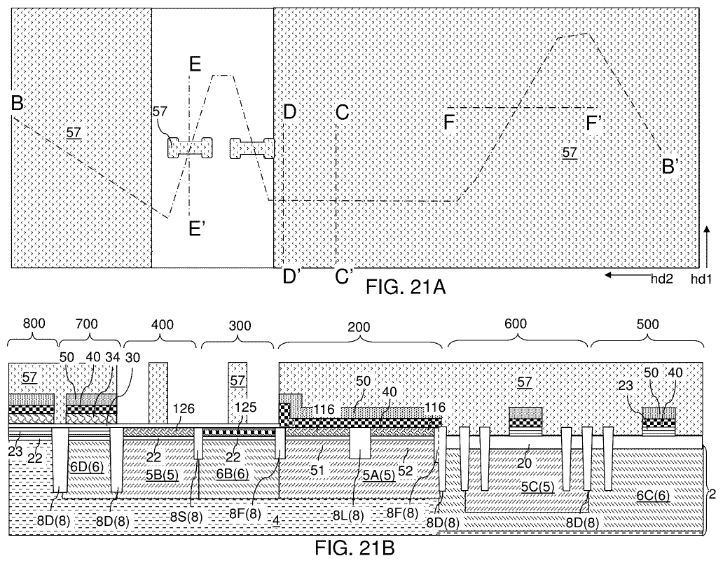

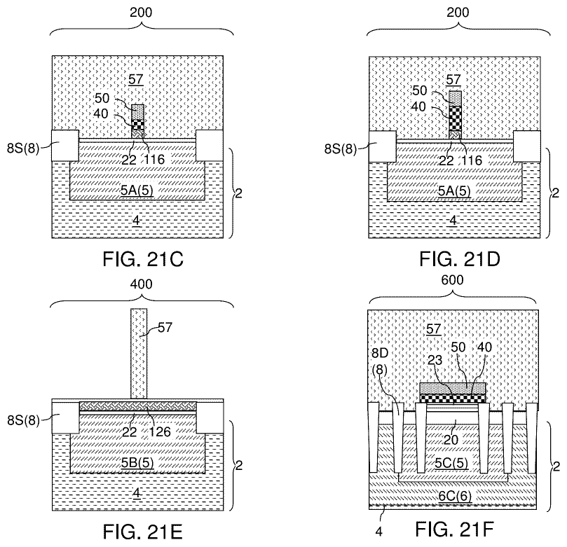

Referring to FIGS. 21A-21F, a second photoresist layer 57 can be applied over the second exemplary structure, and can be lithographically patterned to provide patterned photoresist material portions having the shapes of gate electrodes to be subsequently formed in the second p-type field effect transistor region 300 and the second n-type field effect transistor region 400. The shapes of the patterned portions of the second photoresist layer 57 may be selected as needed. In one embodiment, the patterned portions of the second photoresist layer 57 may have bulging segments adjacent to interface between active regions and the trench isolation structure 8.

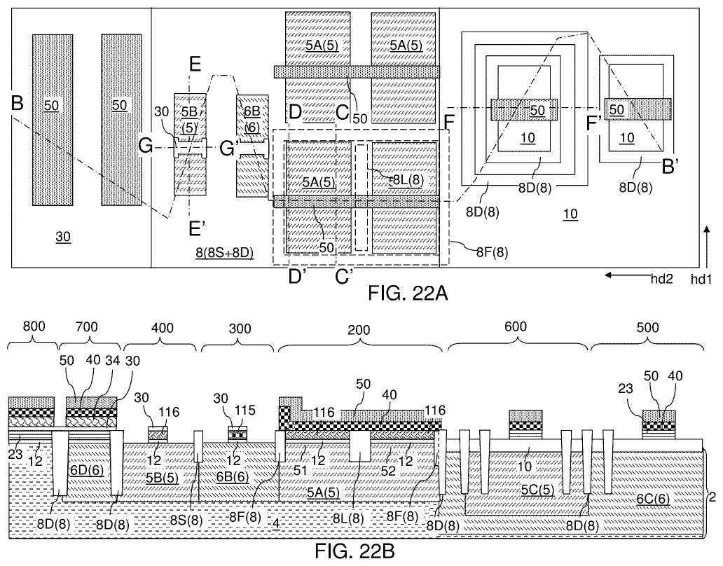

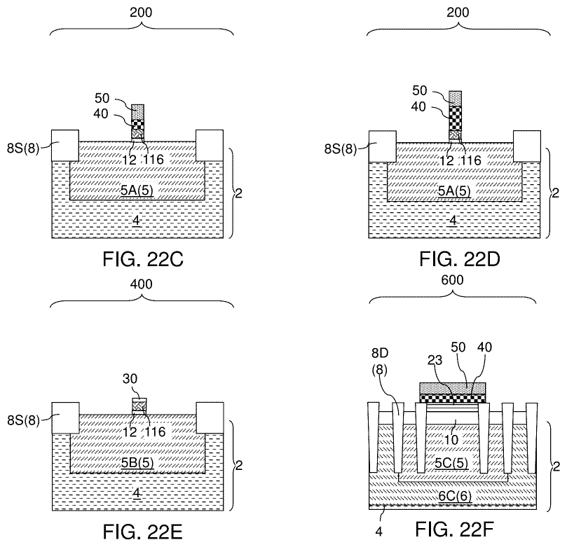

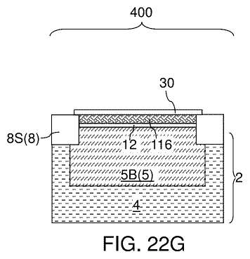

Referring to FIGS. 22A-22G, a second anisotropic etch process can be performed to transfer the pattern of the second photoresist layer 57 through the planar dielectric spacer layer 30L, the gate electrode material plates (126, 125), and the gate dielectric plates 22. Each patterned portion of the planar dielectric spacer layer 30L constitutes a planar dielectric spacer plate 30. Each patterned portion of the gate electrode material plates (126, 125) constitutes a gate electrode (116, 115). Each patterned portion of the gate dielectric plates 22 constitutes a gate dielectric 12. The terminal portion of the second anisotropic etch process may be selective to the to the semiconductor material of the semiconductor substrate 2. The second photoresist layer 57 can be subsequently removed, for example, by ashing.

Subsequently, another anisotropic etch process may be optionally performed to pattern the gate dielectric plates 22 located within the first field effect transistor regions (100, 200). Portions of the gate dielectric plates 22 that do not underlie a gate electrode 126 can be etched, and remaining portions of the gate dielectric plates 22 in the first field effect transistor regions (100, 200) constitute gate dielectrics 12.

A stack of a first gate dielectric 12 and a first gate electrode 116 overlies a first channel region within the first active region 51 in a first field effect transistor region (100 or 200) and contacts a first sidewall of the laterally-extending portion 8F of the trench isolation structure 8. A stack of a second gate dielectric 12 and a second gate electrode 116 overlies a second channel region within the second active region 52 and contacts a second sidewall of the laterally-extending portion 8F of the trench isolation structure 8. A conductive gate connection structure (comprising the first conductive gate cap structure 40) contacts a top surface of the first gate electrode 116, a top surface of the second gate electrode 116, and a portion of a top surface of the laterally-extending portion 8F of the trench isolation structure 8. The conductive gate connection structure comprising the first conductive gate cap structure 40 comprises a pair of widthwise sidewalls that laterally extend along a first horizontal direction hd1 and a pair of lengthwise sidewalls that laterally extend along a second horizontal direction hd2.

The trench isolation structure 8 comprises a frame portion 8F that laterally surrounds the first active region and the second active region continuously. The conductive gate connection structure comprising the first conductive gate cap structure 40 comprises a first end portion and a second end portion that overlies and contacts a respective segment of a top surface of the frame portion 8F of the trench isolation structure 8. Lengthwise sidewalls of the first gate electrode 116 and the second gate electrode 116 are vertically coincident with the pair of lengthwise sidewalls of the conductive gate connection structure that laterally extend along the second horizontal direction hd2.

A first widthwise sidewall (extending along the first horizontal direction hd1) of the first gate dielectric 12 and a first widthwise sidewall (extending along the first horizontal direction hd1) of the first gate electrode 116 are vertically coincident with each other and contact a first sidewall of the laterally-extending portion 8L of the trench isolation structure 8. A first widthwise sidewall (extending along the first horizontal direction hd1) of the second gate dielectric 12 and a first widthwise sidewall (extending along the first horizontal direction hd1) of the second gate electrode 116 are vertically coincident with each other and contact a second sidewall of the laterally-extending portion 8L of the trench isolation structure 8.

A second widthwise sidewall (extending along the first horizontal direction hd1) of the first gate dielectric 12 and a second widthwise sidewall (extending along the first horizontal direction hd1) of the first gate electrode 116 are vertically coincident with each other and contact a first sidewall of the frame portion 8F of the trench isolation structure 8. A second widthwise sidewall (extending along the first horizontal direction hd1) of the second gate dielectric 12 and a second widthwise sidewall (extending along the first horizontal direction hd1) of the second gate electrode 116 are vertically coincident with each other and contact a second sidewall of the frame portion 8F of the trench isolation structure 8.

In one embodiment, the conductive gate connection structure comprises a metallic gate connection structure 40 having a first thickness over a predominant segment of the first gate electrode 116, over the laterally-extending portion 8L of the trench isolation structure 8, and over an entire area of the second gate electrode 116, and having a second thickness that is greater than the first thickness over a complementary segment of the first gate electrode 116.

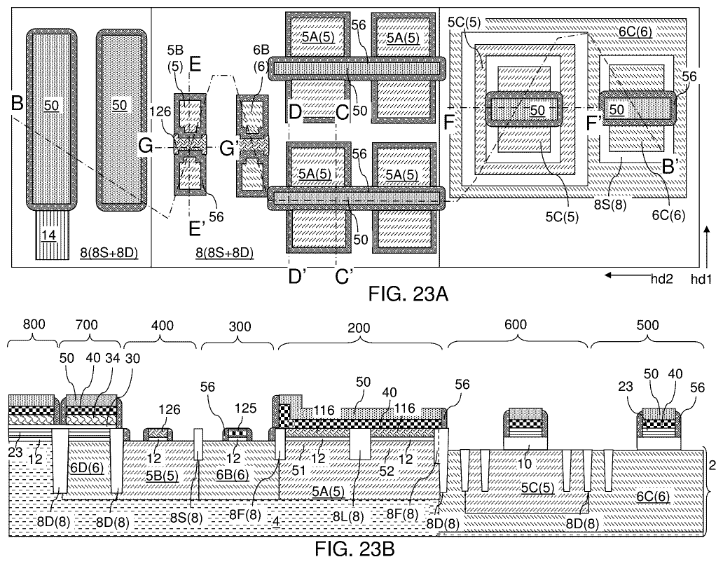

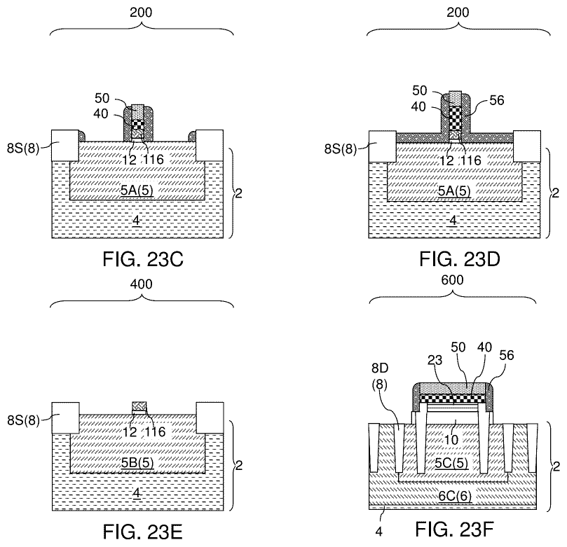

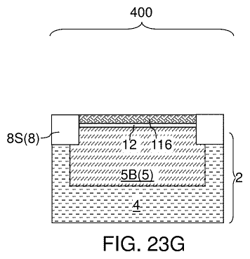

Referring to FIGS. 23A-23G, source/drain extension regions (not shown) can be optionally formed by implantation of p-type dopants and n-type dopants employing a respective patterned implantation mask layer (such as a patterned photoresist layer) and a respective ion implantation process. A dielectric gate spacer material layer including a dielectric material can be deposited by a conformal deposition process such as a chemical vapor deposition process. The dielectric material of the dielectric gate spacer material layer may include, for example, silicon nitride and/or silicon oxide. An anisotropic etch process can be performed to etch horizontally-extending portions of the dielectric gate spacer material layer. Remaining vertically-extending portions of the dielectric gate spacer material layer constitute dielectric gate spacers 56.

The anisotropic etch process may be extended to etch unmasked portions of the dielectric materials of the second gate dielectric plates 20 and the trench isolation structures 8 selective to the materials of the gate electrodes 116. The planar dielectric spacer plates 30 in the second field effect transistor regions (300, 400) can be collaterally etched during the anisotropic etch process. In this case, the second gate dielectric plates 20 in the third field effect transistor regions (500, 600) can be patterned into second gate dielectrics 10, and the physically exposed top surfaces of the trench isolation structures 8 can be vertically recessed. In one embodiment, an outer sidewall of each second gate dielectric 10 can be vertically coincident with an outer sidewall of a respective one of the dielectric gate spacers 56. In one embodiment, the recessed portions of the top surfaces of the trench isolation structure 8 may be at, or about, the height of the top surfaces of the third doped wells (5C, 6C) in the third field effect transistor regions (500, 600).

In one embodiment, a first dielectric gate spacer 56 located within a first field effect transistor region (100 or 200) comprises an upper portion laterally surrounding the conductive gate connection structure comprising first conductive gate cap structure 40, and four lower portions vertically extending between a horizontal plane including a top surface of frame portion 8F of the trench isolation structure 8 and a horizontal plane including top surfaces of the first active region and the second active region and contacting a respective lengthwise sidewall of one of the first gate electrode 116 and the second gate electrode 116.

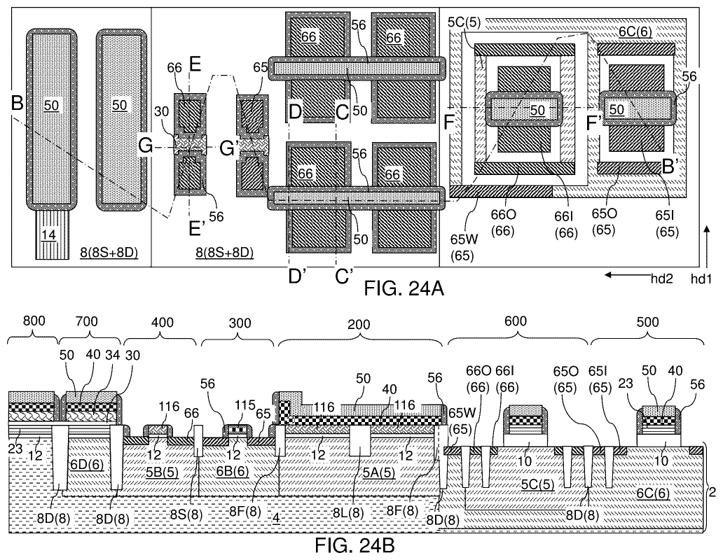

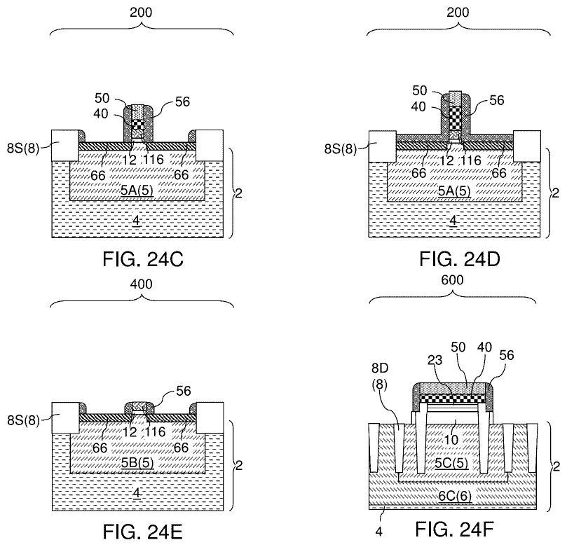

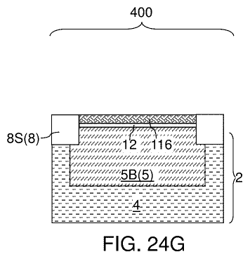

Referring to FIGS. 24A-24G, masked ion implantation processes can be performed to implant p-type dopants within unmasked surface portions of the n-type wells 6, and to implant n-type dopants within unmasked surface portions of the p-type wells 5. A combination of a patterned photoresist layer, the gate structures (12, 10, 116, 115, 13, 34, 40, 50), and the dielectric gate spacers 56 can be employed as a composite implantation mask during each ion implantation process. Source regions and drain regions are formed within the implanted surface portions of the p-doped wells 5 and the n-doped wells 6. The source regions and the drain regions are collectively referred to as source/drain regions (65, 66), which include p-doped source/drain regions 65 that are formed within a respective one of the n-doped wells 6, and n-doped source/drain regions 66 that are formed within a respective one of the p-doped wells 5.

In one embodiment, configurations for increasing the breakdown voltage of field effect transistors may be employed in device regions in which high-voltage field effect transistors are formed such as the third field effect transistor regions (500, 600). In this case, the p-doped source/drain regions 65 may include inner p-doped source/drain regions 651 and outer p-doped source/drain regions 650 that are laterally spaced apart by an additional trench isolation structure 8, which may be disjoined from the trench isolation structure 8 in the first field effect transistor regions (100, 200). Further, the n-doped source/drain regions 66 may include inner n-doped source/drain regions 661 and outer n-doped source/drain regions 660 that are laterally spaced apart by another additional trench isolation structure 8. Optionally, a well contact source/drain region 65W may be employed to facilitate biasing of a doped well.

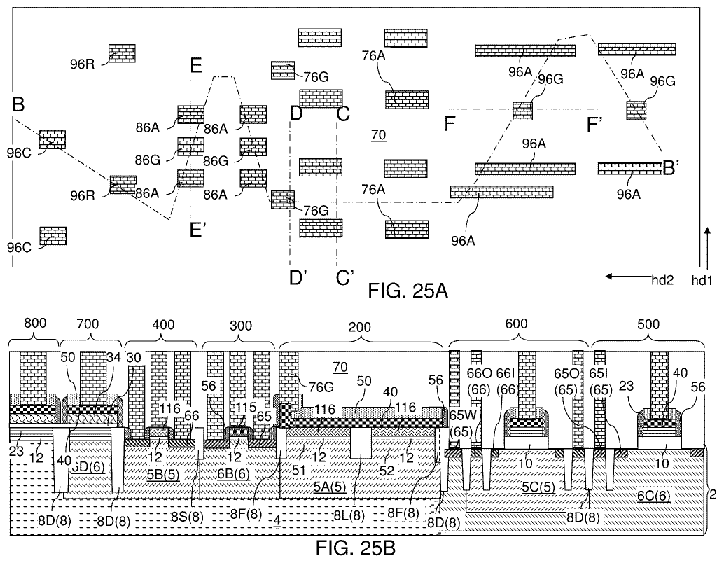

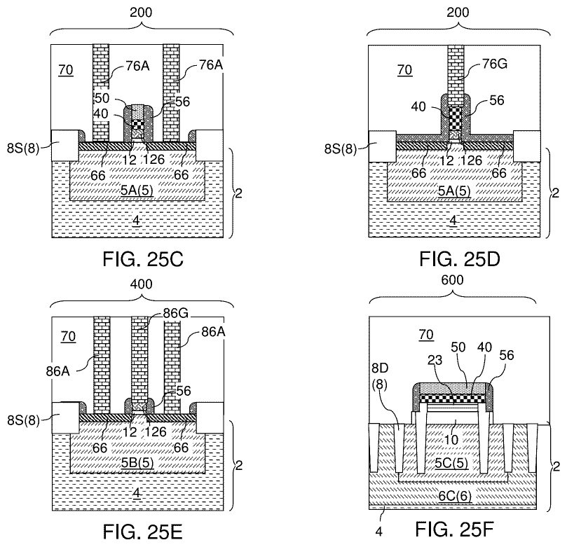

Referring to FIGS. 25A-25F, a contact-level dielectric layer 70 and various contact via structures (76A, 76G, 86A, 86G, 96A, 96G, 96R, 96C) can be subsequently formed. The contact-level dielectric layer 70 includes a dielectric material such as silicon oxide, and can be formed by a conformal or non-conformal deposition process. The top surface of the contact-level dielectric layer 70 can be planarized by a planarization process such as a chemical mechanical polishing (CMP) process. The vertical distance between the topmost surfaces of the gate cap dielectrics 50 and the top surface of the contact-level dielectric layer 70 can be in a range from 30 nm to 500 nm, although lesser and greater vertical distances may also be employed.

The contact via structures (76A, 76G, 86A, 86G, 96A, 96G, 96R, 96C) comprise first source/drain region contact via structures 76A contacting source/drain regions (65, 66) within the first field effect transistor regions (100, 200), first gate contact via structures 76G contacting top surfaces of conductive gate cap structures 40 within the first field effect transistor regions (100, 200), second source/drain region contact via structures 86A contacting source/drain regions (65, 66) within the second field effect transistor regions (300, 400), second gate contact via structures 86G contacting the second gate electrodes (25, 26), third source/drain region contact via structures 96A contacting source/drain regions (65, 66) within the third field effect transistor regions (500, 600), and third gate contact via structures 96G contacting top surfaces of conductive gate cap structures 40 within the third field effect transistor regions (500, 600). Further, the contact via structures (76A, 76G, 86A, 86G, 96A, 96G, 96R, 96C) can comprise first passive device contact via structures 96R that contact first passive devices such as resistors, and second passive device contact via structures 96C that contact second passive devices such as capacitors.

Generally, various field effect transistors having different gate dielectric thicknesses, different gate lengths (i.e., different lateral distances between a source region and a drain region), and different configurations can be formed in the various field effect transistor regions (100, 200, 300, 400, 500, 600). A dielectric gate spacer 56 may overlie a periphery region of a source/drain region (65, 66) of field effect transistors in the second field effect transistor regions (300, 400), and contact sidewalls of a respective portion of the trench isolation structure 8.

The second exemplary structure can include a combination of a first field effect transistor and a second field effect transistor located in a first field effect transistor region (100 or 200). The first field effect transistor and the second field effect transistor comprise a first active region 51 and a second active region 52, respectively. The first active region and the second active region contact sidewalls of, and are laterally surrounded by, a trench isolation structure 8. A laterally-extending portion 8L of the trench isolation structure 8 is located between the first active region 51 and the second active region 52.

The second exemplary structure may comprise a third field effect transistor located in a second field effect transistor region (300 or 400). The third field effect transistor comprises: a third active region that is laterally surrounded by an additional portion of the trench isolation structure 8, a stack of a third gate dielectric 12 and a third gate electrode (116 or 115) having widthwise sidewalls contacting sidewalls of the additional portion of the trench isolation structure 8 and laterally extending along the first horizontal direction hd1, additional dielectric gate spacers 56 having a respective opening therethrough and contacting a respective subset of sidewalls of the additional portion of the trench isolation structure 8 and a respective lengthwise sidewall (which laterally extends along the second horizontal direction hd2) of the third gate electrode (116 or 115).

The first gate electrode 116 and the second gate electrode 116 do not contact the contact-level dielectric layer 70, and are spaced from the contact-level dielectric layer 70 by a first dielectric gate spacer 56 and a conductive gate connection structure (as embodied as a conductive gate cap structure 40). The third gate electrode (116 or 115) can have a same thickness as the first gate electrode 116 and the second gate electrode 116. A portion of a top surface of the third gate electrode (116 or 115) is in direct contact with the contact-level dielectric layer 70.

At least one gate contact structure (such as a first gate contact via structure 76G) extends through the contact-level dielectric layer 70 and contacts a top surface of the portion of the conductive gate connection structure comprising the conductive gate cap structure 40 which at least partially overlies the underlying first gate electrode 116, and at least one additional gate contact structure (such as a second gate contact via structure 86G) extends through the contact-level dielectric layer 70 and contacts a portion of a top surface of the third gate electrode 116. An entirety of the top surface of the third gate electrode 116 is in contact with the at least one additional gate contact structure or the contact-level dielectric layer 70.

The second exemplary structure can comprise an additional field effect transistor such as a fourth field effect transistor formed in a third field effect transistor region (500 or 600). The additional field effect transistor comprises an additional active region having a pair of lengthwise sidewalls and a pair of widthwise sidewalls that contact sidewalls of, and are laterally surrounded by, an additional portion of the trench isolation structure 8. The additional field effect transistor comprises an additional gate structure (10, 13, 40, 50) overlies the additional active region. The additional gate structure (10, 13, 40, 50) can include an additional composite gate dielectric (10, 13) comprising a silicon oxide sublayer 10 having a greater thickness than the first gate dielectric 12, and a silicon nitride sublayer 13, and an additional conductive gate cap structure 40 having a same thickness and a same material composition as the first segment of the first conductive gate cap structure 40. An entirety of a top surface of the silicon nitride sublayer 13 is in contact with a bottom surface of the additional conductive gate cap structure 40.

In one embodiment, the second exemplary structure may comprise a passive device, which may be selected from a capacitor, a resistor, or any other passive device known in the art. The passive device comprises a layer stack including, from bottom to top, a first dielectric layer (such as another instance of a silicon oxide gate dielectric 12 and a silicon nitride gate dielectric 13), a second dielectric layer (such as a planar dielectric spacer plate 30), a second semiconductor plate (such as a planar semiconductor spacer plate 34), and a metallic plate (such as a conductive gate cap structure 40). The first dielectric layer has a same material composition and a same thickness as the first gate dielectric 12. The first semiconductor plate may a same thickness as the first gate electrode (14, 25 or 26). The second dielectric layer has a same material composition and a same thickness as the first planar dielectric spacer plate 30. The metallic plate has a same material composition and a same thickness as the first segment of the first conductive gate cap structure 40.

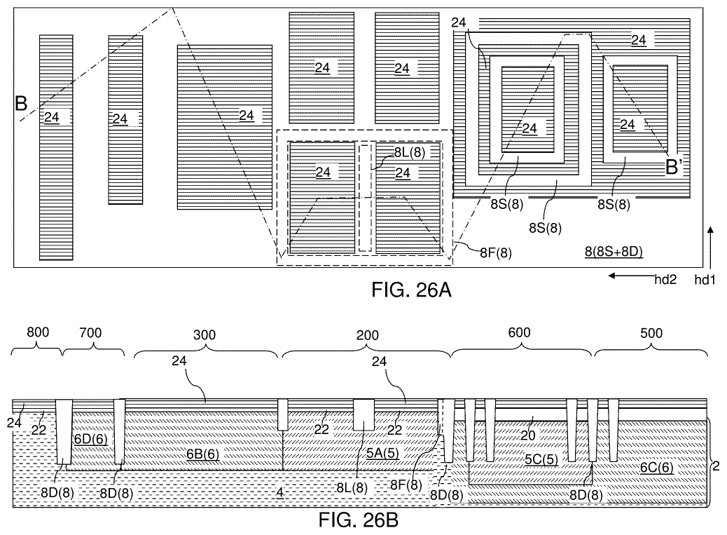

Referring to FIGS. 26A and 26B, a third exemplary structure according to a third embodiment of the present disclosure may be derived from the first exemplary structure of FIGS. 5A-5F by rearranging and/or omitting a subset of the doped wells (5, 6). For example, the first p-doped wells 5A can be formed such that a plurality of active regions laterally surrounded by a respective portion of the trench isolation structure 8 is provided within the first n-type field effect transistor region 200. A second field effect transistor region (300 or 400) may be formed adjacent to a first field effect transistor region (100 or 200). The first p-type field effect transistor region 100 and the second n-type field effect transistor region 400 are not illustrated for the drawings of the third exemplary structure, but may be present within the third exemplary structure. While the present disclosure is described employing an embodiment in which pairs of active regions are present within the first n-type field effect transistor region 200, embodiments are expressly contemplated herein in which pairs of active regions are present within the first p-type field effect transistor region 100 and field effect transistors having the same geometrical features are formed in the first p-type field effect transistor region 100. In other words, the devices of the present disclosure may be formed with opposite conductivity types.

Generally, at least one gate dielectric layer and at least one semiconductor material layer over a semiconductor material layer within the semiconductor substrate 2, and a trench isolation structure 8 can be formed through the at least one semiconductor material layer and the at least one gate dielectric layer. Patterned portions of the at least one semiconductor material layer and the at least one gate dielectric layer comprise a first stack (22, 24) of a first gate dielectric plate 22 and a first gate electrode material plate 24 overlying a first active region of the semiconductor material layer and a second stack (22, 24) of a second gate dielectric plate 22 and a second gate electrode material plate 24 overlying a second active region of the semiconductor material layer. The first stack (22, 24) and the second stack (22, 24) can be located within a same field effect transistor region such as the first n-type field effect transistor region 200. The trench isolation structure 8 comprises a frame portion 8F that laterally surrounds the first active region and the second active region continuously. A laterally-extending portion 8L of the trench isolation structure 8 can be located between the first active region and the second active region. Optionally, masked ion implantation processes can be performed to dope any portion of the gate electrode material plates 24 with suitable conductivity types.

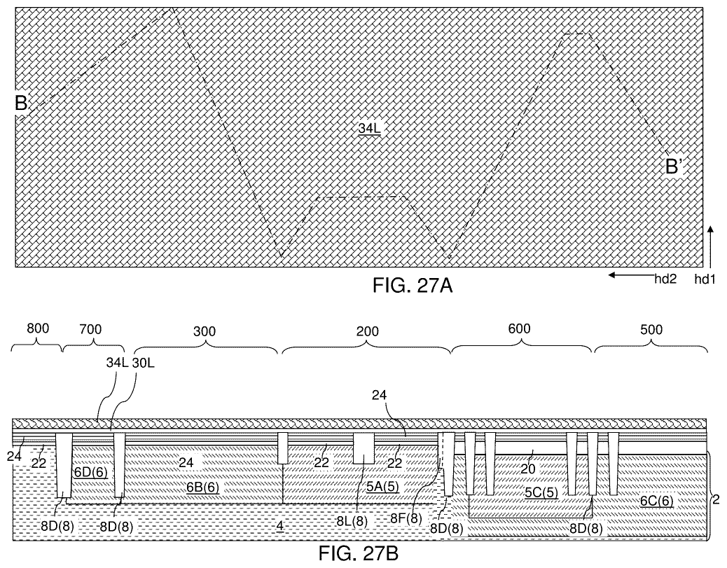

Referring to FIGS. 27A and 27B, the processing steps of FIGS. 6A-6F can be performed to form a planar dielectric spacer layer 30L and a planar semiconductor spacer layer 34L over the top surfaces of the gate electrode material plates 24 and the trench isolation structure 8. The thickness and the material composition of each of the planar dielectric spacer layer 30L and the planar semiconductor spacer layer 34L may be the same as in the first exemplary structure.

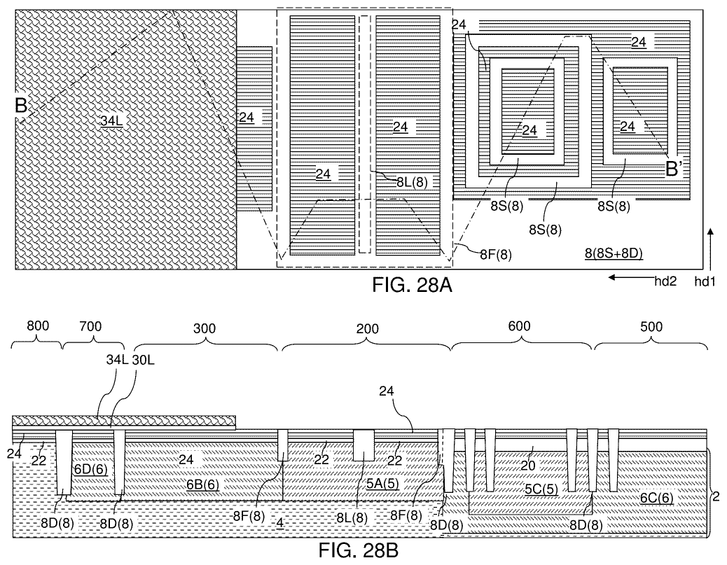

Referring to FIGS. 28A-28F, the processing steps of FIGS. 7A-7F can be performed to pattern the planar dielectric spacer layer 30L and the planar semiconductor spacer layer 34L. In the third embodiment, the planar dielectric spacer layer 30L and the planar semiconductor spacer layer 34L can be patterned such that sidewalls of patterned remaining portions of the planar dielectric spacer layer 30L and the planar semiconductor spacer layer 34L are formed in the second field effect transistor regions (300 or 400). The planar dielectric spacer layer 30L and the planar semiconductor spacer layer 34L can be removed from the first field effect transistor regions (100, 200), the third field effect transistor regions (500, 600), and peripheral regions of the second field effect transistor regions (300, 400) that border the first field effect transistor regions (100, 200). In this case, a first active region and a second active region may be provided within the first n-type field effect transistor region 200, and remaining portions of the planar dielectric spacer layer 30L and the planar semiconductor spacer layer 34L can be located outside areas of the first active region and the second active region. In one embodiment, the sidewall of the planar semiconductor spacer layer 34L can be perpendicular to the direction of gate electrodes to be patterned in a second field effect transistor region (300, 400). For example, the sidewall of the planar semiconductor spacer layer 34L can be parallel to the first horizontal direction hd1.

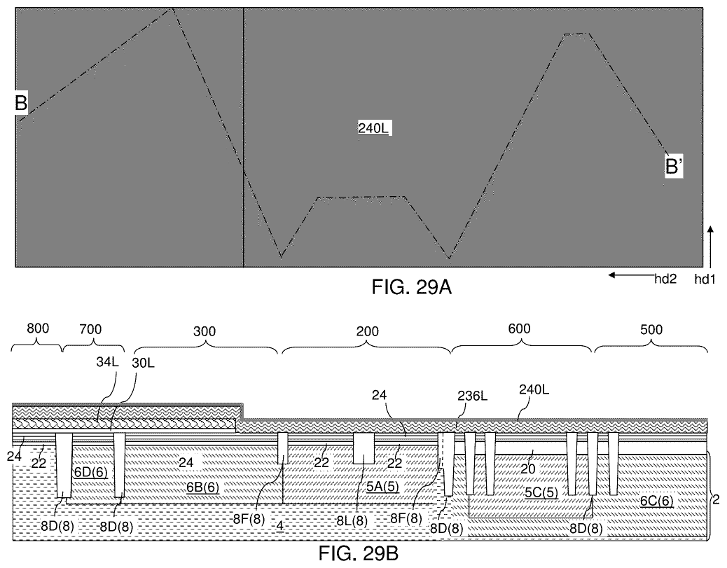

Referring to FIGS. 29A-29F, the processing steps of FIGS. 8A-8F can be performed to deposit a conductive gate connection material layer (234L, 236L) directly on physically exposed top surfaces of the gate electrode material plates 24 and the trench isolation structure 8 and over the planar semiconductor spacer layer 34. In one embodiment, the conductive gate connection material layer (236L, 240L) may comprise a vertical stack including, from bottom to top, a semiconductor gate cap layer 236L including a heavily doped semiconductor material and an optional conductive gate cap layer 240L. The heavily doped semiconductor material may include a doped semiconductor material such as polysilicon, and can have a same type of doping as an underlying gate electrode material plate 24. If multiple gate electrode material plates 24 having different conductivity types are employed, different portions of the semiconductor gate cap layer 236L may be doped with electrical dopants of different conductivity types to match the conductivity type of a respective underlying gate electrode material plate 24. The thickness of the semiconductor gate cap layer 236L may be in a range from 30 nm to 300 nm, such as from 40 nm to 100 nm, although lesser and greater thicknesses may also be employed. The conductive gate cap layer 240L can have the same material composition and the same thickness range as the conductive gate cap layer 40 in the first exemplary structure. The conductive gate cap layer 240L may comprise a metal silicide layer. Alternatively, the conductive gate cap layer 240L may be omitted at this step and then formed in subsequent steps by silicidiation of upper surfaces of gate electrodes. Optionally, a gate cap dielectric layer (not shown) may be subsequently deposited over the conductive gate cap layer 240L. The gate cap dielectric layer includes a dielectric material such as silicon nitride. The thickness of the gate cap dielectric layer, if present, can be in a range from 20 nm to 100 nm, such as from 30 nm to 50 nm, although lesser and greater thicknesses may also be employed.

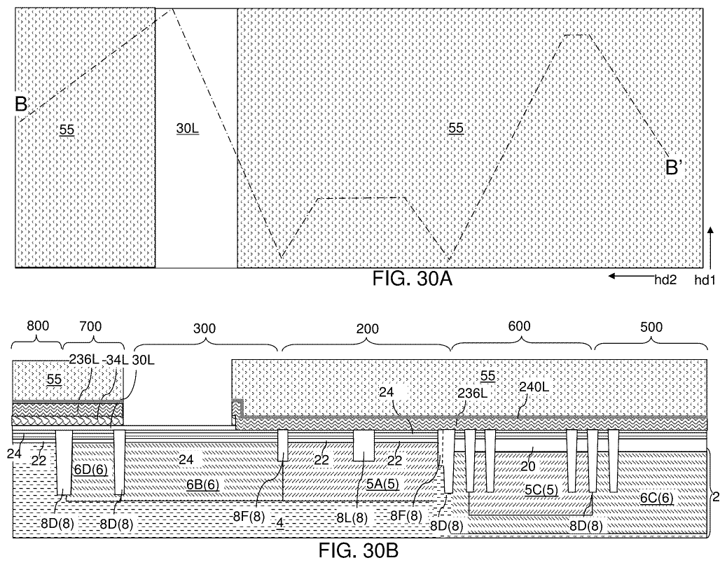

Referring to FIGS. 30A and 30B, a first photoresist layer 53 can be applied over the third exemplary structure, and can be lithographically patterned to form discrete patterned photoresist material portions. The patterned portions of the first photoresist layer 53 can include an opening in a second field effect transistor region (300 and/or 400). A first anisotropic etch process can be performed to transfer the pattern in the first photoresist layer 53 through the optional gate cap dielectric layer (if present), the conductive gate cap layer 240L, the semiconductor gate cap layer 236L, and the planar semiconductor spacer layer 34L. The first anisotropic etch process may be selective to the dielectric material of the planar dielectric spacer layer 30L.

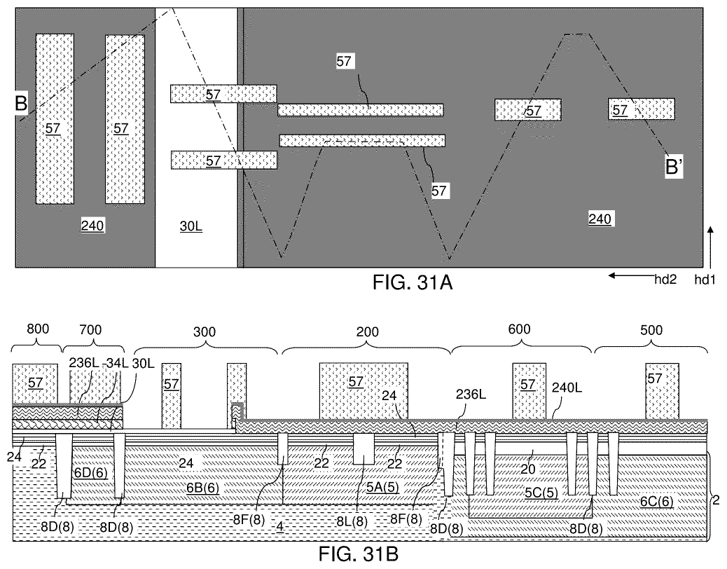

Referring to FIGS. 31A and 31B, a second photoresist layer 57 can be applied over the third exemplary structure, and can be lithographically patterned to provide patterned photoresist material portions having the shapes of gate electrodes and passive devices to be subsequently formed. The shapes of the patterned portions of the second photoresist layer 57 may be selected as needed. In one embodiment, a patterned portions of the second photoresist layer 57 may have extend across an edge of the planar semiconductor spacer layer 34L and across an edge of a portion of the conductive gate connection material layer (234L, 240L) that overlies a peripheral portion of the planar semiconductor spacer layer 34L within a second field effect transistor region (300 and/or 400).

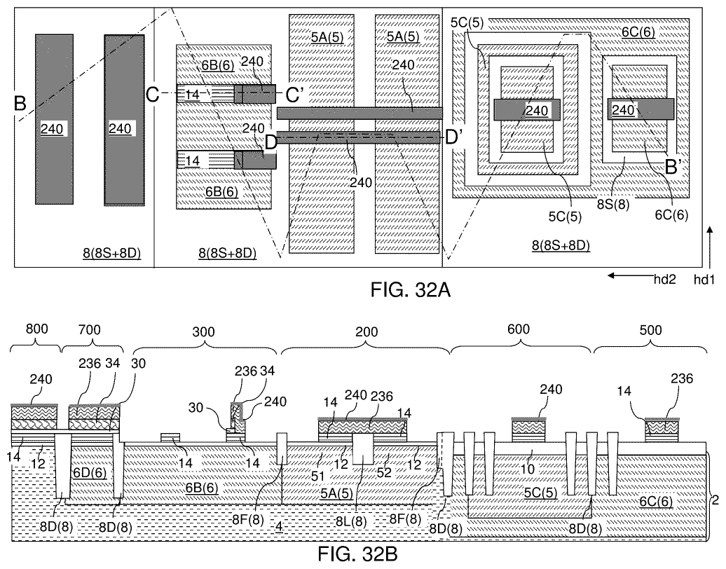

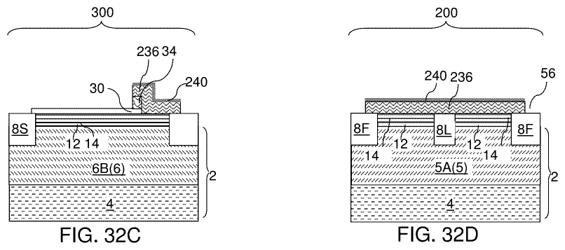

Referring to FIGS. 32A-32D, a second anisotropic etch process can be performed to transfer the pattern of the second photoresist layer 57 through the dielectric gate cap layer (if present), the conductive gate connection material layer (234L, 240L), the planar semiconductor spacer layer 34L, the planar dielectric spacer layer 30L, the gate electrode material plates 24, and the gate dielectric plates 22. Each patterned portion of the conductive gate cap layer 240L constitutes a conductive gate cap structures 240. Each patterned portion of the semiconductor gate cap layer 236L constitutes a semiconductor gate cap structure 236. Each patterned portion of the planar semiconductor spacer layer 34L constitutes a planar semiconductor spacer plate 34. Each patterned portion of the planar dielectric spacer layer 30L constitutes a planar dielectric spacer plate 30. Each patterned portion of the gate electrode material plates 24 constitutes a gate electrode 14. Each patterned portion of the gate dielectric plates 22 constitutes a gate dielectric 12. The terminal portion of the second anisotropic etch process may be selective to the to the semiconductor material of the semiconductor substrate 2. The second photoresist layer 57 can be subsequently removed, for example, by ashing.

A stack of a first gate dielectric 12 and a first gate electrode 14 overlies a first channel region within the first active region 51 in a first field effect transistor region (100 or 200) and contacts a first sidewall of the laterally-extending portion 8F of the trench isolation structure 8. A stack of a second gate dielectric 12 and a second gate electrode 14 overlies a second channel region within the second active region 52 and contacts a second sidewall of the laterally-extending portion 8F of the trench isolation structure 8. A first conductive gate connection structure comprising the semiconductor gate cap structure 236 and the conductive gate cap structure 240 contacts a top surface of the first gate electrode 14, a top surface of the second gate electrode 14, and a portion of a top surface of the laterally-extending portion 8F of the trench isolation structure 8. The first conductive gate connection structure comprising the first conductive gate cap structure 240 comprises a pair of widthwise sidewalls that laterally extend along a first horizontal direction hd1 and a pair of lengthwise sidewalls that laterally extend along a second horizontal direction hd2. An entirety of a top surface of the first gate electrode 14 and an entirety of a top surface of the second gate electrode 14 contact a bottom surface of the conductive gate connection structure (236, 240), such as the bottom surface of the semiconductor gate cap structure 236.

The trench isolation structure 8 comprises a frame portion 8F that laterally surrounds the first active region 51 and the second active region 52 continuously. The first conductive gate connection structure comprising as a stack of a semiconductor gate cap structure 236 and a conductive gate cap structure 240 comprises a first end portion and a third end portion that overlies and contacts a respective segment of a top surface of the frame portion 8F of the trench isolation structure 8, as shown in FIG. 32A. Lengthwise sidewalls of the first gate electrode 14 and the second gate electrode 14 are vertically coincident with the pair of lengthwise sidewalls of the first conductive gate connection structure that laterally extend along the second horizontal direction hd2.

A first widthwise sidewall (extending along the first horizontal direction hd1) of the first gate dielectric 12 and a first widthwise sidewall (extending along the first horizontal direction hd1) of the first gate electrode 14 are vertically coincident with each other and contact a first sidewall of the laterally-extending portion 8L of the trench isolation structure 8. A first widthwise sidewall (extending along the first horizontal direction hd1) of the second gate dielectric 12 and a first widthwise sidewall (extending along the first horizontal direction hd1) of the second gate electrode 14 are vertically coincident with each other and contact a second sidewall of the laterally-extending portion 8L of the trench isolation structure 8.

A second widthwise sidewall (extending along the first horizontal direction hd1) of the first gate dielectric 12 and a second widthwise sidewall (extending along the first horizontal direction hd1) of the first gate electrode 14 are vertically coincident with each other and contact a first sidewall of the frame portion 8F of the trench isolation structure 8. A second widthwise sidewall (extending along the first horizontal direction hd1) of the second gate dielectric 12 and a second widthwise sidewall (extending along the first horizontal direction hd1) of the second gate electrode 14 are vertically coincident with each other and contact a second sidewall of the frame portion 8F of the trench isolation structure 8.

In one embodiment, the first conductive gate connection structure comprises a metallic gate connection structure includes the conductive gate cap structure 240 having a uniform thickness over the entirety of the first gate electrode 14 (which includes a predominant segment of the first gate electrode 14), over the laterally-extending portion 8L of the trench isolation structure 8, and over the entirety of the second gate electrode 14.

In one embodiment, the first conductive gate connection structure further comprises a semiconductor gate connection structure comprising the semiconductor gate cap structure 236 having a uniform thickness throughout and contacting top surfaces of the first gate electrode 14, the laterally-extending portion of the trench isolation structure 8L, and the second gate electrode 14. In one embodiment, the first conductive gate connection structure also comprises a metallic gate connection structure comprising the conductive gate cap structure 240 contacting an entirety of a top surface of the semiconductor gate connection structure and having a same area as the semiconductor gate structure.

According to an aspect of the present disclosure, second conductive gate connection structure can be provided within the second field effect transistor region (300 and/or 400). The second conductive gate connection structure comprises a stack of a second semiconductor gate cap structure 236 and a second conductive gate cap structure 240. The second semiconductor gate cap structure 236 comprises a first segment that contacts portion of the top surface of an underlying gate electrode 14; a second segment that overlies a planar dielectric spacer plate 34; and a connecting segment that contacts a first sidewall of the planar dielectric spacer plate 34 and connecting the first segment and the second segment.

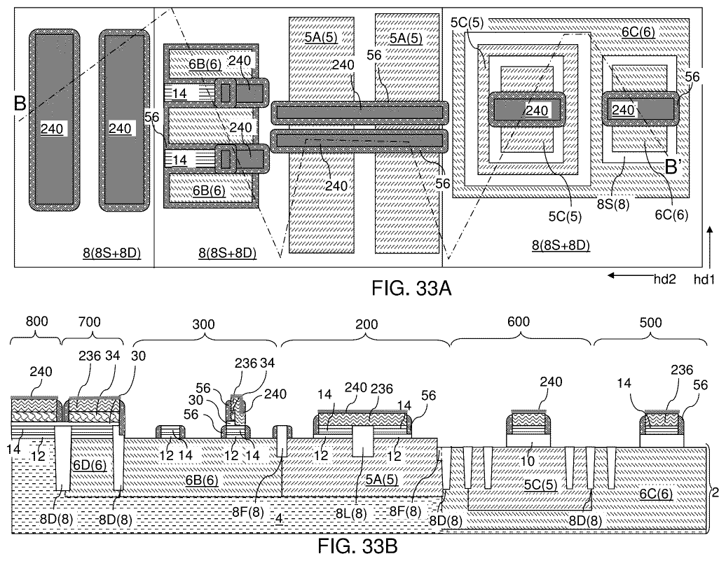

Referring to FIGS. 33A and 33B, source/drain extension regions (not shown) can be optionally formed by implantation of p-type dopants and n-type dopants employing a respective patterned implantation mask layer (such as a patterned photoresist layer) and a respective ion implantation process. A dielectric gate spacer material layer including a dielectric material can be deposited by a conformal deposition process such as a chemical vapor deposition process. The dielectric material of the dielectric gate spacer material layer may include, for example, silicon nitride and/or silicon oxide. An anisotropic etch process can be performed to etch horizontally-extending portions of the dielectric gate spacer material layer. Remaining vertically-extending portions of the dielectric gate spacer material layer constitute dielectric gate spacers 56.

The anisotropic etch process may be extended to etch unmasked portions of the dielectric materials of the first gate dielectrics 12, the second gate dielectric plates 20 and the trench isolation structures 8 selective to the materials of the gate electrodes 14. The planar dielectric spacer plates 30 in the second field effect transistor regions (300, 400) can be collaterally etched during the anisotropic etch process. In this case, the second gate dielectric plates 20 in the third field effect transistor regions (500, 600) can be patterned into second gate dielectrics 10, and the physically exposed top surfaces of the trench isolation structures 8 can be vertically recessed. In one embodiment, an outer sidewall of each second gate dielectric 10 can be vertically coincident with an outer sidewall of a respective one of the dielectric gate spacers 56. In one embodiment, the recessed portions of the top surfaces of the trench isolation structure 8 may be at, or about, the height of the top surfaces of the third doped wells (5C, 6C) in the third field effect transistor regions (500, 600).

In one embodiment, a first dielectric gate spacer 56 located within a first field effect transistor region (100 or 200) comprises an upper portion laterally surrounding the conductive gate connection structure (comprising the stack of the semiconductor gate cap structure 236 and the conductive gate cap structure 240), and four lower portions vertically extending between a horizontal plane including a top surface of frame portion 8F of the trench isolation structure 8 and a horizontal plane including top surfaces of the first active region and the second active region and contacting a respective lengthwise sidewall of one of the first gate electrode 14 and the second gate electrode 14 and contacting a top surface of a respective one of the first active region and the second active region.

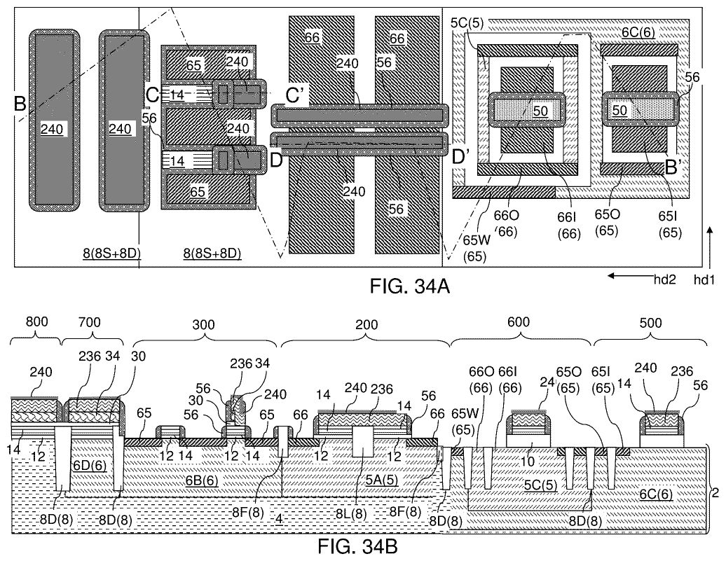

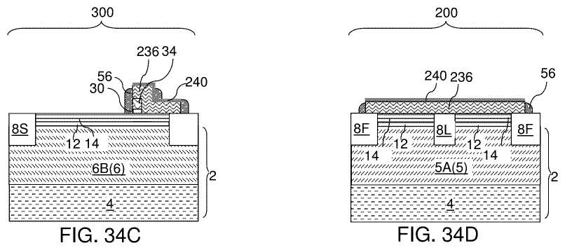

Referring to FIGS. 34A-34D, masked ion implantation processes can be performed to implant p-type dopants within unmasked surface portions of the n-type wells 6, and to implant n-type dopants within unmasked surface portions of the p-type wells 5. A combination of a patterned photoresist layer, the gate structures (12, 10,14, 30, 34, 236, 240), and the dielectric gate spacers 56 can be employed as a composite implantation mask during each ion implantation process. Source regions and drain regions are formed within the implanted surface portions of the p-doped wells 5 and the n-doped wells 6. The source regions and the drain regions are collectively referred to as source/drain regions (65, 66), which include p-doped source/drain regions 65 that are formed within a respective one of the n-doped wells 6, and n-doped source/drain regions 66 that are formed within a respective one of the p-doped wells 5.

In one embodiment, configurations for increasing the breakdown voltage of field effect transistors may be employed in device regions in which high-voltage field effect transistors are formed such as the third field effect transistor regions (500, 600). In this case, the p-doped source/drain regions 65 may include inner p-doped source/drain regions 651 and outer p-doped source/drain regions 650 that are laterally spaced apart by an additional trench isolation structure 8, which may be disjoined from the trench isolation structure 8 in the first field effect transistor regions (100, 200). Further, the n-doped source/drain regions 66 may include inner n-doped source/drain regions 661 and outer n-doped source/drain regions 660 that are laterally spaced apart by another additional trench isolation structure 8. Optionally, a well contact source/drain region 65W may be employed to facilitate biasing of a doped well.

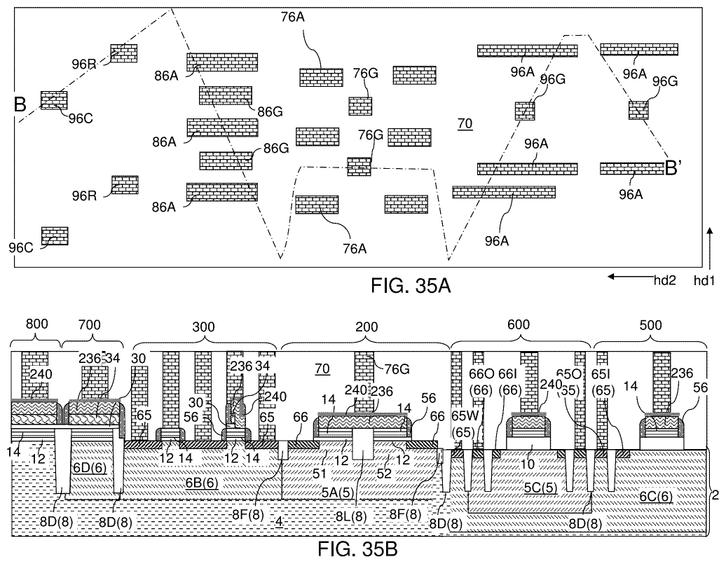

Referring to FIGS. 35A and 35B, a contact-level dielectric layer 70 and various contact via structures (76A, 76G, 86A, 86G, 96A, 96G, 96R, 96C) can be subsequently formed. The contact-level dielectric layer 70 includes a dielectric material such as silicon oxide, and can be formed by a conformal or non-conformal deposition process. The top surface of the contact-level dielectric layer 70 can be planarized by a planarization process such as a chemical mechanical polishing (CMP) process. The vertical distance between the topmost surfaces of the gate cap dielectrics 50 and the top surface of the contact-level dielectric layer 70 can be in a range from 30 nm to 500 nm, although lesser and greater vertical distances may also be employed.

The contact via structures (76A, 76G, 86A, 86G, 96A, 96G, 96R, 96C) comprise first source/drain region contact via structures 76A contacting source/drain regions (65, 66) within the first field effect transistor regions (100 or 200), first gate contact via structures 76G contacting top surfaces of conductive gate cap structures 240 within the first field effect transistor regions (100 or 200), second source/drain region contact via structures 86A contacting source/drain regions (65, 66) within the second field effect transistor regions (300 or 400), second gate contact via structures 86G contacting the second gate electrodes (25, 26), third source/drain region contact via structures 96A contacting source/drain regions (65, 66) within the third field effect transistor regions (500, 600), and third gate contact via structures 96G contacting top surfaces of conductive gate cap structures 240 within the third field effect transistor regions (500, 600). Further, the contact via structures (76A, 76G, 86A, 86G, 96A, 96G, 96R, 96C) can comprise first passive device contact via structures 96R that contact first passive devices such as resistors, and second passive device contact via structures 96C that contact second passive devices such as capacitors.

Generally, various field effect transistors having different gate dielectric thicknesses, different gate lengths (i.e., different lateral distances between a source region and a drain region), and different configurations can be formed in the various field effect transistor regions (100, 200, 300, 400, 500, 600). A dielectric gate spacer 56 may overlie a periphery region of a source/drain region (65, 66) of field effect transistors in the second field effect transistor regions (300 or 400), and contact sidewalls of a respective portion of the trench isolation structure 8.

The third exemplary structure can include a combination of a first field effect transistor and a second field effect transistor located in a first field effect transistor region (100 or 200). The first field effect transistor and the second field effect transistor comprise a first active region 51 and a second active region 52, respectively. The first active region and the second active region contact sidewalls of, and are laterally surrounded by, a trench isolation structure 8. A laterally-extending portion 8L of the trench isolation structure 8 is located between the first active region 51 and the second active region 52.

The third exemplary structure may comprise a third field effect transistor located in a second field effect transistor region (300 or 400). The third field effect transistor comprises: a third active region that is laterally surrounded by an additional portion of the trench isolation structure 8, a stack of a third gate dielectric 12 and a third gate electrode 14 having widthwise sidewalls contacting sidewalls of the additional portion of the trench isolation structure 8 and laterally extending along the first horizontal direction hd1, additional dielectric gate spacers 56 having a respective opening therethrough and contacting a respective subset of sidewalls of the additional portion of the trench isolation structure 8 and a respective lengthwise sidewall (which laterally extends along the second horizontal direction hd2) of the third gate electrode 14.

A portion of the top surface of third gate electrode 14 of the third field effect transistor can be contacted by the contact-level dielectric material layer 70. An additional conductive gate cap structure comprising a stack of a semiconductor gate cap structure 236 and a conductive gate cap structure 240 can contact another portion of the top surface of the third gate electrode 14. The additional conductive gate cap structure can comprise a same set of materials as the conductive gate connection structure in the first field effect transistor region (100 and/or 200). At least one gate contact structure (such as a first gate contact via structure 76G) can vertically extend through the contact-level dielectric layer 70 and can contact a top surface of a conductive gate connection structure (236, 240) in the first field effect transistor region (100 and/or 200), and at least one additional gate contact structure (such as a second gate contact via structure 86G) can vertically extend through the contact-level dielectric layer 70 and can contact a top surface of the additional conductive gate cap structure (236, 240).

The first gate electrode 14 and the second gate electrode 14 do not contact the contact-level dielectric layer 70, and are spaced from the contact-level dielectric layer 70 by a first dielectric gate spacer 56 and a conductive gate connection structure comprising the conductive gate cap structure 240). The third gate electrode 14 can have a same thickness as the first gate electrode 14 and the second gate electrode 14. A portion of a top surface of the third gate electrode 14 is in direct contact with the contact-level dielectric layer 70.

At least one gate contact structure (such as a first gate contact via structure 76G) extends through the contact-level dielectric layer 70 and contacts a top surface of the conductive gate connection structure comprising the conductive gate cap structure 240, and at least one additional gate contact structure (such as a second gate contact via structure 86G) extends through the contact-level dielectric layer 70 and contacts a portion of a top surface of the third gate electrode 14. An entirety of the top surface of the third gate electrode 14 is in contact with the at least one additional gate contact structure or the contact-level dielectric layer 70.

The third exemplary structure can comprise an additional field effect transistor such as a fourth field effect transistor formed in a third field effect transistor region (500 or 600). The additional field effect transistor comprises an additional active region having a pair of lengthwise sidewalls and a pair of widthwise sidewalls that contact sidewalls of, and are laterally surrounded by, an additional portion of the trench isolation structure 8. The additional field effect transistor comprises an additional gate structure (10, 14, 236, 240) overlies the additional active region. The additional gate structure (10, 14, 236, 240) can include an additional gate dielectric 10 having a greater thickness than the first gate dielectric 12, an additional gate electrode 14 (which may have a same thickness as the first gate electrode 14, an additional semiconductor gate cap structure 236 having a same thickness and a same material composition as the first semiconductor gate cap structures 236, and an additional conductive gate cap structure 240 having a same thickness and a same material composition as the first conductive gate cap structure 240. An entirety of a top surface of the additional gate electrode 14 is in contact with a bottom surface of the additional semiconductor gate cap structure 236.

In one embodiment, the third exemplary structure may comprise a passive device, which may be selected from a capacitor, a resistor, or any other passive device known in the art. The passive device comprises a layer stack including, from bottom to top, a first dielectric layer (such as another instance of a gate dielectric 12), a first semiconductor plate (such as a gate electrode 14), a second dielectric layer (such as a planar dielectric spacer plate 30), a second semiconductor plate (such as a planar semiconductor spacer plate 34), a third semiconductor plate (such as a semiconductor gate cap structure 236), and a metallic plate (such as a conductive gate cap structure 240). The first dielectric layer has a same material composition and a same thickness as the first gate dielectric 12. The first semiconductor plate may a same thickness as the first gate electrode 14. The second dielectric layer has a same material composition and a same thickness as the first planar dielectric spacer plate 30. The third semiconductor plate has the same material composition and the same thickness as the first semiconductor gate cap structure 236 in the first field effect transistor region (100 and/or 200). The metallic plate has a same material composition and a same thickness as the first conductive gate cap structure 240 in the first field effect transistor region (100 and/or 200).

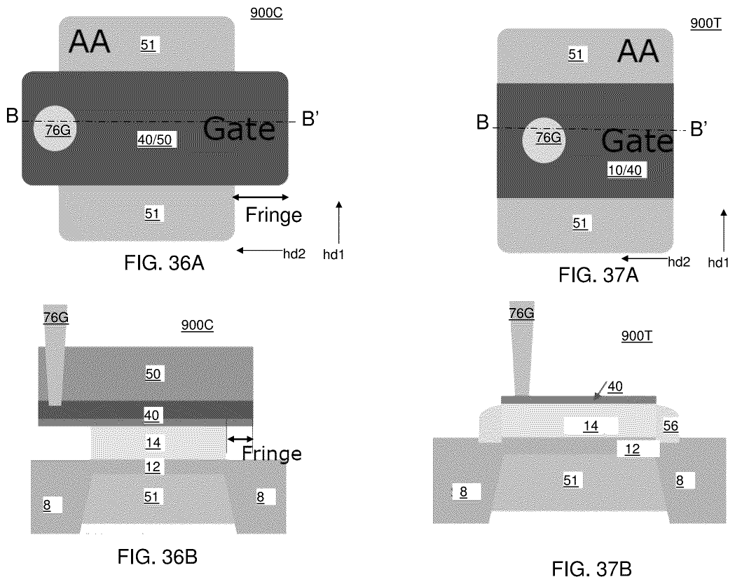

FIGS. 36A and 36B illustrate a comparative sense amplifier transistor 900C. The transistor 900C may be located in the sense amplifier region of the driver circuit. The gate electrode (40, 50) of the transistor 900C extends over the active region 51 in the second horizontal direction (e.g., transistor width direction) hd2. The second horizontal direction hd2 is perpendicular to the first horizontal direction (e.g., transistor length direction) hd1 which is parallel to the source to drain direction. The comparative sense amplifier transistor 900C includes fringe region in which the gate electrode (40, 50) extends past the active region 51 in the second horizontal direction hd2 and overlies a portion of the trench isolation region 8.

FIGS. 37A and 37B illustrate a fourth exemplary sense amplifier transistor 900T according to the fourth embodiment of the present disclosure. The gate cap dielectric 50 may be omitted in the transistor 900T, and the gate electrode may comprise a heavily doped polysilicon portion 14 and a conductive gate cap structure which comprises a self-aligned silicide portion 40 located on the polysilicon portion 14. The transistor 900T does not include the fringe region in which the gate electrode (14, 40) extends past the active region 51 in the second horizontal direction hd2. Thus, the gate electrodes (14, 40) does not overlie a portion of the trench isolation region 8 and the entire foot print of the gate electrode (14, 40) is located over and within the lateral boundary of the active region 51. Thus, the gate electrode (14, 40) may be self-aligned to the active region 51 and have a width that is substantially the same as the active region 51 width. The silicide portion 40 may act as a gate contact via structure 76G tap area. Alternatively, the conductive gate cap structure 40 may comprise a metal and/or metal nitride structure, such as a W/TiN/Ti structure.

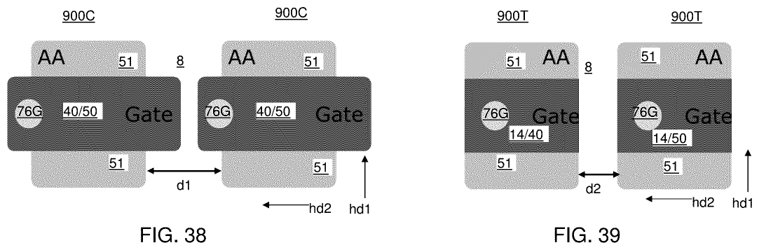

FIG. 38 is a top-down view of two adjacent comparative sense amplifier transistors 900C of FIG. 36A, and FIG. 39 is a top-down view of two adjacent fourth exemplary sense amplifier transistors 900T of FIG. 37A according to the fourth embodiment of the present disclosure. Due to the fringe region in the transistor 900C, the distance d1 along the second horizontal direction hd2 between the active regions 51 of adjacent transistors 900C is longer than the distance d2 along the second horizontal direction hd2 between the active regions 51 of adjacent transistors 900T. Therefore, the fringeless transistors 900T may be formed closer to each other and take up less chip space than the comparative transistors 900C. Thus, the overall chip size may be reduced.

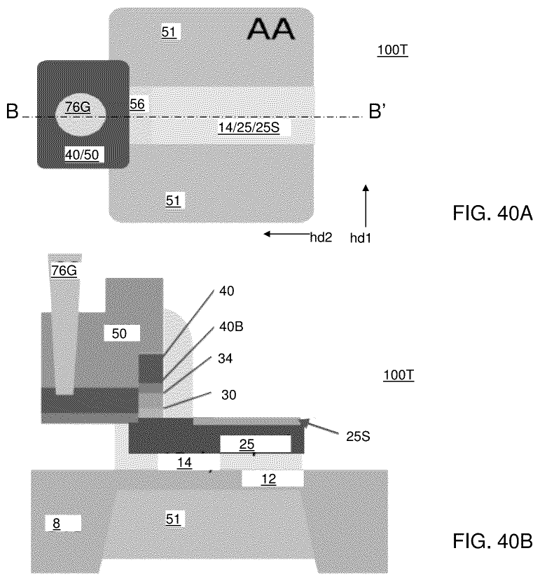

FIGS. 40A and 40B illustrate a first exemplary transistor 100T according to the first embodiment of the present disclosure. The transistor 100T may be located in the low or very low voltage transistor regions (100, 200, 300 or 400) of the peripheral circuit. For example, the transistor 100T may be located in region 100 of FIGS. 14A and 14B. The transistor 100T is also fringeless and lacks the above described fringe region.

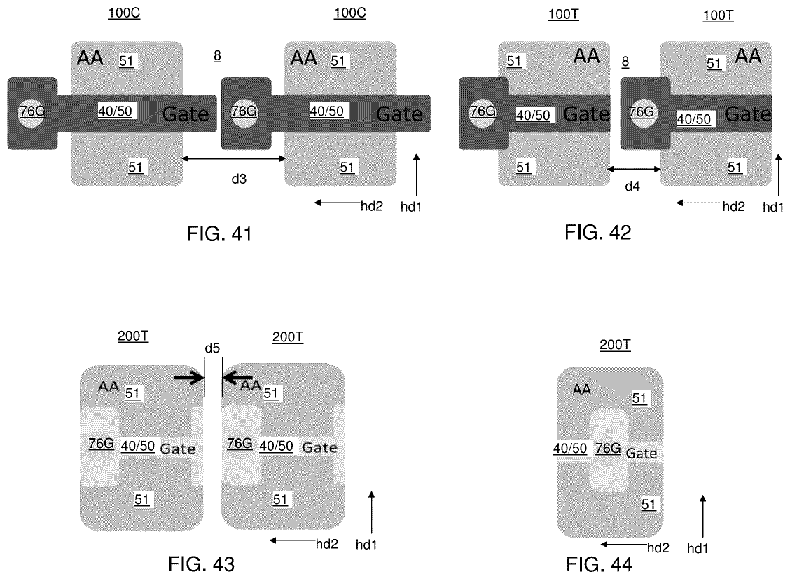

FIG. 41 is a top-down view of two adjacent comparative transistors 100C which contain the above described fringe region in which the gate electrode (40, 50) extends past the back side boundary of the active region 51. FIG. 42 is a top-down view of two adjacent first exemplary transistors 100T of FIG. 40A which lack the fringe region on the back side of the active region 51. Due to the fringe region in the transistor 100C, the distance d3 along the second horizontal direction hd2 between the active regions 51 of adjacent transistors 100C is longer than the distance d4 along the second horizontal direction hd2 between the active regions 51 of adjacent transistors 100T. Therefore, the embodiment transistors 100T may be formed closer to each other and take up less chip space than the comparative transistors 100C. Thus, the overall chip size may be reduced.

FIG. 43 is a top-down view of two adjacent second exemplary transistors 200T according to the second embodiment of the present disclosure. The second exemplary transistors 200T may be located in the low or very low voltage transistor region 200 of FIGS. 25A and 25B. The transistors 200T are fringeless and lack fringe regions on front and back sides of the active region 51. The gate electrode (40, 50) is located above and entirely within the boundaries (i.e., footprint) of the active region 51. Therefore, the fringeless transistors 200T may be formed even closer to each other than transistors 100T, and the distance d5 along the second horizontal direction hd2 between the active regions 51 of adjacent transistors 200C is even shorter longer than the distance d4 along the second horizontal direction hd2 between the active regions 51 of adjacent transistors 100T. Therefore, the embodiment transistors 200T may be formed even closer to each other and take up even less chip space.

FIG. 44 is a top-down view of an alternative configuration of the second exemplary transistor 200T according to the second embodiment of the present disclosure. In the configuration of FIG. 44, the first gate contact via structures 76G may be located closer to the middle of the underlying gate electrode (40, 50), than to the edge of the underlying gate electrode (40, 50) as shown in FIG. 43. This configuration reduces the risk of misalignment between the contact pad area of the underlying gate electrode (40, 50) and the first gate contact via structures 76G.

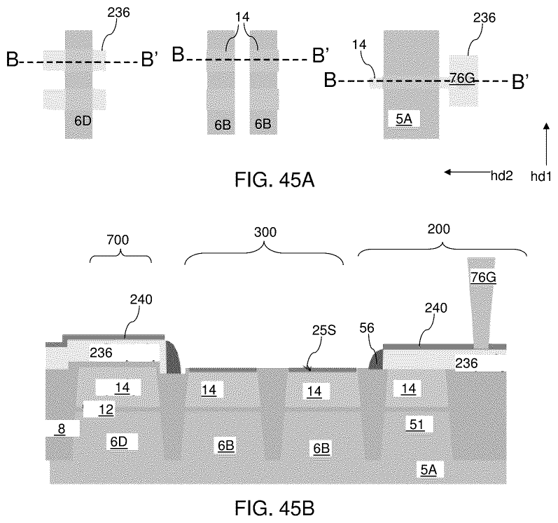

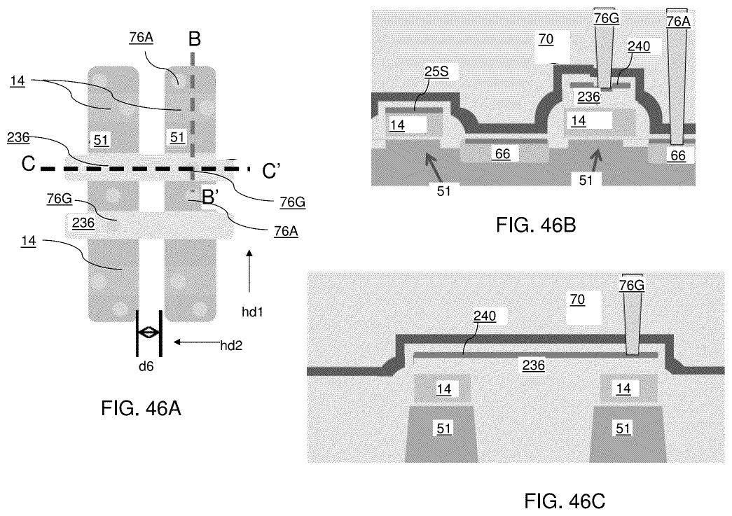

FIGS. 45A, 45B, 46A, 46B and 46C illustrate third exemplary transistor structures according to the third embodiment of the present disclosure. The overlying semiconductor gate cap structure 236 and the conductive gate cap structure 240 are used as the gate contact via structure 76G tap area for transistor structures containing both fringed and fringeless transistors. Specifically, the fringeless transistors lack the overlying semiconductor gate cap structure 236 and may include a fringeless gate electrode 14. The fringed transistors include both the overlying semiconductor gate cap structure 236 and the underlying gate electrode 14 which extend past the boundary of the active regions 51, as shown in FIGS. 46A and 46C.

The polysilicon gate electrode 14 and semiconductor gate cap structure 236 resistance is reduced by including respective silicide regions 25S and 240 on their upper surfaces. The semiconductor gate cap structure 236 extends along the second horizontal direction hd2 between two adjacent transistor structures and acts as the common gate contact via structure 76G tap area. Furthermore, since both the underlying gate electrodes 14 and the overlying semiconductor gate cap structures 236 comprise polysilicon with a silicide cap structure, it becomes easier to tune the characteristics of the fringeless transistors which include only the underlying gate electrode 14 and the fringed transistors which include both the underlying gate electrodes 14 and the overlying semiconductor gate cap structures 236.

The transistor structures may be formed closer to each other (e.g., be separated by relatively small distance d2 along the second horizontal direction) and take up relatively less chip space. Thus, the overall chip size may be reduced.

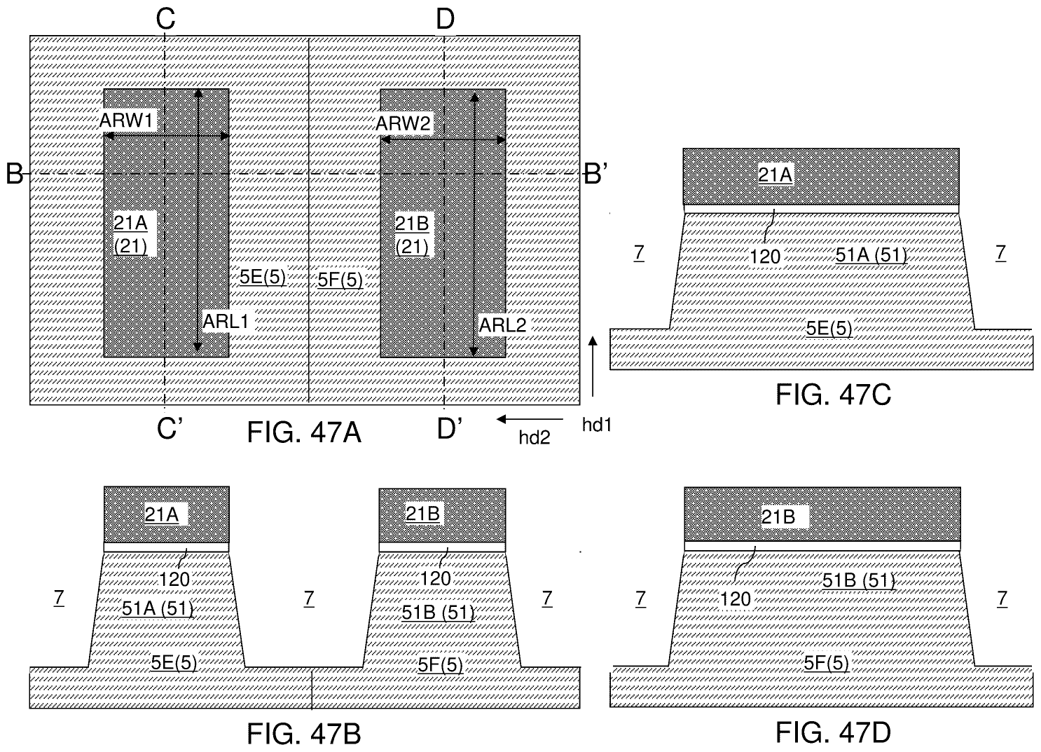

Referring to FIGS. 47A-47D, a fifth exemplary structure according to a fifth embodiment of the present disclosure is illustrated after formation of shallow trenches. The fifth exemplary structure can be formed as an additional portion of the first exemplary structure, the second exemplary structure, or the third exemplary structure, or may replace the entirety, or a portion of, any of the first exemplary structure, the second exemplary structure, or the third exemplary structure. In one embodiment, the fifth exemplary structure can be derived from the first exemplary structure illustrated in FIGS. 1A-1F by forming additional device regions, or by replacing one or more device regions in the first exemplary structure of FIGS. 1A-1E with the device regions illustrated in FIGS. 47A-47D.

In an illustrative example, the fifth exemplary structure may comprise a first doped well 5E and a second doped well 5F, each of which may independently have a doping of a first conductivity type or a doping of a second conductivity type. Each of the first doped well 5E and the second doped well 5F may be formed in an upper portion of a substrate semiconductor layer 4 in the same manner as the p-type wells (5A, 5B, 5C) or the n-type wells (6A, 6B, 6C, 6D) illustrated in FIGS. 1A-1F. Each of the first doped well 5E and the second doped well 5F may independently include dopants of the first conductivity type or dopants of the second conductivity type at an atomic concentration in a range from 1.0×10¹⁴/cm³ to 1.0×10¹⁸/cm³, such as from 1.0×10¹⁵/cm³ to 1.0×10¹¹/cm³, although lesser and greater atomic concentrations can also be employed. The depth of each doped well (5E, 5F) may be in a range from 50 nm to 2,000 nm, although lesser and greater depths may also be employed. The first doped well 5E is used to form a peripheral transistor, while the second doped well is used to form a sense amplifier transistor for a memory device, such as a three dimensional memory device.

A silicon oxide pad dielectric layer and a hardmask material layer can be sequentially deposited over a top surface of the semiconductor substrate including the doped wells (5E, 5F). A photoresist layer (not shown) can be applied over the top surface of the hardmask material layer, and can be lithographically patterned to form a plurality of discrete photoresist material portions. In one embodiment, the plurality of discrete photoresist material portions may comprise photoresist material portion having a respective rectangular horizontal cross-sectional shape and located entirely within the area of a respective one of the doped wells (5E, 5F). In one embodiment, the rectangular horizontal cross-sectional shapes may have a pair of lengthwise edges that are parallel to a first horizontal direction hd1 and a pair of widthwise edges that are parallel to a second horizontal direction hd2 that is perpendicular to the first horizontal direction hd1.

A first anisotropic etch process can be performed to transfer the pattern of the photoresist material portions through the hardmask material layer and the silicon oxide pad dielectric layer. Vertical stacks of a silicon oxide pad dielectric 120 and a hardmask plate 21 can be formed underneath each patterned photoresist material portion. Each silicon oxide pad dielectric 120 is a patterned portion of the silicon oxide pad dielectric layer, and each hardmask plate 21 is a patterned portion of the hardmask material layer. In one embodiment, the silicon oxide pad dielectrics 120 may consist essentially of silicon oxide, and may have a thickness in a range from 3 nm to 30 nm, such as from 6 nm to 15 nm, although lesser and greater thicknesses may also be employed. In one embodiment, the hardmask plates 21 may consist essentially of silicon nitride, and may have a thickness in a range from 60 nm to 300 nm, such as from 100 nm to 200 nm, although lesser and greater thicknesses may also be employed. The photoresist layer may be removed, for example, by ashing, or alternatively, may be collaterally removed during a subsequent anisotropic etch process.

A second anisotropic etch process can be performed to transfer the pattern of the hardmask plates 21 into an upper portion of the semiconductor substrate. The upper portion of the semiconductor substrate that is not masked by the hardmask plates 21 is anisotropically etched by the second anisotropic etch process to form a shallow isolation trench 7. The shallow isolation trench 7 laterally surrounds active regions 51 of the semiconductor substrate, which are patterned upper portions of the semiconductor substrate that are laterally surrounded by the shallow isolation trench 7. The active regions 51 comprise a first active region 51A that underlies a first hardmask plate 21A of the hardmask plates 21 and comprises a portion of the first doped well 5E, and a second active region 51B that underlies a second hardmask plate 21B of the hardmask plates 21 and comprises a portion of the second doped well 5F.

In one embodiment, each active region 51 may have a respective rectangular top surface. In one embodiment, a top surface of the first active region 51A has a first active region length ARL1 along the first horizontal direction hd1 and has a first active region width ARW1 along the second horizontal direction hd2. In one embodiment, a top surface of the second active region 51B has a second active region length ARL2 along the first horizontal direction hd1 and has a second active region width ARW2 along the second horizontal direction hd2. The depth of the shallow isolation trench 7 may be in a range from 200 nm to 800 nm, such as from 300 nm to 600 nm, although lesser and greater depths may also be employed. The thickness of each active region 51 can be the same as the depth of the shallow isolation trench 7.

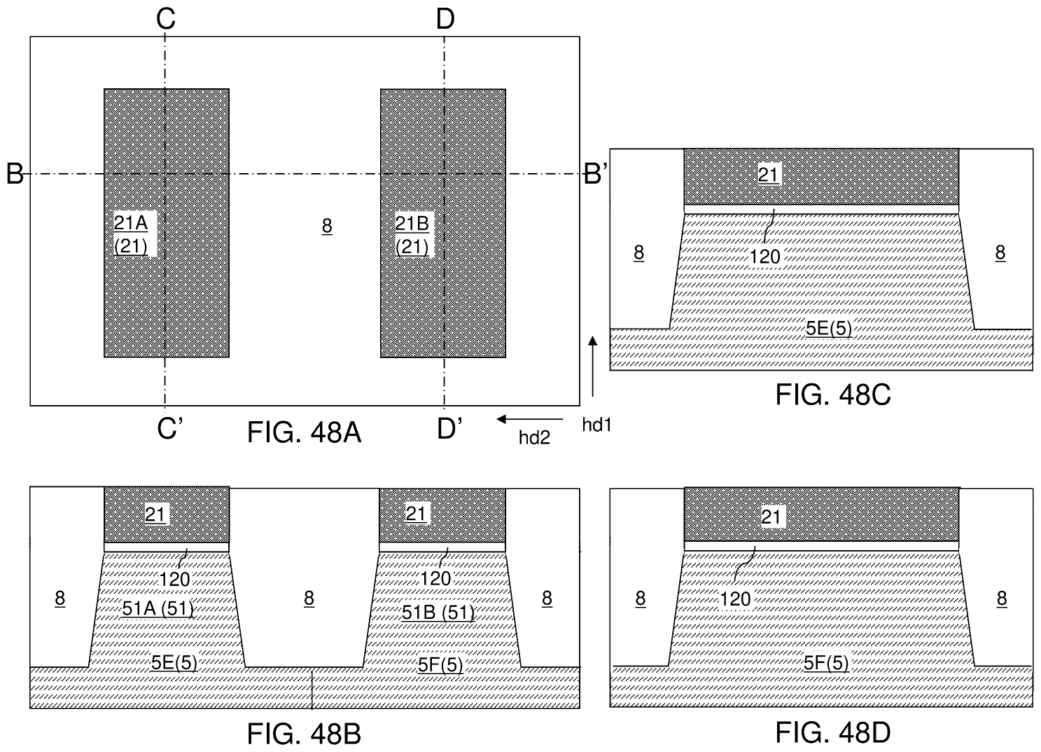

Referring to FIGS. 48A-48D, at least one dielectric fill material can be conformally deposited in the trenches 7 and over the hardmask plates 21. The at least one dielectric fill material may comprise a silicon oxide material. Optionally, a dielectric liner such as a silicon nitride liner (not expressly shown) may be deposited prior to deposition of the at least one dielectric fill material. Excess portions of the at least one dielectric fill material can be removed from above the horizontal plane including the top surfaces of the hardmask plates 21 by a planarization process, which may include a chemical mechanical polishing (CMP) process. In one embodiment, the CMP process stops on the hardmask plates 21.

The remaining portions of the at least one dielectric fill material filling the trenches 7 constitute a trench isolation structure 8, which may be a continuous structure contacting the semiconductor material of the semiconductor substrate with dielectric surfaces and providing electrical isolation between active regions 51 of adjacent semiconductor devices to be subsequently formed. The trench isolation structures 8 may comprise shallow trench isolation structures located in the shallow isolation trenches 7. Each device active region 51 may comprise a patterned portion of a respective doped well (5E, 5F) that is laterally surrounded by a respective portion of the trench isolation structure 8. Each of the hardmask plates 21 may comprise a respective horizontal bottom surface located within a horizontal plane and a respective horizontal top surface located within another horizontal plane.

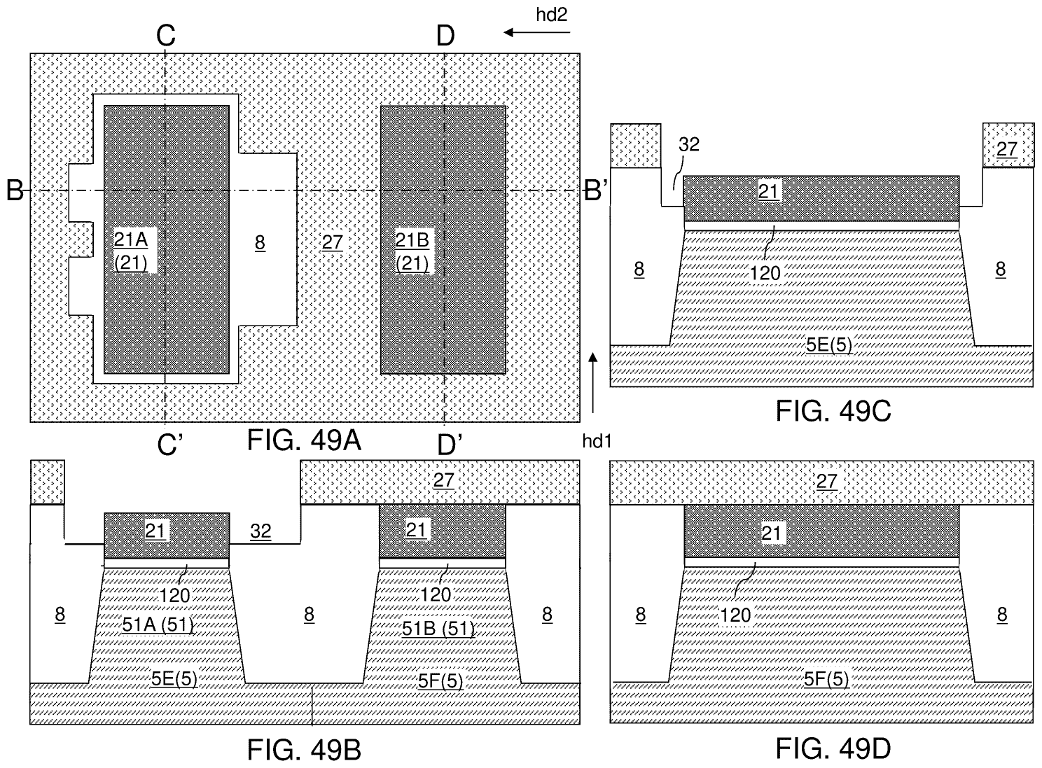

Referring to FIGS. 49A-49D, a photoresist layer 27 can be applied over the hardmask plates 21 and the trench isolation structure 8, and can be lithographically patterned to form an opening having an area that includes the entirety of the area of the first hardmask plate 21A located over the first doped well 5E. According to an aspect of the present disclosure, the periphery of the opening in the patterned photoresist layer 27 can be laterally offset outward from the sidewalls of the first hardmask plate 21A at least by a minimum lateral offset distance. In one embodiment, the minimum lateral offset distance can be the same as, or greater than, the lateral thickness of dielectric spacers to be subsequently formed. In one embodiment, the minimum lateral offset distance may be in a range from 5 nm to 200 nm, such as from 10 nm to 100 nm, although lesser and greater minimum lateral offset distances may also be employed.

According to an aspect of the present disclosure, at least one region of the area between the sidewalls of the first hardmask plate 21A and the periphery of the opening in the patterned photoresist layer 27 that surrounds the first hardmask plate 21A may be wide enough to accommodate at least one gate contact via structure. In other words, a gap region 32 between the sidewalls of the first hardmask plate 21A and the periphery of the opening in the patterned photoresist layer 27 can continuously extend around the first hardmask plate 21A, and includes an area in which at least one gate contact via structure can be subsequently formed without areal overlap with the first hardmask plate 21A or the patterned photoresist layer 27.

An etch process that etches the material of the trench isolation structure 8 selective to the material of the hardmask plates 21 can be performed to vertically recess the gap region 32 of the trench isolation structure 8 that laterally surrounds the first active region 51A (i.e., the portion of the first doped well 5E that underlies the first hardmask plate 21A) while masking the second hardmask plate 21B, the second active region 5F and a field region of the trench isolation structure 8 that laterally surrounds the gap region 32. The etch process may comprise an anisotropic etch process (such as a reactive ion etch process). The field region of the trench isolation structure 8 can include the portion of the portion of the trench isolation structure 8 that is covered by the photoresist layer 27. A recessed horizontal surface of the trench isolation structure 8 is formed in a portion of the trench isolation structure 8 located in the gap region 32. The recessed horizontal surface is vertically recessed relative to a topmost surface of the trench isolation structure 8 located in the field region and contained with the second horizontal plane.

Generally, the gap region 32 of the trench isolation structure 8 is vertically recessed by performing the etch process, which etches unmasked portions of the trench isolation structure 8 while the hardmask plates 21 are present over the semiconductor substrate. The recessed horizontal surface is formed above the horizontal plane including the bottom surfaces of the hardmask plates 21, and below the horizontal plane including the top surfaces of the hardmask plates 21. In one embodiment, the recess horizontal surface may be located within a horizontal plane. The patterned photoresist layer 27 can be subsequently removed, for example, by ashing.

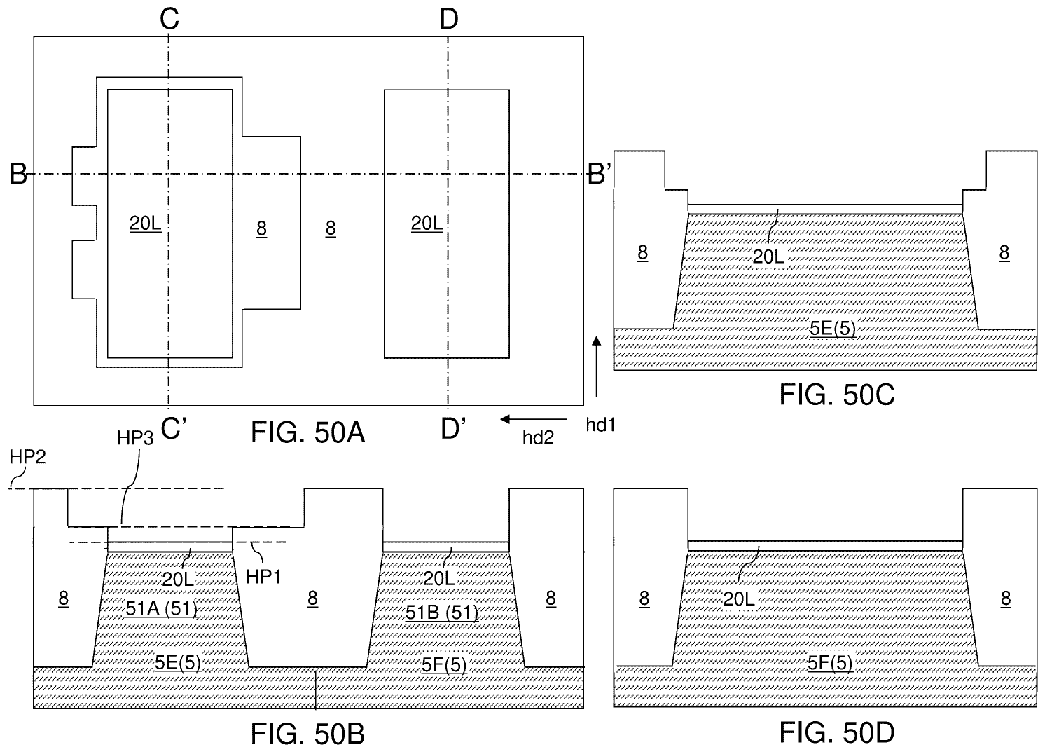

Referring to FIGS. 50A-50D, a selective first etch process (such as a wet etch process) can be performed to remove the hardmask plates 21 selective to the materials of the trench isolation structure 8 and the silicon oxide pad dielectrics 120. For example, if the hardmask plates 21 comprise silicon nitride, the first etch process may comprise a wet etch process employing hot phosphoric acid.

An optional second etch process can be performed to remove the silicon oxide pad dielectrics 120 selective to the materials of the semiconductor substrate. For example, the second etch process may comprise an anisotropic etch process (such as a reaction ion etch process) or an isotropic etch process (such as a wet etch process). The silicon oxide pad dielectrics 120, if present, can be removed, and the top surfaces of the active regions can be physically exposed around openings through the trench isolation structure 8.

A gate dielectric layer 20L can be formed on the physically exposed surfaces of the doped wells (5E, 5F), for example, by thermal oxidation of the surface portions of the doped wells (5E, 5F) and/or by conformal deposition of a gate dielectric material layer. The conformally deposited gate dielectric material layer, if employed, may comprise silicon oxide and/or a dielectric metal oxide material (such as aluminum oxide, hafnium oxide, tantalum oxide, lanthanum oxide, yttrium oxide, etc.). The thickness of the gate dielectric layer 20L may be in a range from 2 nm to 50 nm, such as from 6 nm to 30 nm, although lesser and greater thicknesses may also be employed.

Alternatively, second etch process may be omitted and the pad dielectrics 120 may be retained. In this case, the pad dielectrics 120 function as the gate dielectric layer 20L.

The top surface of the gate dielectric layer 20L may be located within a first horizontal plane HP1. The topmost surfaces of the trench isolation structure 8 may be located within a second horizontal plane HP2. The recessed horizontal surface of the trench isolation structure 8 in the gap region 32 may be located within a third horizontal plane HP3. The vertical distance between the first horizontal plane HP1 and the second horizontal plane HP2 may be in a range from 60 nm to 300 nm, although lesser and greater vertical distances may also be employed. In one embodiment, the vertical distance between the third horizontal plane HP3 and the first horizontal plane HP1 may be in a range from 10% to 90%, such as from 20% to 80% and/or from 30% to 70%. of the vertical distance between the second horizontal plane HP2 and the first horizontal plane HP1.

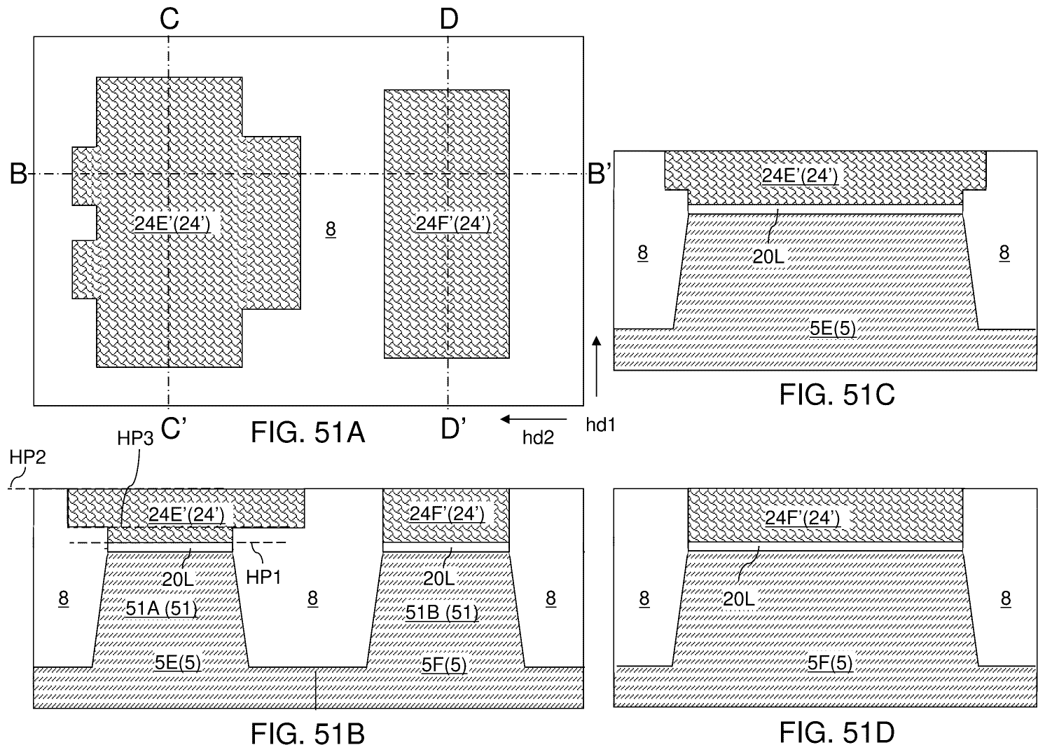

Referring to FIGS. 51A-51D, at least one gate electrode material can be deposited in the cavities located in the openings through the trench isolation structure 8. The at least one gate electrode material comprises a conductive material, such as heavily doped polysilicon and/or a metallic (i.e., metal or metal alloy) material, and/or a heavily doped amorphous semiconductor material (such as heavily doped amorphous silicon) that can be converted into a conductive material (such as heavily doped polysilicon) upon a subsequent anneal process.

A planarization process, such as a chemical mechanical polishing (CMP) process, can be performed to remove portions of the at least one gate electrode material from above the second horizontal plane HP2, i.e., the horizontal plane including the topmost surfaces of the trench isolation structure 8. A thermal anneal may be performed as needed to convert any amorphous semiconductor material in the at least one gate electrode material into a heavily doped polycrystalline semiconductor material that is electrically conductive. Remaining portions of the at least one gate electrode material constitute gate electrode material portions 24′, which comprise a first gate electrode material portion 24E′ and a second gate electrode material portion 24F′. The first gate electrode material portion 24E′ can overlie the first active region 51A (i.e., a portion of the first doped well 5E), and the second gate electrode material portion 24F′ can overlie the second active region 51B (i.e., a portion of the second doped well 5F). The first gate electrode material portion 24E′ can be formed over and on the gate dielectric layer 20L and the recessed horizontal surface of the trench isolation structure 8 located within the third horizontal plane HP3.

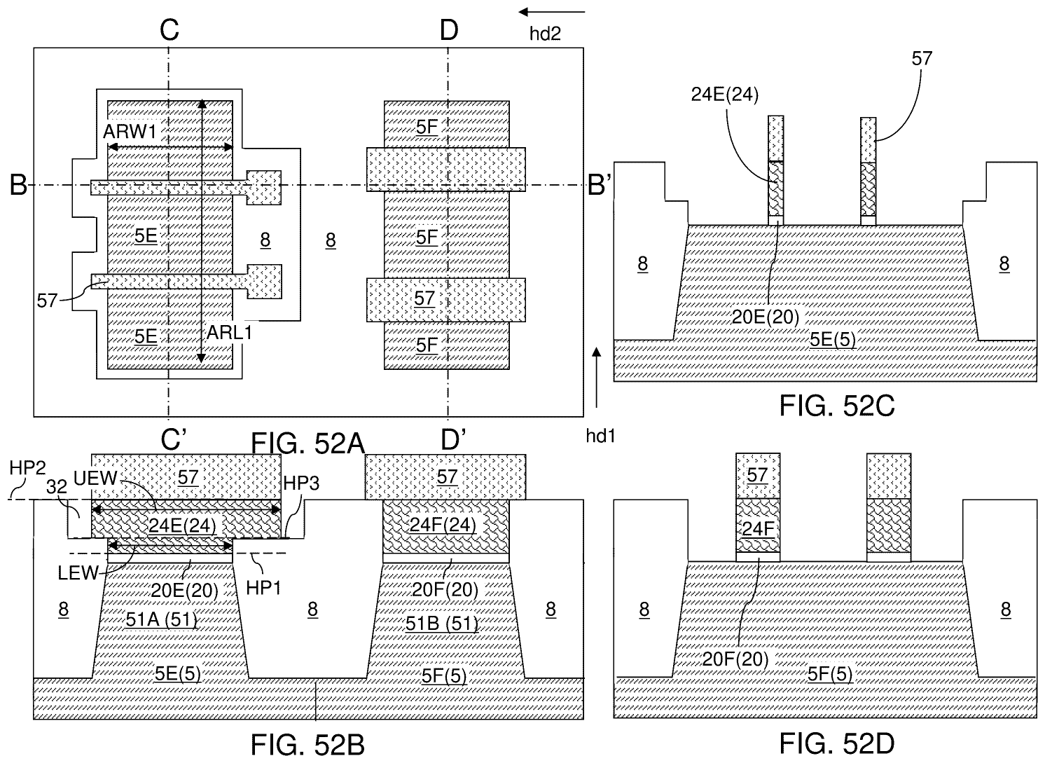

Referring to FIGS. 52A-52D, a photoresist layer 57 can be applied over the gate electrode material portions 24′ and the trench isolation structure 8, and can be lithographically patterned into patterns of gate electrodes to be subsequently formed. In an illustrative example, the patterned photoresist layer 57 may include a pair of first photoresist material portions that straddle the first active region 51A along the second horizontal direction hd2 and a pair of second photoresist material portions that straddle the second active region 51B along the second horizontal direction hd2. According to an aspect of the present disclosure, the peripheries of the pairs first photoresist material portions in a plan view may be located entirely within the area defined by the outer periphery of the gap region 32, i.e., by the outer periphery of the recessed horizontal surface of the trench isolation structure 8 that laterally surrounds the first active region 51A. In one embodiment, the peripheries of the pair first photoresist material portions in the plan view may be laterally spaced inward from the outer periphery of the gap region 32 at least by the lateral thickness of dielectric spacers to be subsequently formed. In one embodiment, the lateral extent of each photoresist material portion of the patterned photoresist layer 57 overlying the second active region 51B may be greater than the width of the second active region 51B along the second horizontal direction hd2, and the widthwise edges of the photoresist material portions of the patterned photoresist layer 57 overlying the second active region may be located entirely outside the area of the second active region in the plan view (such as the top-down view of FIG. 52A).

An anisotropic etch process can be performed to etch portions of the gate electrode material portions 24′ and the gate dielectric layers 20L that are not masked by the patterned photoresist layer 57. The anisotropic etch process may include a first etch step that etches the material(s) of the gate electrode material portions 24′ selective to the materials of the trench isolation structure 8 and the gate dielectric layers 20L, and a second etch step that etches the material of the gate dielectric layers 20L selective to the material of the semiconductor substrate (which is the material of the doped wells (5E, 5F)). Patterned portions of the gate electrode material portion 24′ constitute gate electrodes 24, which comprise first gate electrodes 24E that overlie the first action region 51A in the first doped well 5E, and second gate electrodes 24F that overlie the second active region 51B in the second doped well 5F. Patterned portions of the gate dielectric layers 20L constitute gate dielectrics 20, which comprise first gate dielectrics 20E and second gate dielectrics 20F.

Generally, at least one first gate electrode 24E can be formed by patterning the first gate electrode material portion 24E′, and at least one second gate electrode 24F can be formed by patterning the second gate electrode material portion 24F′. The at least one first gate electrode 24E comprises a respective lower gate electrode portion contacting a top surface of a respective first gate dielectric 20E and a pair of sidewall segments of the trench isolation structure 8, and comprises a respective upper gate electrode portion contacting top surfaces respective first segments of the recessed horizontal surface of the trench isolation structure 8 and having sidewalls exposed in the gap region 32. Each lower gate electrode portion is located entirely between the first horizontal plane HP1 and the third horizontal plane HP3, and each upper gate electrode portion is located entirely between the second horizontal plane HP2 and the third horizontal plane HP3.

In one embodiment, a top surface of the first active region 51A has an active region length ARL along a first horizontal direction hd1 and has an active region width ARW along a second horizontal direction hd2. In one embodiment, the lower gate electrode portion of each first gate electrode 24E has a lower electrode width LEW along the second horizontal direction hd2 that is the same as the active region width ARW. The upper gate electrode portion has an upper electrode width UEW along the second horizontal direction hd2 that is greater than the active region width ARW. The patterned photoresist layer 57 can be subsequently removed, for example, by ashing.

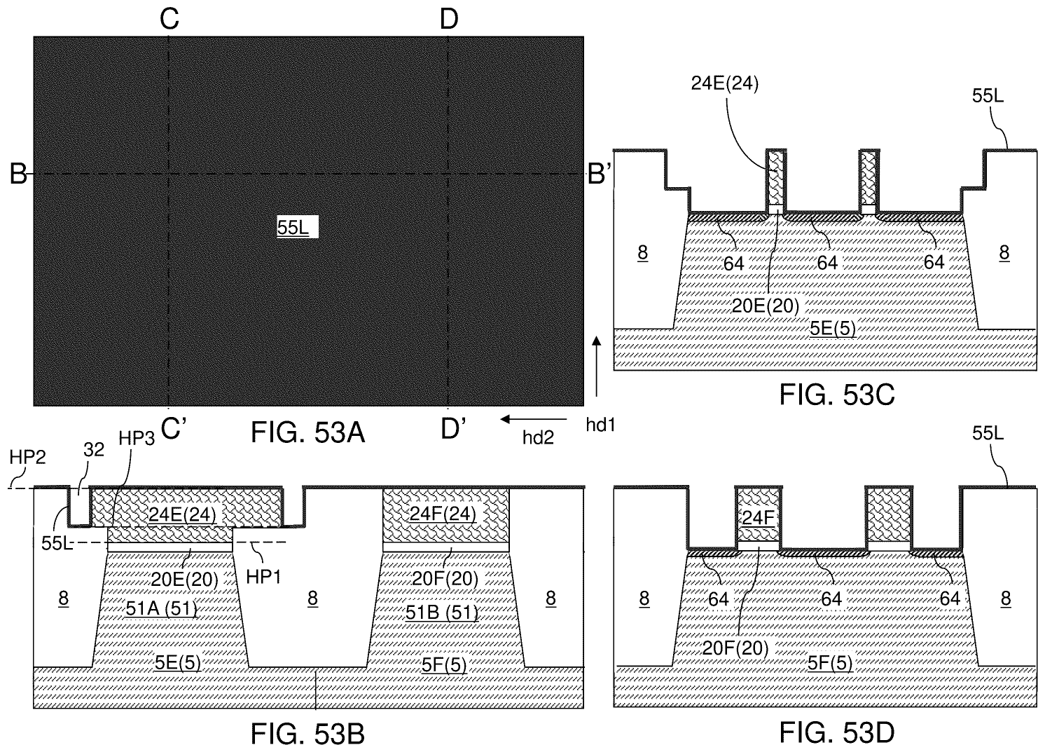

Referring to FIGS. 53A-53D, an optional dielectric liner layer 55L can be conformally deposited on the physically exposed surfaces of the gate electrodes 24 and the trench isolation structure 8, including in the gap region 32. The dielectric liner layer 55L, if present, comprises first dielectric spacer material layer. The dielectric liner layer 55L can be conformally formed over, and around, the gate electrodes 24 and over the recessed horizontal surface of the trench isolation structure 8. The dielectric liner 55L comprises a dielectric material such as silicon nitride, and has a thickness in a range from 1 nm to 20 nm, such as from 2 nm to 10 nm, although lesser and greater thicknesses may also be employed. Generally, the thickness of the dielectric liner layer 55L may be selected to optimize the profile of the source/drain extension regions 64 to be subsequently formed.

Electrical dopants can be implanted into exposed surface portions of the active regions (51A, 51B) to form source/drain extension regions 64. Each source/drain extension region 64 can form a p-n junction with a respective underlying doped well (5E, 5F). The source/drain extension regions 64 may include electrical dopants of a respective conductivity type at an atomic concentration in a range from 1.0×10⁷/cm³ to 1.0×10²⁰/cm³, although lower and higher atomic concentrations may also be employed. The depth of each source/drain extension region 64 may be in a range from 5 nm to 100 nm, such as from 10 nm to 50 nm, although lesser and greater depths may also be employed.

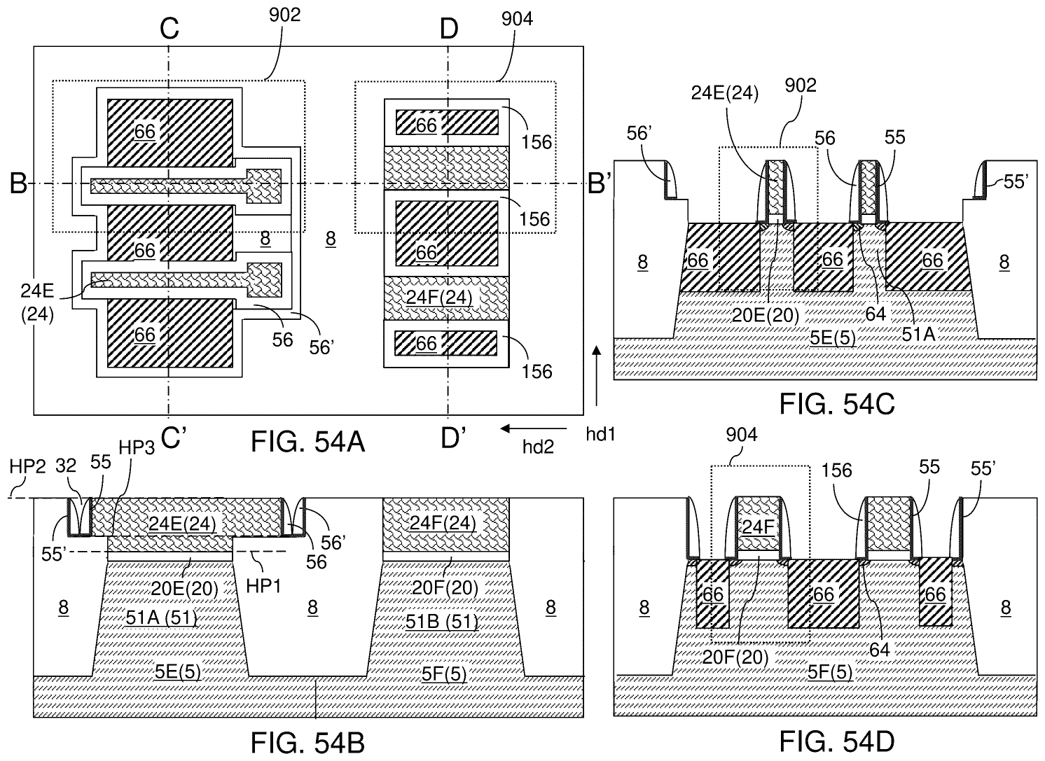

Referring to FIGS. 54A-54D, a main dielectric spacer layer can be conformally deposited. The main dielectric spacer layer comprises a dielectric spacer material layer. Generally, at least one dielectric spacer material layer can be deposited over the gate electrodes 24 and trench isolation structure 8. The at least one dielectric spacer material layer comprises the optional dielectric liner layer 55L and the main dielectric spacer layer. The main dielectric spacer layer comprises a dielectric material such as silicon oxide. The thickness of the main dielectric spacer layer may be in a range from 10 nm to 300 nm, such as from 20 nm to 150 nm, although lesser and greater thicknesses may also be employed.

An anisotropic etch process can be performed to remove horizontally-extending portions of the at least one dielectric spacer material layer. Generally, at least one dielectric spacer material layer can be conformally formed over and around the first gate electrodes 24E, the second gate electrodes 24F, and over the recessed horizontal surface and the topmost surface of the trench isolation structure 8. Remaining portions of the at least one dielectric spacer material layer comprise dielectric gate spacers (55, 56) laterally surrounding, and contacting, a respective one of the gate electrodes 24, and a dielectric isolation spacer (55′, 56′) contacting sidewalls of the trench isolation structure 8 that are located between the second horizontal plane HP2 and the third horizontal plane HP3.

In one embodiment, each dielectric gate spacer (55, 56) may be a composite dielectric gate spacer including at least two different components (which may have different dielectric compositions), and the dielectric isolation spacer (55′, 56′) may be a composite dielectric isolation spacer including at least two different components. In one embodiment, each dielectric gate spacer (55, 56) may comprise a main dielectric gate spacer 56 (which is a patterned portion of the main dielectric spacer layer) and an optional liner dielectric gate spacer 55 (which is a patterned portion of the dielectric liner layer 55L). In one embodiment, the dielectric isolation spacer (55′, 56′) may comprise a main dielectric isolation spacer 56′ (which is a patterned portion of the main dielectric spacer layer) and an optional liner dielectric isolation spacer 55′ (which is a patterned portion of the dielectric liner layer 55L).

The dielectric gate spacers (55, 56) comprise at least one first dielectric gate spacer (55, 56) laterally surrounding a respective first gate electrode 24E and contacting respective second segments of the recessed horizontal surface of the trench isolation structure 8. The dielectric isolation spacer (55′, 56′) contacts sidewalls of the trench isolation structure 8 in the gap region 32 that connect the recessed horizontal surface of the trench isolation structure 8 to the topmost surface of the trench isolation structure 8.

In one embodiment, the dielectric isolation spacer (55′, 56′) comprises a same set of materials as the dielectric gate spacers (55, 56). In one embodiment, a lateral dimension between an inner periphery of a bottom surface of the dielectric isolation spacer (55′, 56′) and an outer periphery of the bottom surface of the dielectric isolation spacer (55′, 56′) may be the same as a lateral dimension between an inner periphery of a bottom surface of a dielectric gate spacer (55, 56) and an outer periphery of the bottom surface of the dielectric gate spacer (55, 56).

In one embodiment, the dielectric isolation spacer (55′, 56′) is not in direct contact with the semiconductor substrate, and the entirety of the dielectric isolation spacer (55′, 56′) is located above a horizontal plane including the recessed horizontal surface of the trench isolation structure 8 (i.e., above the third horizontal plane HP3). In one embodiment shown in FIGS. 54B and 54C, each dielectric gate spacer (55, 56) comprises a pair of first bottom surfaces contacting segments of a top surface of the first active region 51A, and a pair of second bottom surfaces contacting second segments of the recessed horizontal surface of the trench isolation structure 8 located above a horizontal plane including the pair of first bottom surfaces.

In one embodiment, the dielectric gate spacer (55, 56) is laterally spaced from sidewalls of the trench isolation structure 8 that connect the recessed horizontal surface of the trench isolation structure 8 to the topmost surface of the trench isolation structure 8.

Electrical dopants can be implanted into surface portions of the doped regions 64 and the source/drain extension regions 64 to form deep source/drain regions 66. Each deep source/drain region 66 can form a p-n junction with a respective active region (51A, 51B) in a respective underlying doped well (5E, 5F). Implanted portions of the source/drain extension regions 64 can be incorporated into a respective one of the deep source/drain regions 66, and can have a doping of the same conductivity type as the respective one of the deep source/drain regions 66. The deep source/drain regions 66 may include electrical dopants of a respective conductivity type at an atomic concentration in a range from 5.0×10¹⁸/cm³ to 2.0×10²¹/cm³, although lower and higher atomic concentrations may also be employed. The depth of each deep source/drain region 66 may be in a range from 30 nm to 600 nm, such as from 60 nm to 300 nm, although lesser and greater depths may also be employed. Each continuous combination of a source/drain extension region 64 and a deep source/drain region 66 constitutes a source/drain region (64, 66), which may function as a source region or as a drain region. A p-n junction may be formed between each source/drain region (64, 66) and a respective active region (51A, 51B) in the underlying doped well (5E, 5F).

A first field effect transistor 902 and a second field effect transistor 904 can be formed. The first field effect transistor 902 may comprise peripheral transistor that is not a sense amplifier transistor. The first field effect transistor 902 comprises a first active region 51A including a portion of the semiconductor substrate located within a first opening through the trench isolation structure 8, and a first gate structure (20E, 24E) that includes a first gate dielectric 20E and a first gate electrode 24E. The first gate electrode 24E comprises a lower gate electrode portion contacting a top surface of the first gate dielectric 20E and a pair of sidewall segments of the trench isolation structure 8, and comprises an upper gate electrode portion contacting first segments of the recessed horizontal surface of the trench isolation structure 8. The lower gate electrode portion can be located below the third horizontal plane HP3 including the recessed horizontal surface of the trench isolation structure 8, and the upper gate electrode portion can be located above the third horizontal plane HP3. A first dielectric gate spacer (55, 56) laterally surrounds the first gate electrode 24E and contacts second segments of the recessed horizontal surface of the trench isolation structure 8. The first field effect transistor 902 includes the above described fringe region.

The second field effect 904 comprises a fringeless sense amplifier transistor. The second field effect transistor 904 includes a second active region 51B including another portion of the semiconductor substrate located within a second opening through the trench isolation structure 8, and comprises a second gate structure (20F, 24F) including a second gate dielectric 20F and a second gate electrode 24F. The second gate electrode 24F comprises a pair of sidewalls vertically extending straight from a respective edge of the top surface of the second gate electrode 24F to a respective edge of a top surface of a second gate dielectric 20F that underlies the second gate electrode 24F. In one embodiment, an entirety of the pair of sidewalls of the second gate electrode 24F is in contact with a respective sidewall of the trench isolation structure 8. In one embodiment, the second gate electrode 24F comprises first sidewalls in contact with sidewall segments of the trench isolation structure 8 and second sidewalls in contact with a pair of second dielectric gate spacers (55, 156) that includes a respective main dielectric gate spacer 156 and an optional liner dielectric gate spacer 55. Each second dielectric gate spacer (55, 156) contacts the second gate electrode 24F and sidewalls of the trench isolation structure 8.

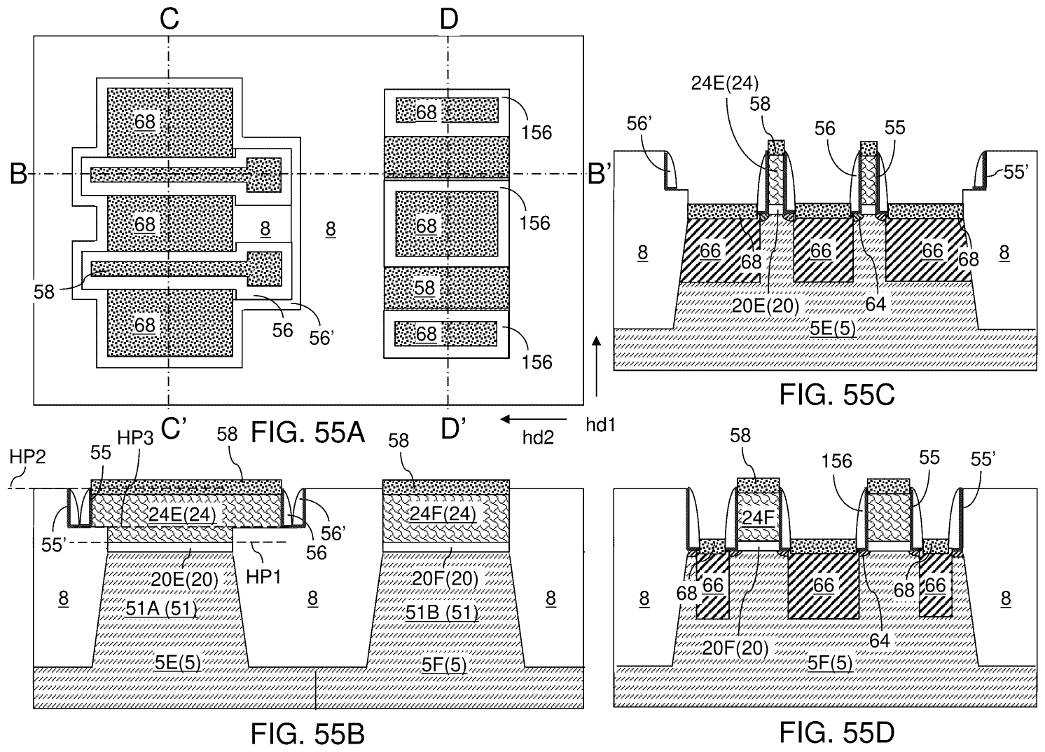

Referring to FIGS. 55A-55D, a metal (e.g., W, Co, Ni, Ti, Ta, etc.) that forms a metal-semiconductor alloy (such as a metal silicide) can be deposited on the physically exposed surfaces of the source/drain regions (64, 66) and on the top surfaces of the gate electrodes 24. Metal semiconductor alloy regions (e.g., silicide regions, such as W, Co, Ni, Ti, Ta, etc. silicide regions) (68, 58) can be formed by performing an anneal process that induces reaction of the metal with surface portions of the source/drain regions (64, 66) and surface portions of the gate electrodes 24 (in case the gate electrodes 24 comprises a semiconductor material such as silicon or a silicon-germanium alloy). The metal-semiconductor-alloy regions (68, 58) comprise source/drain metal-semiconductor alloy regions 68 in contact with the source/drain regions (64, 66), and gate metal-semiconductor alloy regions 58 in contact with the gate electrodes 24. Unreacted portions of the metal can be removed, for example, by a wet etch process that etches the metal selective to the metal-semiconductor alloys of the metal-semiconductor-alloy regions (68, 58).

In one embodiment, a first gate metal-semiconductor alloy region 58 can have a bottom surface that contacts a top surface of the first gate electrode 24E within a horizontal plane located below a horizontal plane including the topmost surface of the trench isolation structure 8 (i.e., below the second horizontal plane HP2), and can have a top surface located above the horizontal plane including the topmost surface of the trench isolation structure 8. In one embodiment, the second gate electrode 24F comprises a top surface located within a same horizontal plane as a top surface of the first gate electrode (20E, 24E).

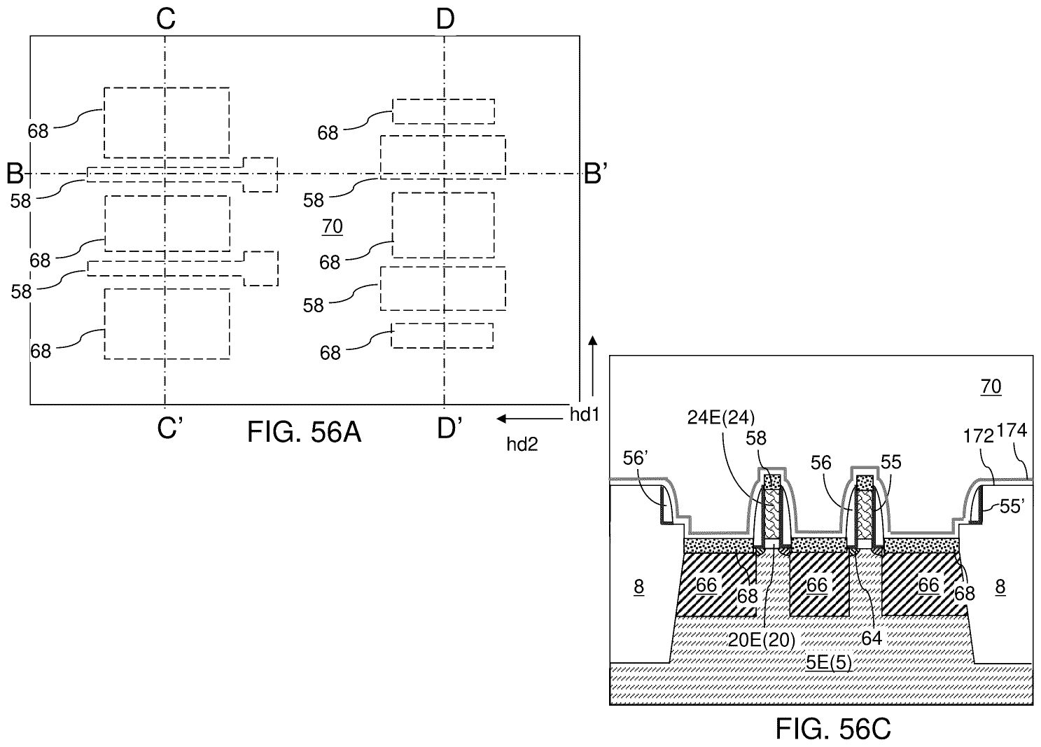

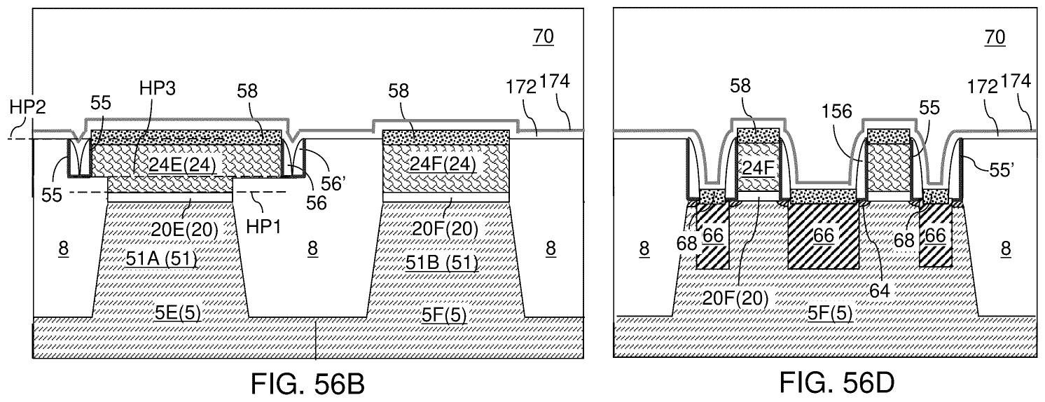

Referring to FIGS. 56A-56D, at least one dielectric liner (172, 174) can be conformally deposited over the trench isolation structure 8, the metal-semiconductor alloy regions (68, 58), and the dielectric spacers {(55, 56), (55′, 56′), (55, 136)}. The at least one dielectric liner (172, 174) may comprise a first dielectric liner 172 and a second dielectric liner 174. In one embodiment, the first dielectric liner 172 may comprise a silicon oxide liner having a thickness in a range from 3 nm to 60 nm, and a second dielectric liner 174 may comprise a silicon nitride liner having a thickness in a range from 3 nm to 60 nm.

A contact-level dielectric layer 70 can be deposited over the at least one dielectric liner (172, 174). The contact-level dielectric layer 70 includes a dielectric material such as undoped silicate glass, a doped silicate glass, or organosilicate glass. Optionally, a planarization process may be performed to planarize the top surface of the contact-level dielectric layer 70.

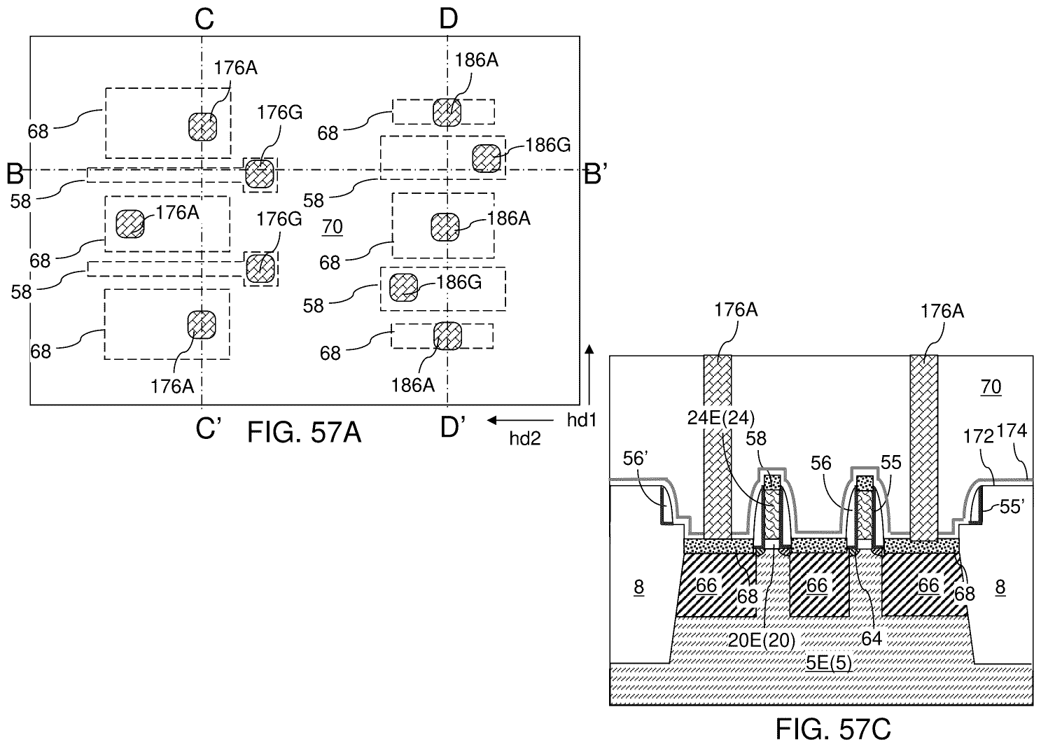

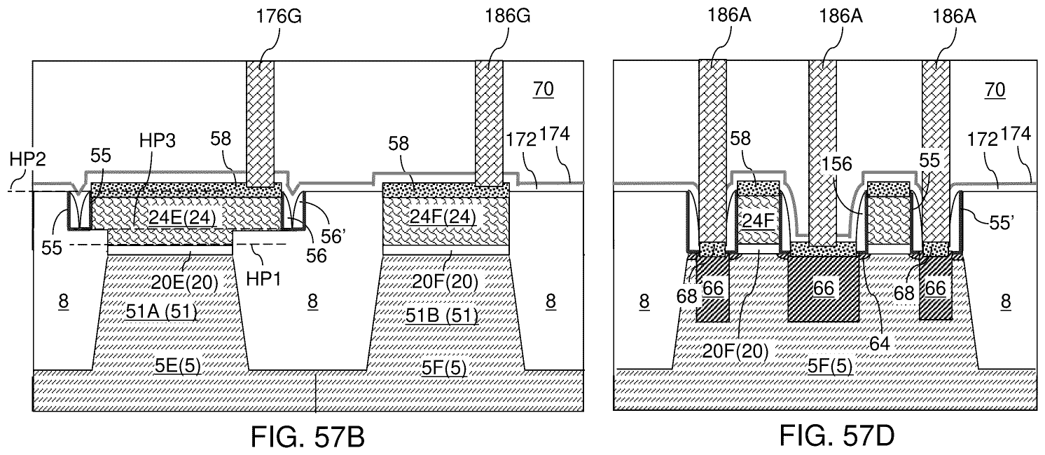

Referring to FIGS. 57A-57D, contact via cavities can be formed through the contact-level dielectric layer 70 and the at least one dielectric liner (172, 174), and can be filled with at least one conductive material to form various contact via structures (176A, 176G, 186A, 186G). The contact via structures (176A, 176G, 186A, 186G) can comprise first source/drain contact via structures 176A that contact a respective one of the source/drain metal-semiconductor alloy regions 68 or the source/drain regions (64, 66) of the first field effect transistor 902, first gate contact via structures 176G that contact a respective one of the gate metal-semiconductor alloy regions or the first gate electrodes 24E, second source/drain contact via structures 186A that contact a respective one of the source/drain metal-semiconductor alloy regions 68 or the source/drain regions (64, 66) of the second field effect transistor 904, and second gate contact via structures 186G that contact a respective one of the gate metal-semiconductor alloy regions or the second gate electrodes 24F. Generally, the gate contact via structures (176G, 186G) can be formed through the planarization dielectric layer 70 such that the first gate contact via structures 176G are electrically connected to a respective one of the first gate electrodes 24E, and the second gate contact via structures 186G are electrically connected to a respective one of the second gate electrodes 24F.

In one embodiment, each of the first gate contact via structures 176G can be located entirely outside an area of a top surface of the first active region 51A in a plan view, and can be located entirely within the gap region 32, i.e., the region laterally bounded by the inner periphery of the recessed horizontal surface of the trench isolation structure 8 and the outer periphery of the recessed horizontal surface of the trench isolation structure 8. In other words, the first gate contact via structure 176G may be located entirely inside an area of the recessed horizontal surface of the trench isolation structure 8 in the plan view. Each of the second gate contact via structures 186G can be located entirely inside an area of a top surface of the second active region 51B in a plan view.

Referring the fifth embodiment, a semiconductor structure comprising a first field effect transistor is provided. The semiconductor structure comprises a trench isolation structure 8 located in an upper portion of a semiconductor substrate and comprising a first opening therethrough. The trench isolation structure 8 comprises a gap region having a recessed horizontal surface, laterally surrounding the first opening, and laterally surrounded by a field region of the trench isolation structure 8 including a topmost surface of the trench isolation structure 8. The first field effect transistor comprises a first active region including a portion of a semiconductor substrate located within the first opening through the trench isolation structure 8. The first field effect transistor comprises a first gate structure (24E, 20E) that includes a first gate dielectric 20E and a first gate electrode 24E. The first gate electrode 24E comprises a lower gate electrode portion contacting a top surface of the first gate dielectric 20E and a pair of sidewall segments of the trench isolation structure 8, and comprises an upper gate electrode portion contacting first segments of the recessed horizontal surface of the trench isolation structure 8. A first dielectric gate spacer (55, 56) laterally surrounds the first gate electrode 24E and contacts second segments of the recessed horizontal surface of the trench isolation structure 8.

In the embodiments of the present disclosure, the high voltage non-sense amplifier peripheral transistor 902 (which is located outside the sense amplifier circuit) may be formed with a gate fringe area to improve the stability of its electrical characteristics, since its gate electrode 24E length in the first horizontal direction hd1 is narrow and the contact process has a large impact on its gate dielectric layer. In contrast, the low or very low voltage sense amplifier transistor 904 (which operates at a lower voltage than transistor 902) may be formed with a larger gate electrode 24F length and without the gate fringe area. The gate contact 186G for the transistor 904 is located over the active region 51B. Thus, the device area is reduced. Furthermore, both transistors 902 and 904 can be made in parallel using the same processing steps, which reduces the number of processing steps and the cost of the process.

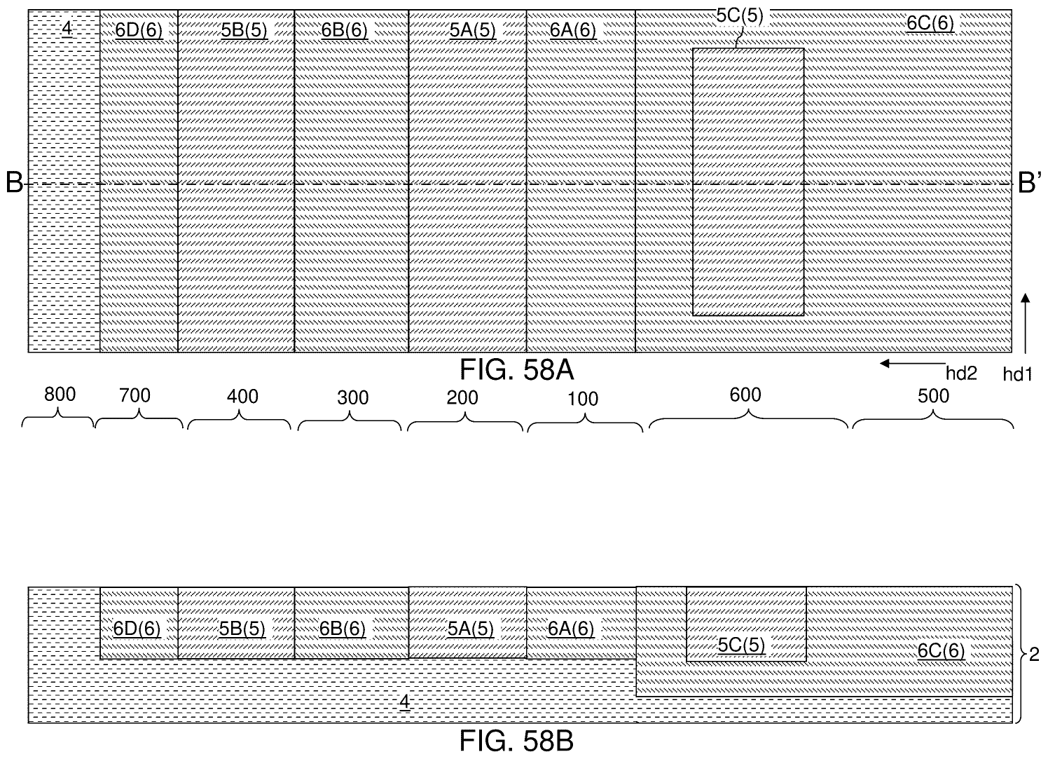

Referring to FIGS. 58A and 58B, a sixth exemplary structure according to a sixth embodiment of the present disclosure may be derived from the first exemplary structure illustrated in FIGS. 1A and 1B by modifying and/or rearranging the various doped wells (5, 6). In one embodiment, the third n-type field effect transistor region 600 may comprise a third p-type well 5C that is embedded in a third n-type well 6C.

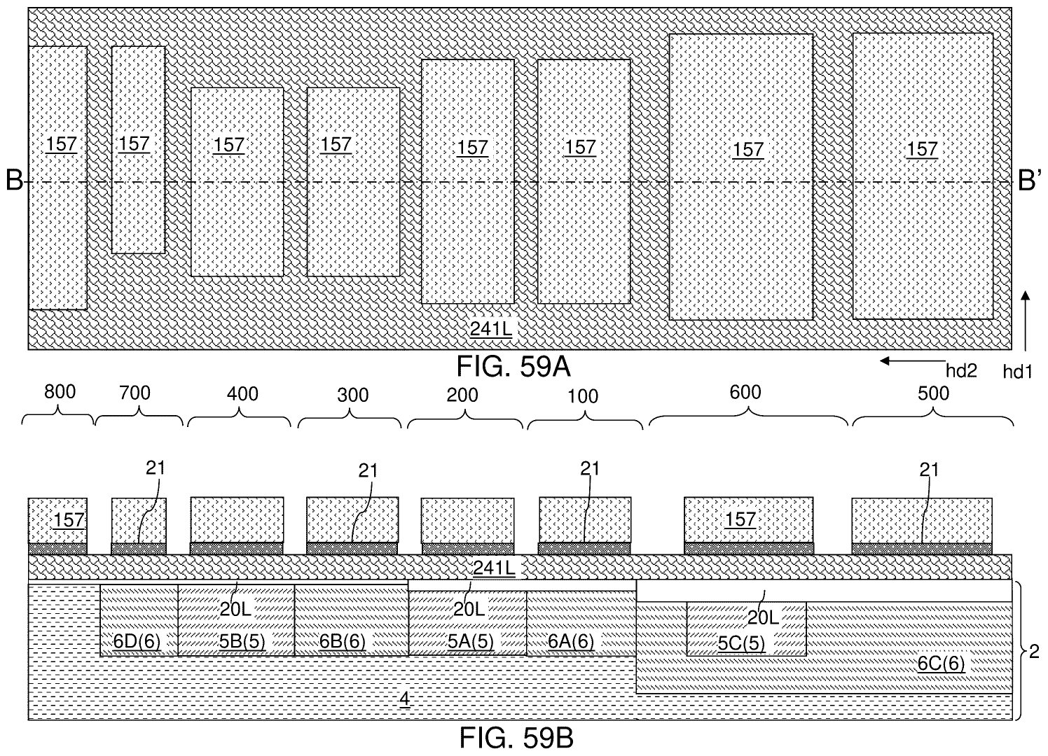

Referring to FIGS. 59A and 59B, gate dielectric layers 20L having different thicknesses can be formed over the top surface of the semiconductor substrate 2, for example, by performing a plurality of thermal oxidation processes and patterning processes, and optionally by depositing one or more gate dielectric material layers. A first semiconductor material layer 241L can be subsequently formed over the gate dielectric layers 20L. The first semiconductor material layer 241L may comprise a semiconductor material such as polysilicon, may have a thickness in a range from 50 nm to 300 nm, and may be doped with p-type electrical dopants and/or n-type electrical dopants over the various doped wells (5, 6). A patterned hardmask layer 21 including hardmask plates formed over the first semiconductor material layer 241L, such that active regions for various semiconductor devices are covered with the hardmask plates of the patterned hardmask layer 21. The patterned hardmask layer 21 comprises a hardmask material, such as silicon nitride, and may have a thickness in a range from 50 nm to 200 nm, although lesser and greater thicknesses may also be employed.

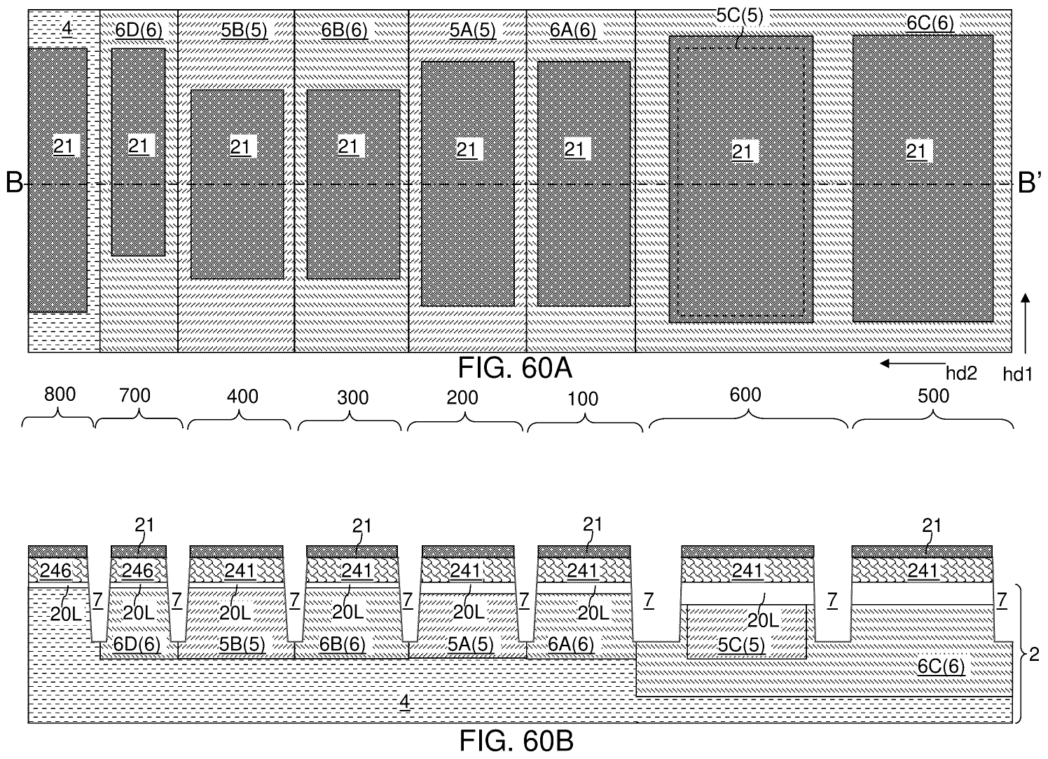

Referring to FIGS. 60A and 60B, the pattern in the hardmask layer 21 can be transferred through the first semiconductor material layer 241L, the gate dielectric layers 20L, and the upper region of the semiconductor substrate 2 by performing an anisotropic etch process. Shallow trenches 7 can be formed in areas that are not covered by the hardmask layer 21. Each patterned portion of the first semiconductor material layer 241L comprises a gate semiconductor material portion 241. Various patterned stacks {20L, 241, 21} can be formed, each of which comprises a respective gate dielectric layer 20L, a gate semiconductor material portion 241, and a hardmask plate 21. The various patterned stacks {20L, 241, 21} may comprise a first patterned stack (20L, 241, 21) including a first gate dielectric layer 20L and a first gate semiconductor material portion 241, and a second patterned stack (20L, 241, 21) including a second gate dielectric layer 20L and a second gate semiconductor material portion 241. Remaining portions of the first semiconductor material layer 241L located in passive device regions (700, 800) may comprise first semiconductor plates 246.

In one embodiment, each sidewall of the gate semiconductor material portions 241 may have a respective taper angle relative to a vertical direction. In one embodiment, sidewalls of the gate semiconductor material portions 241 that laterally extend along a first horizontal direction hd1 may have a first taper angle with respective to vertical planes that are parallel to the first horizontal direction hd1 and perpendicular to a second horizontal direction hd2. Sidewalls of the gate semiconductor material portions 241 that laterally extend along the second horizontal direction hd2 may have a second taper angle with respective to vertical planes that are parallel to the second horizontal direction hd2 and perpendicular to the first horizontal direction hd1. The first taper angle and the second taper angle may be in a range from 0.1 degree to 15 degrees, such as from 0.3 degrees to 10 degrees, and/or from 0.6 degrees to 6 degrees, although lesser and greater taper angles may also be employed. Generally, each of the gate semiconductor material portions 241 may have a first variable lateral extent along the first horizontal direction hd1 that decreases with a vertical distance from a horizontal plane including a topmost surface of the semiconductor substrate 2, and may have a second variable lateral extent along the second horizontal direction hd2 that decreases with the vertical distance from the horizontal plane including the topmost surface of the semiconductor substrate 2.

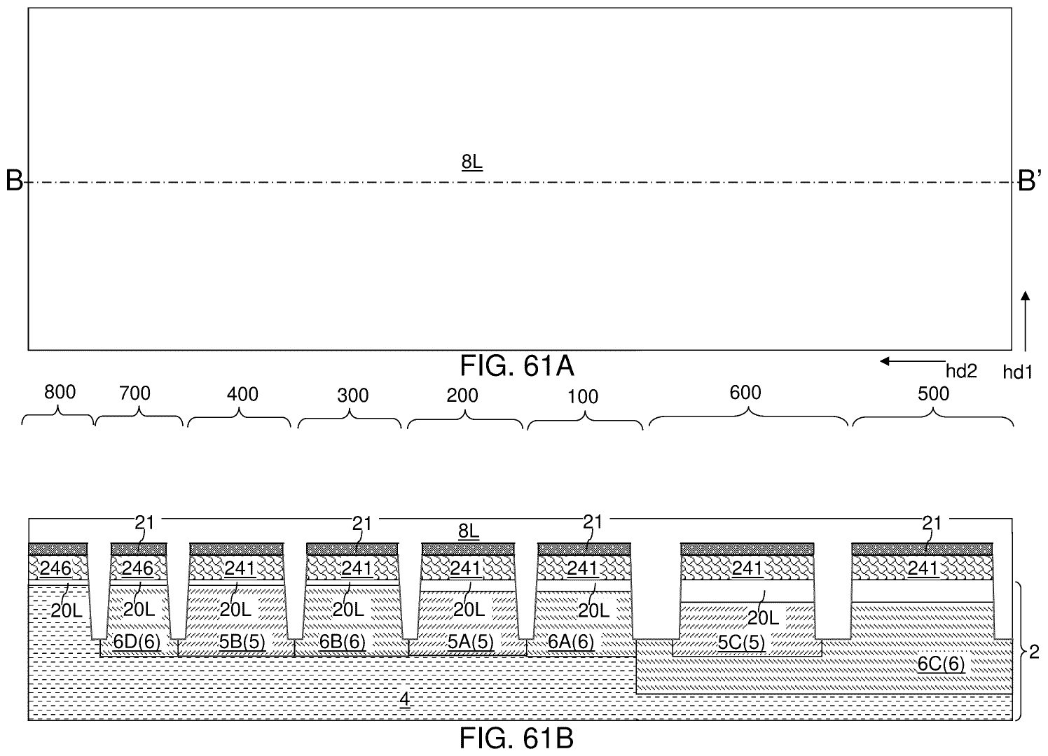

Referring to FIGS. 61A and 61B, a dielectric fill material, such as undoped silicate glass (e.g., silicon oxide) or a doped silicate glass can be deposited in the shallow trenches 7 to form a trench fill material layer 8L.

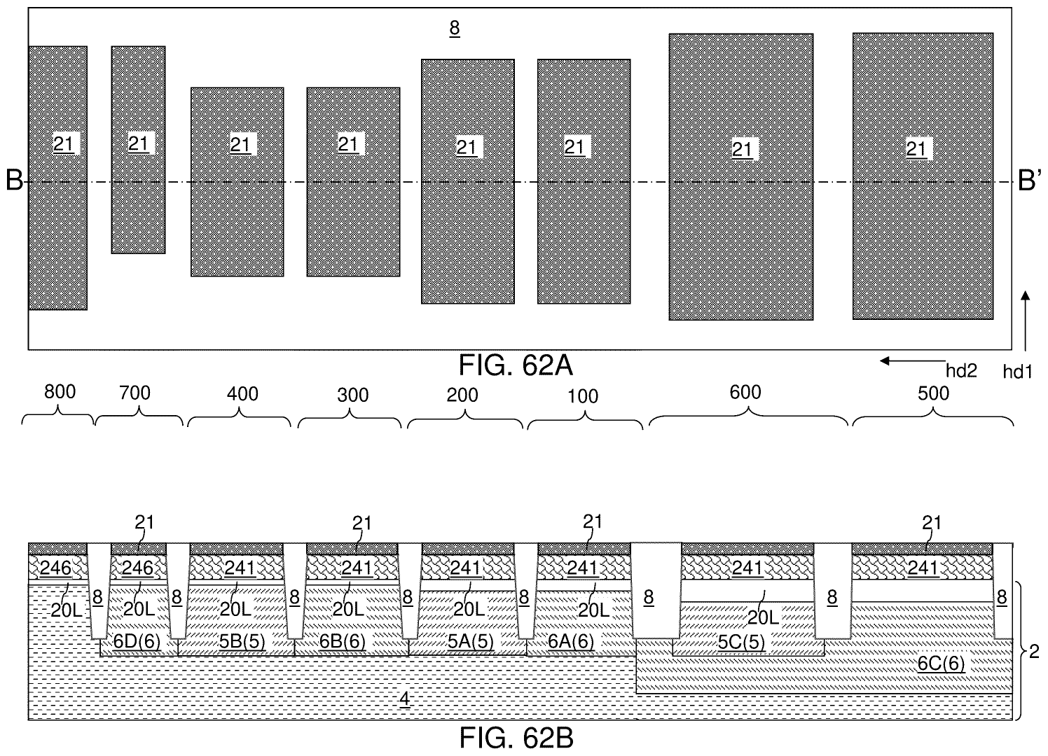

Referring to FIGS. 62A and 62B, a planarization process can be performed to remove portions of the dielectric fill material from above the horizontal plane including the top surface of the patterned hardmask layer 21. The planarization process may comprise a chemical mechanical polishing process and/or a recess etch process. Remaining portions of the dielectric fill material that fill the shallow trenches 7 comprise dielectric trench isolation structures, which are herein referred to as shallow trench isolation structures 8. Top surfaces of the shallow trench isolation structures 8 may be formed within a horizontal plane including top surfaces of the hardmask plates of the patterned hardmask layer 21.

In summary, shallow trench isolation structures 8 may be formed around the patterned stacks {20L, 241, 21} in an upper portion of the semiconductor substrate 2. In one embodiment, a first patterned stack (20L, 241, 21) comprising a first hardmask plate 21 and a first gate semiconductor material portion 241 can be formed in one device region, such as a first transistor region (e.g., a first n-type field effect transistor region 200), and a second patterned stack (20L, 241, 21) comprising a second hardmask plate 21 and a second gate semiconductor material portion 241 can be formed in another device region such as a third n-type field effect transistor region 600.

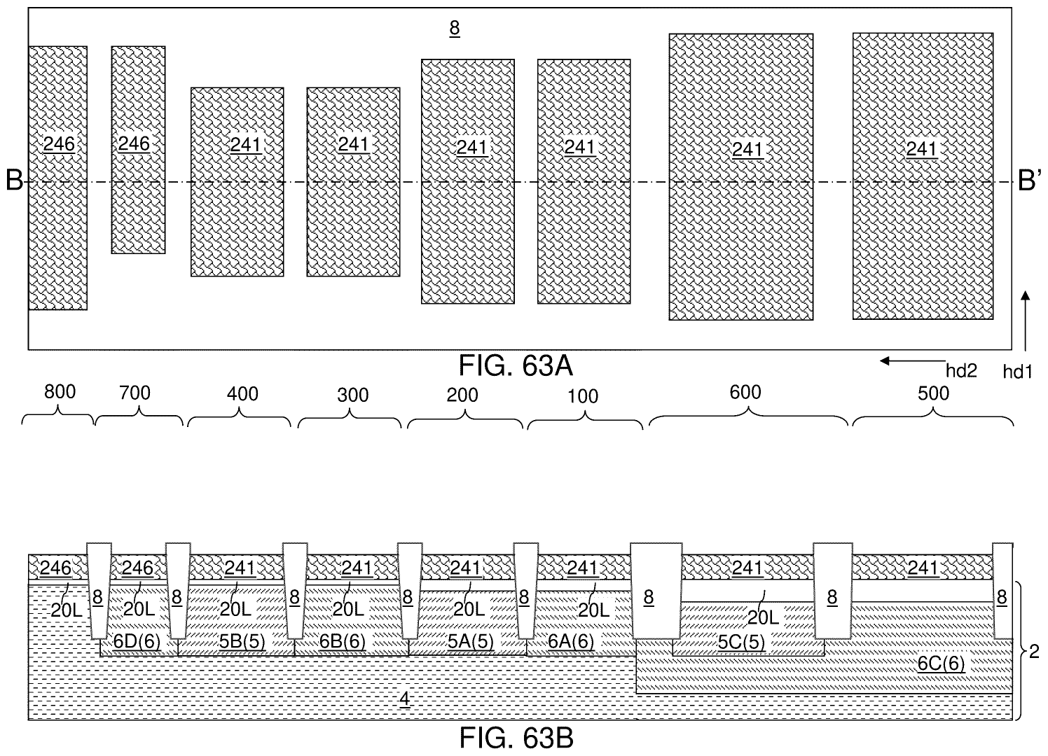

Referring to FIGS. 63A and 63B, the patterned hardmask layer 21 may be removed selective to the materials of the shallow trench isolation structures 8 and the gate semiconductor material portions 241. In an illustrative example, if the patterned hardmask layer 21 comprises silicon nitride, a wet etch process employing hot phosphoric acid may be performed to remove the patterned hardmask layer 21 selective to the materials of the shallow trench isolation structures 8 and the gate semiconductor material portions 241.

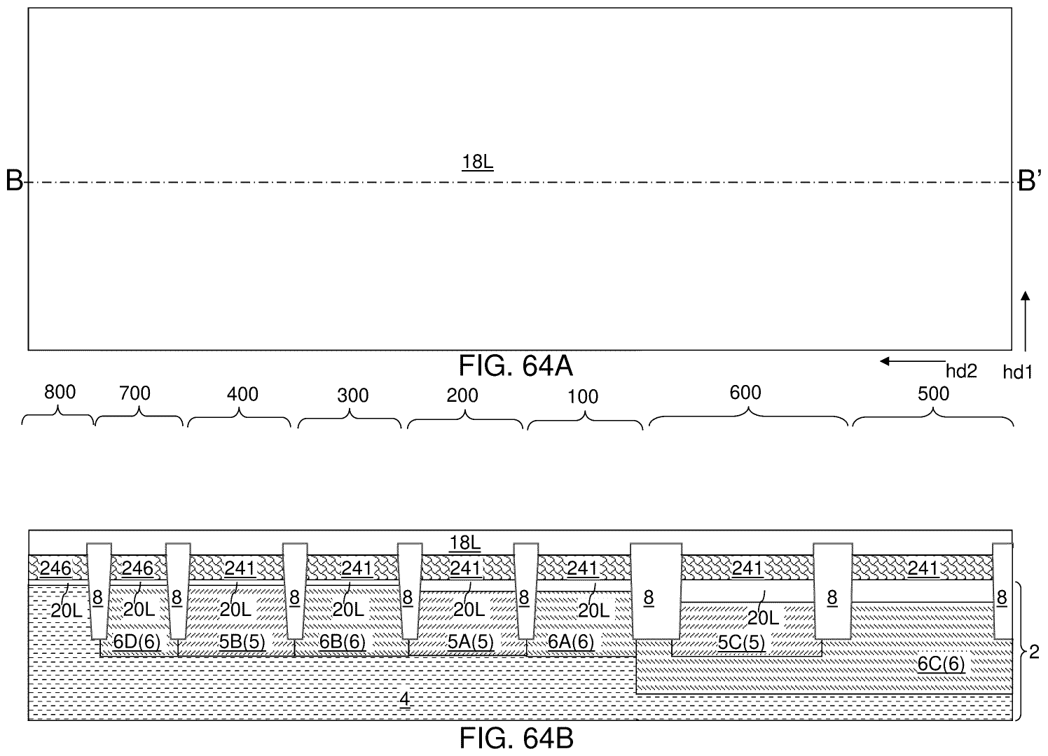

Referring to FIGS. 64A and 64B, a dielectric material, such as silicon oxide, can be deposited over the shallow trench isolation structures 8 and the gate semiconductor material portions 241 to form a dielectric capping layer 18L. The dielectric capping layer 18L can be formed on the top surfaces of the gate semiconductor material portions 241. The thickness of the dielectric capping layer 18L may be in a range from 5 nm to 100 nm, such as from 10 nm to 50 nm, although lesser and greater thicknesses may also be employed.

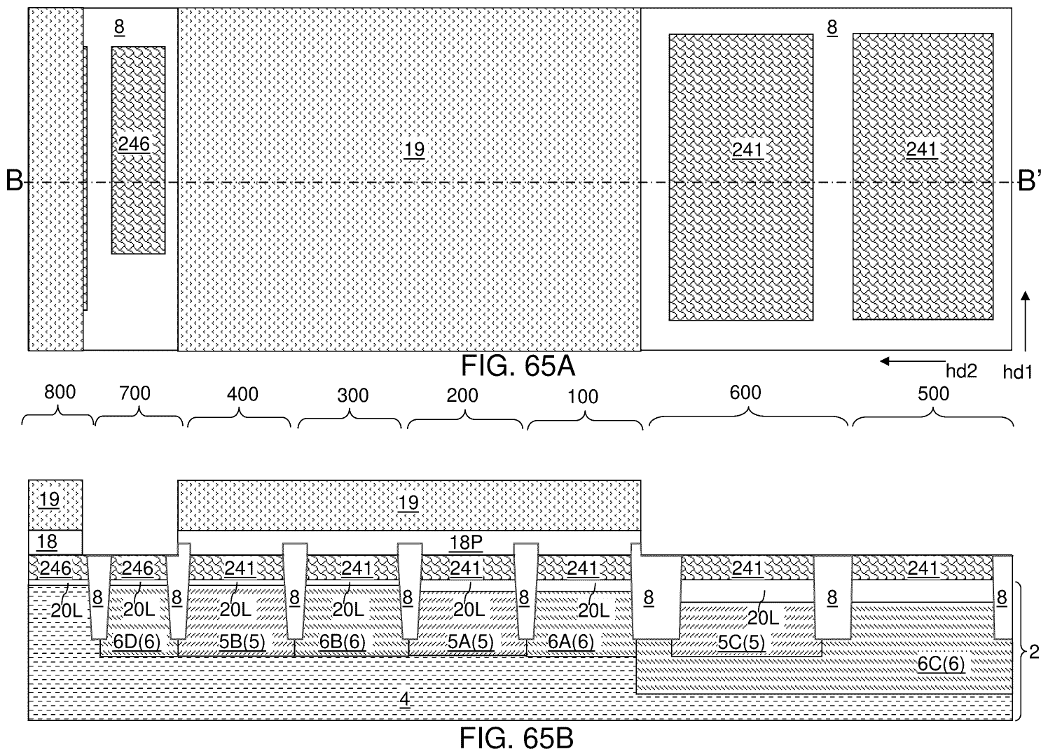

Referring to FIGS. 65A and 65B, a first photoresist layer 19 can be applied over the sixth exemplary structure, and can be lithographically patterned to cover a first subset of the device regions without covering a second subset of the device regions. In a non-limiting illustrative example, the first p-type field effect transistor region 100, the first transistor region (e.g., the first n-type field effect transistor region 200), the second p-type field effect transistor region 300, the second n-type field effect transistor region 400, and the second passive device region 800 may be covered by the first photoresist layer 19, while the third p-type field effect transistor region 500, the third n-type field effect transistor region 600, and the first passive device region 700 may not be covered by the first photoresist layer 19.

An etch process can be performed to remove unmasked portions of the dielectric capping layer 18L. A dielectric capping plate 18P is formed over at least one device region, such as the first p-type field effect transistor region 100, the first transistor region (e.g., a first n-type field effect transistor region 200), the second p-type field effect transistor region 300, and the second n-type field effect transistor region 400. A patterned portion of the dielectric capping layer 18L that remains in the second passive device region 800 may comprise a dielectric material layer 18. Generally, a portion of the dielectric capping layer 18L may be removed from above the top surface of at least one gate semiconductor material portion 241 (such as the second gate semiconductor material portion 241 located in the third n-type field effect transistor region 600). The photoresist layer 19 can be subsequently removed, for example, by ashing.

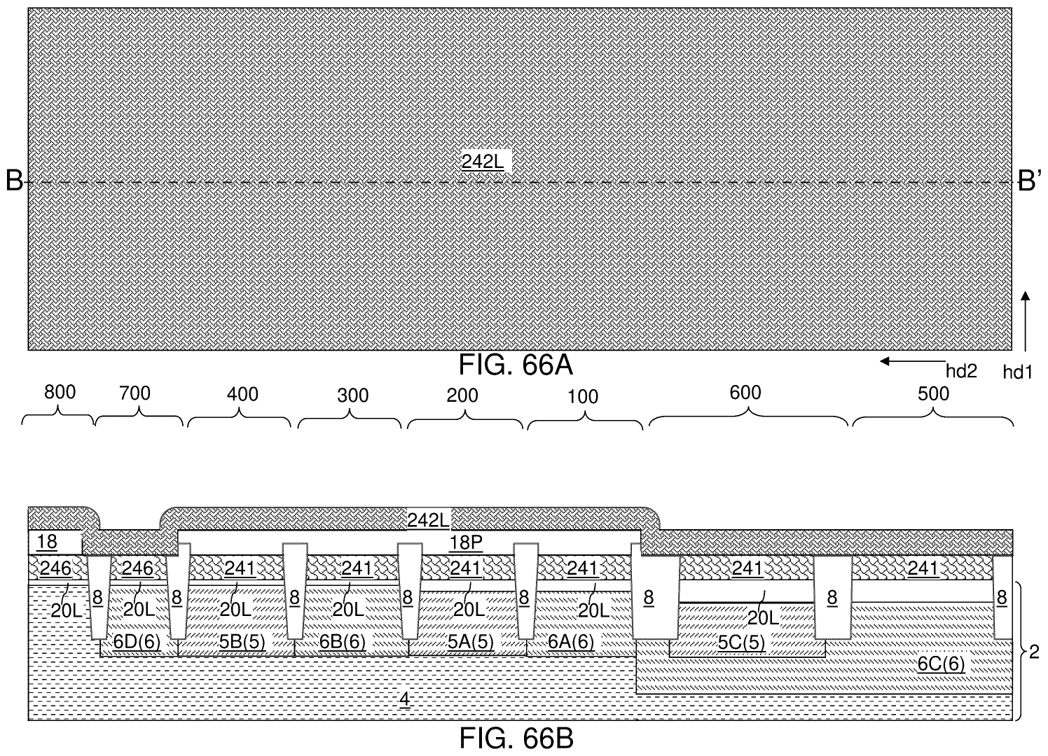

Referring to FIGS. 66A and 66B, a semiconductor material, such as polysilicon, can be deposited over the physically exposed surfaces of a subset of the gate semiconductor material portions 241, the dielectric capping plate 18P, and the dielectric material layer 18 to form a second semiconductor material layer 242L. The second semiconductor material layer 242L may have a thickness is in a range from 50 nm to 300 nm, such as from 100 nm to 200 nm. Various portions of the second semiconductor material layer 242L may be suitably doped as needed. In a non-limiting illustrative example, the second semiconductor material layer 242L may formed directly on the top surface of the second gate semiconductor material portion 241 located in the third n-type field effect transistor region 600.

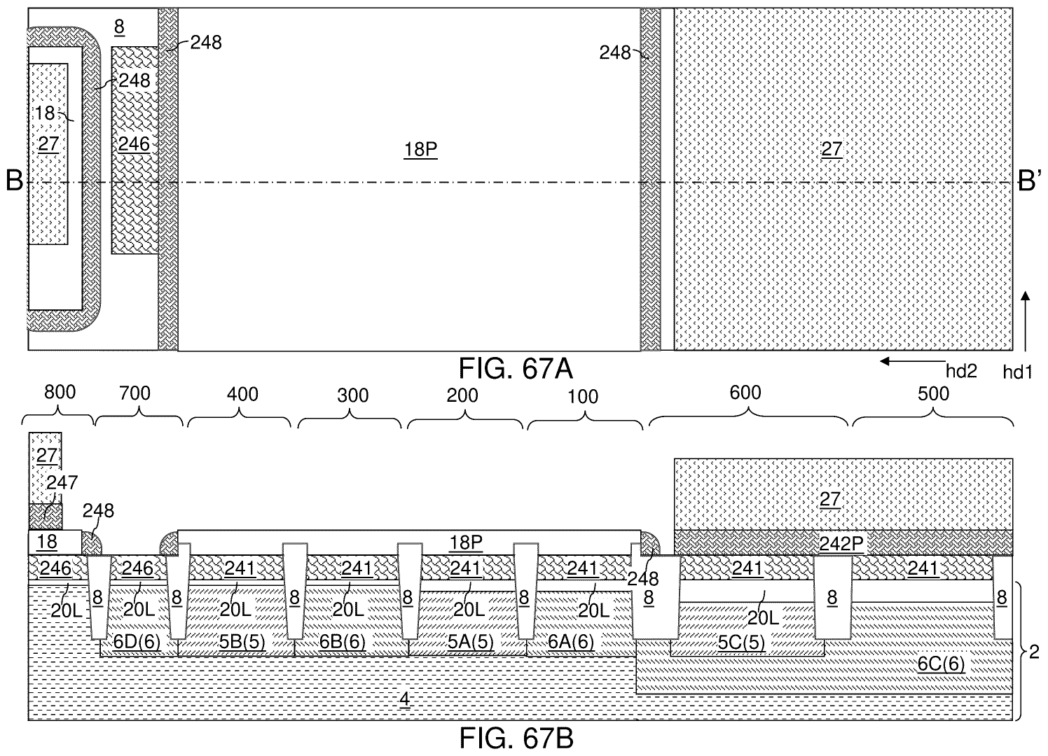

Referring to FIGS. 67A and 67B, a second photoresist layer 27 can be formed over the sixth exemplary structure, and can be lithographically patterned to cover device regions that do not contain the dielectric capping plate 18P therein. In a non-limiting illustrative example, the third p-type field effect transistor region 500 and the third n-type field effect transistor region 600 may be covered by the second photoresist layer 27. Further, an area located within a periphery of the dielectric material layer 18 may be covered by a portion of the second photoresist layer 27.

An anisotropic etch process can be performed to etch portions of the second semiconductor material layer 242L that are not covered by the second photoresist layer 27. A remaining portion of the second semiconductor material layer 242L underlying the second photoresist layer 27 comprises a second semiconductor material plate 242P located in at least one device region, such as the third p-type field effect transistor region 500 and the third n-type field effect transistor region 600. Another remaining portion of the second semiconductor material layer 242L underlying the second photoresist layer 27 is located another device region, such as in the second passive device region 800, may comprise a second semiconductor plate 247. Remaining portions of the second semiconductor material layer 242L in recessed areas that are not covered by the second photoresist layer 27 may comprise semiconductor spacers 248. A top surface of a first semiconductor material plate 246 may be exposed in a device region, such as the first passive device region 700. The top surface of the dielectric capping plate 18P may be exposed in some other device regions, such as the first p-type field effect transistor region 100, the first transistor region (e.g., a first n-type field effect transistor region 200), the second p-type field effect transistor region 300, and the second n-type field effect transistor region 400. The second photoresist layer 27 can be removed, for example, by ashing.

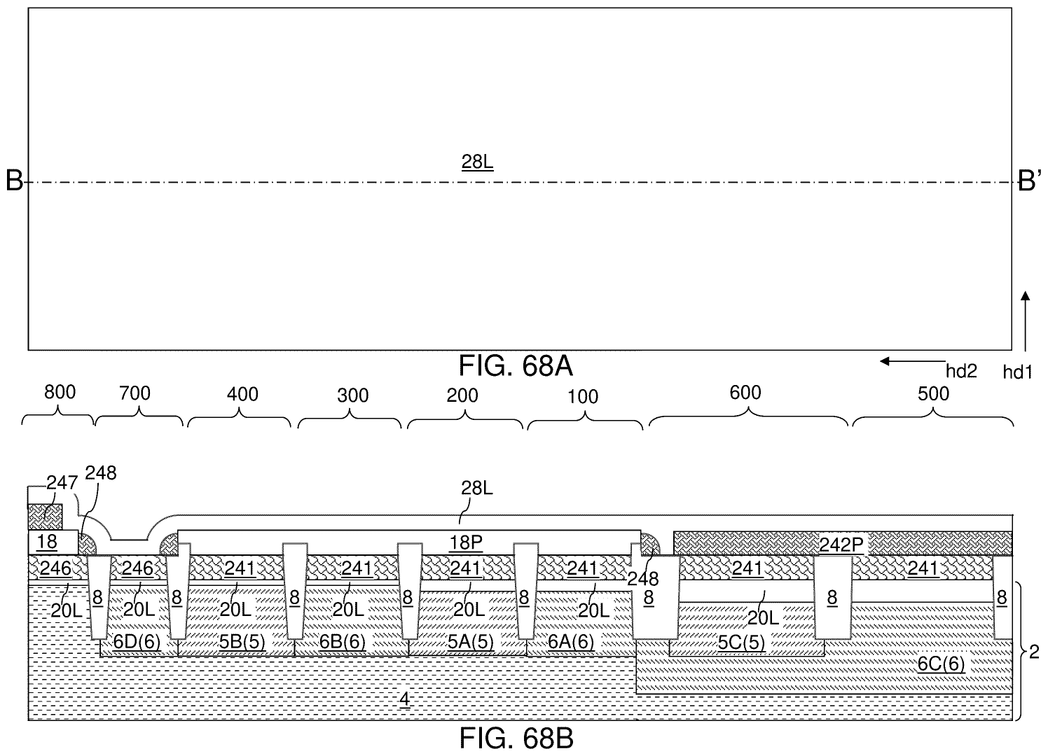

Referring to FIGS. 68A and 68B, a dielectric cover layer 28L can be deposited over the second semiconductor material plate 242P, the second semiconductor plate 247, and the dielectric capping plate 18P. The dielectric cover layer 28L comprises a dielectric material, such as silicon oxide, and may have a thickness in a range from 50 nm to 300 nm, such as from 100 nm to 200 nm, although lesser and greater thicknesses may also be employed.

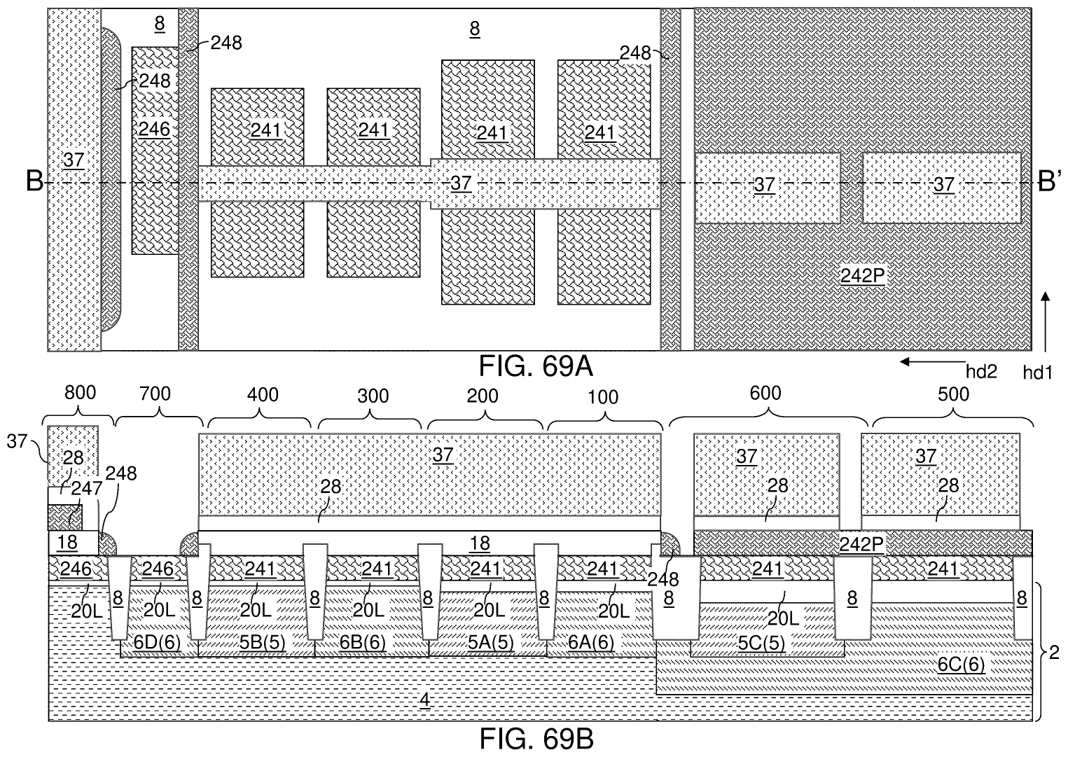

Referring to FIGS. 69A and 69B, a third photoresist layer (which is also referred to as a gate photoresist layer) can be applied over the dielectric cover layer 28L, and can be lithographically patterned into gate patterns. A first anisotropic etch process can be performed to transfer the gate pattern through the dielectric cover layer 28L. The dielectric cover layer 28L is patterned into dielectric capping plates 28. The dielectric capping plates 28 may have the pattern of gate electrodes in device regions in which field effect transistors are to be formed, and may cover the dielectric material layer 18 in the second passive device region 800. A subset of the dielectric capping plates 28 having the gate pattern functions as dielectric gate mask portions.

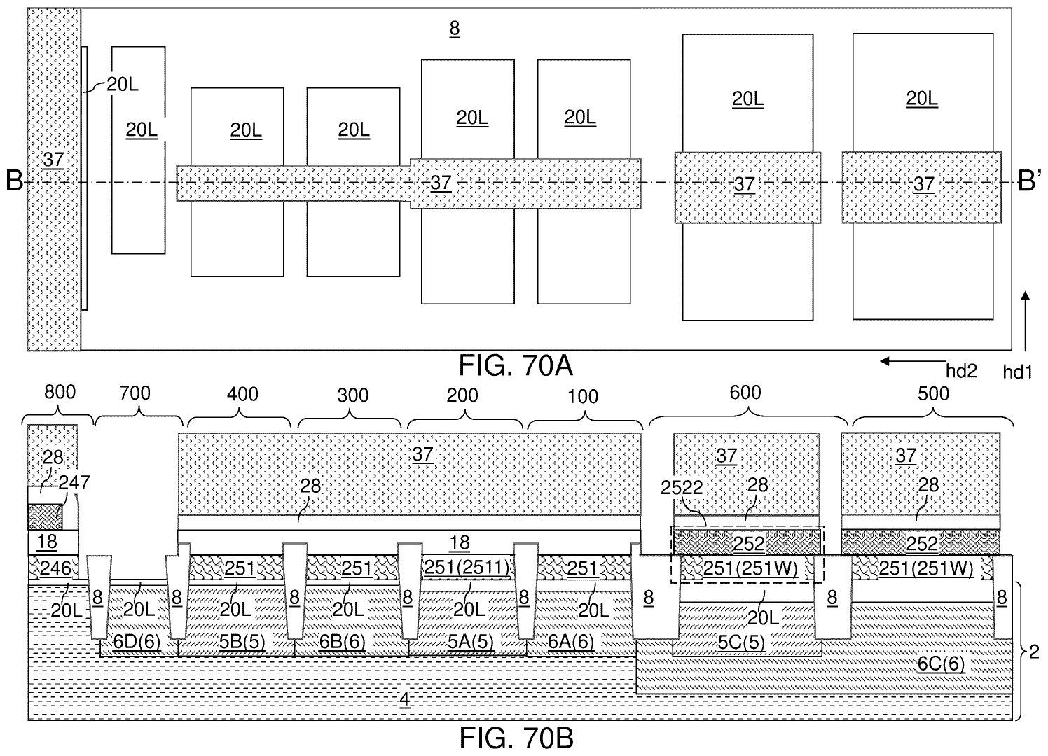

Referring to FIGS. 70A and 70B, a second anisotropic etch process can be performed to remove unmasked semiconductor material portions, such as unmasked portions of the second semiconductor material plate 242P, the semiconductor spacers 248, and the gate semiconductor material portions 241. The second semiconductor material plate 242P can be patterned into upper semiconductor gate electrode portions 252. The semiconductor spacers 248 can be removed. The gate semiconductor material portions 241 can be patterned into first semiconductor gate electrode portions 251. A subset of the first semiconductor gate electrode portions 251 that underlie the upper semiconductor gate electrode portions 252 is referred to as lower semiconductor gate electrode portions 251W.

In summary, the gate pattern is transferred through the second semiconductor material layer 242L, the dielectric material layer 18, and the first semiconductor material layer 241L. The semiconductor capping plate 242P and the first semiconductor material layer 241L are patterned into various semiconductor gate electrode portions (251, 252), which include first semiconductor gate electrode portions 251 and second semiconductor gate electrode portions 252. In one embodiment, each first semiconductor gate electrode portion 251 contacts sidewall surface segments of a respective trench isolation structure 8. Each lower semiconductor gate electrode portion 251W is a subset of the first semiconductor gate electrode portions 251, and as such, may have a same material composition and a same thickness as other first semiconductor gate electrode portions 251. In one embodiment, each upper semiconductor gate electrode portion 252 comprises a bottom surface contacting a respective lower semiconductor gate electrode portion 251W and top surface segments of a respective second shallow trench isolation structure 8.

In one embodiment, a first gate electrode 2511 of a first field effect transistor (which may comprise, for example, a field effect transistor to be formed in the first transistor region (e.g., a first n-type field effect transistor region 200)) may consist of only the first semiconductor gate electrode portion 251. In one embodiment, a maximum lateral dimension of the first gate electrode 2511 along a first gate electrode direction (which is the lateral extension direction of the first gate electrode 2511 such as the second horizontal direction hd2) equals a lateral dimension of a top surface of the first active region (e.g., 5A) along the first gate electrode direction (such as the second horizontal direction hd2). Generally, a gate electrode direction of a field effect transistor can be perpendicular to the channel direction of the field effect transistor.

In one embodiment, a maximum lateral dimension of the lower semiconductor gate electrode portion 251W along a second gate electrode direction (which is the lateral extension direction of a second gate electrode 2522 such as the second horizontal direction hd2) equals a lateral dimension of a top surface of the second active region (e.g., 5C) along the second gate electrode direction (such as the second horizontal direction hd2). In one embodiment, a lateral dimension of upper semiconductor gate electrode portion 252 along the second gate electrode direction (such as the second horizontal direction hd2) is greater than the third lateral dimension. In one embodiment, the upper semiconductor gate electrode portion 252 and the lower semiconductor gate electrode portion 251W have a same width along the second channel direction (such as the first horizontal direction hd1).

First field effect transistors including a respective first gate electrode 2511 can be formed in transistor region 200. In one embodiment, each sidewall of a first semiconductor gate electrode portion 251 that contacts sidewall surface segments of a trench isolation structure 8 has a respective taper angle relative to a vertical plane that is perpendicular to a first gate electrode direction (such as the second horizontal direction hd2) of a respective first field effect transistor. The first gate electrode 2511 has a variable lateral dimension along the first gate electrode direction (such as the second horizontal direction hd2) that decreases with a vertical distance from a horizontal plane including a top surface of a respective first active region (e.g., 5A). Thus, each first gate electrode 2511 may have a vertical cross-sectional shape of a trapezoid as illustrated in FIG. 70B.

Second field effect transistors including a respective second gate electrode 2522 can also be formed in another transistor region 600. Each lower semiconductor gate electrode portion 251W has a variable lateral dimension along the second gate electrode direction (such as the second horizontal direction hd2) that decreases with a vertical distance from a horizontal plane including a top surface of the second active region (e.g., 5C). In one embodiment, each upper semiconductor gate electrode portion 252 has a uniform lateral dimension along the second gate electrode direction (such as the second horizontal direction hd2) that is invariant with the vertical distance from the horizontal plane including the top surface of the second active region (e.g., 5C).

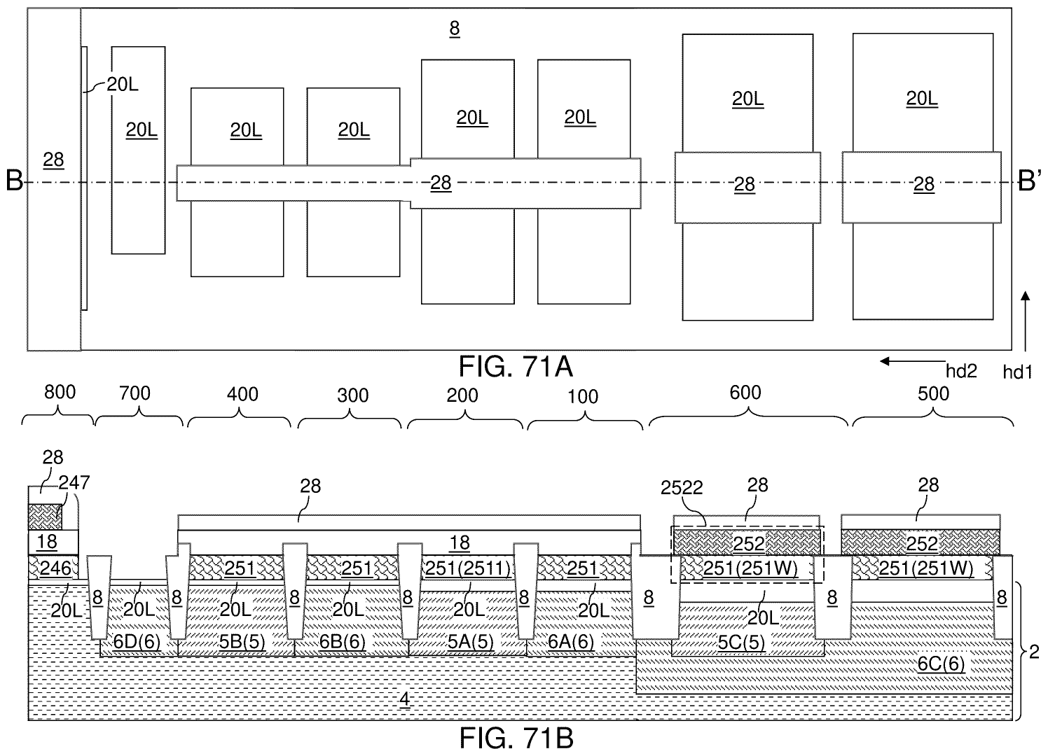

Referring to FIGS. 71A and 71B, the third photoresist layer 37 can be removed, for example, by ashing.

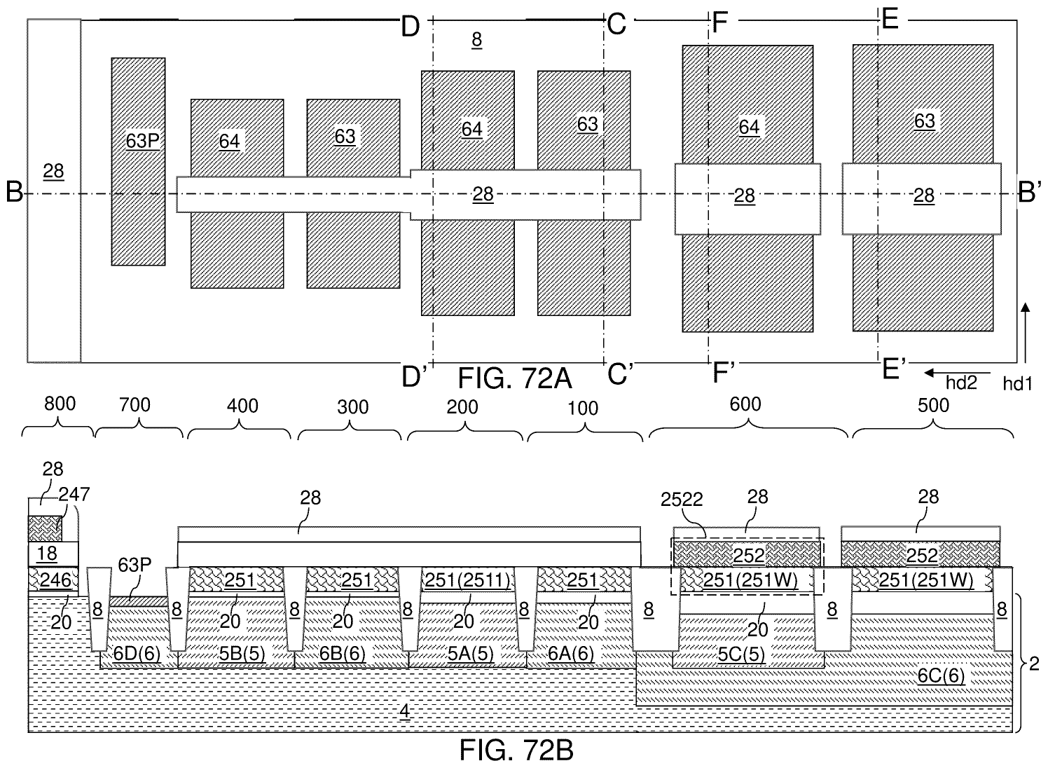

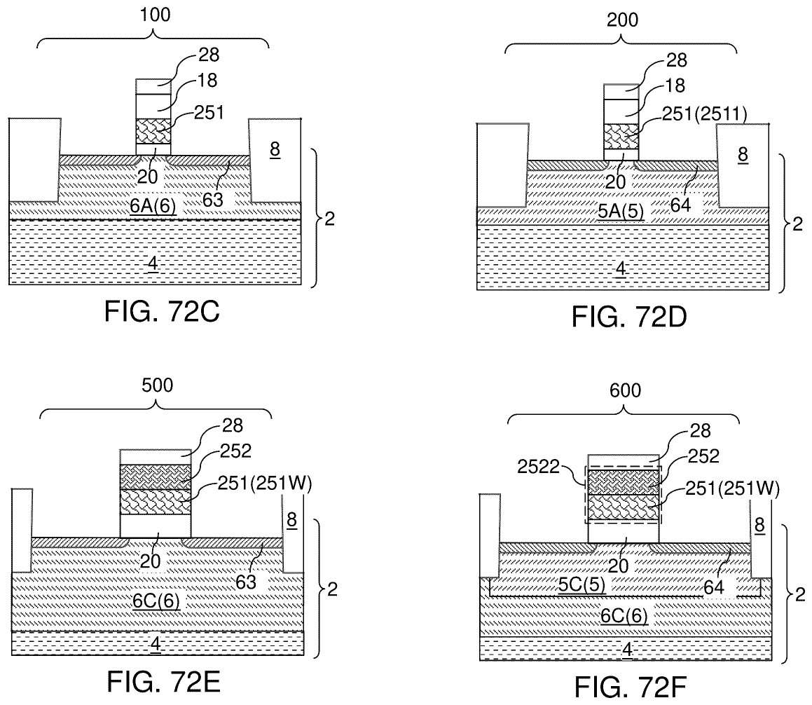

Referring to FIGS. 72A-72F, ion implantation processes can be performed to form source/drain extension regions (63, 64). The source/drain extension regions (63, 64) comprise p-doped source/drain extension regions 63 that are formed in n-doped wells 6 of the p-type field effect transistor regions (100, 300, 500), and n-doped source/drain extension regions 64 that are formed in the p-doped wells of the n-type field effect transistor regions (200, 400, 600). A p-type doped region 63P is concurrently formed in the n-doped well 6D in region 700. The dielectric capping plates 28 and the dielectric material layers 18 function as implantation masks during the ion implantation processes employed to form the source/drain extension regions (63, 64).

Subsequently, an anisotropic etch process can be performed to etch unmasked portions of the various gate dielectric layers 20L. First gate dielectrics 20 can be formed, which overlie first active regions (such as a portion of a first p-doped well 5A or a portion of a first n-doped well 6A that is laterally surrounded by a respective first trench isolation structure 8), for example, in the first p-type field effect transistor region 100 and in the first transistor region (e.g., a first n-type field effect transistor region 200). A lateral dimension of a first gate dielectric 20 along a first channel direction (such as the first horizontal direction hd1) equals a width of a respective overlying first gate electrode 2511 along the first channel direction.

Second gate dielectrics 20 can be formed, which overlie second active region (such as a portion of a third p-doped well 5C or a portion of a third n-doped well 6C), for example, in the third p-type field effect transistor region 500 and in the third n-type field effect transistor region 600. Each second gate dielectric 20 underlies a respective lower semiconductor gate electrode portion 251W. A lateral dimension of the second gate dielectric 20 along a second channel direction (such as the first horizontal direction hd1) equals a width of the second gate electrode 2522 along the second channel direction. The second gate dielectrics may be thicker than the first gate dielectrics.

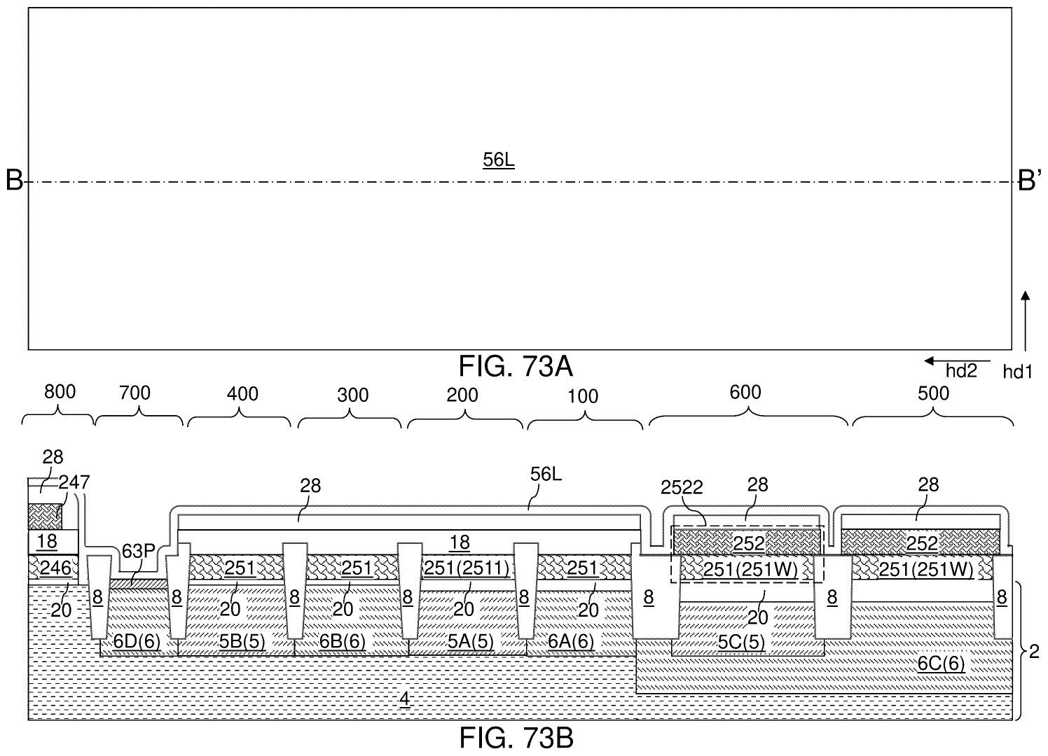

Referring to FIGS. 73A and 73B, a dielectric gate spacer layer 56L comprising a dielectric material (e.g., silicon oxide and/or silicon nitride) may be conformally deposited. The thickness of the dielectric gate spacer layer 56L may be in a range from 10 nm to 100 nm, although lesser and greater thicknesses may also be employed.

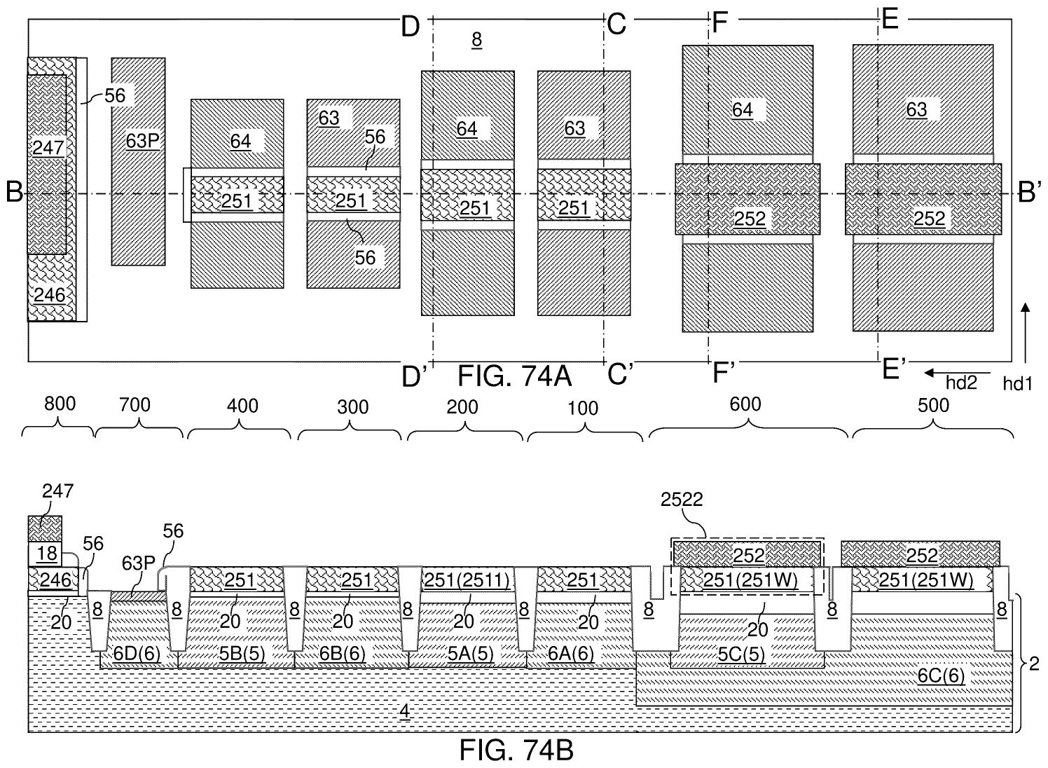

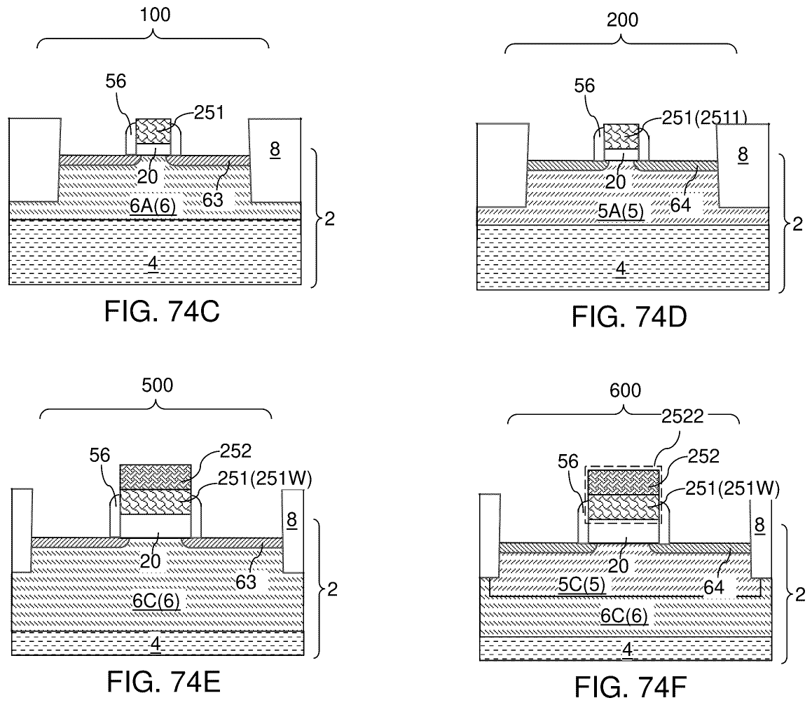

Referring to FIGS. 74A-74F, an anisotropic etch process can be performed to remove horizontally-extending portions of the dielectric gate spacer layer 56L, the dielectric capping plates 28, and portions of the dielectric material layer 18 that do not underlie a second semiconductor plate 247, and to remove unmasked portions of the dielectric gate spacer layer 56L. In one embodiment, the chemistry of the anisotropic etch process is selective to semiconductor materials, such as the semiconductor materials of the upper semiconductor gate electrode portion 252, the first semiconductor gate electrode portions 251, and the semiconductor substrate 2. In one embodiment, the dielectric gate spacer layer 56L, the dielectric capping plates 28, and portions of the dielectric material layer 18 may comprise silicon oxide, and the anisotropic etch process may etch silicon oxide selective to silicon.

Top surfaces of the upper semiconductor gate electrode portion 252 and the first semiconductor gate electrode portions 251 and top surfaces of the source/drain extension regions (63, 64) can be physically exposed after the anisotropic etch process. Remaining portions of the dielectric gate spacer layer 56L comprise dielectric gate spacers 56. In this case, a pair of gate spacers 56 can be formed on each gate structure including a respective gate dielectric 20 and a respective gate electrode (2511 or 2522). In one embodiment, the two first dielectric gate spacers 56 are not in direct contact with each other, and have a maximum height that is less than a sum of a thickness of the first gate dielectric 20 and a thickness of the first gate electrode 2511.

In one embodiment, first dielectric gate spacers 56 can be formed on sidewalls of a first gate electrode 2511, and second dielectric gate spacers 56 can be formed on sidewalls of the second gate electrode 2522. In one embodiment, second dielectric gate spacers 56 contact the lower semiconductor gate electrode portion 251W (which is a remaining portion of a second gate semiconductor material portion 241) and do not contact the upper semiconductor gate electrode portion 252 (which is a remaining portion of the second semiconductor material layer 242L), as illustrated in FIGS. 74E and 74F.

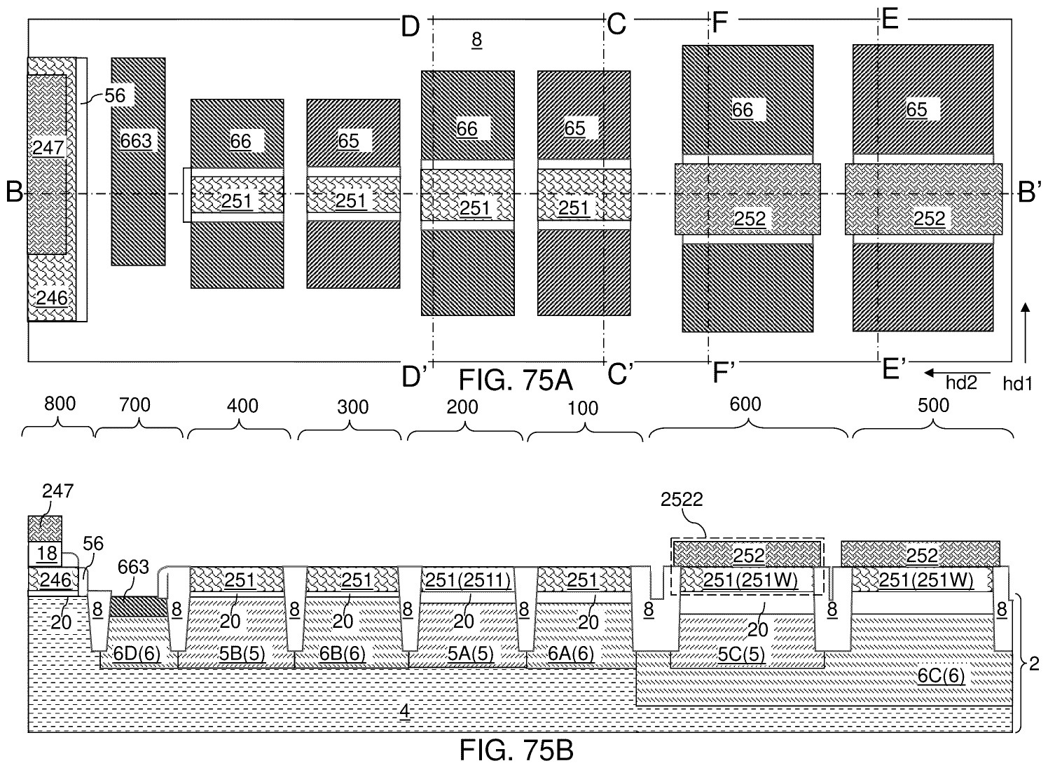

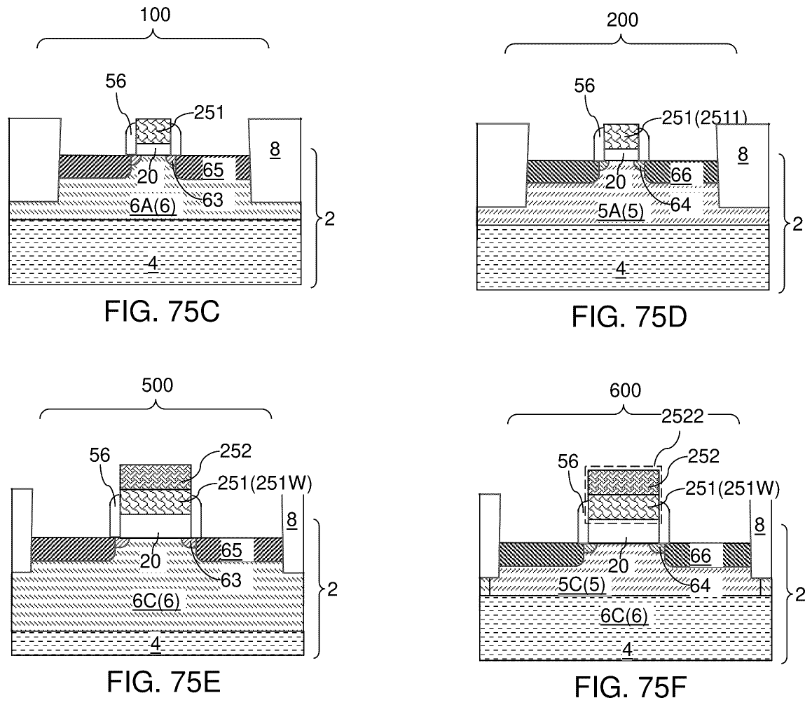

Referring to FIGS. 75A-75F, masked ion implantation processes can be performed to form deep source/drain regions (65, 66), which comprise p-doped deep source/drain regions 65 and n-doped deep source/drain regions 66. Further, a doped semiconductor portion 663 that can function as a resistor may be formed in the first passive device region 700.

A first field effect transistor can be provided in transistor region 200 by forming a first source region (such as one of the n-type source/drain regions (64, 66)) and a first drain region (such as one of the n-type source/drain regions (64, 66)) in portions of the semiconductor substrate 2 adjacent to the first gate electrode 2511. A second field effect transistor can be provided in transistor region 600 by forming a second source region (such as one of the n-type source/drain regions (64, 66)) and a second drain region (such as one of the n-type source/drain regions (64, 66)) in portions of the semiconductor substrate 2 adjacent to the second gate electrode 2522. The first field effect transistor in transistor region 200 comprises a first active region (e.g., (5A, 64, 66)) and a first gate electrode 2511 which comprises a first semiconductor gate electrode portion 251. The upper portion of the well 5A located between the source and drain regions (64, 66) functions as the channel of the first field effect transistor. A first trench isolation structure 8 laterally surrounds the first active region (e.g., (5A, 64, 66)). The second field effect transistor comprises a second active region (e.g., (5C, 64, 66)) and a second gate electrode 2522 that comprises a stack of a lower semiconductor gate electrode portion 251W and an upper semiconductor gate electrode portion 252. The upper portion of the well 5C located between the source and drain regions (64, 66) functions as the channel of the second field effect transistor. A second trench isolation structure 8 laterally surrounds the second active region (e.g., (5C, 64, 66)).

In one embodiment, the first active region (e.g., (5A, 64, 66)) comprises a first source region (such as one of the n-type source/drain regions (64, 66)) and a first drain region (such as one of the n-type source/drain regions (64, 66)) that are laterally spaced from each other by the first channel 5A along a first channel direction (such as the first horizontal direction hd1). In one embodiment, the first gate electrode 2511 laterally extends along a first gate electrode direction (such as the second horizontal direction hd2) that is perpendicular to the first channel direction (such as the first horizontal direction hd1). In one embodiment, the second active region (e.g., (5C, 64, 66)) comprises a second source region (such as one of the n-type source/drain regions (64, 66)) and a second drain region (such as one of the n-type source/drain regions (64, 66)) that are laterally spaced from each other by the second channel 5C along a second channel direction (such as the first horizontal direction hd1). In one embodiment, the second gate electrode 2522 laterally extends along a second gate electrode direction (such as the second horizontal direction hd2) that is perpendicular to the second channel direction (such as the first horizontal direction hd1).

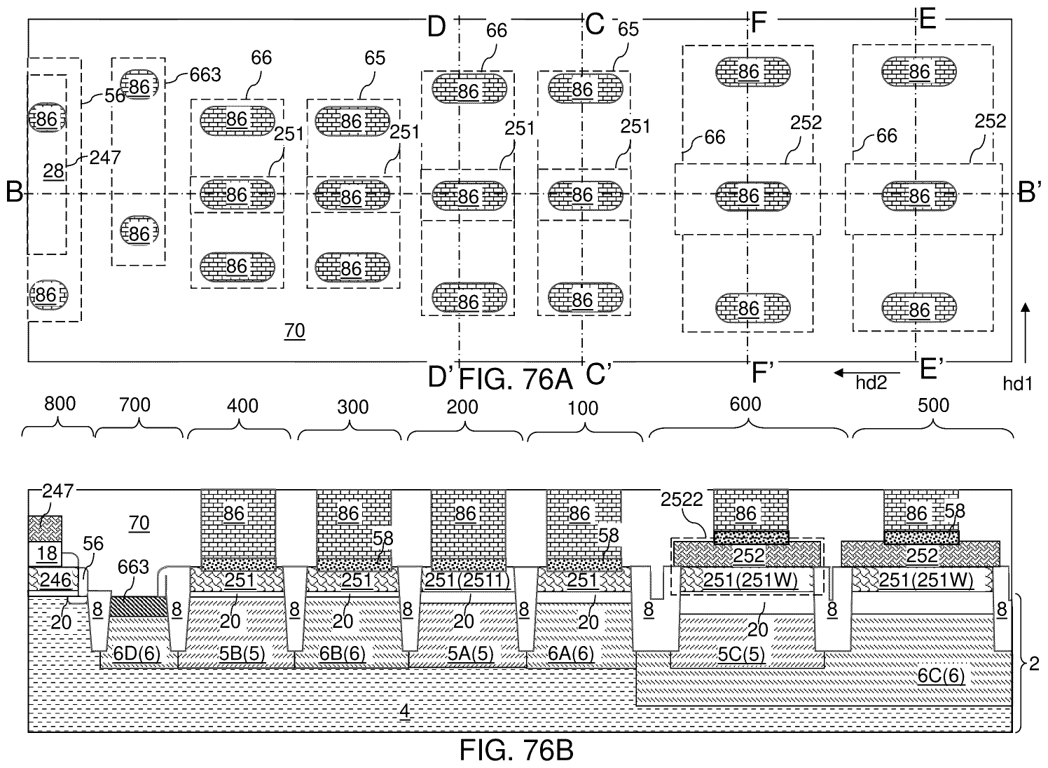

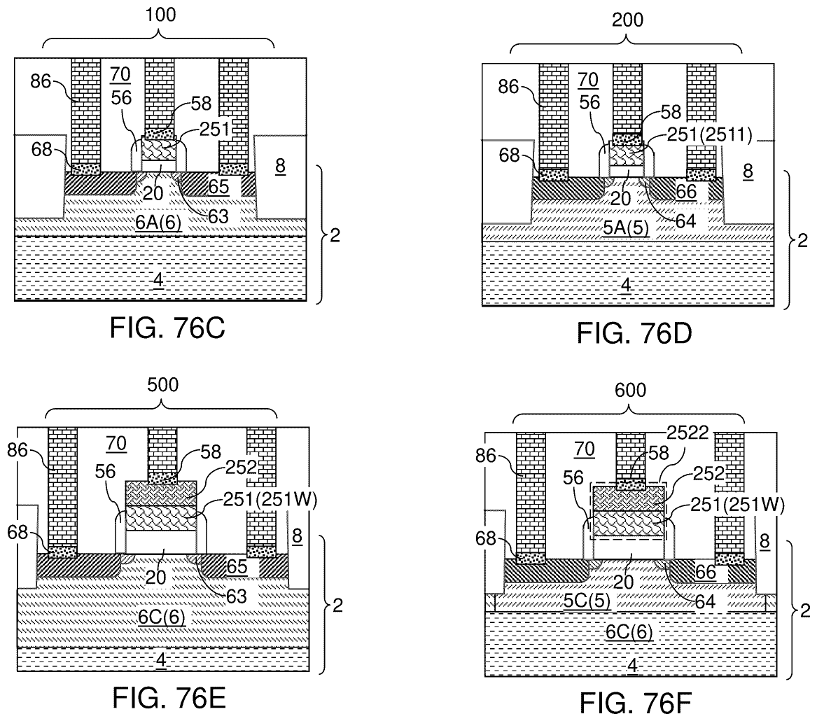

Referring to FIGS. 76A-76F, at least one dielectric material layer, such as at least one optical dielectric liner (not shown) and a contact-level dielectric layer 70, can be formed. A top surface of the contact-level dielectric layer 70 can be planarized. Various via cavities can be formed through the contact-level dielectric layer 70, and metal-semiconductor alloy regions (e.g., silicide regions, such as nickel platinum silicide regions) (58, 68) can be formed at the bottom of the via cavities, for example, by depositing a metal layer, by inducing formation of metal-semiconductor alloy regions (58, 68), and by removing unreacted portions of the metal layer. The metal-semiconductor alloy regions (58, 68) may comprise source/drain metal-semiconductor alloy regions 68 that are formed on the source/drain regions (65, 66), and gate metal-semiconductor alloy regions 58 that are formed on gate electrode (2511, 2522). In one embodiment, the gate metal-semiconductor alloy regions 58 may comprise first gate metal-semiconductor alloy regions 58 in contact with a top surface segment of a first semiconductor gate electrode portion 251 of a respective first gate electrode 2511, and second gate metal-semiconductor alloy regions 58 in contact with a top surface segment of an upper semiconductor gate electrode portion 252 or a respective second gate electrode 2522.

In the sixth embodiment of the disclosure, the fringeless low voltage transistors (100, 200) and very low voltage transistors (300, 400) include gate electrode 2511 comprising a single semiconductor layer portion 251. The single semiconductor layer portion 251 gate electrode 2511 has a lower resistance because it lacks an interface between lower and upper gate electrode portions. A low gate resistance is advantageous in low and very low voltage transistors. In contrast, the high voltage transistors (500, 600) include a gate electrode 2522 comprising two semiconductor layer portions (251W, 252). Such gate electrodes prevent ion implant penetration and are suitable for forming metal silicide contacts 58, such as NiPtSi type contacts. Furthermore, parasitic transistor threshold voltage decrease and off current degradation at the trench isolation structures 8 is decreased or avoided.

Referring collectively to FIGS. 58A-76F and according to various embodiments of the present disclosure, a semiconductor structure comprises: a first field effect transistor 200 comprising a first active region (e.g., (5A, 64, 66)) and a first gate electrode 2511 that comprises a first semiconductor gate electrode portion 251; a first trench isolation structure 8 laterally surrounding the first active region (e.g., (5A, 64, 66)); a second field effect transistor 600 comprising a second active region (e.g., (5C, 64, 66)) and a second gate electrode 2522 that comprises a stack of a lower semiconductor gate electrode portion 251W and an upper semiconductor gate electrode portion 252; a second trench isolation structure 8 laterally surrounding the second active region (e.g., (5C, 64, 66)); and at least one dielectric material layer (such as a contact-level dielectric layer 70) overlying the first field effect transistor and the second field effect transistor. The first semiconductor gate electrode portion 251 contacts sidewall surface segments of the first trench isolation structure 8 and comprises a top surface contacting the at least one dielectric material layer (such as a contact-level dielectric layer 70); the lower semiconductor gate electrode portion 251W has a same material composition and a same thickness as the first semiconductor gate electrode portion 251, and contacts sidewall surface segments of the second trench isolation structure 8; and the upper semiconductor gate electrode portion 252 comprises a bottom surface contacting the lower semiconductor gate electrode portion 251W and top surface segments of the second shallow trench isolation structure 8.

In one embodiment, the first gate electrode 2511 does not include any additional semiconductor gate electrode portion which contacts the first semiconductor gate electrode portion 251, and the first gate electrode 2511 lacks an interface between two semiconductor gate portions. In one embodiment, the first active region (e.g., (5A, 64, 66)) comprises a first source region (such as one of the n-type source/drain regions (64, 66)) and a first drain region (such as one of the n-type source/drain regions (64, 66)) that are laterally spaced from each other by a first channel 5A along a first channel direction (such as the first horizontal direction hd1); the first gate electrode 2511 laterally extends along a first gate electrode direction (such as the second horizontal direction hd2) that is perpendicular to the first channel direction (such as the first horizontal direction hd1); the second active region (e.g., (5C, 64, 66)) comprises a second source region (such as one of the n-type source/drain regions (64, 66)) and a second drain region (such as one of the n-type source/drain regions (64, 66)) that are laterally spaced from each other by a second channel 5C along a second channel direction (such as the first horizontal direction hd1); and the second gate electrode 2522 laterally extends along a second gate electrode direction (such as the second horizontal direction hd2) that is perpendicular to the second channel direction (such as the first horizontal direction hd1).

In one embodiment, a maximum lateral dimension of the first gate electrode 2511 along the first gate electrode direction (such as the second horizontal direction hd2) equals a lateral dimension of a top surface of the first active region (e.g., (5A, 64, 66)) along the first gate electrode direction (such as the second horizontal direction hd2). In one embodiment, a maximum lateral dimension of the lower semiconductor gate electrode portion 251W along the second gate electrode direction (such as the second horizontal direction hd2) equals a lateral dimension of a top surface of the second active region (e.g., (5C, 64, 66)) along the second gate electrode direction (such as the second horizontal direction hd2). In one embodiment, a lateral dimension of upper semiconductor gate electrode portion along the second gate electrode direction (such as the second horizontal direction hd2) is greater than the third lateral dimension.

In one embodiment, the upper semiconductor gate electrode portion and the lower semiconductor gate electrode portion 251W have a same width along the second channel direction (such as the first horizontal direction hd1). In one embodiment, the first field effect transistor 200 comprises a first gate dielectric 20 overlying the first active region (e.g., (5A, 64, 66)) and underlying the first gate electrode 2511, and two first dielectric gate spacers 56 contacting a respective sidewall of the first gate electrode 2511; and a lateral dimension of the first gate dielectric 20 along the first channel direction (such as the first horizontal direction hd1) equals a width of the first gate electrode 2511 along the first channel direction (such as the first horizontal direction hd1).

In one embodiment, the second field effect transistor 600 comprises a second gate dielectric 20 overlying the second active region (e.g., (5C, 64, 66)) and underlying the lower semiconductor gate electrode portion 251W, and two second dielectric gate spacers 56 contacting a respective sidewall of the lower semiconductor gate electrode portion 251W; the second gate dielectric 20 is thicker than the first gate dielectric 20; and a lateral dimension of the second gate dielectric 20 along the second channel direction (such as the first horizontal direction hd1) equals a width of the second gate electrode 2522 along the second channel direction (such as the first horizontal direction hd1). In one embodiment, the two first dielectric gate spacers 56 are not in direct contact with each other, and have a maximum height that is less than a sum of a thickness of the first gate dielectric 20 and a thickness of the first gate electrode 2511.

In one embodiment, each sidewall of the first semiconductor gate electrode portion 251 that contacts the sidewall surface segments of the first trench isolation structure 8 has a respective taper angle relative to a vertical plane that is perpendicular to the first gate electrode direction (such as the second horizontal direction hd2). In one embodiment, the first gate electrode 2511 has a variable lateral dimension along the first gate electrode direction (such as the second horizontal direction hd2) that decreases with a vertical distance from a horizontal plane including a top surface of the first active region (e.g., (5A, 64, 66)). In one embodiment, the lower semiconductor gate electrode portion 251W has a variable lateral dimension along the second gate electrode direction (such as the second horizontal direction hd2) that decreases with a vertical distance from a horizontal plane including a top surface of the second active region (e.g., (5C, 64, 66)). In one embodiment, the upper semiconductor gate electrode portion 252 has a uniform lateral dimension along the second gate electrode direction (such as the second horizontal direction hd2) that is invariant with the vertical distance from the horizontal plane including the top surface of the second active region (e.g., (5C, 64, 66)).

In one embodiment, semiconductor structure comprises: a first gate metal-semiconductor alloy region 58 in contact with a top surface segment of the first semiconductor gate electrode portion 251; and a second gate metal-semiconductor alloy region 58 in contact with a top surface segment of the upper semiconductor gate electrode portion 252, wherein the lower semiconductor gate electrode portion 251W is not in direct contact with any metal-semiconductor alloy material.

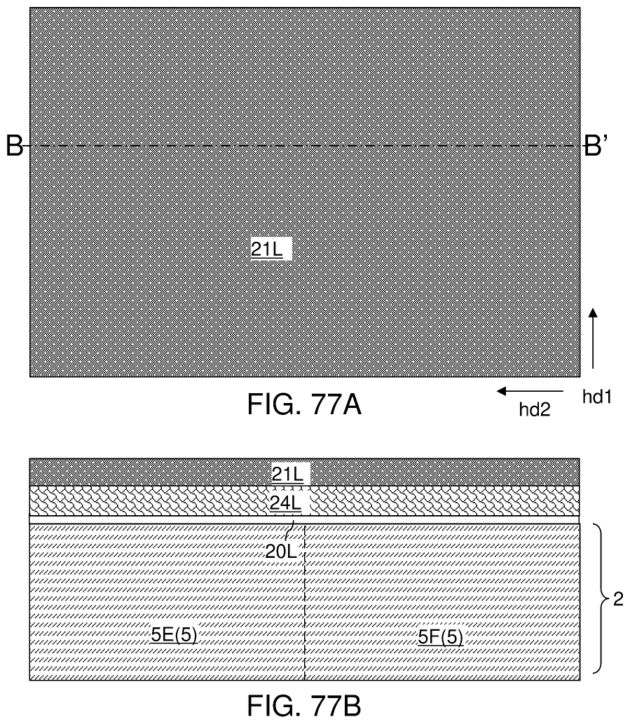

Referring to FIGS. 77A and 77B, a seventh exemplary structure according to a seventh embodiment of the present disclosure is illustrated. In one embodiment, the seventh exemplary structure may be formed in lieu of the fifth exemplary structure and/or as a component of the first exemplary structure or the sixth exemplary structure. For example, various doped wells 5 including a first doped well 5E and a second doped well 5F can be formed in a semiconductor substrate 2. The first doped well 5E and the second doped well 5F may be the same as described above. For example, a peripheral field effect transistor may be formed on the first doped well 5E and a sense amplifier transistor 5F may be formed in the second doped well 5F. A gate dielectric layer 20L, a semiconductor gate electrode material layer 24L, and a hardmask layer 21L can be formed over the semiconductor substrate 2. The semiconductor gate electrode material layer 24L includes a semiconductor material such as polysilicon, and may be suitably doped. The semiconductor gate electrode material layer 24L may have a thickness in a range from 50 nm to 200 nm, although lesser and greater thicknesses may also be employed. The hardmask layer 21L comprises a hardmask material such as silicon nitride, and may have a thickness in a range from 50 nm to 200 nm, although lesser and greater thicknesses may also be employed.

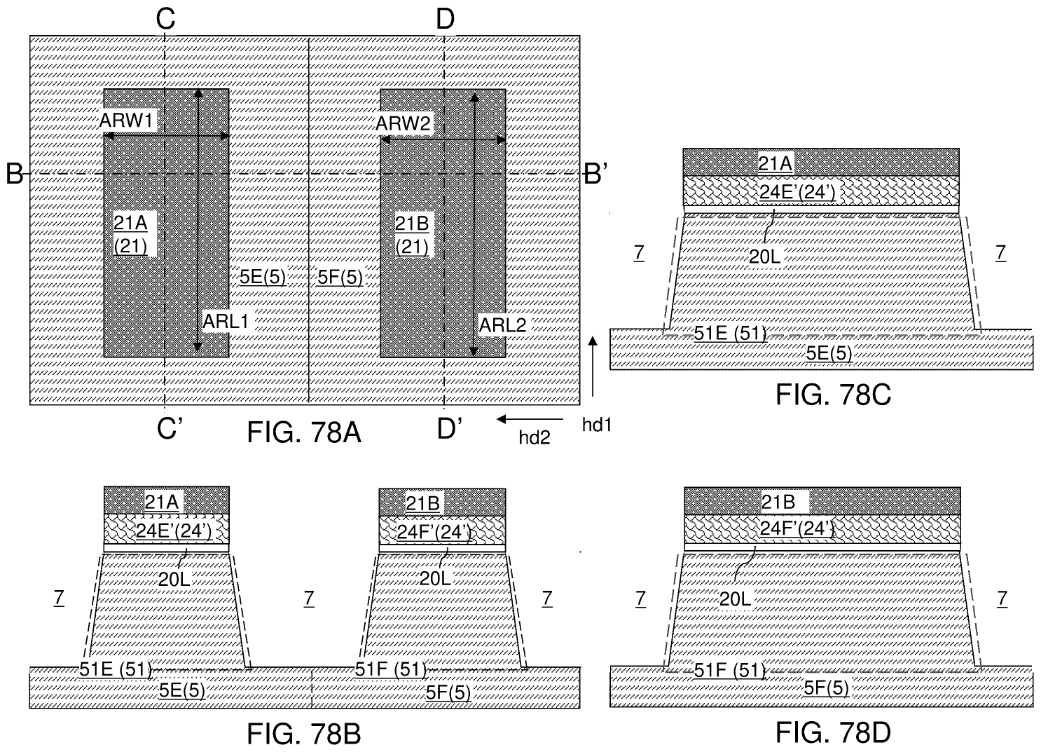

Referring to FIGS. 78A-78D, a photoresist layer (not shown) can be applied over the hardmask layer 21L, and can be lithographically patterned into patterns of active regions. A first anisotropic etch process can be performed to transfer the pattern in the photoresist layer through the hardmask layer 21L. The hardmask layer 21L is patterned into hardmask plates 21, which may comprise a first hardmask plate 21A and a second hardmask plate 21B. Each hardmask plate 21 may have a respective rectangular area. In one embodiment, the first hardmask plate 21A has a first active region length ARL1 along the first horizontal direction hd1 and has a first active region width ARW1 along the second horizontal direction hd2; and the second hardmask plate 21B has a second active region length ARL2 along the first horizontal direction hd1 and has a second active region width ARW2 along the second horizontal direction hd2. The photoresist layer can be removed, for example, by ashing.

A second anisotropic etch process can be performed to transfer the pattern of the hardmask plates 21 through the semiconductor gate electrode material layer 24L, the gate dielectric layer 20L, and an upper portion of the semiconductor substrate 2, such as unmasked portions of the first doped well 5E and the second doped well 5F. Patterned portions of the semiconductor gate electrode material layer 24L comprise gate semiconductor material portions 24′, which comprises a first gate semiconductor material portion 24E′ underlying the first hardmask plate 21A and a second gate semiconductor material portion 24F′ underlying the second hardmask plate 21B. Patterned portions of the gate dielectric layer 20L may have the same area as a respective overlying gate semiconductor material portion 24′. Shallow trenches 7 are formed in volumes from which the material of the semiconductor substrate 2 is removed, such as the volumes from which the materials of first doped well 5E and the second doped well 5F are removed. Active regions 51 laterally surrounded by a respective shallow trench 7 can be formed. The active regions 51 may comprise a first active region 51E that is formed underneath the first hardmask plate 21A and a second active region 51F that is formed underneath the second hardmask plate 21B.

A first patterned stack (20L, 24E′, 21A) including a first gate dielectric layer 20L, a first gate semiconductor material portion 24E′, and a first hardmask plate 21A can be formed over a first portion of a semiconductor substrate 2. A second patterned stack (20L, 24F′, 21B) including a second gate dielectric layer 20L, a second gate semiconductor material portion 24F′, and a second hardmask plate 21B can be formed over a second portion of the semiconductor substrate 2.

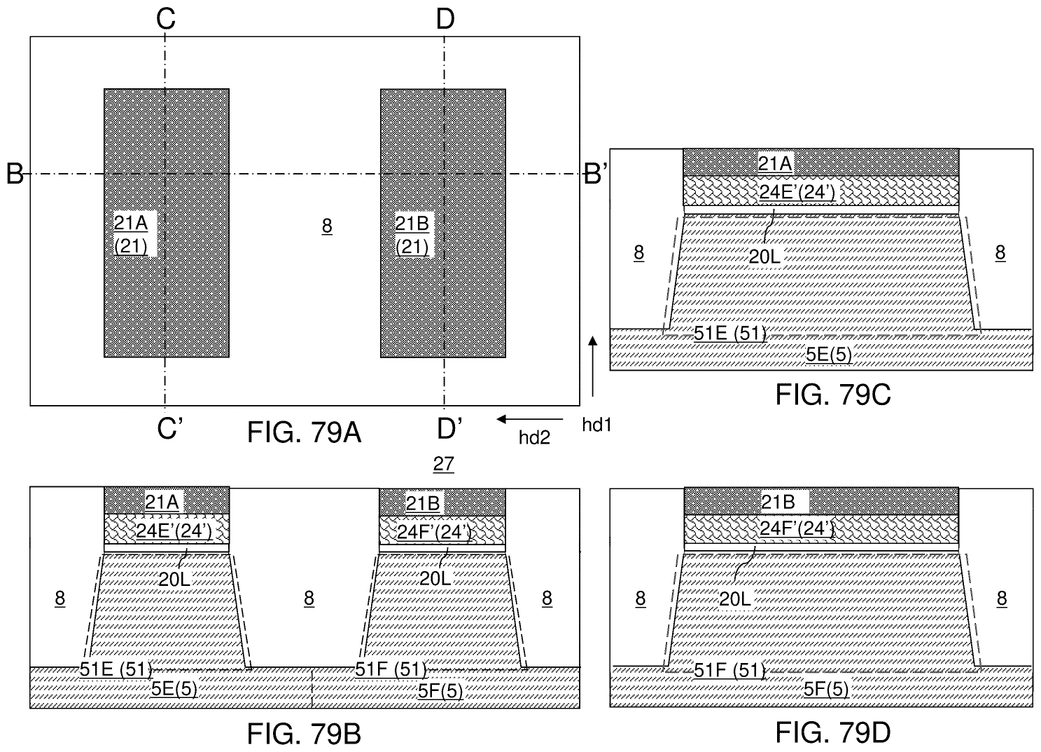

Referring to FIGS. 79A-79D, at least one dielectric fill material can be conformally deposited in the trenches 7 and over the hardmask plates 21. The at least one dielectric fill material may comprise a silicon oxide material. Optionally, a dielectric liner such as a silicon nitride liner (not expressly shown) may be deposited prior to deposition of the at least one dielectric fill material. Excess portions of the at least one dielectric fill material can be removed from above the horizontal plane including the top surfaces of the hardmask plates 21 by a planarization process, which may include a chemical mechanical polishing (CMP) process. In one embodiment, the CMP process stops on the hardmask plates 21.

The remaining portions of the at least one dielectric fill material filling the trenches 7 constitute trench isolation structures 8. The trench isolation structures 8 may form a continuous structure contacting the semiconductor material of the semiconductor substrate 2 with dielectric surfaces and providing electrical isolation between active regions 51 of adjacent semiconductor devices to be subsequently formed. The trench isolation structures 8 may comprise shallow trench isolation structures located in the shallow isolation trenches 7. Each device active region 51 may comprise a patterned portion of a respective doped well (5E, 5F) that is laterally surrounded by a respective trench isolation structure 8. Each of the hardmask plates 21 may comprise a respective horizontal bottom surface located within a horizontal plane and a respective horizontal top surface located within another horizontal plane. In one embodiment, the trench isolation structures 8 may have a top surface that is formed within a horizontal plane including the top surfaces of the hardmask plates 21. The trench isolation structures 8 may comprise a first trench isolation structure 8 that is formed around the first patterned stack (20L, 24E′, 21A) and into the first portion of the semiconductor substrate 2, and a second trench isolation structure 8 that is formed around the second patterned stack (20L, 24F′, 21B) and into the second portion of the semiconductor substrate 2.

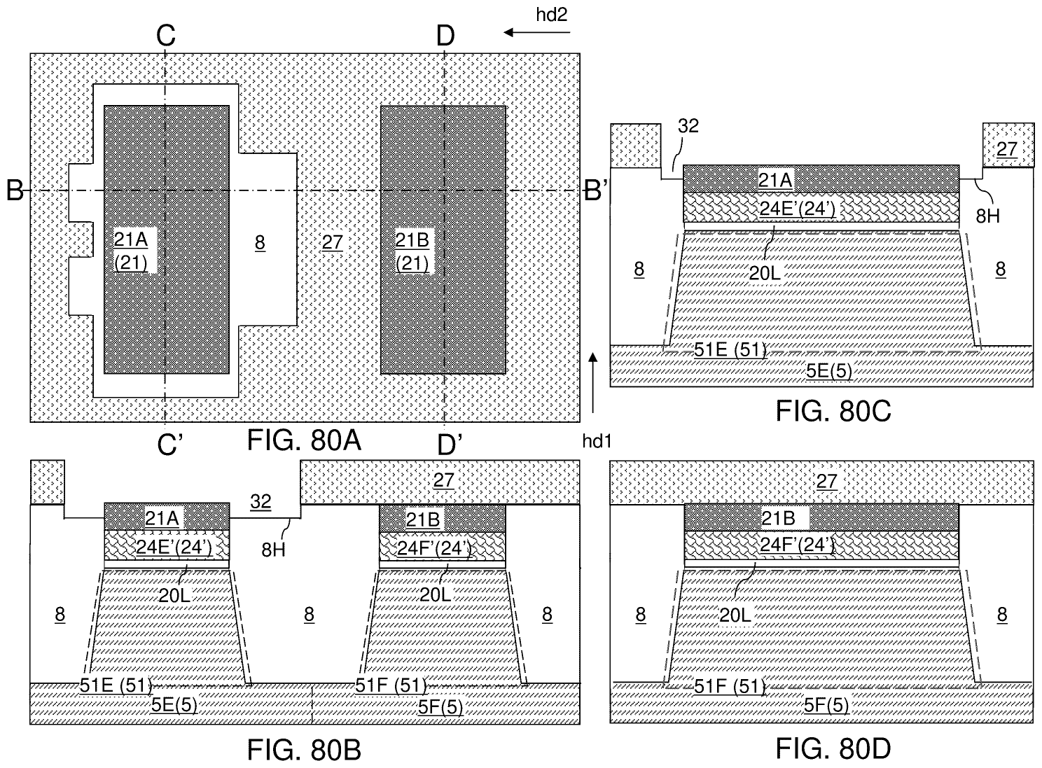

Referring to FIGS. 80A-80D, a photoresist layer 27 can be applied over the hardmask plates 21 and the trench isolation structure 8, and can be lithographically patterned to form an opening having an area that includes the entirety of the area of the first hardmask plate 21A located over the first doped well 5E. According to an aspect of the present disclosure, the periphery of the opening in the patterned photoresist layer 27 can be laterally offset outward from the sidewalls of the first hardmask plate 21A at least by a minimum lateral offset distance. In one embodiment, the minimum lateral offset distance can be the same as or greater than the lateral thickness of dielectric spacers to be subsequently formed. In one embodiment, the minimum lateral offset distance may be in a range from 5 nm to 200 nm, such as from 10 nm to 100 nm, although lesser and greater minimum lateral offset distances may also be employed.

According to an aspect of the present disclosure, at least one region of the area between the sidewalls of the first hardmask plate 21A and the periphery of the opening in the patterned photoresist layer 27 that surrounds the first hardmask plate 21A may be wide enough to accommodate at least one gate contact via structure. In other words, a gap region 32 between the sidewalls of the first hardmask plate 21A and the periphery of the opening in the patterned photoresist layer 27 can continuously extend around the first hardmask plate 21A, and includes an area in which at least one gate contact via structure can be subsequently formed without areal overlap with the first hardmask plate 21A or the patterned photoresist layer 27. The gap region 32 is also referred to as a peripheral recess region.

An etch process that etches the material of the trench isolation structure 8 selective to the material of the hardmask plates 21 can be performed to vertically recess the gap region 32 of the trench isolation structure 8 that laterally surrounds the first active region 51A (i.e., the portion of the first doped well 5E that underlies the first hardmask plate 21A) while masking the second hardmask plate 21B, the second active region 5F and a field region of the trench isolation structure 8 that laterally surrounds the gap region 32 are not recessed. The etch process may comprise an anisotropic etch process (such as a reactive ion etch process). The field region of the trench isolation structure 8 can include the portion of the trench isolation structure 8 that is covered by the photoresist layer 27. A recessed horizontal surface 8H of the trench isolation structure 8 is formed in a portion of the trench isolation structure 8 located in the gap region 32. The recessed horizontal surface 8H is vertically recessed relative to a topmost surface of the trench isolation structure 8 located in the field region and contained with the second horizontal plane.

In summary, the gap region 32 of the trench isolation structure 8 is vertically recessed by performing the etch process, which etches unmasked portions of the trench isolation structure 8 while the hardmask plates 21 are present over the semiconductor substrate. The recessed horizontal surface 8H is formed above the horizontal plane including the bottom surfaces of the hardmask plates 21, and below the horizontal plane including the top surfaces of the hardmask plates 21. In one embodiment, the recess horizontal surface 8H may be located within a horizontal plane that is located above the horizontal plane including the bottom surfaces of the hardmask plates 21. The patterned photoresist layer 27 can be subsequently removed, for example, by ashing. Generally, the gap region 32 (i.e., the peripheral recess region) may be formed around the first patterned stack (20L, 24E′, 21A) in a portion of the first trench isolation structure 8 that is proximal to the first hardmask plate 21A by vertically recessing a portion of the first trench isolation structure 8.

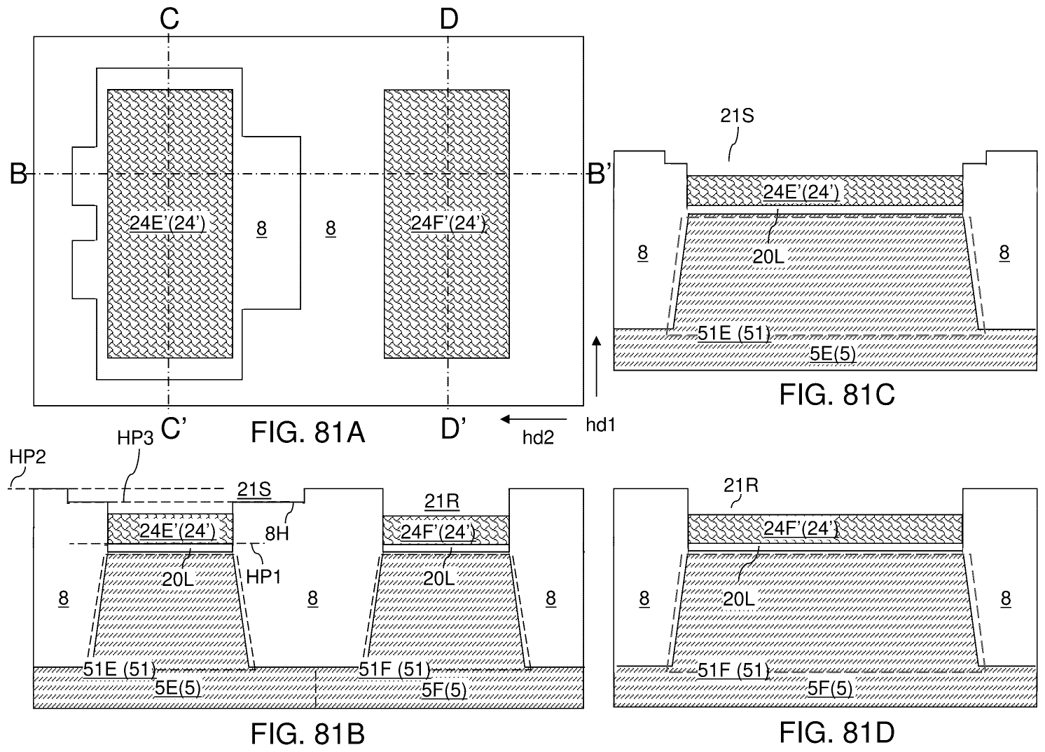

Referring to FIGS. 81A-81D, a selective etch process can be performed to remove hardmask plates 21 selective to the trench isolation structures 8 and the gate semiconductor material portions 24′. For example, if the hardmask plates 21 comprise silicon nitride, a wet etch process employing hot phosphoric acid may be performed to remove the hardmask plates 21 selective to the trench isolation structures 8 and the gate semiconductor material portions 24′.

A stepped cavity 21S can be formed by removing the first hardmask plate 21A. The stepped cavity comprises a volume from which the first hardmask plate 21A is removed and a volume of the peripheral recess region, i.e., the volume of the gap region 32. A recess cavity 21R can be formed in the volume from which the second hardmask plate 21B is removed. Interfaces between the gate dielectric layers 20L and the gate semiconductor material portions 24′ can be located within a first horizontal plane HP1. Topmost surfaces of the trench isolation structures 8 can be located within a second horizontal plane HP2. Recessed horizontal surfaces 8H of the trench isolation structures 8 can be located within a third horizontal plane HP3 that overlies the top surfaces of the gate semiconductor material portions 24′.

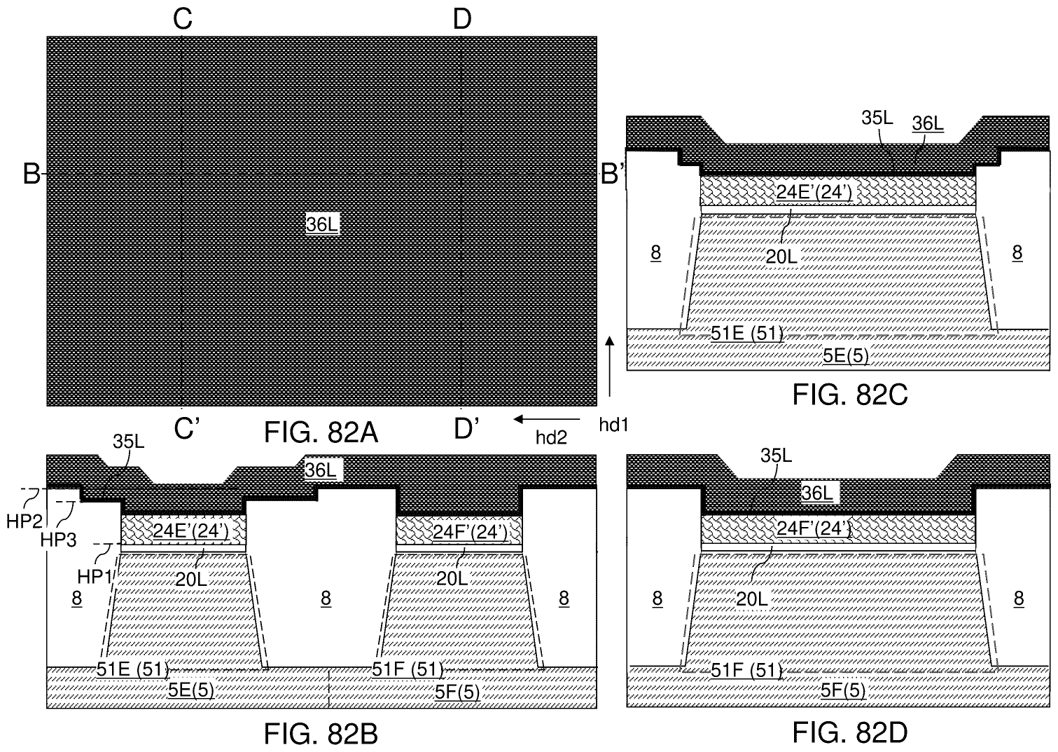

Referring to FIGS. 82A-82D, a metallic gate electrode liner layer 35L and a metallic gate electrode material layer 36L can be deposited in the stepped cavity and in the recess cavity. In one embodiment, the metallic gate electrode liner layer 35L comprises a metallic barrier material such as a metal and/or conductive metallic nitride material. Exemplary conductive metallic nitride materials include TiN, TaN, WN, MoN, etc. Exemplary metals include Ti, Ta, etc. The thickness of the metallic gate electrode liner layer 35L may be in a range from 3 nm to 30 nm, although lesser and greater thicknesses may also be employed. The metallic gate electrode material layer 36L comprises a metallic gate material such as W, Ti, Ta, Mo, Co, Ru, etc. The thickness of a horizontally-extending portion of the metallic gate electrode material layer 36L may be in a range from 50 nm to 300 nm, such as from 100 nm to 200 nm, although lesser and greater thicknesses may also be employed. For example, the metallic gate electrode liner layer 35L may comprise a Ti/TiN bilayer and the metallic gate electrode material layer 36L may comprise a tungsten layer overlying the TiN sublayer of the Ti/TiN bilayer.

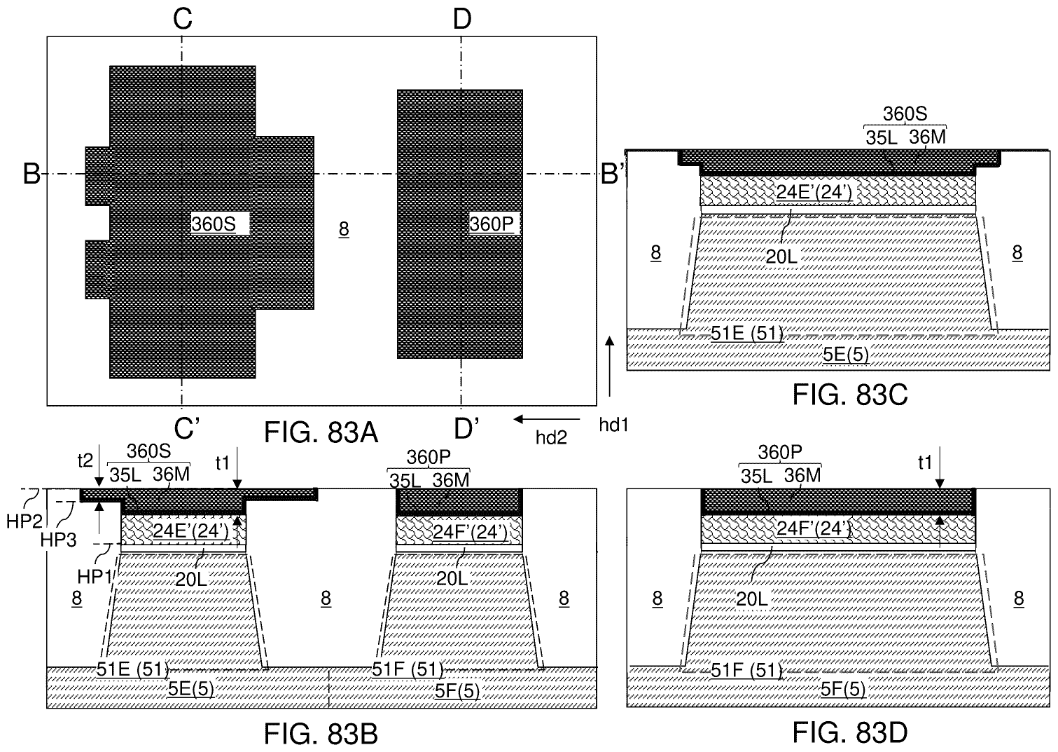

Referring to FIGS. 83A-83D, a planarization process, such as a chemical mechanical polishing process, can be performed to remove portions of the metallic gate electrode liner layer 35L and the metallic gate electrode material layer 36L from above the horizontal plane including the topmost surface of the trench isolation structures 8, i.e., from above the second horizontal plane. The metallic gate electrode liner layer 35L is patterned into multiple metallic gate electrode liner layers 35L. The metallic gate electrode material layer 36L is patterned into metallic material portions 36M. Each contiguous combination of a metallic gate electrode liner layer 35L and a metallic material portion 36M constitutes a metallic plate (35L, 36M). The metallic plates (35L, 36M) comprise a stepped metallic plate 360S that is formed in the stepped cavity 21S over the first active region 51E, and a planar metallic plate 360P that is formed in the recess cavity over the second active region 51F. In one embodiment, the stepped metallic plate 360S comprise a first region having a first thickness t1 and a second region having a second thickness t2 that is less than the first thickness t1. The first region has an areal overlap with the first gate electrode material portion 24E′ in a plan view, and the second region has an areal overlap with a trench isolation structure 8 in the plan view. The planar metallic plate 360P may have the first thickness t1 throughout.

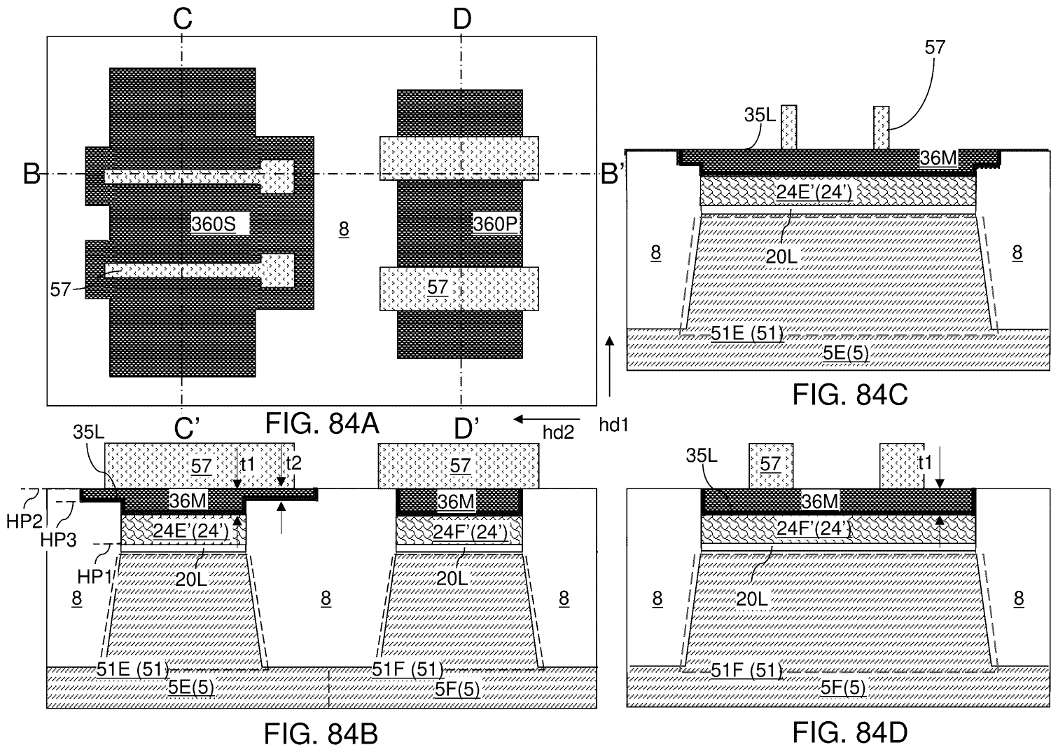

Referring to FIGS. 84A-84D, a photoresist layer 57 can be applied over the metallic plates (35L, 36M) and the trench isolation structure 8, and can be lithographically patterned into patterns of gate electrodes to be subsequently formed. In an illustrative example, the patterned photoresist layer 57 may include a pair of first photoresist material portions that straddle the first active region 51E along the second horizontal direction hd2 and a pair of second photoresist material portions that straddle the second active region 51F along the second horizontal direction hd2. According to an aspect of the present disclosure, the peripheries of the pairs first photoresist material portions in a plan view may be located entirely within the area defined by the outer periphery of the gap region 32, i.e., by the outer periphery of the stepped metallic plates 360S overlying the first active region 51E. In one embodiment, the peripheries of the pair first photoresist material portions in the plan view may be laterally spaced inward from the outer periphery of the stepped metallic plates 360S at least by the lateral thickness of dielectric spacers to be subsequently formed. In one embodiment, the lateral extent of each photoresist material portion of the patterned photoresist layer 57 overlying the second active region 51F may be greater than the width of the second active region 51F along the second horizontal direction hd2, and the widthwise edges of the photoresist material portions of the patterned photoresist layer 57 overlying the second active region may be located entirely outside the area of the second active region in the plan view (such as the top-down view of FIG. 84A).

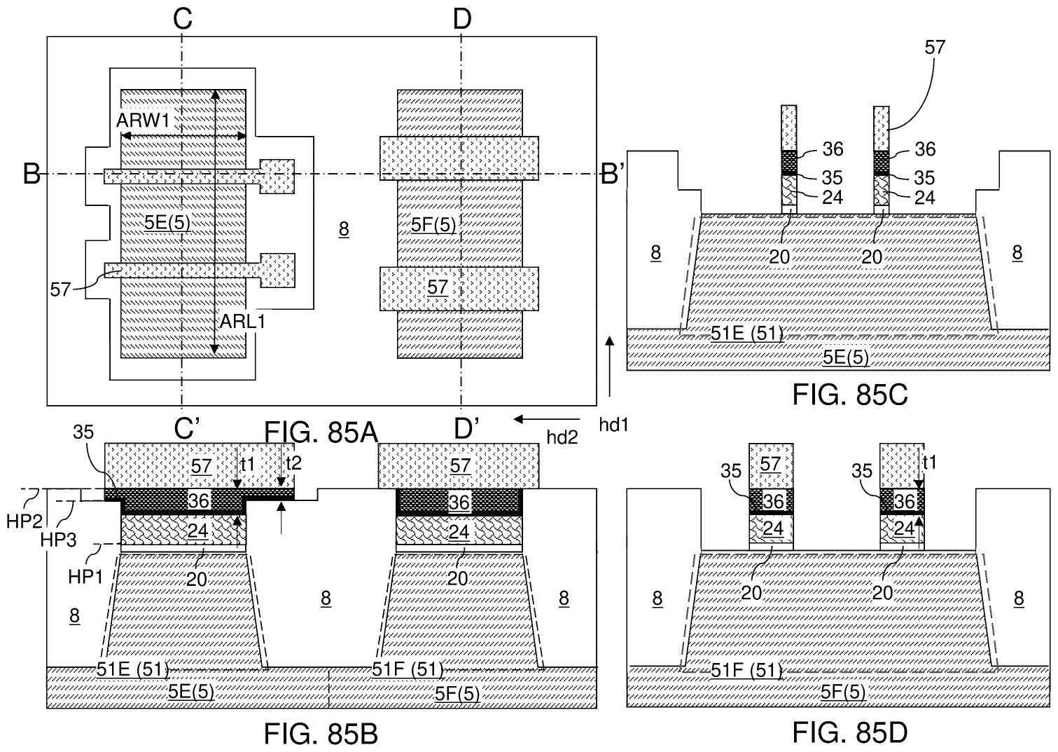

Referring to FIGS. 85A-85D, a first selective anisotropic etch process can be performed to etch the metallic materials of the metallic plates (35L, 36M) selective to the dielectric material of the trench isolation structure 8. Remaining portions of the metallic plates (35L, 36M) comprise metallic gate electrodes (35, 36). A second selective anisotropic etch process can be performed to etch unmasked portions of the gate electrode material portions 24′ selective to the dielectric material of the trench isolation structure 8 and selective to the gate dielectric layers 20L. Remaining portions of the gate electrode material portions 24′ comprise semiconductor gate electrode portions 24. Subsequently, a third anisotropic etch process can be performed to etch unmasked portions of the gate dielectric layers 20L. Remaining portions of the gate dielectric layers 20L comprise gate dielectrics 20. The photoresist layer 57 can be subsequently removed, for example, by ashing.

Each contiguous combination of a semiconductor gate electrode portion 24 and a metallic gate electrode (35, 36) constitutes a gate electrode (24, 35, 36). Generally, a stepped metallic plate 360S and a first semiconductor gate semiconductor material portion 24E′ that overlie a first active region 51E can be patterned into a first gate electrode (24, 35, 36), and a planar metallic plate 360P and a second semiconductor gate semiconductor material portion 24F′ that overlie a second active region 51F can be patterned into a second gate electrode (24, 35, 36).

In one embodiment, the first gate electrode (24, 35, 36) laterally extends along a first gate electrode direction (such as the second horizontal direction hd2) that is perpendicular to a first channel direction (such as the first horizontal direction hd1). A maximum lateral extent of the first metallic gate electrode portion (35, 36) along the first gate electrode direction (such as the second horizontal direction hd2) is greater than a maximum lateral extent of the first semiconductor gate electrode portion 24 along the first gate electrode direction (such as the second horizontal direction hd2) as illustrated, for example, in FIGS. 85A and 85B.

In one embodiment, the second gate electrode (24, 35, 36) laterally extends along a second gate electrode direction (such as the second horizontal direction hd2) that is perpendicular to the second channel direction (such as the first horizontal direction hd1). A maximum lateral extent of the second metallic gate electrode portion (35, 36) along the second gate electrode direction (such as the second horizontal direction hd2) is the same as a maximum lateral extent of the second semiconductor gate electrode portion 24 along the second gate electrode direction (such as the second horizontal direction hd2) as illustrated in FIG. 85B.

In one embodiment, the first metallic gate electrode portion (35, 36) comprises a center segment having a first thickness t1 and peripheral segments having a second thickness t2 that is less than the first thickness t1. In one embodiment, an entirety of the center segment of the first metallic gate electrode portion (35, 36) has an areal overlap with the first semiconductor gate electrode portion 24 in a plan view (such as a top-down view of FIG. 85A). In one embodiment, an entirety of the peripheral segments of the first metallic gate electrode portion (35, 36) does not have any areal overlap with the first semiconductor gate electrode portion 24 in a plan view.

In one embodiment, top surfaces of the peripheral segments and a top surface of the center segment are located entirely within a horizontal plane such as the second horizontal plane HP2. In one embodiment, the semiconductor structure comprises: a first trench isolation structure 8 laterally surrounding the first active region 51E; and a second trench isolation structure 8 laterally surrounding the second active region 51F. The first metallic gate electrode portion (35, 36) comprises peripheral segments that overlie first trench isolation structure 8. In one embodiment, a center segment of the first metallic gate electrode portion (35, 36) having an areal overlap with the first active region 51E has a first thickness t1; and peripheral segments of the first metallic gate electrode portion (35, 36) having an areal overlap with the first trench isolation structure 8 have a second thickness t2 that is less than the first thickness t1. In one embodiment, the peripheral segments of the first metallic gate electrode portion (35, 36) do not have any areal overlap with the first semiconductor gate electrode portion 24 in a plan view.

In one embodiment, the first semiconductor gate electrode portion 24 has an areal overlap with the first active region 51E and does not have any areal overlap with the first trench isolation structure 8 in a plan view. In one embodiment, the first trench isolation structure 8 comprises: a top surface 8T that is located within a same horizontal plane as a top surface of the first metallic gate electrode portion (35, 36); a first widthwise sidewall 8S that connects an edge of the top surface 8T to an edge of the recessed horizontal surface 8H; the recessed horizontal surface 8H that is adjoined to a bottom edge of the first widthwise sidewall 8S and contacting a first bottom surface of the first metallic gate electrode portion (35, 36); and a second widthwise sidewall 8W that contacts a lower widthwise sidewall of the first metallic gate electrode portion (35, 36). The patterned photoresist layer 57 may be subsequently removed, for example, by ashing.

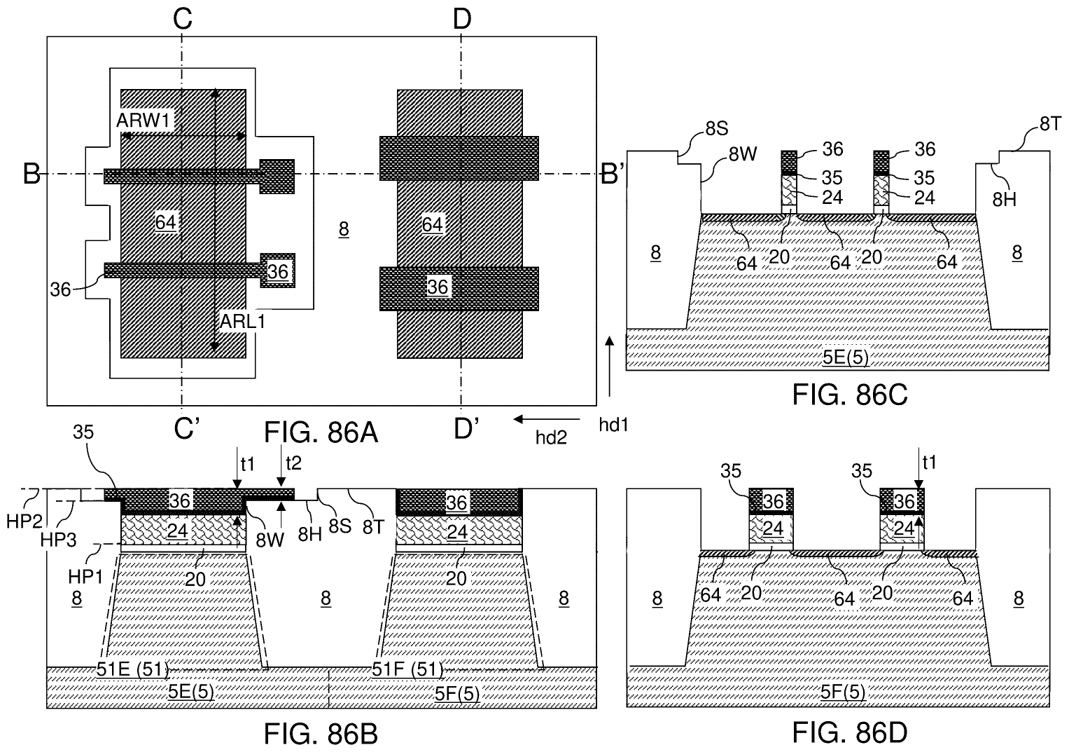

Referring to FIGS. 86A-86D, source/drain extension regions 64 can be formed by implanting dopants into top surface portions of the first doped well 5E and the second doped well 5F. For example, the processing steps described with reference to FIGS. 53A-53D can be performed to form the source/drain extension regions 64. The source/drain extension regions 64 may comprise lightly doped drain (LDD) and source regions.

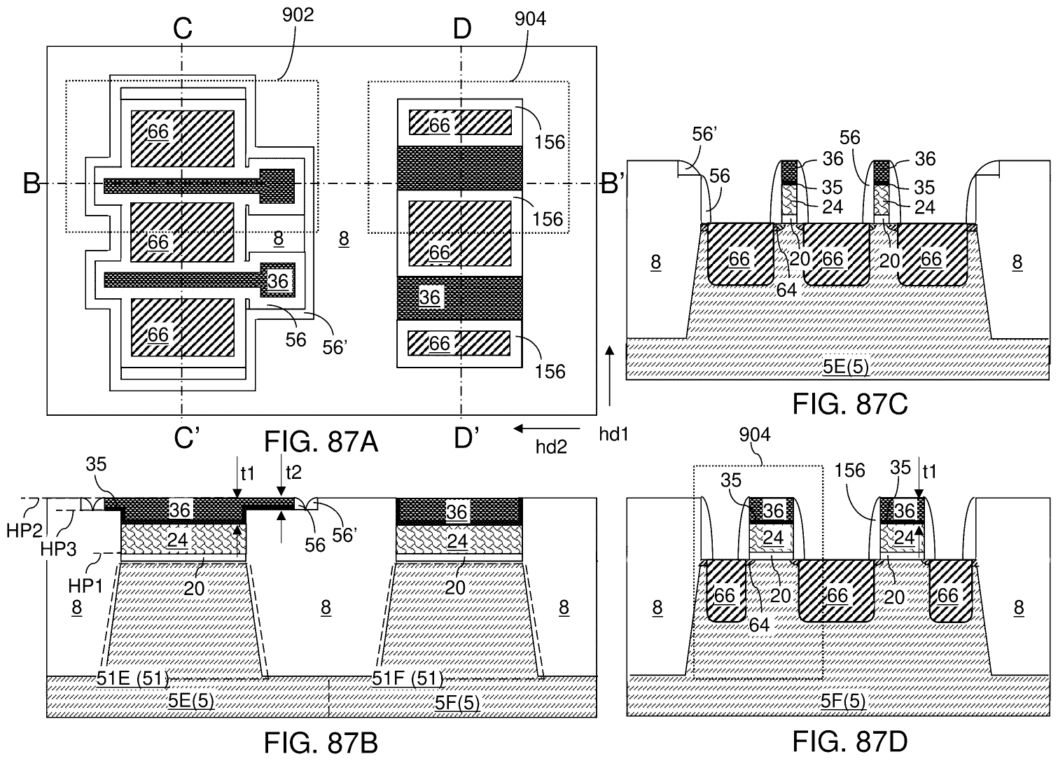

Referring to FIGS. 87A-87D, dielectric spacers 56 can be formed, for example, by performing the processing steps described with reference to FIGS. 54A-54D. Subsequently, deep (i.e., heavily doped) source/drain regions 66 can be formed by implanting additional electrical dopants. Source/drain regions (64, 66) can be formed in each doped well (5E, 5F).

In one embodiment, a first dielectric gate spacer 56 around the first gate electrode (24, 35, 36) and on sidewalls of the first trench isolation structure 8. The first dielectric gate spacer 56 comprises at least three openings therethrough, and the first gate electrode (24, 35, 36) can be located in a first opening of the at least three openings. In one embodiment, a first source region (such as one of the source/drain regions (64, 66)) of the first field effect transistor 902 underlies a second opening of the at least three openings; and a first drain region (such as one of the source/drain regions (64, 66)) of the first field effect transistor 902 underlies a third opening of the at least three openings. The first dielectric gate spacer 56 can contact lengthwise sidewalls of the first semiconductor gate electrode portion 24, lengthwise sidewalls of the first metallic gate electrode portion (35, 36), and sidewalls of the first trench isolation structure 8.

In one embodiment, the first shallow trench isolation structure 8 comprises a top surface 8T and a recessed horizontal surface 8H that is recessed relative to the top surface 8T; the recessed horizontal surface 8H laterally surrounds the first active region 51E; and an outer dielectric spacer 56′ having a same material composition as the first dielectric gate spacer 56 overlies the recessed horizontal surface 8H and the second widthwise sidewall 8W of the first trench isolation structure 8.

In one embodiment, the first active region 51E comprises a first source region (such as one of the source/drain regions (64, 66)) and a first drain region (such as one of the source/drain regions (64, 66)) that are laterally spaced from each other by a first channel region comprising an upper portion of the doped well 5E along a first channel direction (such as the first horizontal direction hd1). The second active region 51F comprises a second source region (such as one of the source/drain regions (64, 66)) and a second drain region (such as one of the source/drain regions (64, 66)) that are laterally spaced from each other by a second channel region comprising an upper portion of the doped well 5F along a second channel direction (such as the first horizontal direction hd1).

The first field effect transistor 902 and a second field effect transistor 904 are formed on the substrate 2. The first field effect transistor 902 can be provided by forming a first source region (such as one of the source/drain regions (64, 66)) and a first drain region (such as one of the source/drain regions (64, 66)) in the first portion of the semiconductor substrate 2 (e.g., in doped well 5E) adjacent to the first gate electrode (24, 35, 36). The second field effect transistor 904 can be provided by forming a second source region (such as one of the source/drain regions (64, 66)) and a second drain region (such as one of the source/drain regions (64, 66)) in the second portion of the semiconductor substrate 2 (e.g., in doped well 5F) adjacent to the second gate electrode (24, 35, 36).

The first field effect transistor 902 may comprise a peripheral transistor that is not a sense amplifier transistor. The first field effect transistor 902 comprises a first active region 51F including a portion of the semiconductor substrate 2 located within a first opening through the trench isolation structures 8, and a first gate structure (20, 24, 35, 36) that includes a first gate dielectric 20 and a first gate electrode (24, 35, 36). A first dielectric gate spacer 56 laterally surrounds the first gate electrode (24, 35, 36) and contacts second segments of the recessed horizontal surface 8H of the trench isolation structure 8.

The second field effect 904 comprises a fringeless sense amplifier transistor. The second field effect transistor 904 includes a second active region 51F including another portion of the semiconductor substrate 2 located within a second opening through the trench isolation structures 8, and comprises a second gate structure (20, 24, 35, 36) including a second gate dielectric 20 and a second gate electrode (24, 35, 36). The second gate electrode 24F comprises a pair of sidewalls vertically extending straight from a respective edge of the top surface of the second gate electrode (24, 35, 36) to a respective edge of a top surface of a second gate dielectric 20 that underlies the second gate electrode (24, 35, 36). In one embodiment, an entirety of the pair of sidewalls of the second gate electrode (24, 35, 36) is in contact with a respective sidewall of the trench isolation structure 8. In one embodiment, shown in FIG. 87B, the second gate electrode (24, 35, 36) comprises first sidewalls in contact with sidewall segments of the trench isolation structure 8 and second sidewalls in contact with a pair of second dielectric gate spacers 156. Each second dielectric gate spacer 156 contacts the second gate electrode (24, 35, 36) and sidewalls of the trench isolation structure 8.

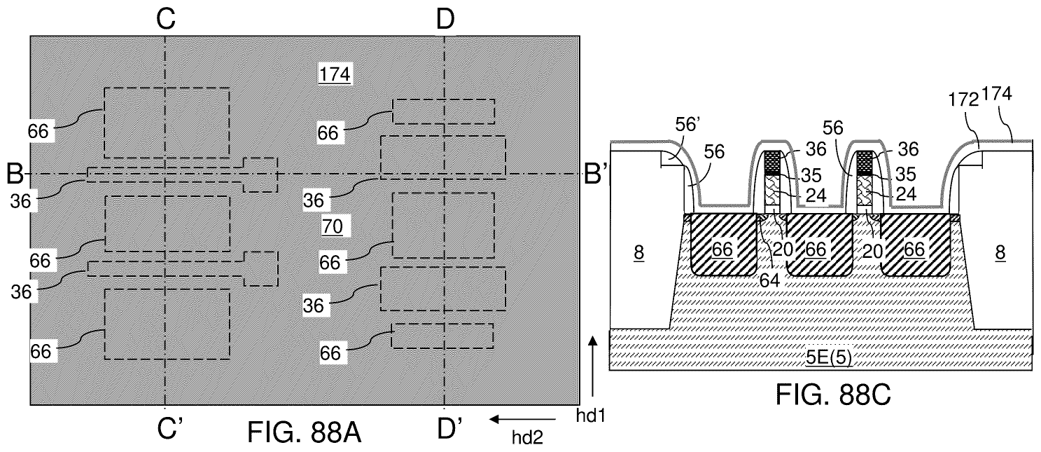

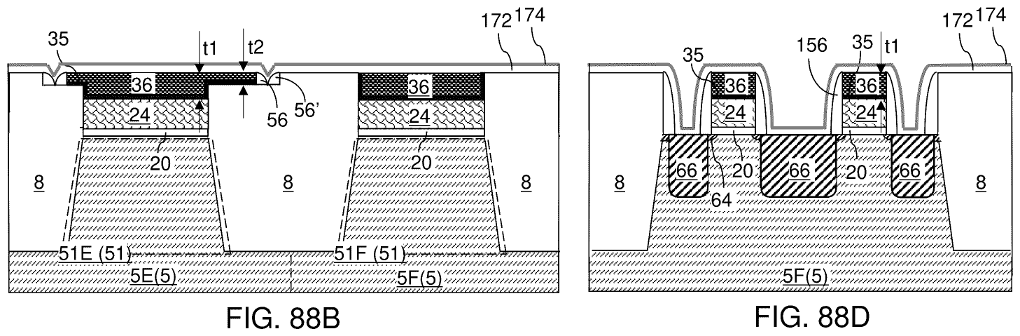

Referring to FIGS. 88A-88D, at least one dielectric liner (172, 174) can be formed, for example, by performing a set of processing steps described with reference to FIGS. 56A-56D.

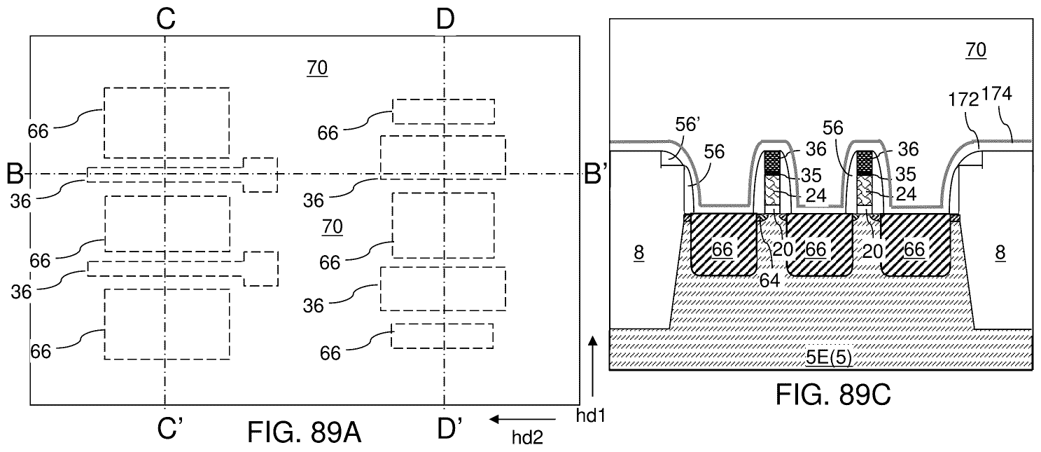

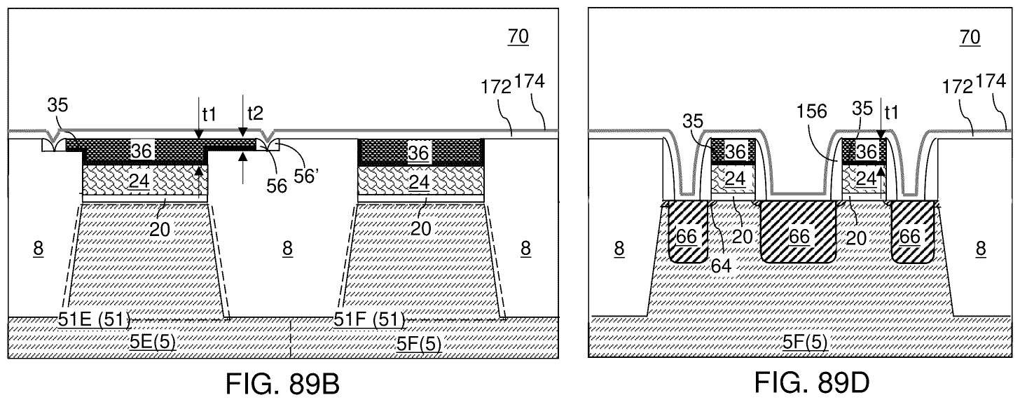

Referring to FIGS. 89A-89D, the contact-level dielectric layer 70 can be formed, for example, by performing a set of processing steps described with reference to FIGS. 56A-56D.

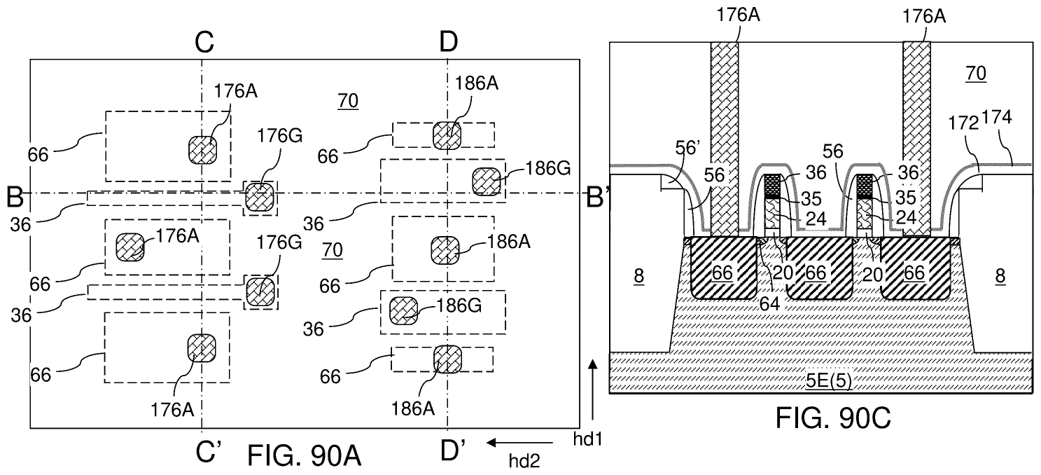

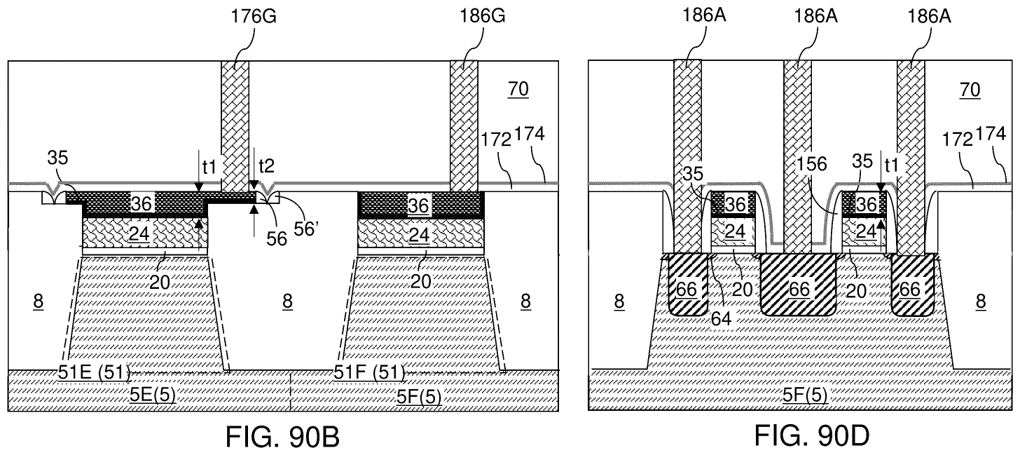

Referring to FIGS. 90A-90D, various contact via structures (176A, 176G, 186A, 186G) can be formed, for example, by performing a set of processing steps described with reference to FIGS. 57A-57D.

In the seventh embodiment, a fringeless sense amplifier transistor 904 can be formed during the same process steps as a peripheral transistor 902 which includes a gate electrode extending into the fringe region. A metal gate electrode portion 36, such as tungsten gate electrode portion, may be formed by a damascene type process in which the metal layer is deposited into recesses formed by selective removal of the hardmask plates 21 followed a CMP step to planarize the top of the metal gate electrode portion 36 with a top surface of the trench isolation structures 8. Thus, a simplified method of simultaneously forming both fringeless and fringe type transistors during the same steps is provided.

Referring collectively to FIGS. 77A-90D and according to various embodiments of the present disclosure, a semiconductor structure comprises: a first field effect transistor 902 comprising a first active region 51E and a first gate electrode (24, 35, 36) that comprises a first semiconductor gate electrode portion 24 and a first metallic gate electrode portion (35, 36); and a second field effect transistor 904 comprising a second active region 51F and a second gate electrode (24, 35, 36) that comprises a second semiconductor gate electrode portion 24 and a second metallic gate electrode portion (35, 36). The first active region 51E comprises a first source region (such as one of the source/drain regions (64, 66)) and a first drain region (such as one of the source/drain regions (64, 66)) that are laterally spaced from each other by a first channel 5E along a first channel direction (such as the first horizontal direction hd1); the first gate electrode (24, 35, 36) laterally extends along a first gate electrode direction (such as the second horizontal direction hd2) that is perpendicular to the first channel direction (such as the first horizontal direction hd1); and a maximum lateral extent of the first metallic gate electrode portion (35, 36) along the first gate electrode direction (such as the second horizontal direction hd2) is greater than a maximum lateral extent of the first semiconductor gate electrode portion 24 along the first gate electrode direction (such as the second horizontal direction hd2).

In one embodiment, the second active region 51F comprises a second source region (such as one of the source/drain regions (64, 66)) and a second drain region (such as one of the source/drain regions (64, 66)) that are laterally spaced from each other by a second channel 5F along a second channel direction (such as the first horizontal direction hd1); the second gate electrode (24, 35, 36) laterally extends along a second gate electrode direction (such as the second horizontal direction hd2) that is perpendicular to the second channel direction (such as the first horizontal direction hd1); and a maximum lateral extent of the second metallic gate electrode portion (35, 36) along the second gate electrode direction (such as the second horizontal direction hd2) is the same as a maximum lateral extent of the second semiconductor gate electrode portion 24 along the second gate electrode direction (such as the second horizontal direction hd2).

In one embodiment, the first metallic gate electrode portion (35, 36) comprises a center segment having a first thickness t1 and peripheral segments having a second thickness t2 that is less than the first thickness t1. In one embodiment, an entirety of the center segment of the first metallic gate electrode portion (35, 36) has an areal overlap with the first semiconductor gate electrode portion 24 in a plan view. In one embodiment, an entirety of the peripheral segments of the first metallic gate electrode portion (35, 36) does not have any areal overlap with the first semiconductor gate electrode portion 24 in a plan view.

In one embodiment, top surfaces of the peripheral segments and a top surface of the center segment are located entirely within a horizontal plane. In one embodiment, the semiconductor structure comprises: a first trench isolation structure 8 laterally surrounding the first active region 51E; and a second trench isolation structure 8 laterally surrounding the second active region 51F. The first metallic gate electrode portion (35, 36) comprises peripheral segments that overlie first trench isolation structure 8. In one embodiment, a center segment of the first metallic gate electrode portion (35, 36) having an areal overlap with the first active region 51E has a first thickness t1; and peripheral segments of the first metallic gate electrode portion (35, 36) having an areal overlap with the first trench isolation structure 8 have a second thickness t2 that is less than the first thickness t1. In one embodiment, the peripheral segments of the first metallic gate electrode portion (35, 36) do not have any areal overlap with the first semiconductor gate electrode portion 24 in a plan view.

In one embodiment, the first semiconductor gate electrode portion 24 has an areal overlap with the first active region 51E and does not have any areal overlap with the first trench isolation structure 8 in a plan view. In one embodiment, the first trench isolation structure 8 comprises: a top surface 8T that is located within a same horizontal plane as a top surface of the first metallic gate electrode portion (35, 36); a recessed horizontal surface 8H that contacts bottom surfaces of the peripheral segments of the first metallic gate electrode portion (35, 36); and a first widthwise sidewall 8S that connects an edge of the top surface 8T to an edge of the recessed horizontal surface 8H. In one embodiment, the first trench isolation structure 8 further comprises a second widthwise sidewall 8W that contacts a lower widthwise sidewall of the first metallic gate electrode portion (35, 36).

In one embodiment, the semiconductor structure comprises a first dielectric gate spacer 56 contacting lengthwise sidewalls of the first semiconductor gate electrode portion 24, lengthwise sidewalls of the first metallic gate electrode portion 35, 36, and sidewalls of the first trench isolation structure 8. In one embodiment, the first dielectric gate spacer 56 comprises at least three openings therethrough, wherein: the first gate electrode (24, 35, 36) is located in a first opening of the at least three openings; a first source region (such as one of the source/drain regions (64, 66)) of the first field effect transistor underlies a second opening of the at least three openings; and a first drain region (such as one of the source/drain regions (64, 66)) of the first field effect transistor underlies a third opening of the at least three openings. In one embodiment, the first shallow trench isolation structure 8 comprises a top surface and a recessed horizontal surface that is recessed relative to the top surface; the recessed horizontal surface laterally surrounds the first active region 51E; and an outer dielectric spacer 56′ having a same material composition as the first dielectric gate spacer 56 overlies the recessed horizontal surface and sidewalls of the first trench isolation structure 8 that connect the top surface and the recessed horizontal surface.

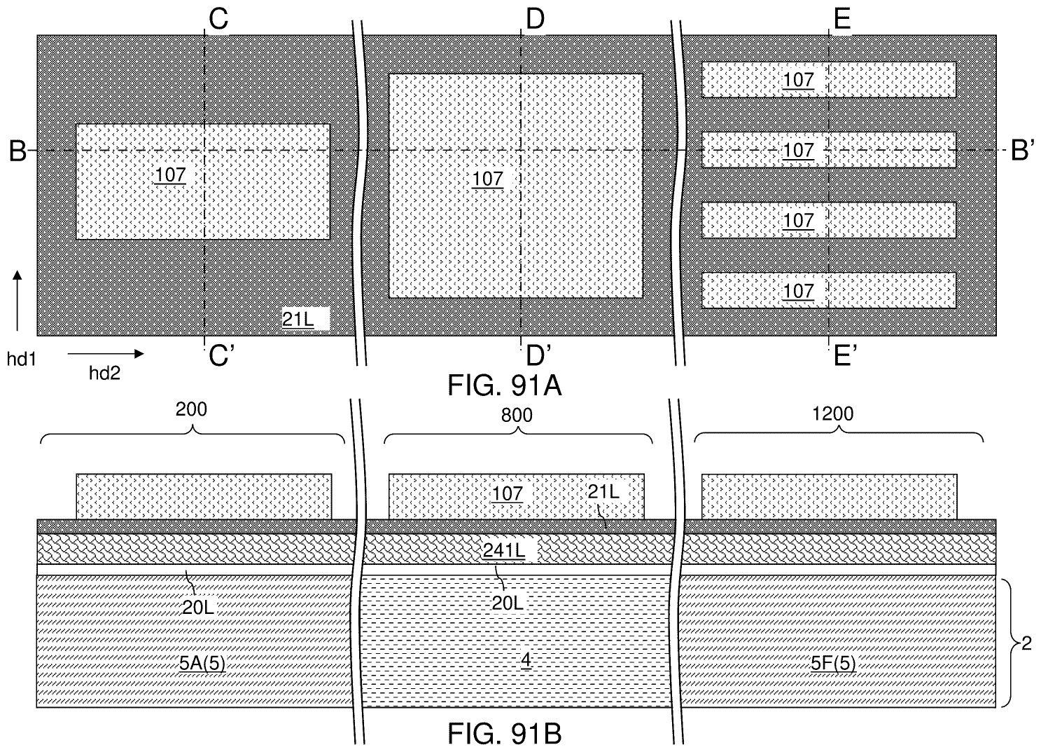

Referring to FIGS. 91A and 91B, an eighth exemplary structure according to an eighth embodiment of the present disclosure is illustrated, which may be formed as portions of the first exemplary structure or the sixth exemplary structure, or may be formed as additional structures that are formed in conjunction with the first exemplary structure or the sixth exemplary structure. The eighth exemplary structure comprises a semiconductor substrate 2, in which various doped wells 5 such as a first doped well 5A and a second doped well 5F can be formed. In one embodiment, the first doped well 5A may be formed in a first transistor region (e.g., a first n-type field effect transistor region 200), and the second doped well 5F may be formed in a transistor array region 1200 in which sense amplifiers and bit line bias switches are to be subsequently formed. A passive device region, such as a second passive device region 800, is located over portion 4 of the semiconductor substrate 2.

A gate dielectric layer 20L, a first semiconductor material layer 241L, and a hardmask layer 21L can be formed over the semiconductor substrate 2. The first semiconductor material layer 241L comprises a first semiconductor material, such as polysilicon. The first semiconductor material is also referred to as a first semiconductor gate electrode material. The first semiconductor material layer 241L may have a thickness in a range from 50 nm to 200 nm, although lesser and greater thicknesses may also be employed. The hardmask layer 21L comprises a hardmask material, such as silicon nitride, and may have a thickness in a range from 50 nm to 200 nm, although lesser and greater thicknesses may also be employed.

A patterned photoresist layer 107 can be formed over the hardmask layer 21L. The patterned photoresist layer 107 comprises patterned photoresist material portions. Each of the patterned photoresist material portions may have an area of a respective active region to be subsequently patterned in the semiconductor substrate 2. In one embodiment, a subset of the patterned photoresist material portions in the transistor array region 1200 may be arranged as a periodic one-dimensional array or as a periodic two-dimensional array, such as a rectangular array. The patterned photoresist material portions in the transistor array region 1200 may be elongated along a second horizontal direction hd2, which can be channel directions for the field effect transistors to be formed therein.

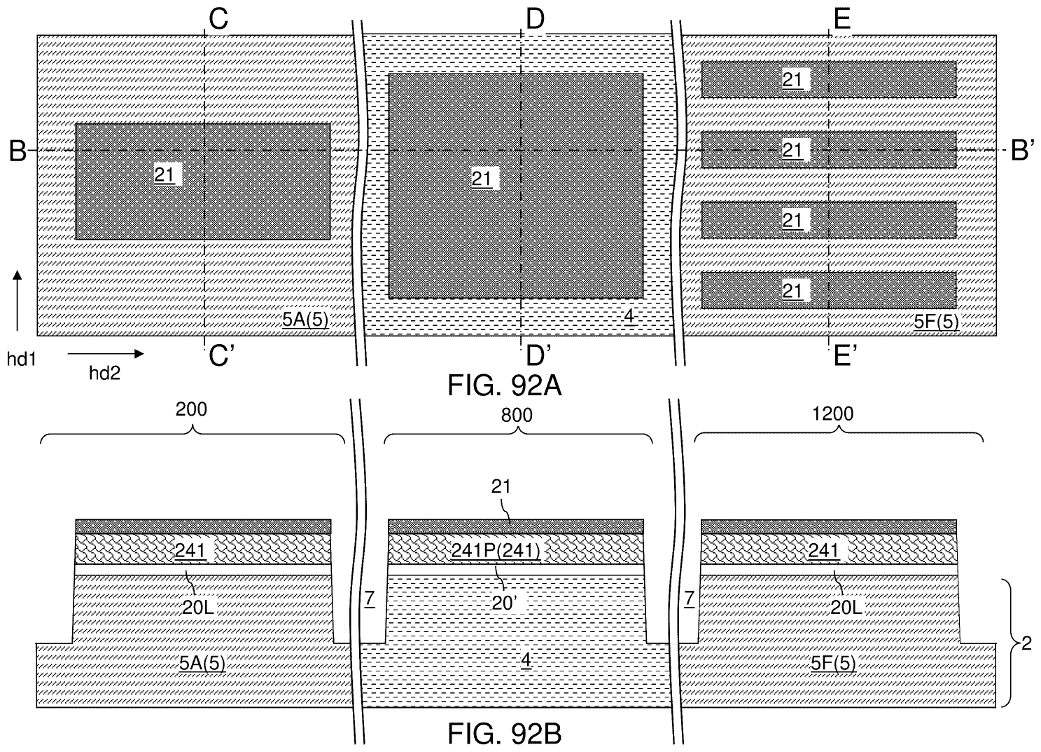

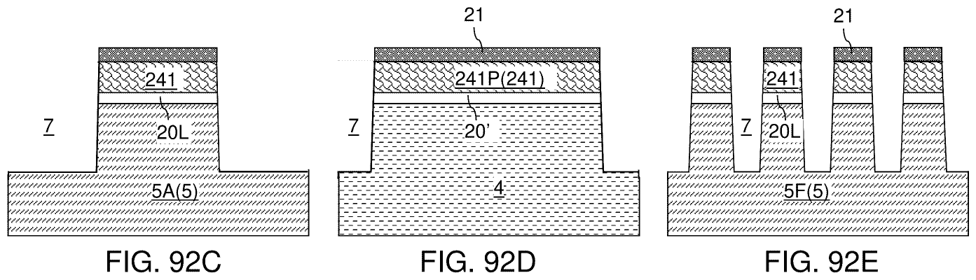

Referring to FIGS. 92A-92E, a first anisotropic etch process can be performed to transfer the pattern in the patterned photoresist layer through the hardmask layer 21L. The hardmask layer 21L is patterned into hardmask plates 21. Each hardmask plate 21 may have a respective rectangular area. The patterned photoresist layer 107 can be removed, for example, by ashing.

A second anisotropic etch process can be performed to transfer the pattern of the hardmask plates 21 through the a first semiconductor material layer 241L, the gate dielectric layer 20L, and an upper portion of the semiconductor substrate 2, such as unmasked portions of substrate portion 4, the first doped well 5A and the second doped well 5F. Patterned portions of the a first semiconductor material layer 241L comprise lower gate material portions 241. One of the lower gate material portions 241 that is formed in the second passive device region 800 is herein referred to as a lower semiconductor plate 241P. A patterned portion of the gate dielectric layer 20L that underlies the lower semiconductor plate 241P is herein referred to as a first dielectric plate 20′.

Shallow trenches 7 are formed in volumes from which the material of the semiconductor substrate 2 is removed, such as the volumes from which the materials of the portion 4, the first doped well 5A and the second doped well 5F are removed. Active regions laterally surrounded by a respective shallow trench 7 can be formed. The active regions may comprise a first active region that is formed in the first transistor region (e.g., a first n-type field effect transistor region 200), a second active region that is formed in the transistor array region 1200.

Patterned stacks (20L, 241, 21) can be formed. Each of the patterned stacks (20L, 241, 21) may include a gate dielectric layer 20L, a lower gate material portion 241, and a hardmask plate 21. The lower gate material portions 241 may comprise a first-transistor lower gate material portion 241 that is formed in the first transistor region (e.g., a first n-type field effect transistor region 200), and second-transistor lower gate material portions 241 that are formed in the transistor array region 1200. A first patterned stack (20L, 241, 21) can be formed in the first transistor region (e.g., a first n-type field effect transistor region 200), and a second patterned stack (20L, 241, 21) can be formed in the transistor array region 1200. A patterned stack that is formed in the second passive device region 800 is herein referred to as a device-region patterned stack (20′, 241P, 21), which includes a first dielectric plate 20′, a lower semiconductor plate 241P, and a hardmask plate 21.

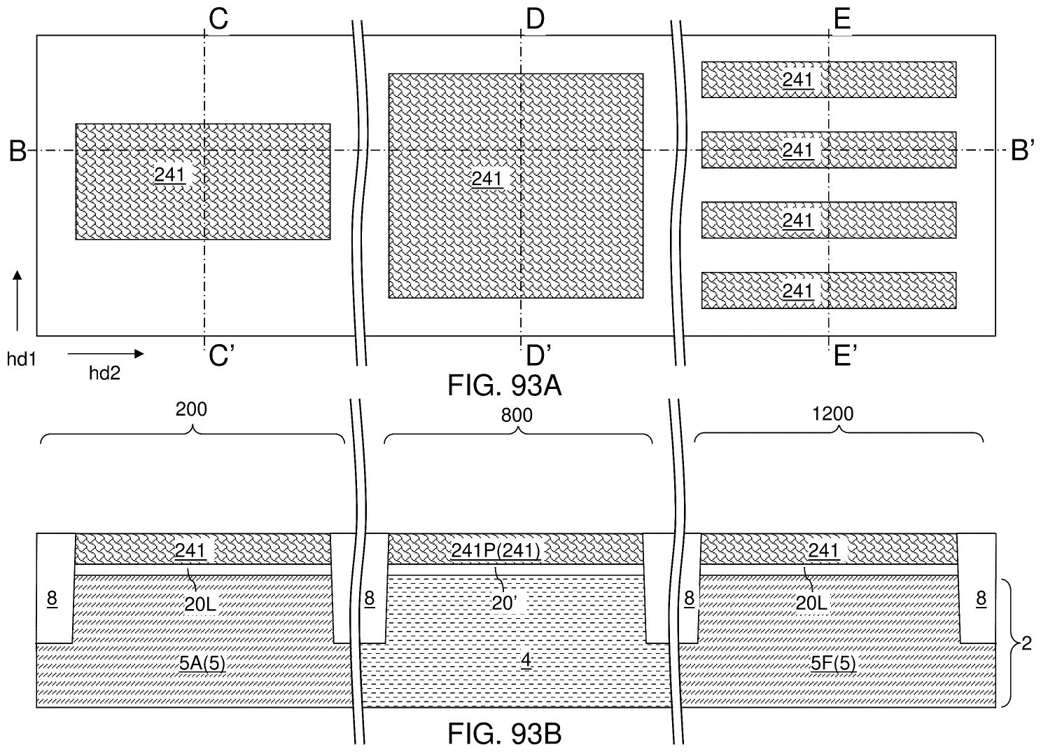

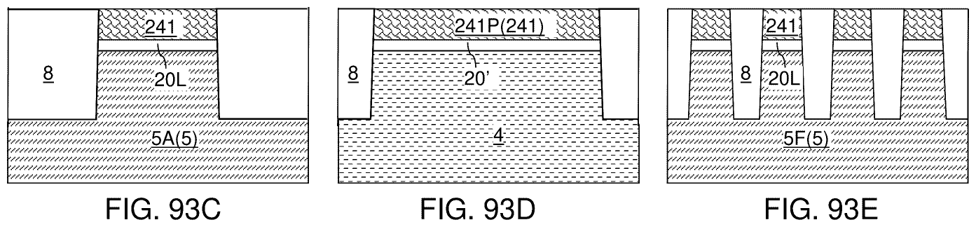

Referring to FIGS. 93A-93E, a dielectric fill material, such as a silicate glass, can be deposited in the shallow trenches 7. Portions of the dielectric fill material overlying the horizontal plane including the top surfaces of the hardmask plates 21 can be removed by performing a planarization process such as a chemical mechanical polishing process. Remaining portions of the dielectric fill material can be vertically recessed, for example, by performing an isotropic etch process, such that top surfaces of the remaining portions of the dielectric fill material are formed approximately at the level of the top surfaces of the lower gate material portions 241. The hardmask plates 21 can be subsequently removed by performing a selective etch process. For example, if the hardmask plates 21 comprise silicon nitride, a wet etch process employing hot phosphoric acid may be performed to remove the hardmask plate 21. Top surfaces of the lower gate material portions 241 can be physically exposed. In one embodiment, top surfaces of the trench isolation structures 8 are formed at or above a horizontal plane including top surfaces of the lower semiconductor plate 241P, a first-transistor lower gate material portion 241 located in the first transistor region (e.g., a first n-type field effect transistor region 200), and second-transistor gate material portion 241 located in the transistor array region 1200.

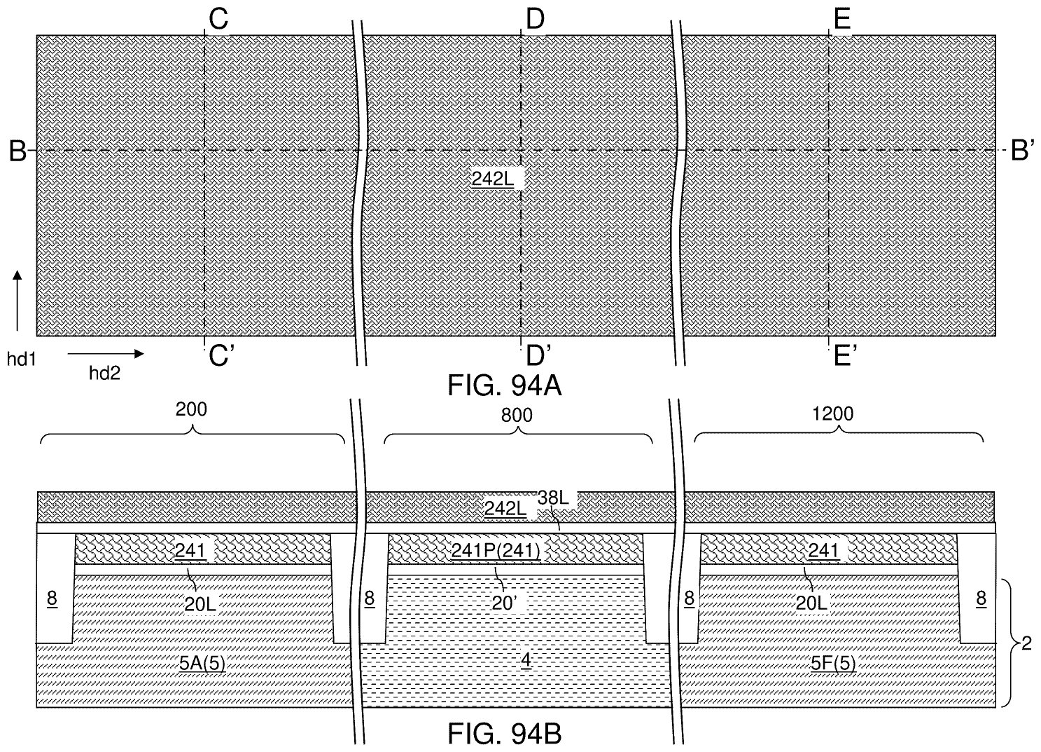

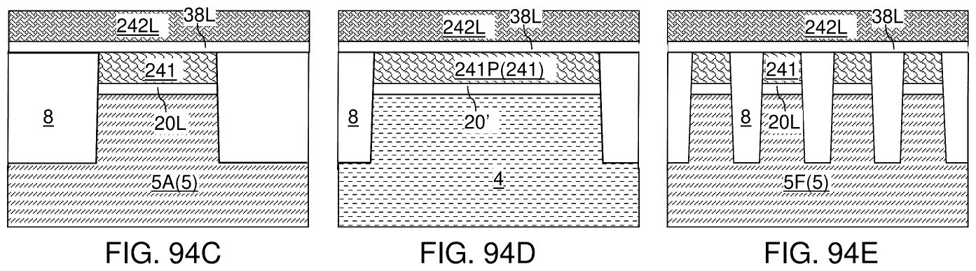

Referring to FIGS. 94A-94E, a dielectric material layer can be formed over the lower gate material portions 241 and the trench isolation structures 8. The dielectric material layer is herein referred to as a node dielectric layer 38L. The node dielectric layer 38L comprises a dielectric material, such as silicon nitride or silicon oxide. The thickness of the node dielectric layer 38L may be in a range from 5 nm to 20 nm, although lesser and greater thicknesses may also be employed.

A second semiconductor material layer 242L including a second semiconductor material can be deposited over the node dielectric layer 38L. The second semiconductor material layer 242L comprises a semiconductor material such as polysilicon, and may have a thickness in a range from 50 nm to 200 nm, although lesser and greater thicknesses may also be employed.

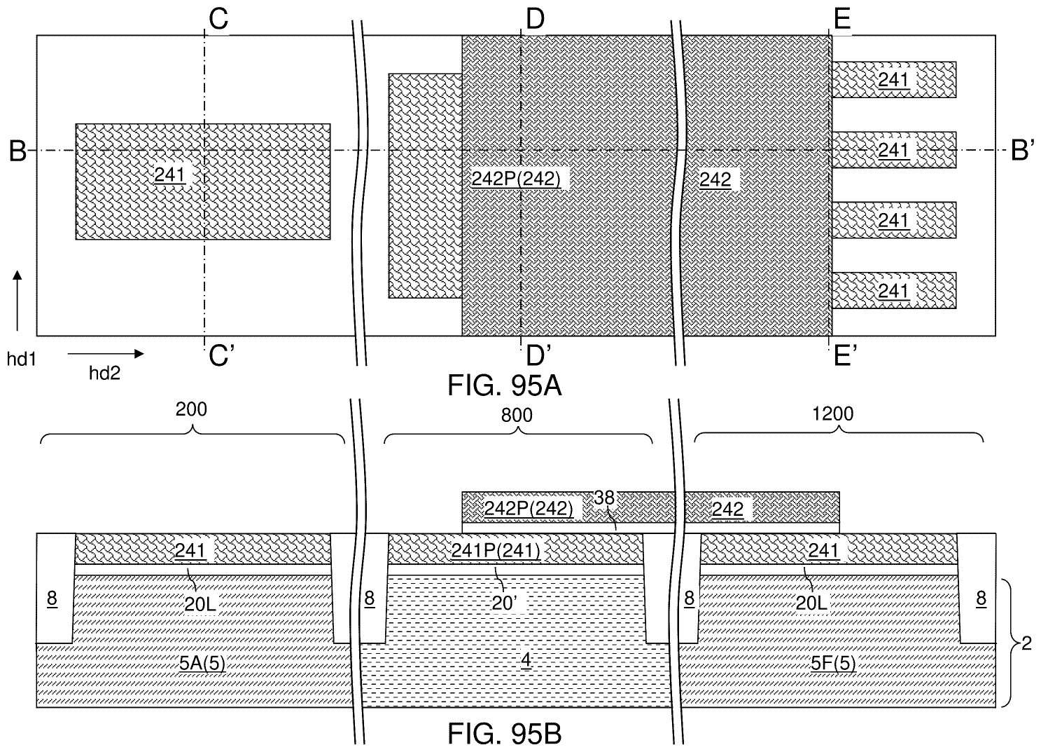

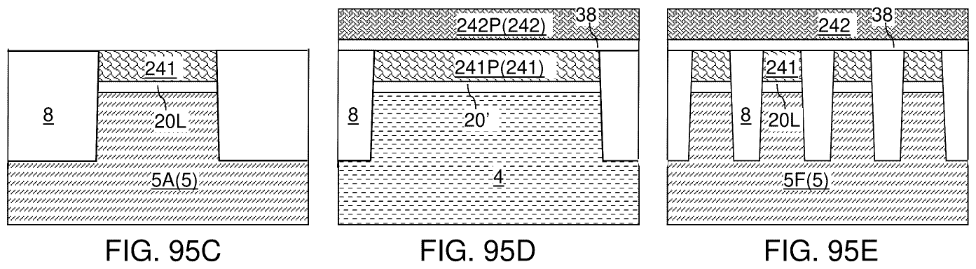

Referring to FIGS. 95A-95E, a photoresist layer (not shown) can be applied over the eighth exemplary structure, and can be lithographically patterned to cover an area within the transistor array region 1200 and to cover an area within the second passive device region 800. An anisotropic etch process can be performed to remove unmasked portions of the second semiconductor material layer 242L and the node dielectric layer 38L. A patterned portion of the second semiconductor material layer 242L that remains in the transistor array region 1200 comprises a middle semiconductor material portion 242. A patterned portion of the second semiconductor material layer 242L that remains in the second passive device region 800 comprises another middle semiconductor material portion 242, and is herein referred to as a middle semiconductor plate 242P. Patterned portions of the node dielectric layer 38L comprise second dielectric plates 38, which are also referred to as node dielectric plates. A second dielectric plate 38 can be formed on a top surface of the lower semiconductor plate 241P.

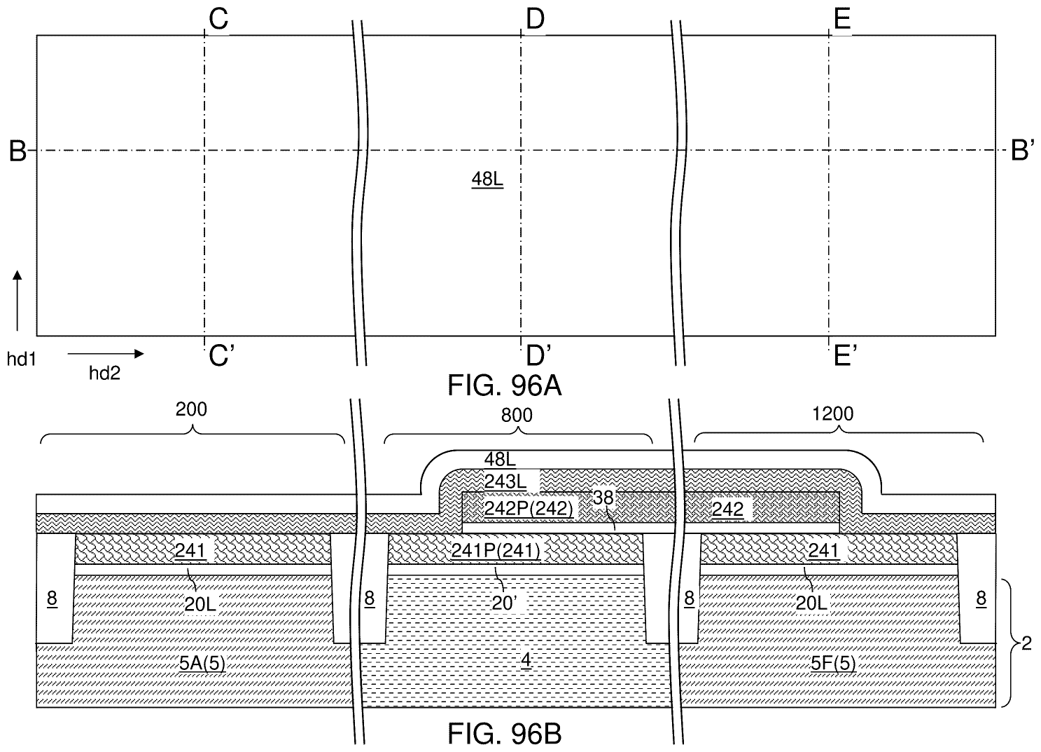

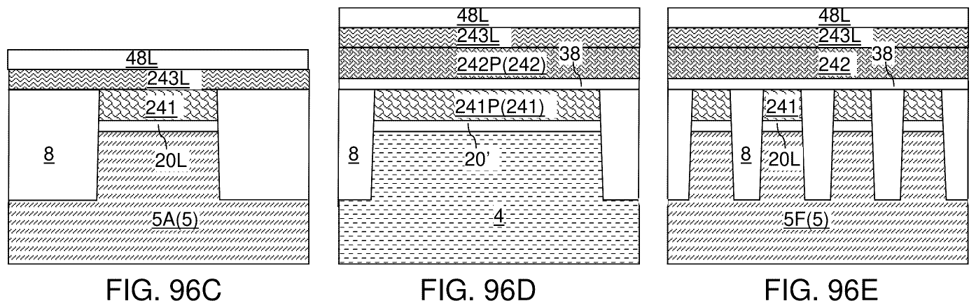

Referring to FIGS. 96A-96E, a third semiconductor material layer 243L comprising a third semiconductor material can be deposited. The third semiconductor material may comprise a second gate semiconductor material, such as polysilicon. The thickness of the third semiconductor material layer 243L may be in a range from 50 nm to 200 nm, although lesser and greater thicknesses may also be employed.

A dielectric capping layer 48L can be deposited over the third semiconductor material layer 243L. The dielectric capping layer 48L comprises a dielectric material such as silicon oxide. The thickness of the dielectric capping layer 48L may be in a range from 50 nm to 200 nm, although lesser and greater thicknesses may also be employed.

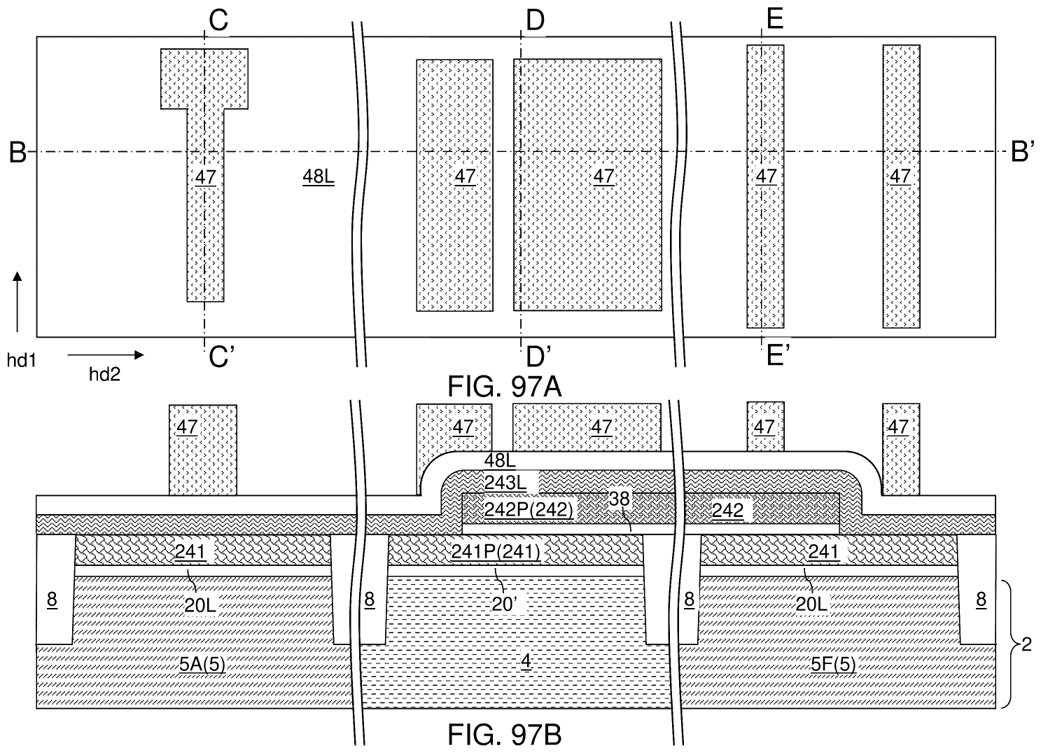

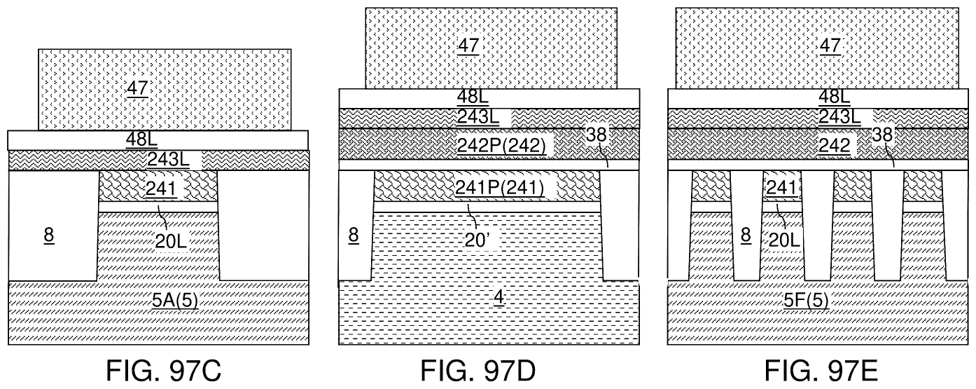

Referring to FIGS. 97A-97E, a photoresist layer 47 can be applied over the dielectric capping layer 48L, and can be lithographically patterned into a combination of a gate pattern and a passive device pattern. The gate pattern in the photoresist layer 47 covers areas in which gate electrodes of field effect transistors are to be subsequently formed. The passive device pattern in the photoresist layer 47 convers areas in which upper portions of a passive device are to be subsequently formed.

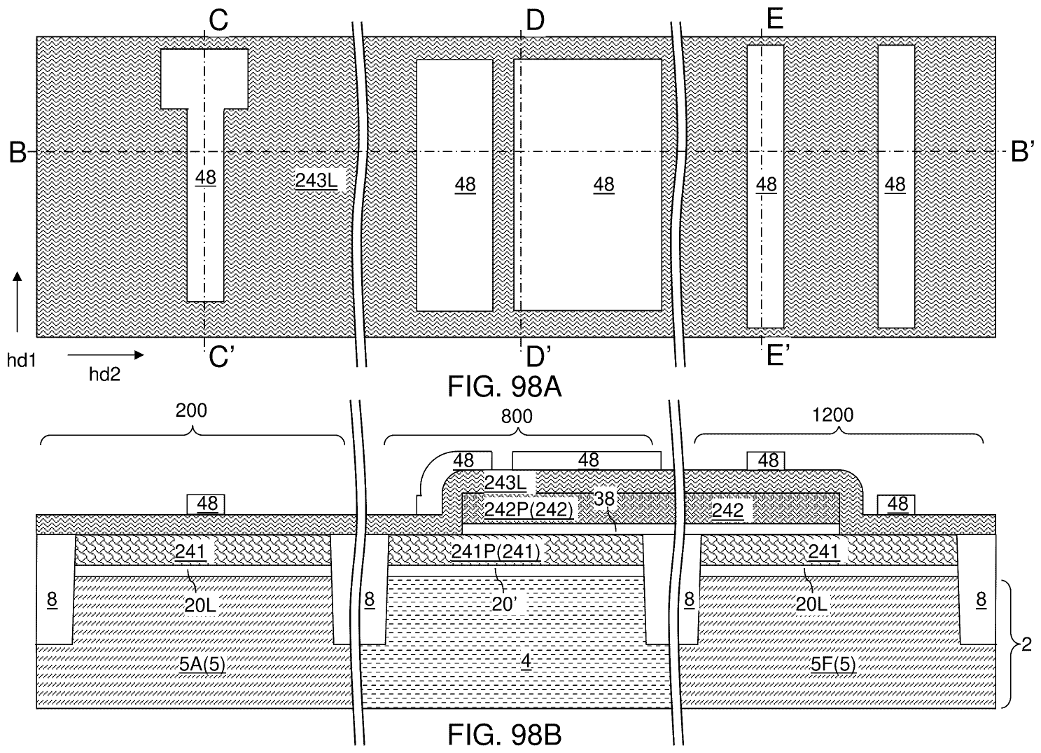

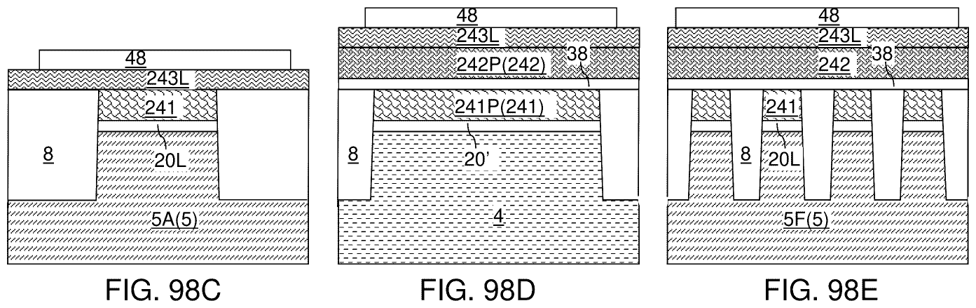

Referring to FIGS. 98A-98E, an anisotropic etch process can be performed to transfer the pattern in the photoresist layer 47 through the dielectric capping layer 48L. The dielectric capping layer 48L is patterned into dielectric plates, which are herein referred to as dielectric capping plates 48. A gap 48G is formed between two dielectric capping plates in the second passive device region 800. The photoresist layer 47 can be subsequently removed, for example, by ashing.

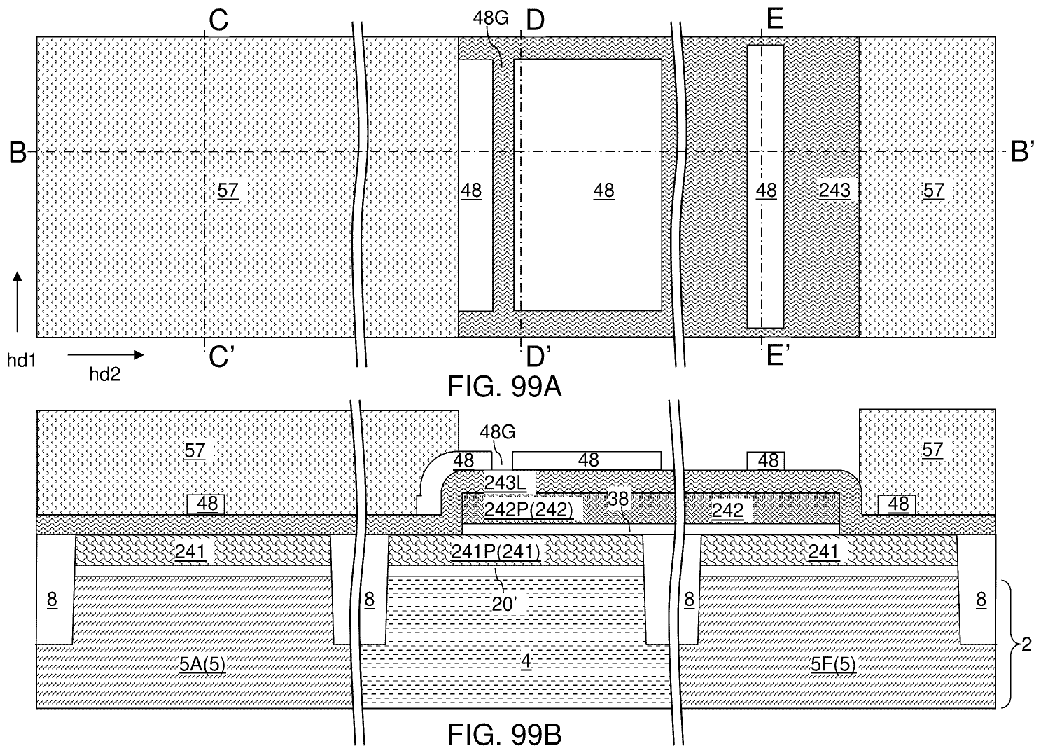

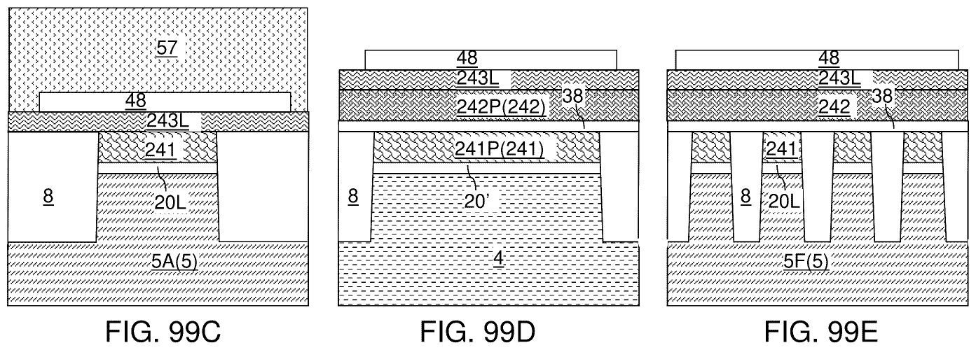

Referring to FIGS. 99A-99E, a photoresist layer 57 can be applied over the eighth exemplary structure, and can be lithographically patterned to cover areas in which the middle semiconductor plate 242P is not present. The photoresist layer 57 may cover a first subset of the dielectric capping plates 48, does not cover a second subset of the dielectric capping plates 48, and partly cover a third subset of the dielectric capping plates 48. In an illustrative example, the photoresist layer 57 may cover the entirety of the n-type field effect transistor region 200, a peripheral area of the second passive device region 800, and an area of a dielectric capping plate 48 in the transistor array region 1200 without covering another dielectric capping plate 48 in the transistor array region 1200.

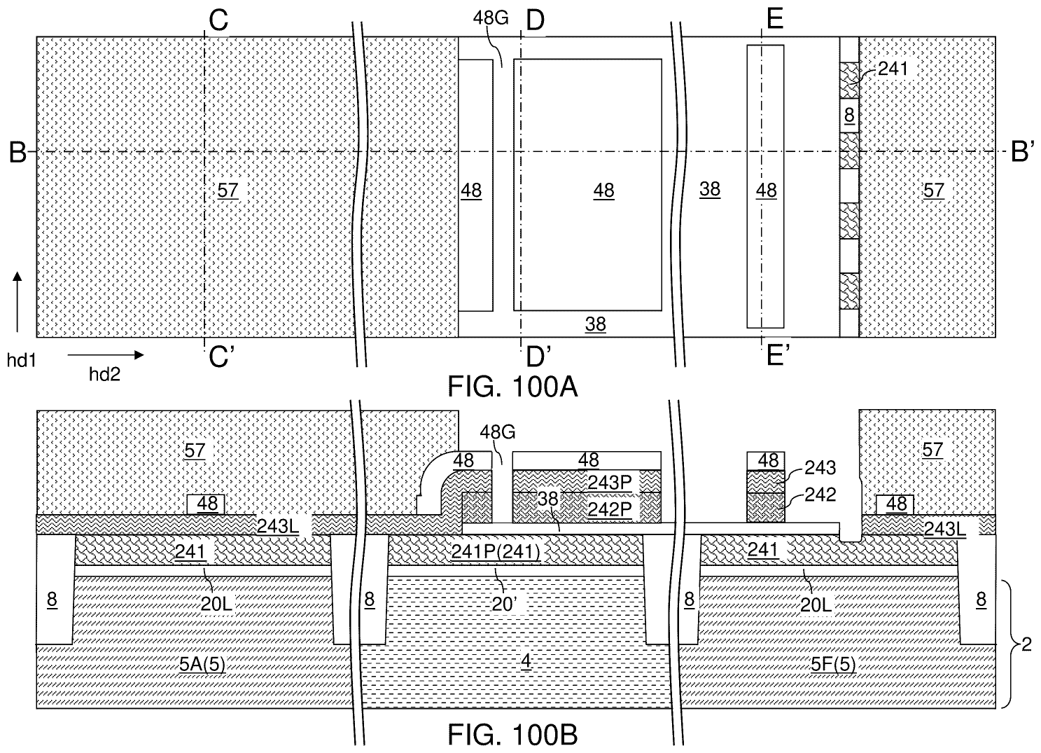

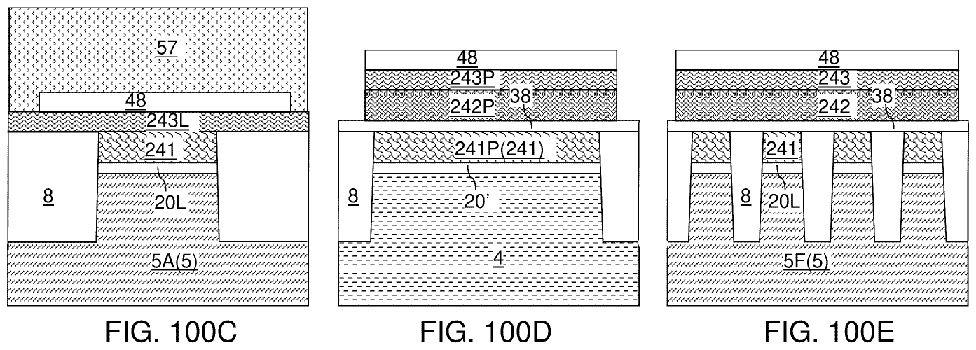

Referring to FIGS. 100A-100E, an anisotropic etch process can be performed to etch unmasked portions of the third semiconductor material layer 243L, the middle semiconductor material portion 242, and the middle semiconductor plate 242P. An unmasked portion of a lower gate material portions 241 in the transistor array region 1200 may be collaterally etched during the anisotropic etch process. A patterned portion of the third semiconductor material layer 243L in the second passive device region 800 comprises an upper semiconductor plate 243P. The upper semiconductor plate 243P is formed on the middle semiconductor plate 242P. The gap 48G is extended through the third semiconductor material layer 243L and the middle semiconductor plate 242P to split them into two respective portions. A patterned portion of the third semiconductor material layer 243L having a shape of a gate electrode and located in the transistor array region 1200 comprises an upper semiconductor strip 243. A patterned portion of the middle semiconductor material portion 242 underlying the upper semiconductor strip 243 comprises a middle semiconductor strip 242. The photoresist layer 57 can be subsequently removed, for example, by ashing.

A passive semiconductor device, such as a capacitor, is formed in the second passive device region 800. The passive semiconductor device comprises a layer stack including a first dielectric plate 20′, a lower semiconductor plate 241P comprising a first portion of the first semiconductor material and having a first thickness, a second dielectric plate 38, a middle semiconductor plate 242P comprising a first portion of the second semiconductor material, and an upper semiconductor plate 243P comprising a first portion of the third semiconductor material.

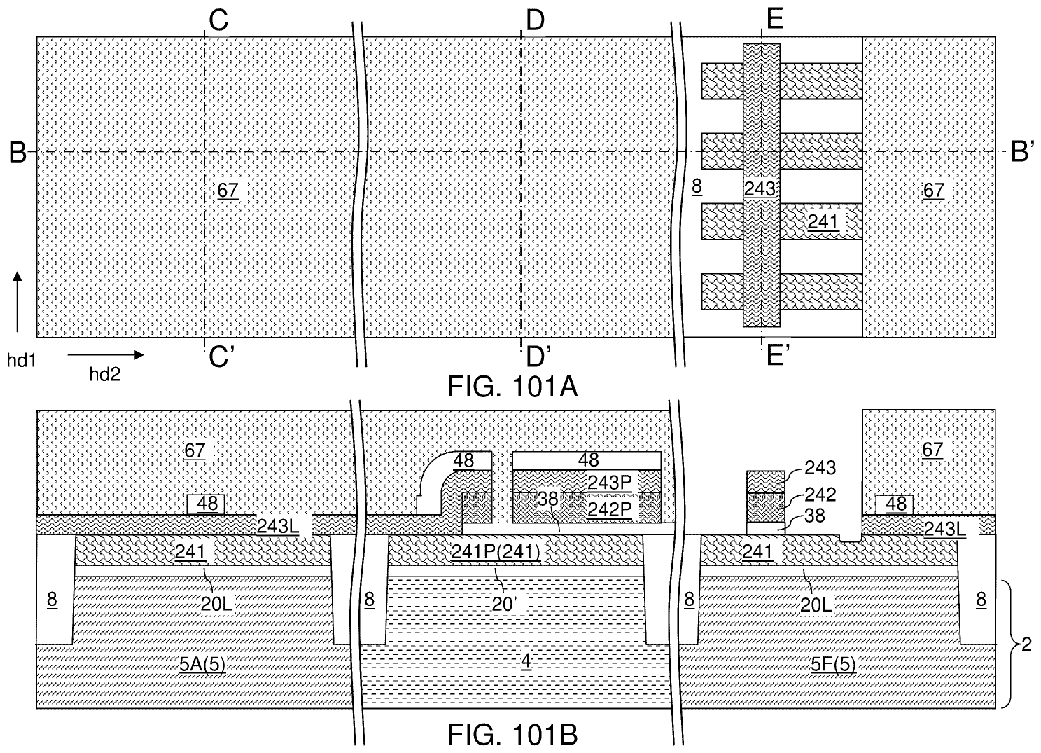

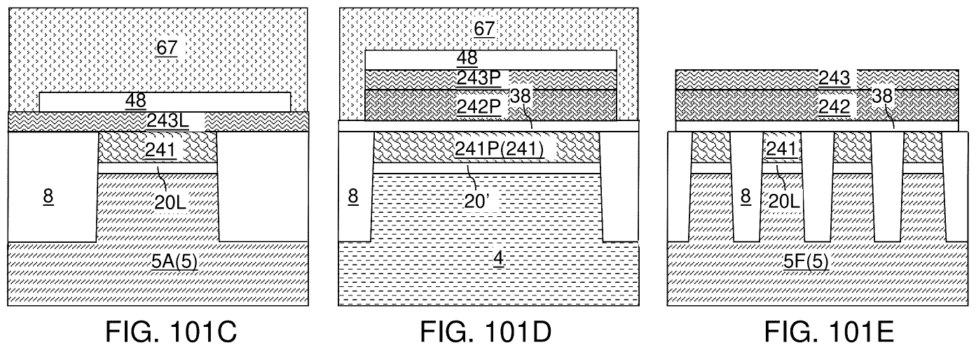

Referring to FIGS. 101A-101E, a photoresist layer 67 can be applied over the eighth exemplary structure, and can be lithographically patterned to form an opening in the area of the transistor array region 1200 in which a stack of a dielectric capping plate 48, an upper semiconductor strip 243, and a middle semiconductor strip 242 is located. An anisotropic etch process can be performed to etch the dielectric capping plate 48 within the opening in the photoresist layer 67 and to etch unmasked portions of a second dielectric plate 38 within the opening in the photoresist layer 67. The dielectric capping plate 48 within the opening in the photoresist layer 67 is removed, and a top surface of the upper semiconductor strip 243 can be physically exposed in the transistor array region 1200 after the anisotropic etch process. The anisotropic etch process may be selective to the semiconductor materials of the upper semiconductor strip 243 and the lower gate material portions 241. The photoresist layer 67 can be subsequently removed, for example, by ashing.

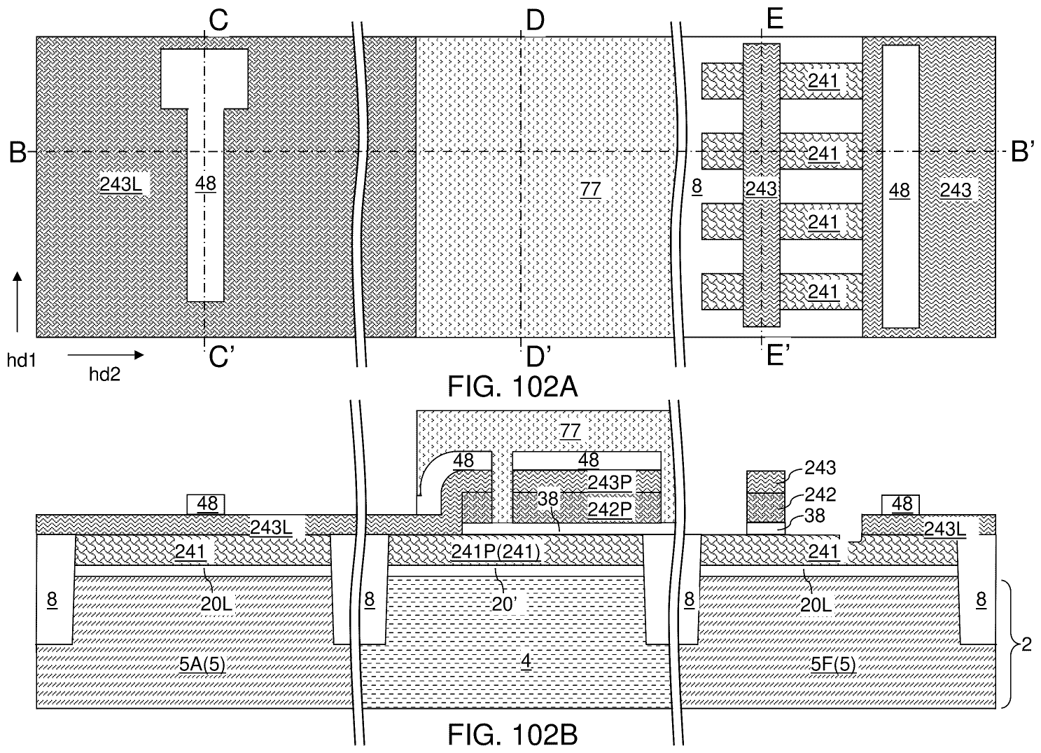

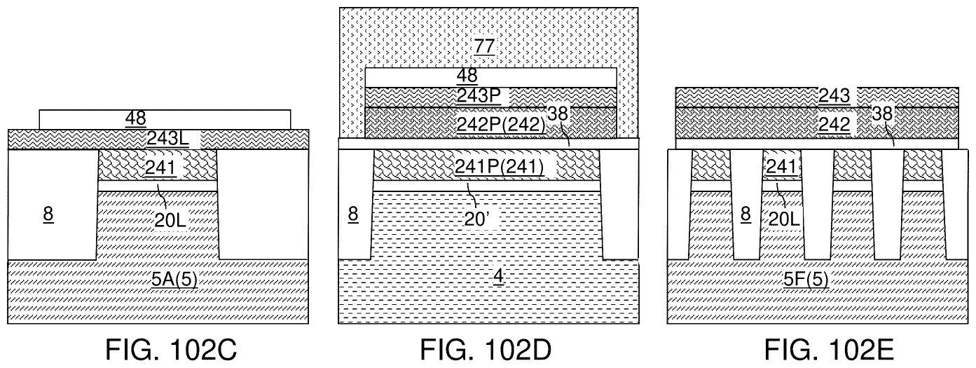

Referring to FIGS. 102A-102E, a photoresist layer 77 can be applied over the eighth exemplary structure, and can be lithographically patterned to cover the area of the semiconductor device in the second passive device region 800.

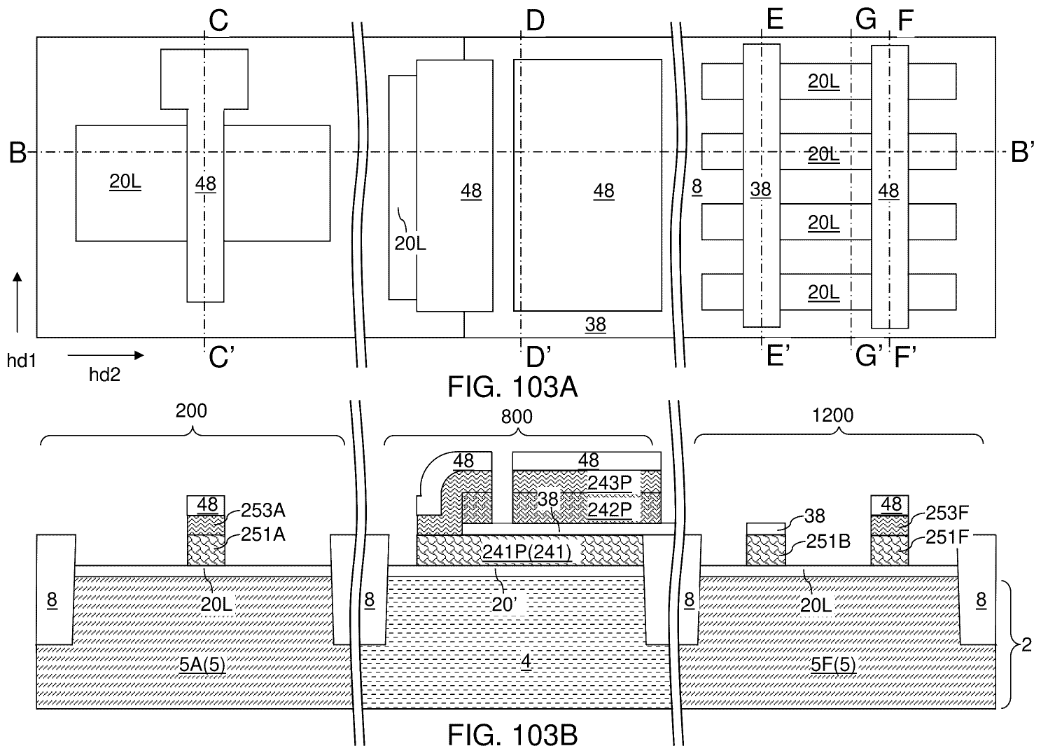

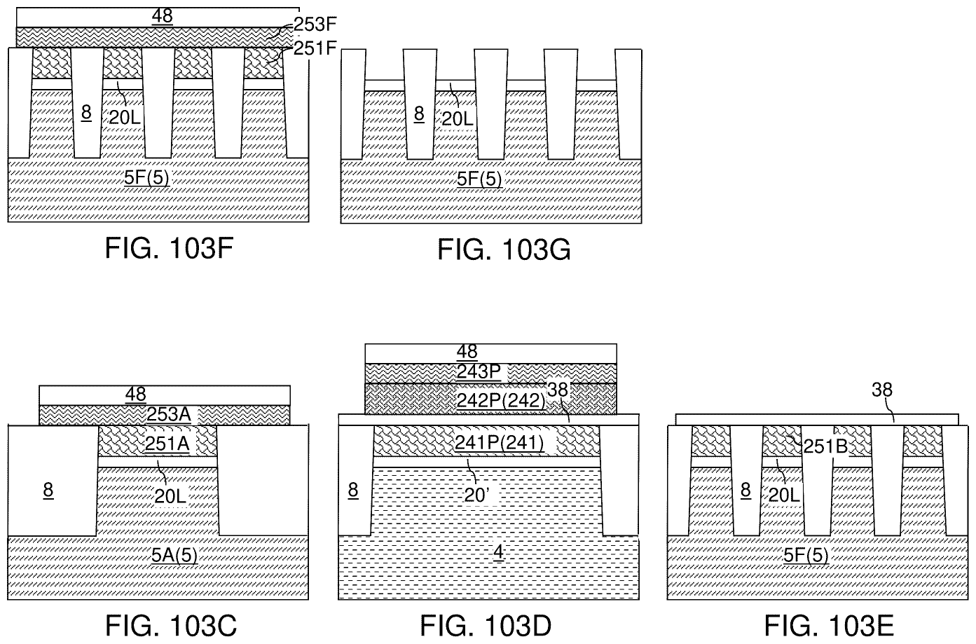

Referring to FIGS. 103A-103G, an anisotropic etch process can be performed to etch semiconductor materials selective to dielectric materials of the dielectric capping plates 48, the trench isolation structures 8, the second dielectric plate 38, the gate dielectric layers 20L, and the first dielectric plate 20′. The semiconductor materials (e.g., polysilicon) that are etched by the anisotropic etch process comprise the materials of the third semiconductor material layer 243L, the upper semiconductor strip 243, the middle semiconductor strip 242, and the lower gate material portions 241. The anisotropic etch process removes the upper semiconductor strip 243 and the middle semiconductor strip 242, and removes portions of the third semiconductor material layer 243L and the lower gate material portions 241 that are not masked by the dielectric capping plates 48, the second dielectric plates 38, or the photoresist layer 77.

A portion of the third semiconductor material layer 243L located in the first transistor region (e.g., a first n-type field effect transistor region 200) can be patterned into a first-transistor upper gate material portion 253A. The first-transistor lower gate material portion 241 (i.e., a lower gate material portion 241 located in the first n-type field effect transistor region 200) can be patterned into a first-transistor lower gate electrode portion 251A. A first gate electrode (251A, 253A) including a stack of a first-transistor lower gate electrode portion 251A and a first-transistor upper gate material portion 253A can be formed in the first transistor region (e.g., a first n-type field effect transistor region 200). The first lower semiconductor gate electrode 251A includes a patterned portion of the first semiconductor material. The first upper semiconductor gate electrode portion 253A includes a patterned portion of the third semiconductor material.

Each second-transistor gate material portion 241 (i.e., a lower gate material portion 242 located in the transistor array region 1200) can be patterned into a second gate electrode which consists of a second semiconductor gate electrode portion 251B, and into a third gate electrode which comprises a stack of a third-transistor lower gate electrode portion 251F and a third-transistor upper gate material portion 253F.

The eighth exemplary structure comprises a semiconductor device comprising a layer stack including a first dielectric plate 20′, a lower semiconductor plate 241P comprising a first portion of a first semiconductor material and having a first thickness, a second dielectric plate 38, a middle semiconductor plate 242P comprising a first portion of a second semiconductor material, and an upper semiconductor plate 243P comprising a first portion of a third semiconductor material in the second passive device region 800.

The eighth exemplary structure further comprises a first field effect transistor comprising a first gate electrode (251A, 253A) that comprises a second portion of the first semiconductor material and having the first thickness, and a second portion of the third semiconductor material that contacts a top surface of the second portion of the first semiconductor material in the first transistor region 200.

In addition, the eighth exemplary structure also comprises a second field effect transistor in the transistor array region 1200 which comprise an active region which may comprise an upper portion of a second doped well 5F in the semiconductor substrate 2 and a second gate electrode which includes a single second semiconductor gate electrode portion 251B including an additional patterned portion of the first semiconductor material. In one embodiment, the second gate electrode 251B comprises and/or consists of a third portion of the first semiconductor material. In one embodiment, a maximum lateral extent of the second gate electrode 251B along a gate length direction (such as the first horizontal direction hd1) that is perpendicular to a channel direction (such as the second horizontal direction hd2) is the same as a maximum lateral extent of a top surface of the active region (which may comprise a portion of a second doped well 5F) along the gate length direction, i.e., the same as the width of the active region as illustrated in FIG. 103E. Thus, the second transistor comprises a fringeless transistor having a gate electrode which includes only one semiconductor layer.

Further, the eighth exemplary structure also comprises a third field effect transistor in the transistor array region 1200 comprising a third gate electrode (251F, 253F) that comprises a fourth portion of the first semiconductor material and a third portion of the third semiconductor material that contacts a top surface of the fourth portion of the first semiconductor material. In one embodiment, a maximum lateral extent of the third gate electrode (251F, 253F) along the second horizontal direction hd2 is greater than the width of the active region (which may comprise a portion of a second doped well 5F). Thus, the third field effect transistor is not a fringeless transistor and includes a gate electrode including two semiconductor layers. At least one additional third field effect transistor may be located adjacent to the third field effect transistor. The third gate electrode (251F, 253F) extends over an active region (which may comprise a portion of a second doped well 5F) of the at least one additional third field effect transistor and constitutes a gate electrode of the additional third field effect transistor. In other words, the third gate electrode (251F, 253F) may be a common gate electrode for a plurality of third field effect transistors as illustrated in FIG. 103F.

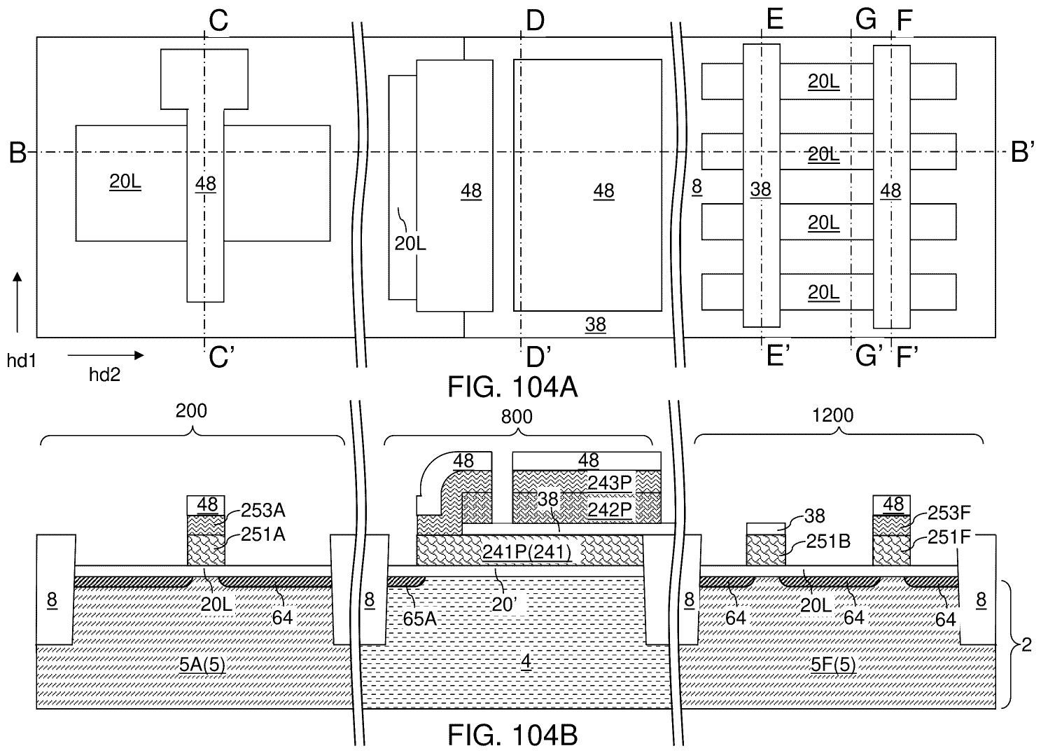

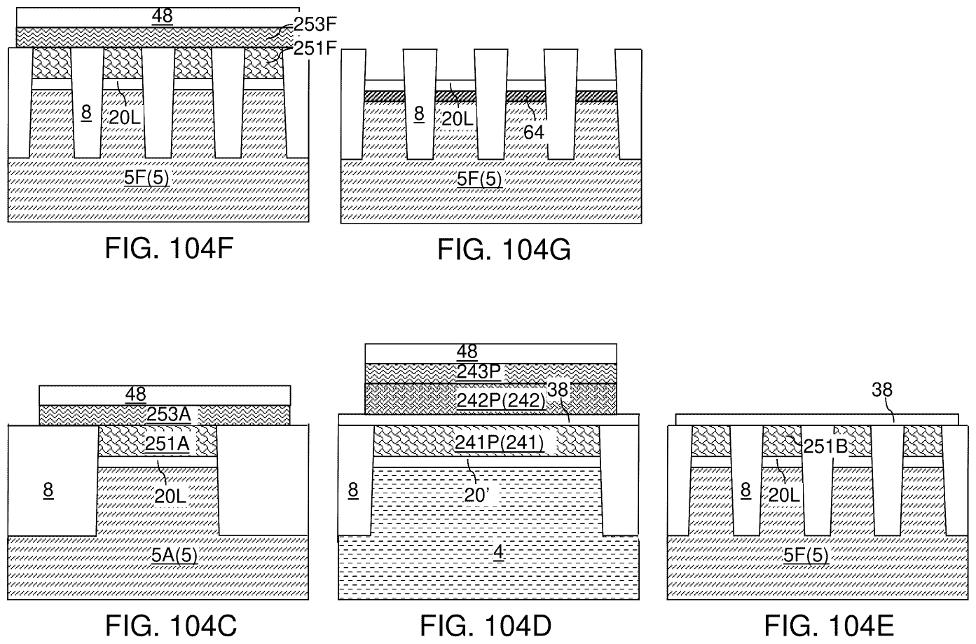

Referring to FIGS. 104A-104G, electrical dopants can be implanted into unmasked upper portions of the semiconductor substrate 8 to form source/drain extension regions 64 in field effect transistor regions (200, 1200), and optionally to form a shallow doped semiconductor region 65A in the second passive device region 800.

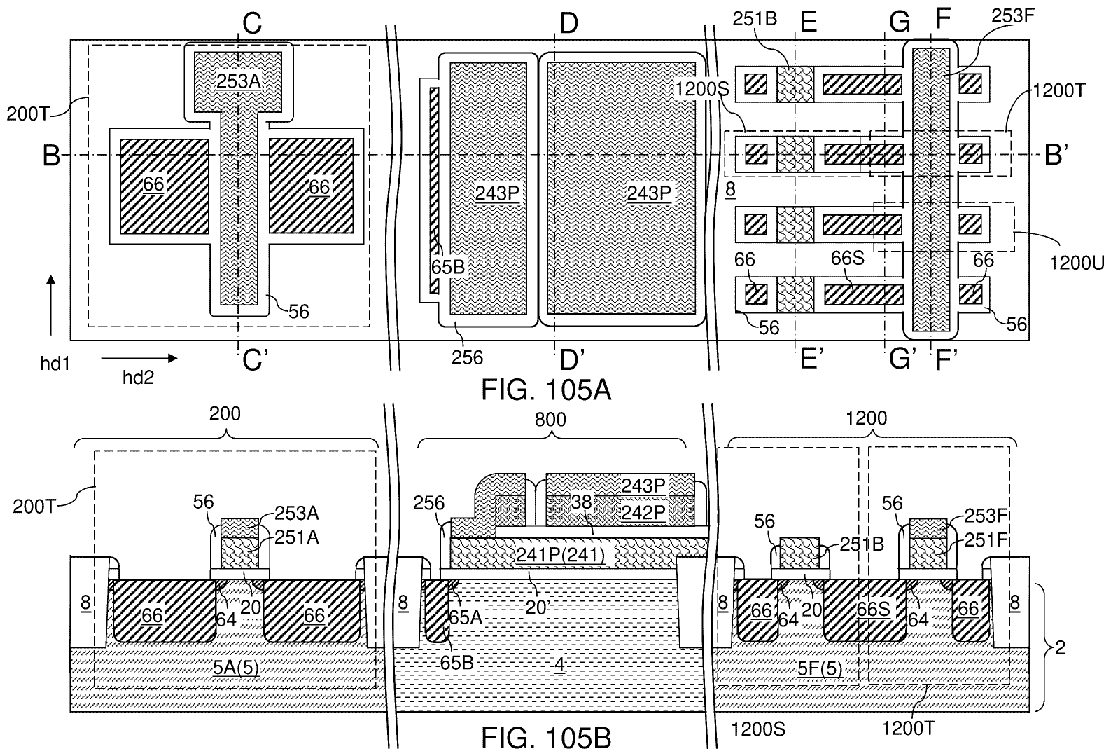

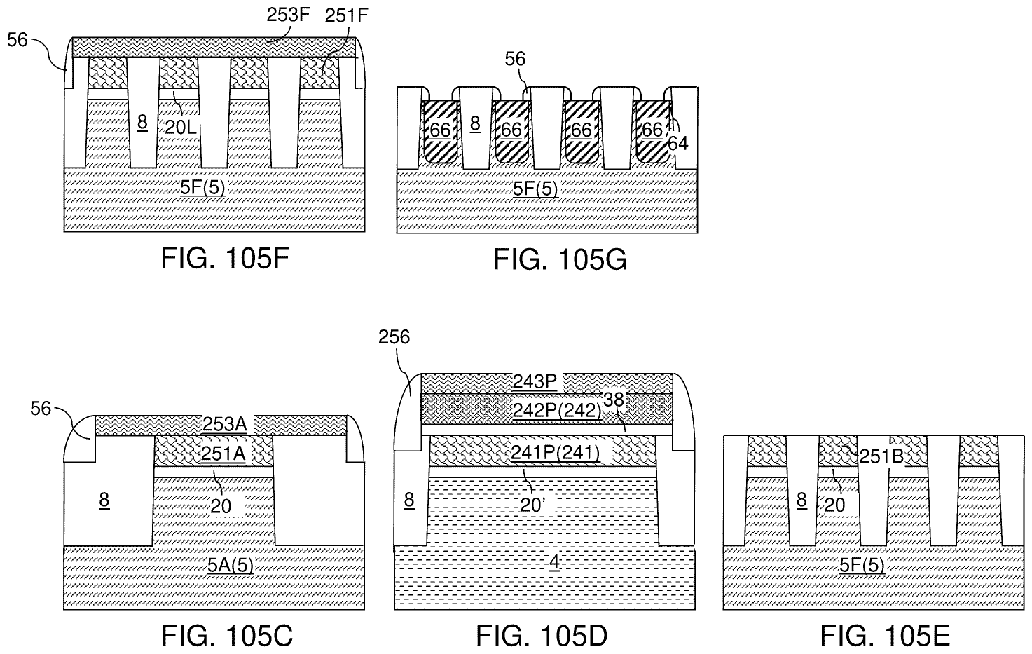

Referring to FIGS. 105A-105G, a dielectric gate spacer layer can be formed by conformal deposition of a dielectric material. The thickness of the dielectric gate spacer layer may be in a range from 10 nm to 100 nm, although lesser and greater thicknesses may also be employed. An anisotropic etch process can be performed to remove horizontally-extending portions of the dielectric gate spacer layer. Remaining vertically-extending portions of the dielectric gate spacer layer in field effect transistor regions (200, 1200) comprise dielectric gate spacers 56. Remaining vertically-extending portions of the dielectric gate spacer in the second passive device region 800 comprise a passive-device spacer 256. Further, the anisotropic etch process can be continued to remove the dielectric capping plates 48, the second dielectric plate 38, and portions of the gate dielectric layers 20L that are not covered by the dielectric gate spacers 56. The anisotropic etch process can be selective to the semiconductor materials of the upper semiconductor gate electrode portion (253A, 253F), the upper semiconductor plates 243P, the second lower semiconductor gate electrode portions 251B, and the semiconductor substrate 2. Each remaining patterned portion of the gate dielectric layers 20L comprise gate dielectrics 20.

Electrical dopants can be implanted into portions of the semiconductor substrate 2 that are not masked by gate structures (i.e., gate dielectrics 20 and gate electrodes) and dielectric gate spacers 56. Deep source/drain regions 66 can be formed in implanted portions of the semiconductor substrate 2 in the field effect transistor regions (200, 1200). A deep doped semiconductor region 65B can be formed in the second passive device region 800.

Each active region in the field effect transistor regions (200, 1200) comprises a respective active region including a respective pair of a source region (64, 66) and a drain region (64, 66) separated by a channel region (e.g., upper portion of a respective doped well 5). A first field effect transistor can be formed in the first transistor region (e.g., a first n-type field effect transistor region 200). Second field effect transistors and third field effect transistors can be formed in the transistor array region 1200.

A pair of a second field effect transistor and a third field effect transistor in the transistor array region 1200 may share an active region 5F. The pair of the second field effect transistor and the third field effect transistor may comprise a shared source/drain region (64, 66), and may be laterally surrounded by a same trench isolation structure 8. In one embodiment, all source/drain regions (64, 66) of the second field effect transistor and the third field effect transistor including the shared source/drain region (64, 66) can be located within an active region (which may comprise a portion of a second doped well 5F) having a width along a first horizontal direction hd1 having a length along a second horizontal direction hd2 along which the third gate electrode (251F, 253F) is laterally spaced from the second gate electrode 251B.

In one embodiment, the first field effect transistor in region 200 comprises a first dielectric gate spacer 56 that laterally surrounds the first gate electrode (251A, 253A). In one embodiment, the first dielectric gate spacer 56 comprises at least three openings therethrough; the first gate electrode (251A, 253A) is located in a first opening of the at least three openings; a first source region (64, 66) of the first field effect transistor underlies a second opening of the at least three openings; and a first drain region (64, 66) of the first field effect transistor underlies a third opening of the at least three openings.

In one embodiment, the second field effect transistor in region 1200 comprises two second dielectric gate spacers 56 that are not in contact with each other, and are laterally spaced by the second gate electrode 251B from each other, as shown in FIG. 105A. In one embodiment shown in FIG. 105A, one of the two second dielectric gate spacers 56 is a rectangular spacer which comprises exactly one opening therethrough; and a source/drain region (64, 66) of the second field effect transistor underlies the one opening in the one of the two second dielectric gate spacers 56.

In one embodiment, the first field effect transistor in region 200 comprises a first active region (which may comprise a portion of the first doped well 5A) that is laterally surrounded by a first trench isolation structure 8; and the first dielectric gate spacer 56 comprises a first portion that overlies and contacts a top surface of the first trench isolation structure 8, as shown in FIG. 105C, and a second portion that overlies the first active region (which may comprise a portion of the doped well 5F), as shown in FIG. 105B and contacts sidewalls of the first trench isolation structure 8. In one embodiment, the second field effect transistor in region 1200 comprises a portion of a second active region (which may comprise a portion of the second doped well 5F) that is laterally surrounded by a second trench isolation structure 8; and one of the second dielectric gate spacers 56 (e.g., the left side spacer 56 in FIG. 105A) does not have any areal overlap with the second trench isolation structure 8 in a plan view.

In one embodiment, a source region (64, 66) and a drain region (64, 66) of the third field effect transistor in region 1200 are laterally spaced from each other by a channel (e.g., upper portion of the second doped well 5F) along a channel direction of the third field effect transistor; and a maximum lateral dimension of the third gate electrode (251F, 253F) along a horizontal direction that is perpendicular to the channel direction of the third field effect transistor is the same as a width of the second active region (which may comprise a portion of a second doped well 5F) along the horizontal direction that is perpendicular to the channel direction of the third field effect transistor.

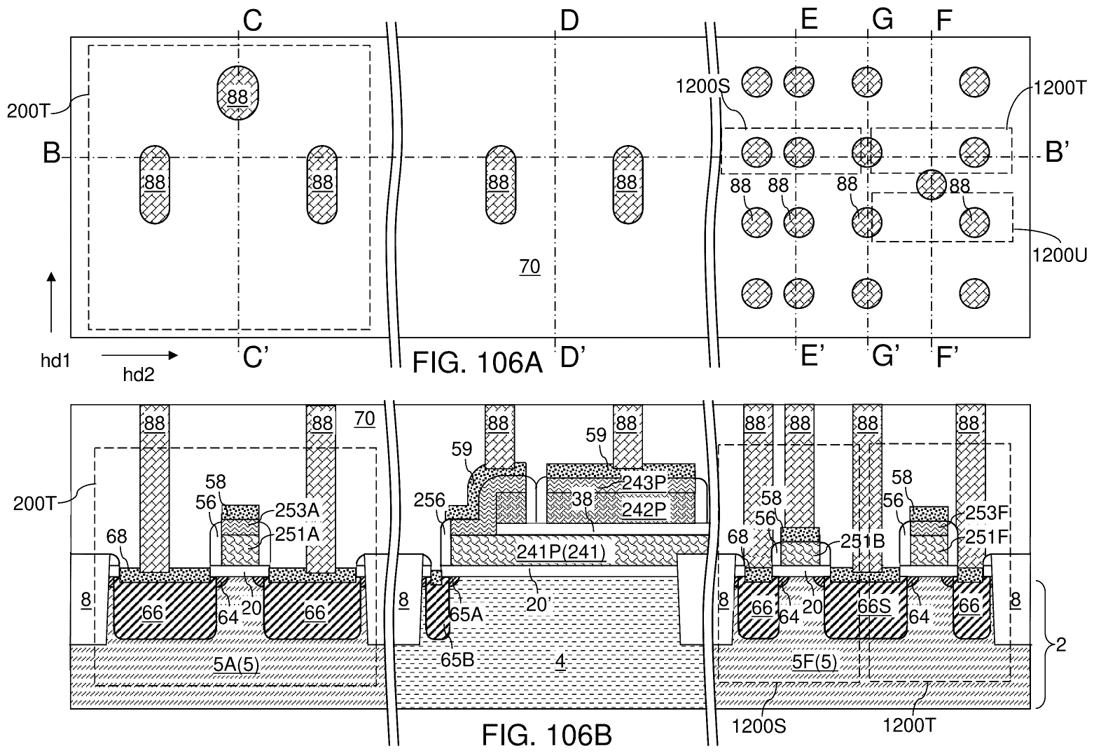

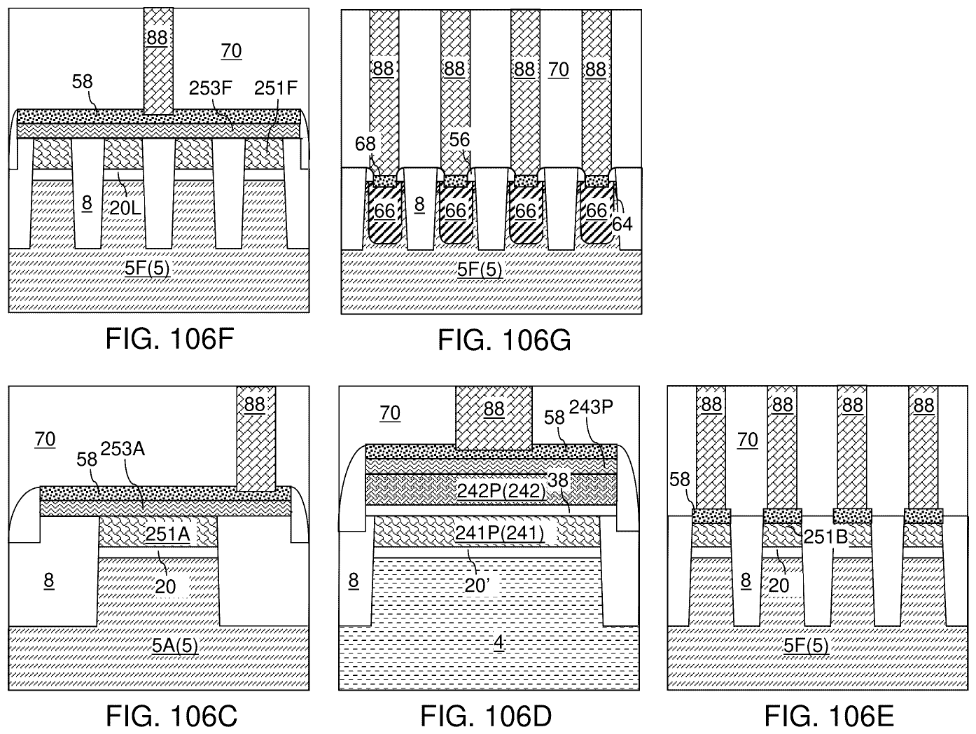

Referring to FIGS. 106A-106G, a metal deposition step can be performed to deposit a metal on the physically exposed top surfaces of the eighth exemplary structure, which include top surfaces of the upper semiconductor plate 243P, the first upper semiconductor gate electrode portion 253A, the second semiconductor gate electrode portion 251B, and the deep source/drain regions 66. Metal-semiconductor alloy regions (58, 68) can be formed by reacting the metal with underlying semiconductor material portions, which include surface portions of the upper semiconductor plate 243P, the first upper semiconductor gate electrode portion 253A, the second semiconductor gate electrode portion 251B, and the deep source/drain regions 66. The metal-semiconductor alloy (e.g., silicide, such as NiPt silicide) regions (58, 68) comprise gate metal-semiconductor alloy regions 58 that are formed on gate electrodes, and source/drain metal-semiconductor alloy regions 68 that are formed on the deep source/drain regions 66.

Subsequently, at least one dielectric material layer such as a contact-level dielectric layer 70 can be formed over the metal-semiconductor alloy regions (58, 68) and the trench isolation structures 8. Various contact via cavities can be formed through the contact-level dielectric layer 70, and various contact via structures 88 can be formed on a respective one of the metal-semiconductor alloy regions (58, 68).

Referring collectively to FIGS. 91A-106G and according to various embodiments of the present disclosure, a semiconductor structure is provided, which comprises: a first field effect transistor 200T; a second field effect transistor 1200S; and a third field effect transistor 1200T, as shown in FIGS. 105B and 106B. The second field effect transistor 1200S and the third field effect transistor 1200T comprise a shared source/drain region 66S, and are located in a same second active region 5F; the second field effect transistor 1200S comprises a second gate electrode (58, 251B) which comprises only one semiconductor layer 251B; the third field effect transistor 1200T comprises a third gate electrode (58, 251F, 253F) which comprises two different semiconductor layers (251F, 253F); a gate length of the second gate electrode along a gate length direction hd1 that is perpendicular to a channel direction hd2 of the second field effect transistor 1200S is the same as a width of the second active region 5F along the gate length direction hd1; and a gate length of the third gate electrode along the gate length direction hd1 that is perpendicular to the channel direction hd2 of the third field effect transistor 1200T is greater than the width of the second active region 5F along the gate length direction hd1 and is greater than the gate length of the second gate electrode.

In one embodiment, the semiconductor structure further comprises a semiconductor device, such as a capacitor located in region 4, comprising a layer stack including a first dielectric plate 20′, a lower semiconductor plate 241P comprising a first portion of a first semiconductor material and having a first thickness, a second dielectric plate 38, a middle semiconductor plate 242P comprising a first portion of a second semiconductor material, and an upper semiconductor plate 243P comprising a first portion of a third semiconductor material. In one embodiment, the first field effect transistor 200T comprises a first gate electrode (58, 251A, 253A) that comprises a second portion of the first semiconductor material and having the first thickness, and a second portion of the third semiconductor material that contacts a top surface of the second portion of the first semiconductor material.

In one embodiment, the semiconductor device comprises a first metal-semiconductor alloy region 59 contacting a top surface of the first portion of the third semiconductor material; and the first field effect transistor 200T comprises a first gate metal-semiconductor alloy region 58 contacting a top surface of the second portion of the third semiconductor material.

In one embodiment, the second gate electrode (58, 251B) comprises a third portion of the first semiconductor material, and a second gate metal-semiconductor alloy region 58 contacting a top surface of the third portion of the first semiconductor material. In one embodiment, the third gate electrode (58, 251F, 253F) comprises a fourth portion of the first semiconductor material and a third portion of the third semiconductor material that contacts a top surface of the fourth portion of the first semiconductor material.

In one embodiment, the second field effect transistor 1200S and the third field effect transistor 1200T are laterally surrounded by a common trench isolation structure 8. In one embodiment, the first field effect transistor 200T is located within a first active region (which may comprise a portion of a first doped well 5A) which is separated from the second active region 5F by the common trench isolation structure 8.

In one embodiment, the semiconductor structure comprises an additional third field effect transistor 1200U that is located adjacent to the third field effect transistor 1200T, in the second active region 5F, wherein the third gate electrode (58, 251F, 253F) comprises a continuous common gate electrode of the third field effect transistor 1200T and the additional third field effect transistor 1200U.

In one embodiment, the third gate electrode further comprises a third gate metal-semiconductor alloy region 58 contacting a top surface of the third portion of the third semiconductor material. In one embodiment, the first field effect transistor 200T further comprises a first dielectric gate spacer 56 that laterally surrounds the first gate electrode (251A, 253A); and the second field effect transistor 1200S comprises two second dielectric gate spacers 56 that are not in contact with each other, and are laterally spaced by the second gate electrode 251B from each other. In one embodiment, the first dielectric gate spacer 56 comprises at least three openings therethrough; the first gate electrode (251A, 253A) is located in a first opening of the at least three openings; a first source region of the first field effect transistor underlies a second opening of the at least three openings; and a first drain region of the first field effect transistor underlies a third opening of the at least three openings.

In one embodiment, one of the two second dielectric gate spacers 56 comprises exactly one opening therethrough; and a source/drain region (64, 66) of the second field effect transistor underlies the one opening of the two second dielectric gate spacers 56. In one embodiment, the first field effect transistor comprises a first active region (which may comprise a portion of a second doped well 5F) that is laterally surrounded by a first trench isolation structure 8; and the first dielectric gate spacer 56 comprises a first portion that overlies, and contacts a top surface of, the first trench isolation structure 8 and a second portion that overlies the first active region (which may comprise a portion of a second doped well 5F) and contacts sidewalls of the first trench isolation structure 8.

In one embodiment, the second active region (which may comprise a portion of a second doped well 5F) is laterally surrounded by a second trench isolation structure 8; and one of the second dielectric gate spacers 56 does not have any areal overlap with the second trench isolation structure 8 in a plan view.

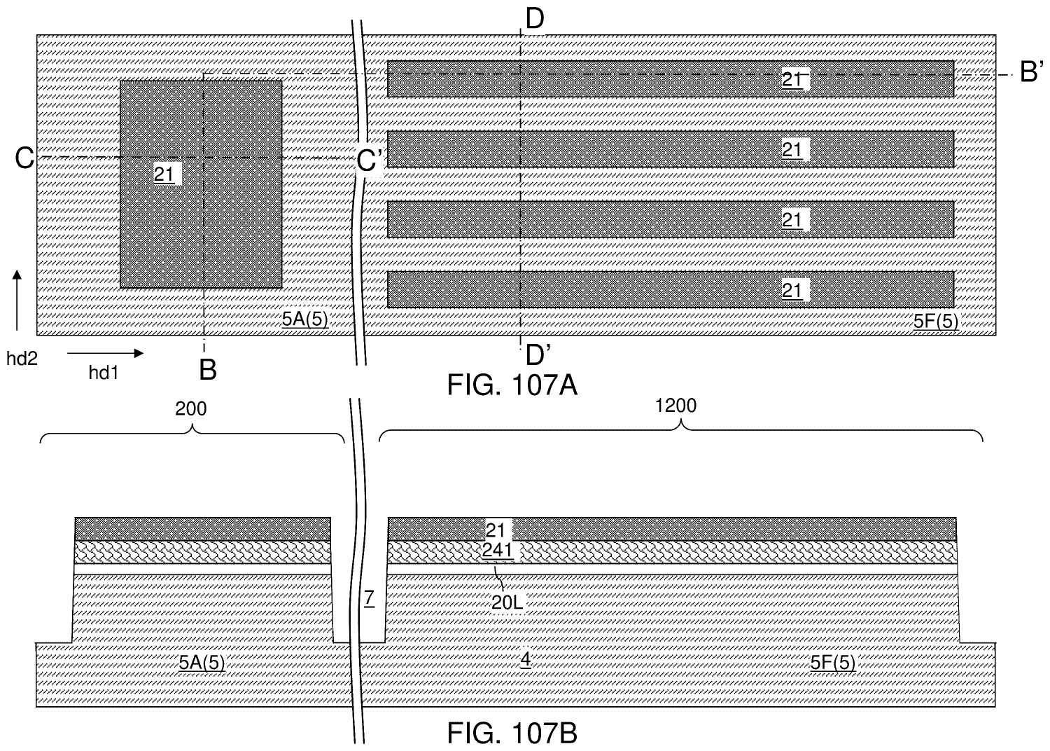

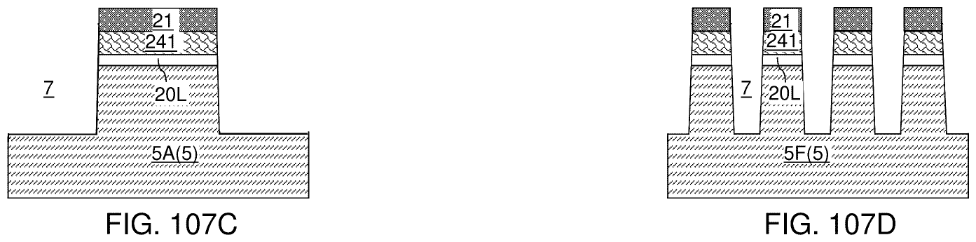

Referring to FIGS. 107A-107D, a ninth exemplary structure according to a ninth embodiment of the present disclosure is illustrated, which may be formed as portions of the first exemplary structure or the sixth exemplary structure, or may be formed as additional structures that are formed in conjunction with the first exemplary structure or the sixth exemplary structure. The ninth exemplary structure comprises a semiconductor substrate 2, in which various doped wells 5 such as a first doped well 5A and a second doped well 5F can be formed. In one embodiment, the first doped well 5A may be formed in a first transistor region (e.g., a first n-type field effect transistor region 200), and the second doped well 5F may be formed in a transistor array region 1200 in which sense amplifiers and bit line bias switches are to be subsequently formed.

Generally, the ninth exemplary structure illustrated in FIGS. 107A-107D may be the same as, or may be similar to, the eighth exemplary structure illustrated in FIGS. 92A-92E. In one embodiment, the processing steps described with reference to FIGS. 91A and 91B and the processing steps described with reference to FIGS. 92A-92E can be performed to provide the ninth exemplary structure illustrated in FIGS. 107A-107D. In one embodiment, the hardmask plates 21 and the lower gate material portions 241 (e.g., semiconductor portions, such as polysilicon portions) in the transistor array regions 1200 may be elongated along a channel direction such as a first horizontal direction hd1 so that four transistors can be formed over a single active region. Patterned portions of a first semiconductor material layer may comprise a first-transistor lower gate material portion 241 formed in the first transistor region (e.g., a first n-type field effect transistor region 200) and a second-transistor lower gate material portion 241 formed in the transistor array region 1200.

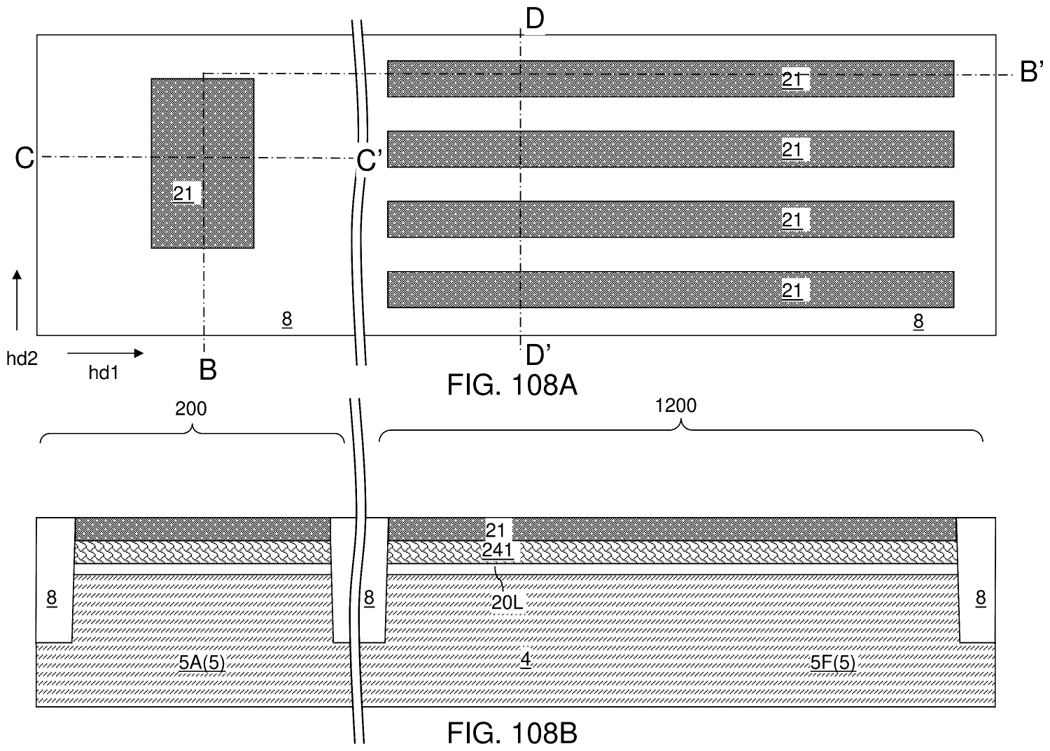

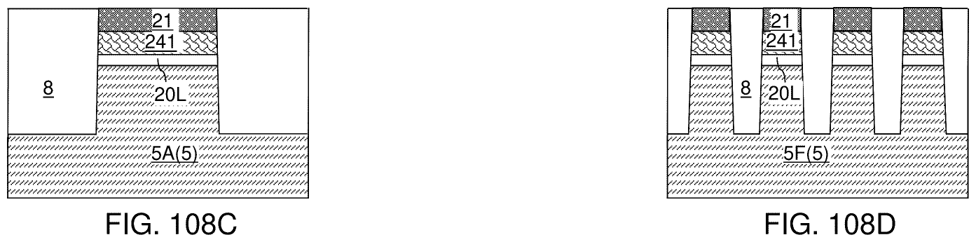

Referring to FIGS. 108A-108D, a dielectric fill material, such as a silicate glass can be deposited in the shallow trenches 7. Portions of the dielectric fill material overlying the horizontal plane including the top surfaces of the hardmask plates 21 can be removed by performing a planarization process, such as a chemical mechanical polishing process.

The first trench isolation structure 8 can be formed around a first-transistor lower gate material portion 241 in the first transistor region (e.g., a first n-type field effect transistor region 200), and a second trench isolation structure 8 can be formed around the second-transistor lower gate material portion 241 in the transistor array region 1200. The first trench isolation structure 8 laterally surrounds a first active region 5A of the semiconductor substrate 2. The second trench isolation structure 8 laterally surrounds a second active region 5F of the semiconductor substrate 8.

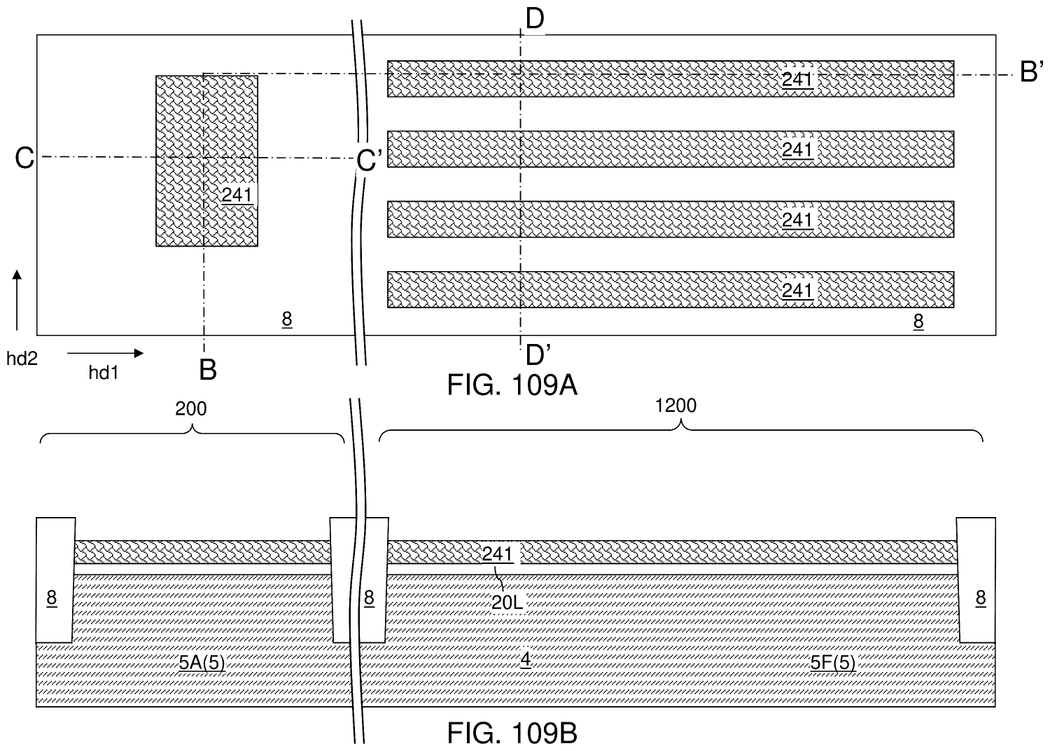

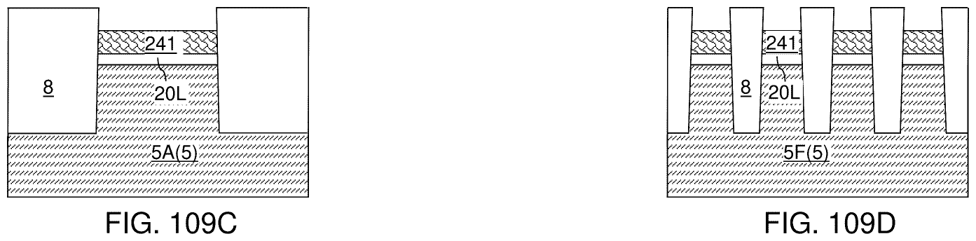

Referring to FIGS. 109A-109D, the hardmask plates 21 can be removed by performing a selective etch process. For example, if the hardmask plates 21 comprise silicon nitride, a wet etch process employing hot phosphoric acid may be performed to remove the hardmask plate 21. Top surfaces of the lower gate material portions 241 can be physically exposed. The top surfaces of the lower gate material portions 241 may be vertically recessed from the horizontal plane including the top surfaces of the trench isolation structures 8 by a vertical recess distance, which may be in a range from 50 nm to 200 nm.

Optionally, the corners of the protruding upper portions of the trench isolation structures 8 may be rounded after removal of the hardmask plates 21. The trench isolation structures 8 may be subjected to a timed wet etch which rounds upper corners of the trench isolation structures 8 without entirely removing the protruding upper portions of the trench isolation structures 8 which extend above the top surfaces of the lower gate material portions 241. If the trench isolation structures 8 comprise silicon oxide, then the wet etch may comprise a dilute hydrofluoric acid wet etch.

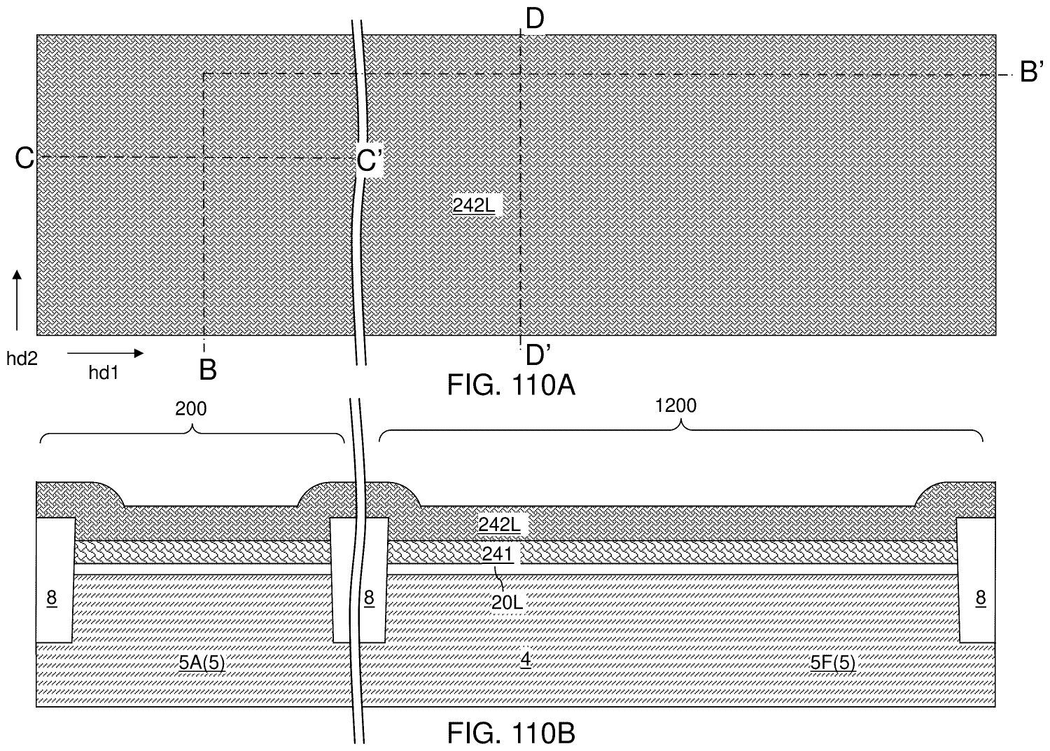

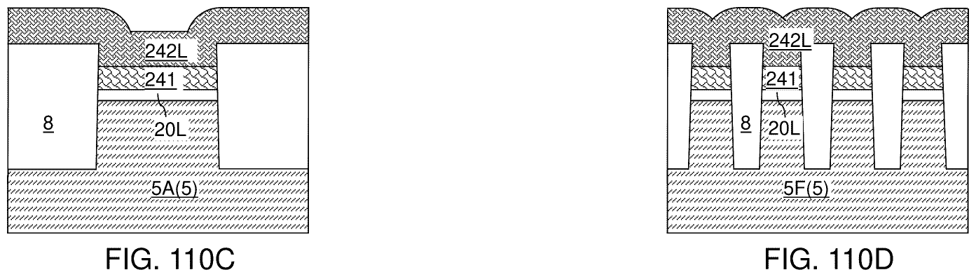

Referring to FIGS. 110A-110D, a second semiconductor material layer 242L including a second semiconductor material, such as polysilicon, can be deposited over the lower gate material portions 241 and the shallow trench isolation structures 8. Portions of the second semiconductor material layer 242L can be doped with electrical dopants as needed. The thickness of the second semiconductor material layer 242L may be greater than the height difference between the top surfaces of the trench isolation structures 8 and the top surfaces of the lower gate material portions 241. For example, the thickness of the second semiconductor material layer 242L may be in a range from 100 nm to 400 nm, such as from 150 nm to 300 nm, although lesser and greater thicknesses may also be employed.

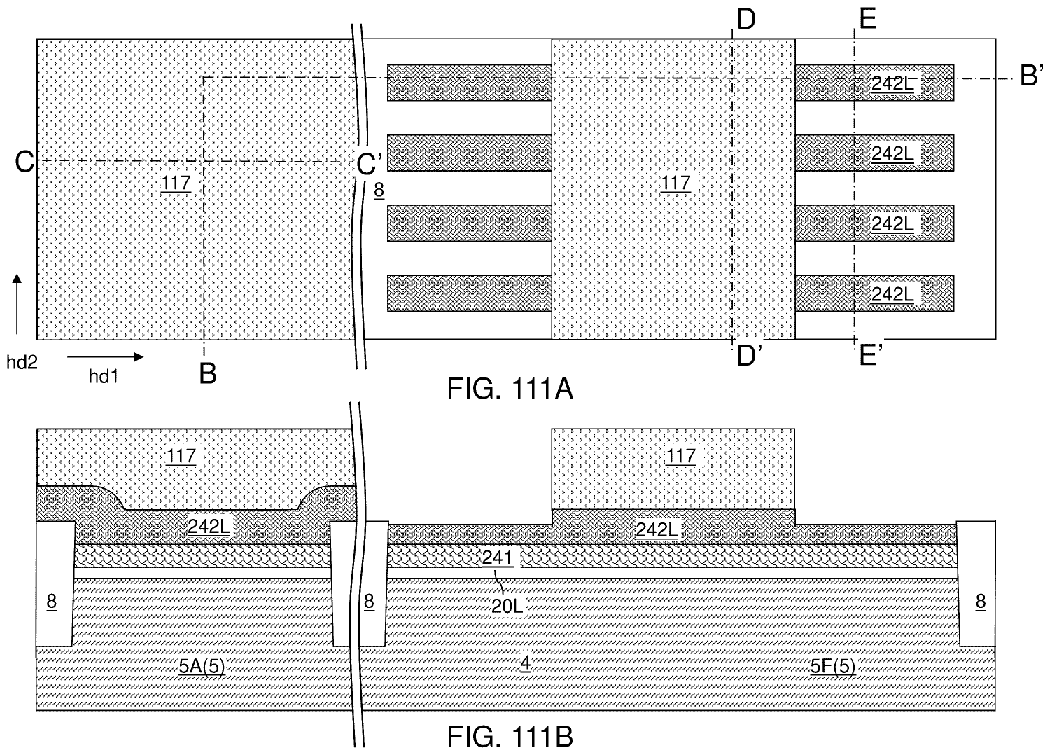

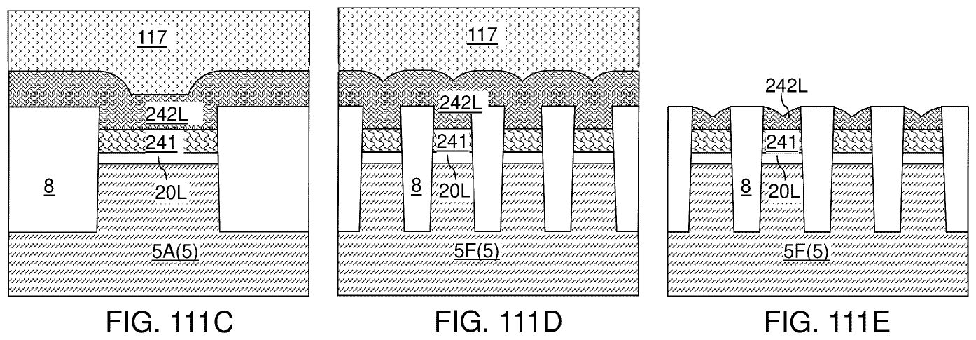

Referring to FIGS. 111A-111E, a photoresist layer 117 can be applied over the second semiconductor material layer 242L, and can be lithographically patterned to cover a transistor region (such as the first n-type field effect transistor region 200) and a portion of the transistor array region 1200. In one embodiment, a center portion of the transistor array region 1200 may be covered. In other embodiments, an end portion of the transistor array region 1200 may be covered. An etch process, such as an anisotropic etch process, can be performed to vertically recess portions of the second semiconductor material layer 242L that are not masked by the photoresist layer 117. In one embodiment, the recess depth of the etch process can be selected to remove the entire thickness of the second semiconductor material layer 242L located over the trench isolation structure 8. Thus, top surfaces of the trench isolation structure 8 can be physically exposed in areas that not covered by the photoresist layer 117. Therefore, remaining portions of the second semiconductor material layer 242L that are not covered by the photoresist layer 117 can be located entirely within areas that are laterally surrounded by the trench isolation structures 8. The photoresist layer 117 can be subsequently removed, for example, by ashing.

In one embodiment, the portion of the second semiconductor material layer 242L overlying a first-transistor lower gate material portion 241 located in a transistor region (such as the first n-type field effect transistor region 200) is not thinned during the processing steps of FIGS. 111A-111E. In one embodiment, a first portion of the second semiconductor material layer 242L overlying a first segment of the second-transistor lower gate material portion 241 located in the transistor array region 1200 can be thinned, while a second portion of the second semiconductor material layer 242L overlying the first-transistor lower gate material portion 241 and a third portion of the second semiconductor material layer 242L overlying a second segment of the second-transistor lower gate material portion 241 are not thinned. In one embodiment, a thinned portion of the second semiconductor material layer 242L may have a top surface that is formed entirely below a horizontal plane including a top surface of the second trench isolation structure 8 in the transistor array region 1200.

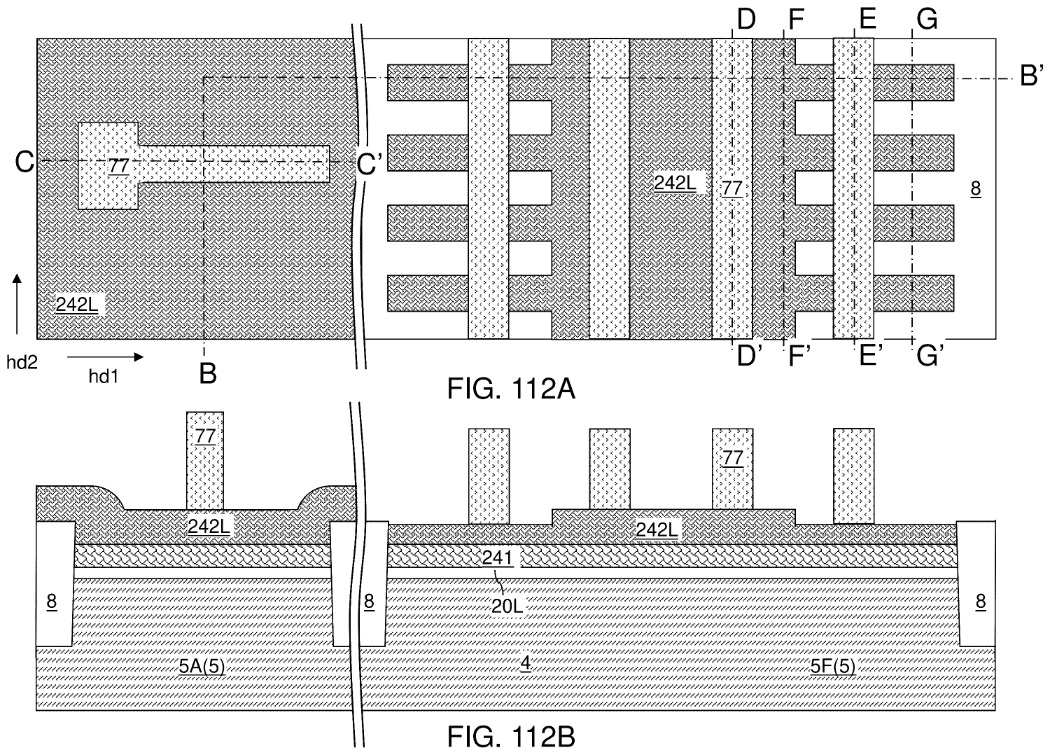

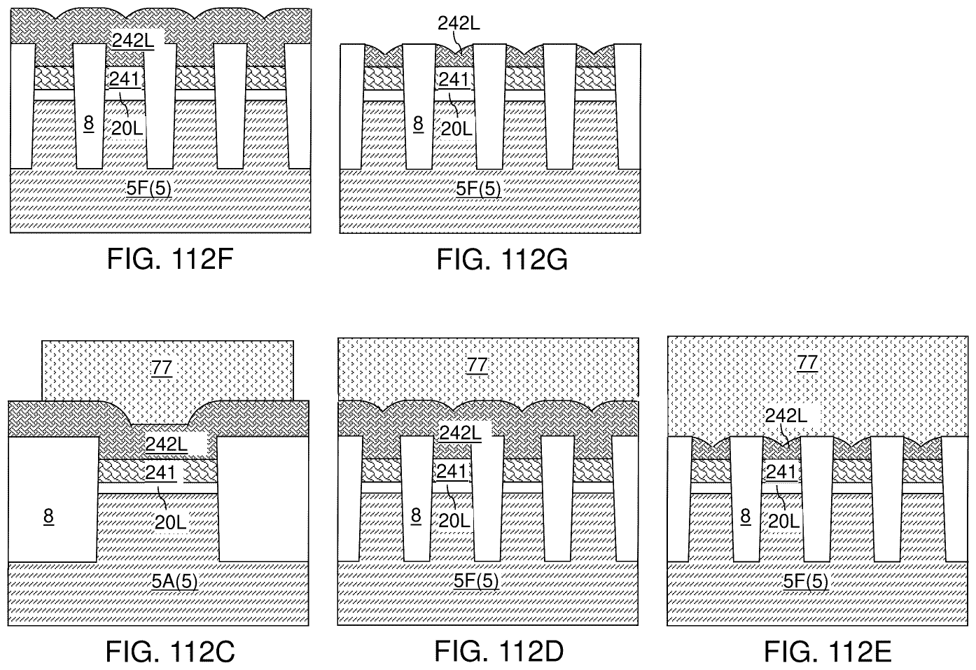

Referring to FIGS. 112A-112G, a photoresist layer 77 can be applied over the second semiconductor material layer 242L, and can be lithographically patterned with a gate pattern. Each gate pattern straddles a respective underlying active region along a respective gate electrode length direction, and has a respective width along a respective channel direction. In an illustrative example, a first gate pattern may straddle the active region 5A in the first transistor region (such as the first n-type field effect transistor region 200). In one embodiment, at least two gate patterns, such as four gate patterns may straddle each active region in the transistor array region 1200. At least one gate pattern, such as two of the four gate patterns may be formed in an area in which the top surface of the second trench isolation structure 8 is not exposed, and at least one additional gate pattern, such as two additional gate patterns of the four gate patterns may straddle the top surface of the second trench isolation structure 8 exposed between second-transistor lower gate material portions 241. In one embodiment, the gate electrode length direction of the gate patterns may be the second horizontal direction hd2.

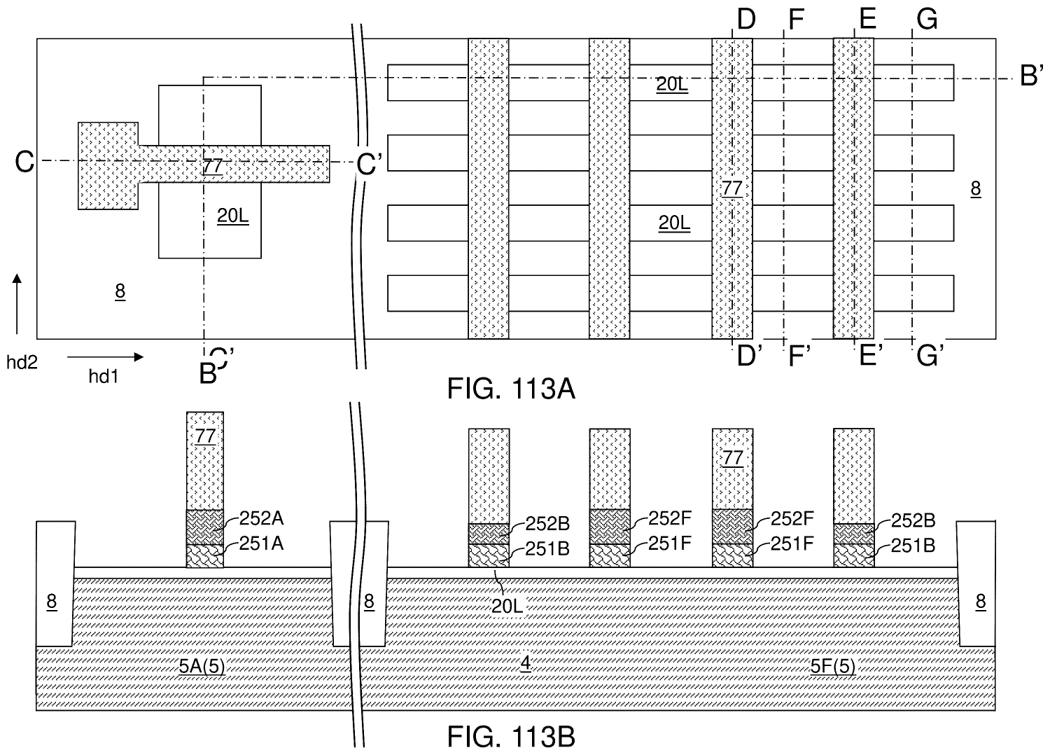

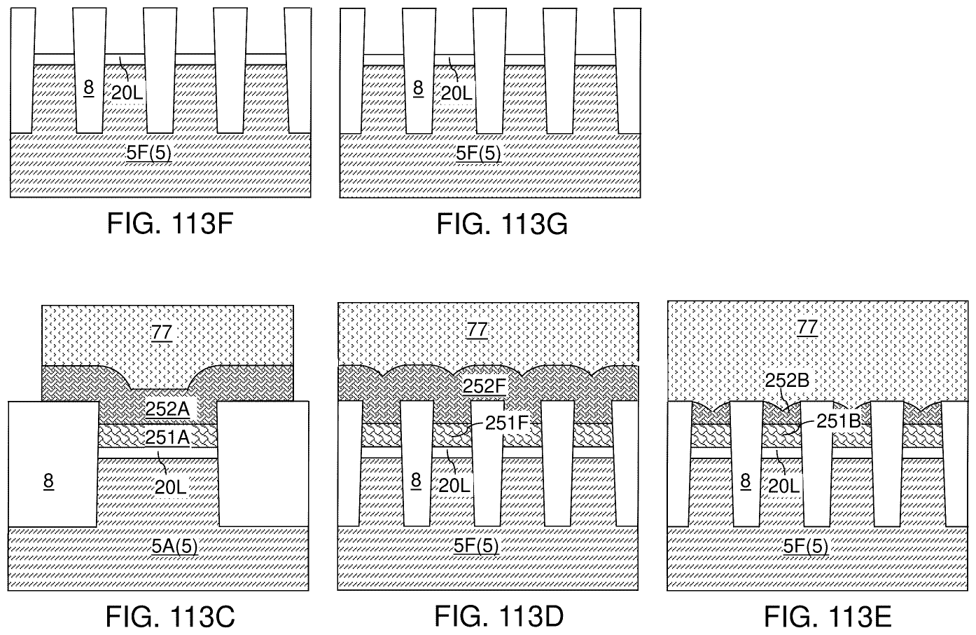

Referring to FIGS. 113A-113G, an anisotropic etch process can be performed to etch unmasked portions of the second semiconductor material layer 242L and the lower gate material portions 241 (which are patterned portions of the first semiconductor material layer 241L). The anisotropic etch process can have an etch chemistry that etches the semiconductor materials of the second semiconductor material layer 242L and the lower gate material portions 241 selective to the dielectric materials of the trench isolation structures 8 and the gate dielectric layers 20L.

Patterned portions of the second semiconductor material layer 242L comprise a first upper semiconductor gate electrode portion 252A that is formed in a first transistor region (such as the first n-type field effect transistor region 200), second upper semiconductor gate electrode portions 252B that are formed in the transistor array region 1200, and third upper semiconductor gate electrode portions 252F that are formed in the transistor array region 1200. Patterned portions of the first-transistor lower gate material portion 241 comprise a first lower semiconductor gate electrode portion 251A that is formed in a first transistor region (such as the first n-type field effect transistor region 200), second lower semiconductor gate electrode portions 251B that are formed in the transistor array region 1200, and third lower semiconductor gate electrode portions 251F that are formed in the transistor array region 1200.

A first gate electrode (251A, 252A) is formed in the first transistor region 200. The first gate electrode (251A, 152A) comprises the first upper semiconductor gate electrode portion 252A (which is a patterned portion of the second portion of the second semiconductor material layer 242L) and the first lower semiconductor gate electrode portion 251A (which is a patterned portion of the first-transistor lower gate material portion 241). Second gate electrodes (251B, 252B) can be formed in the transistor array region 1200. Each second gate electrode (251B, 252B) comprises a second upper semiconductor gate electrode portion 252B (which is a patterned portion of the thinned portion of the second semiconductor material layer 242L) and a second lower semiconductor gate electrode portion 251B (which is a patterned portion of the second-transistor lower gate material portion 241). Third gate electrodes (251F, 252F) can be formed in the transistor array region 1200. Each third gate electrode (251F, 252F) comprises a third upper semiconductor gate electrode portion 252F (which is a patterned portion of the thinned portion of the third semiconductor material layer 242L) and a third lower semiconductor gate electrode portion 251F (which is a patterned portion of the third-transistor lower gate material portion 241).

The first gate electrode (251A, 252A) extends laterally along a first gate electrode length direction (such as the first horizontal direction hd1) and comprises a first lower semiconductor gate electrode portion 251A and a first upper semiconductor gate electrode portion 252A. In one embodiment, the first gate electrode (251A, 252A) laterally extends along the first gate electrode length direction (such as the first horizontal direction hd1) by a lateral distance that is greater than a lateral dimension of a top surface of the first active region 5A.

Each second gate electrode (251B, 252B) overlies a first portion of a second active region 5F. Each second gate electrode (251B, 252B) extends laterally along a second gate electrode length direction (such as the second horizontal direction hd2) normal to the first gate length direction hd1 and comprises a second lower semiconductor gate electrode portion 251B and a second upper semiconductor gate electrode portion 252B. In one embodiment, a maximum lateral dimension of the second gate electrode (251B, 252B) along a second gate electrode length direction (such as the second horizontal direction hd2) is the same as a lateral dimension of a top surface of the second active region 5F along the second gate electrode length direction (such as the second horizontal direction hd2).

In one embodiment, each second gate electrode (251B, 252B) has a variable lateral extent along the second gate electrode length direction (such as the second horizontal direction hd2) extent that decreases with a vertical distance from the top surface of the second active region. In one embodiment, the second active region is laterally surrounded by a trench isolation structure 8 comprising a dielectric fill material; and each second gate electrode (251B, 252B) has tapered widthwise sidewalls that are perpendicular to the second gate electrode length direction (such as the second horizontal direction hd2), and are tilted along the second gate electrode direction (such as the second horizontal direction hd2), and are in contact with the trench isolation structure 8. The tilt angle of the tapered widthwise sidewalls may be in a range from 0.1 degree to 10 degrees, such as from 0.3 degrees to 5 degrees, and/or from 0.6 degrees to 3 degrees.

In one embodiment, for each second gate electrode (251B, 252B), an entirety of two widthwise sidewalls of the second lower semiconductor gate electrode portion 251B is in contact with the trench isolation structure 8; a lower portion of each of two widthwise sidewalls of the second upper semiconductor gate electrode portion 252B is in contact with the trench isolation structure 8; and an upper portion of each of the two widthwise sidewalls of the second upper semiconductor gate electrode portion 252B overlies a top surface of the trench isolation structure 8.

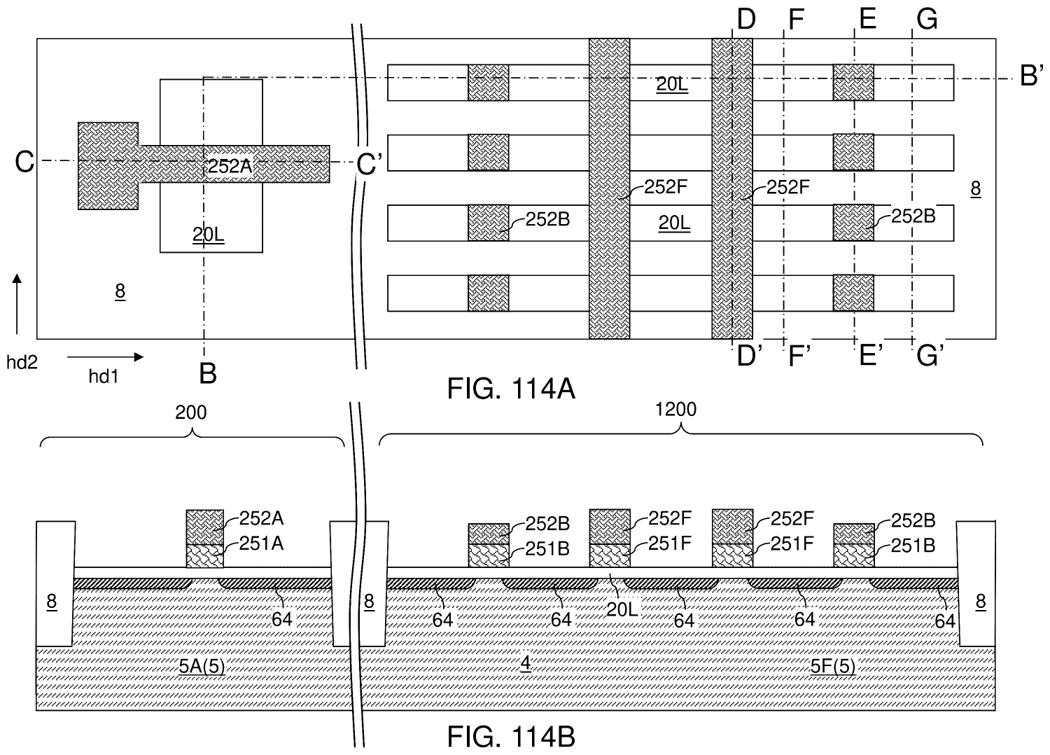

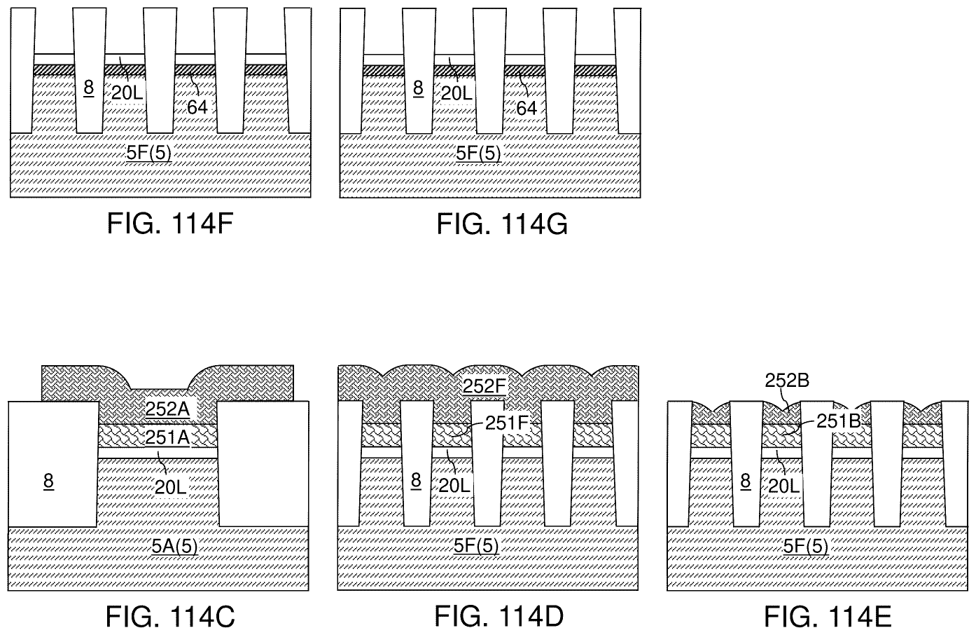

In one embodiment, the first lower semiconductor gate electrode portion 251A has a maximum lateral extent along the first gate electrode length direction (such as the first horizontal direction hd1) that is the same as a lateral extent of a top surface of the first active region 5A along the first gate electrode length direction (such as the first horizontal direction hd1). In one embodiment, the first upper semiconductor gate electrode portion 252A comprises a lower portion having a lateral extent along the first gate electrode length direction (such as the first horizontal direction hd1) that is not greater than the lateral extent of the top surface of the first active region 5A along the first gate electrode length direction (such as the first horizontal direction hd1), and further comprises an upper portion having a lateral extent along the first gate electrode length direction that is greater than the lateral extent of the top surface of the first active region 5A along the first gate electrode length direction, as shown in FIG. 114C.

In one embodiment, the semiconductor structure comprises: a first trench isolation structure 8 laterally surrounding the first active region 5A; and a second trench isolation structure 8 laterally surrounding the second active region 5F. The first gate electrode (251A, 252A) contacts a top surface of the first trench isolation structure 8; and the second gate electrode (251B, 252B) does not contact a top surface of the second trench isolation structure 8. In one embodiment, the first upper semiconductor gate electrode portion 252A includes a first uniform thickness region and two variable thickness regions having an areal overlap with the first active region 5A in a plan view, as shown in FIG. 114A. In one embodiment, the first upper semiconductor gate electrode portion 252A comprises an additional uniform thickness region overlying the top surface of the first trench isolation structure 8, as shown in FIG. 114C.

Third gate electrodes (251F, 252F) are formed in the transistor array region 1200. Each third gate electrode (251F, 252F) overlies a second portion of a respective second active region. Each third gate electrode (251F, 252F) comprises a third upper semiconductor gate electrode portion 252F having a variable thickness that is greater than the uniform thickness in the uniform thickness regions of the first upper semiconductor gate electrode portion 252A.

In one embodiment, a maximum lateral extent of the second gate electrode (251B, 252B) along the second gate electrode length direction (such as the second horizontal direction hd2) is the same as a lateral dimension of a top surface of the second active region 5F along the second gate electrode length direction (such as the second horizontal direction hd2); and the third gate electrode (251F, 252F) extends laterally along the second gate electrode length direction (such as the second horizontal direction hd2) by a lateral distance that is greater than the lateral dimension of the top surface of the second active region 5F along the second gate electrode length direction (such as the second horizontal direction hd2).

Generally, an entirety of the first lower semiconductor gate electrode portion 251A (i.e., the patterned portion of the first-transistor lower gate material portion 241) may be formed below a horizontal plane including a top surface of the first trench isolation structure 8. In one embodiment, the first upper semiconductor gate electrode portion 252A (i.e., the patterned portion of the second portion of the second semiconductor material layer 242L that is not thinned from the initial thickness) comprises a segment that overlies the top surface of the first trench isolation structure 8.

Each third gate electrode (251F, 252F) comprises a third upper semiconductor gate electrode portion 252F (which is a patterned portion of the third portion of the second semiconductor material layer 242L) and a third lower semiconductor gate electrode portion 251F (which is another patterned portion of the second-transistor lower gate material portion 241) that are located over an active region 5F that is laterally surrounded by the second trench isolation structure 8. The third gate electrode (251F, 252F) overlies and contacts a top surface of the second trench isolation structure 8 and extends over an additional active region to function as a gate electrode of an additional field effect transistor. The photoresist layer 77 can be subsequently removed, for example, by ashing.

Referring to FIGS. 114A-114G, source/drain extension regions 64 can be formed by implanting dopants into top surface portions of the semiconductor substrate 2 (such as top portions of the first doped well 5E and the second doped well 5F). For example, the processing steps described with reference to FIGS. 53A-53D can be performed to form the source/drain extension regions 64.

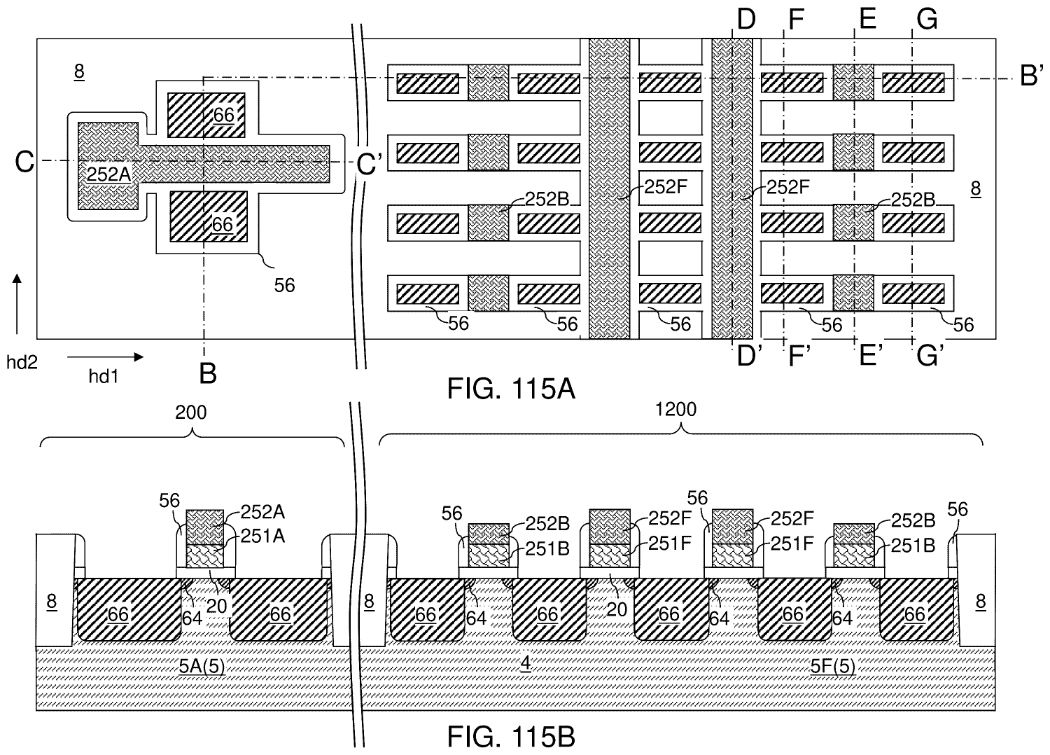

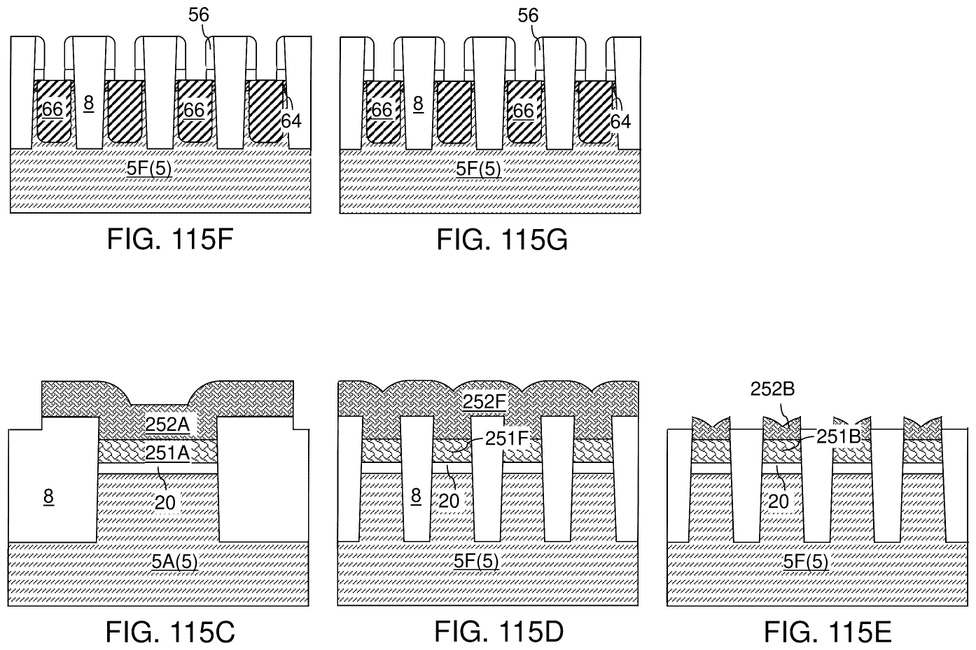

Referring to FIGS. 115A-115G, dielectric spacers 56 can be formed, for example, by performing the processing steps described with reference to FIGS. 54A-54D. Source/drain regions (64, 66) can be formed in each doped well (5E, 5F). In one embodiment, the anisotropic etch process can etch the dielectric materials of a dielectric spacer layer and the trench isolation structures 8 selective to the semiconductor materials of the gate electrodes. The anisotropic etch process that forms the dielectric gate spacers 56 collaterally etches unmasked portions of the trench isolation structures 8 that are not covered by the gate electrodes, such as the first gate electrode (251A, 252A) and the third gate electrodes (251F, 252F). In one embodiment, the first trench isolation structure 8 comprises: a recessed horizontal surface that is recessed relative to the top surface of the first trench isolation structure 8; and a sidewall surface connecting the recessed horizontal surface and the top surface of the first trench isolation structure 8 and vertically coincident with a sidewall of the first upper semiconductor gate electrode portion 252A.

Subsequently, deep source/drain regions 66 can be formed by implanting additional electrical dopants. A first field effect transistor 200T can be formed in the first transistor region (such as the first n-type field effect transistor region 200) by forming a first source region (64, 66) and a first drain region (64, 66) in the first active region 5A. The first source region (64, 66) and the first drain region (64, 66) are laterally spaced from each other by a first channel (i.e., upper portion of the region 5A) along a first channel direction (such as the second horizontal direction hd2). Second field effect transistors 1200S and third field effect transistors 1200T can be formed in the transistor array region 1200 by forming second source regions (64, 66) and second drain regions (64, 66) in the second active region 5F. Each pair of a second source region (64, 66) and a second drain region (64, 66) in a second field effect transistor 1200S can be laterally spaced from each other along a second channel direction (such as the first horizontal direction hd1). Each pair of a third source region (64, 66) and a third drain region (64, 66) in a third field effect transistor 1200T can be laterally spaced from each other along a third channel direction, which can be the same as the second channel direction (such as the first horizontal direction hd1).

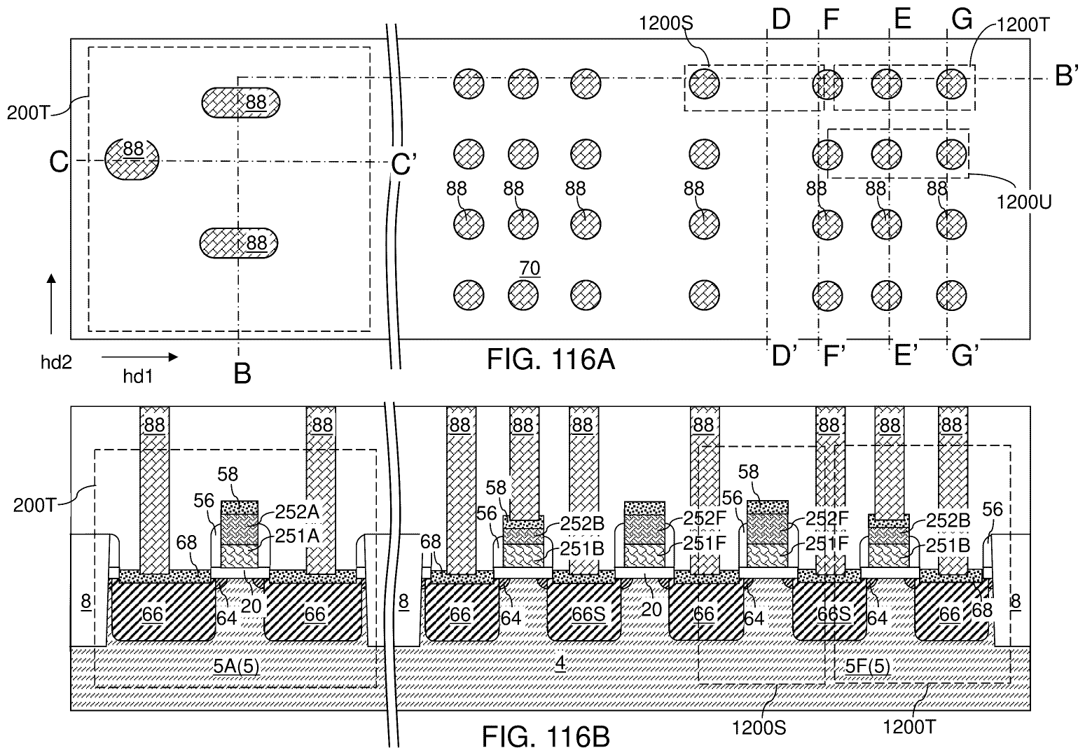

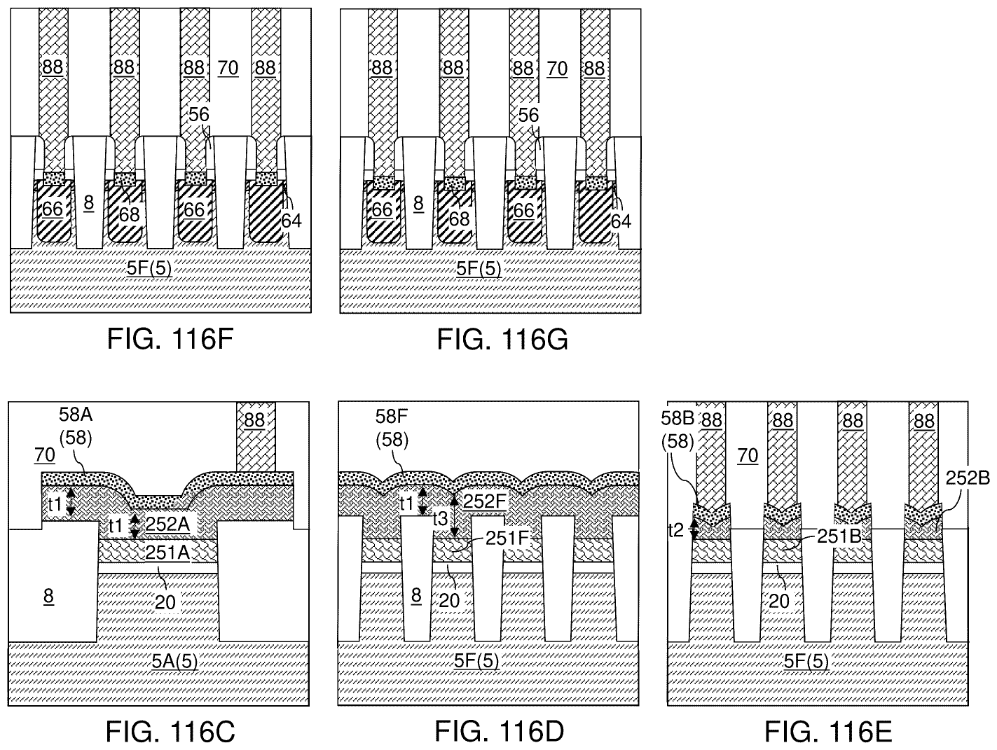

Referring to FIGS. 116A-116G, a metal deposition step can be performed to deposit a metal on the physically exposed top surfaces of the ninth exemplary structure, which include top surfaces of the upper semiconductor gate electrode portions (252A, 252B, 252F) and the deep source/drain regions 66. Metal-semiconductor alloy regions (58, 68) can be formed by reacting the metal with underlying semiconductor material portions, which include surface portions of the upper semiconductor gate electrode portions (252A, 252B, 252F) and the deep source/drain regions 66. The metal-semiconductor alloy regions (58, 68) comprise gate metal-semiconductor alloy regions 58 that are formed on gate electrodes, and source/drain metal-semiconductor alloy regions 68 that are formed on the deep source/drain regions 66.

Subsequently, at least one dielectric material layer such as a contact-level dielectric layer 70 can be formed over the metal-semiconductor alloy regions (58, 68) and the trench isolation structures 8. Various contact via cavities can be formed through the contact-level dielectric layer 70, and various contact via structures 88 can be formed on a respective one of the metal-semiconductor alloy regions (58, 68).

The process of the ninth embodiment reduces the cost of fabrication while providing a more compact fringeless transistors to increase the device density.

Referring to FIGS. 107A-116G and various embodiments of the present disclosure, a semiconductor structure is provided, which comprises: a first field effect transistor 200T; a second field effect transistor 1200S; and a third field effect transistor 1200T, as shown in FIGS. 116A and 116B. The second field effect transistor 1200S and the third field effect transistor 1200T comprise a shared source/drain region 66S, and are located in a same second active region 5F; the second field effect transistor 1200S comprises a second gate electrode (58, 251B, 252B) which comprises a second lower semiconductor gate electrode portion 251B and a second upper semiconductor gate electrode portion 252B; the third field effect transistor 1200T comprises a third gate electrode (58, 251F, 252F) which comprises a third lower semiconductor gate electrode portion 251F and a third upper semiconductor gate electrode portion 252F; and the third gate electrode is thicker than the second gate electrode. A gate length of the second gate electrode along a gate length direction hd2 that is perpendicular to a second channel direction hd1 of the second field effect transistor 1200S is the same as a width of the second active region 5F along the third gate length direction hd2; and a gate length of the third gate electrode along the gate length direction hd2 that is perpendicular to the second channel direction hd1 is greater than the width of the second active region 5F along the gate length direction hd2 and is greater than the gate length of the second gate electrode.

In one embodiment, the first field effect transistor 200T comprises a first gate electrode (58, 251A, 252A) overlying a first active region 5A that contains a first source region 66 and a first drain region 66 that are laterally spaced from each other along a first channel direction hd2. The first gate electrode (58, 251A, 252A) extends laterally along a first gate electrode length direction hd1 that is perpendicular to the first channel direction hd2, and comprises a first lower semiconductor gate electrode portion 251A and a first upper semiconductor gate electrode portion 252A including a uniform-thickness region having a first thickness t1 throughout. The second field effect transistor overlies a first portion of a second active region 5F that contains a second source region 66 and a second drain region 66 that are laterally spaced from each other along a second channel direction hd1. The second gate electrode (251B, 252B) extends laterally along a second gate electrode length direction hd2 that is perpendicular to the second channel direction hd1. The second upper semiconductor gate electrode portion 252B has a variable second thickness that that is less than the first thickness t1,

In one embodiment, the first channel direction hd2 is perpendicular to the second channel direction hd1. In one embodiment, the second active region 5F is laterally surrounded by a trench isolation structure 8 comprising a dielectric fill material; and the second gate electrode (251B, 252B) has tapered widthwise sidewalls that are in contact with the trench isolation structure 8. In one embodiment, the second gate electrode (251B, 252B) has a variable lateral extent along the second gate electrode length direction hd2 extent that decreases with a vertical distance from the top surface of the second active region 5F.

In one embodiment, the second lower semiconductor gate electrode portion 251B has a uniform thickness throughout; and a second upper semiconductor gate electrode portion 252B has a minimum thickness at a midpoint between a pair of sidewalls of the trench isolation structure 8 that contact the tapered widthwise sidewalls of the second gate electrode (251B, 252B). In one embodiment, an entirety of two widthwise sidewalls of the second lower semiconductor gate electrode portion 251B is in contact with the trench isolation structure 8; a lower portion of each of two widthwise sidewalls of the second upper semiconductor gate electrode portion 252B is in contact with the trench isolation structure 8; and an upper portion of each of the two widthwise sidewalls of the second upper semiconductor gate electrode portion 252B overlies a top surface of the trench isolation structure 8.

In one embodiment, the first lower semiconductor gate electrode portion 251A has a maximum lateral extent along the first gate electrode length direction hd1 that is the same as a lateral extent of a top surface of the first active region 5A along the first gate electrode length direction; and the first upper semiconductor gate electrode portion 252A comprises a lower portion having a lateral extent along the first gate electrode length direction hd1 that is not greater than the lateral extent of the top surface of the first active region along the first gate electrode length direction, and further comprises an upper portion having a lateral extent along the first gate electrode length direction that is greater than the lateral extent of the top surface of the first active region along the first gate electrode length direction.

In one embodiment, the semiconductor structure comprises: a first trench isolation structure 8 laterally surrounding the first active region; and a second trench isolation structure 8 laterally surrounding the second active region, wherein: the first gate electrode (251A, 252A) contacts a top surface of the first trench isolation structure 8; and the second gate electrode (251B, 252B) does not contact a top surface of the second trench isolation structure 8. In one embodiment, the first upper semiconductor gate electrode portion 252A includes a variable thickness region having an areal overlap with the first active region in a plan view and having a minimum thickness not less than the first thickness t1. In one embodiment, the first upper semiconductor gate electrode portion comprises an additional uniform-thickness region overlying the top surface of the first trench isolation structure 8 and having the first thickness t1 throughout.

In one embodiment, the first trench isolation structure 8 comprises: a recessed horizontal surface that is recessed relative to the top surface of the first trench isolation structure 8; and a sidewall surface connecting the recessed horizontal surface and the top surface of the first trench isolation structure 8 and vertically coincident with a sidewall of the first upper semiconductor gate electrode portion 252A.

In one embodiment, the third field effect transistor overlies a second portion of the second active region 5F that contains a third source region 66. The shared source/drain region 66S comprises the second drain region which is a common drain region 66S of the second field effect transistor 1200S and the third field effect transistor 1200T. The third gate electrode (251F, 252F) comprises an additional upper semiconductor gate electrode portion (such as a third upper semiconductor gate electrode portion 252F) having a variable thickness that is not less than the first thickness t1. In one embodiment, the minimum thickness of the third upper semiconductor gate electrode portion 252F may be a third thickness t3, which is greater than the first thickness t1.

In one embodiment, a maximum lateral extent of the second gate electrode (251B, 252B) along the second gate electrode length direction hd2 is the same as a lateral dimension of a top surface of the second active region 5F along the second gate electrode length direction; and the third gate electrode (251F, 252F) extends laterally along the second gate electrode length direction hd2 by a lateral distance that is greater than the lateral dimension of the top surface of the second active region 5F along the second gate electrode length direction.

In one embodiment, the third gate electrode (251F, 252F) comprises an additional lower gate electrode portion 251F having a same material composition and a same thickness as the first lower gate electrode portion, and further comprises an additional upper gate electrode portion 252F having a variable thickness which is the same as or greater than the first thickness t1. In one embodiment, a minimum thickness of a first segment of the additional upper gate electrode portion 252F having an areal overlap with the second active region in a plan view is a third thickness t3 that is greater than the first thickness t1; and a second segment of the additional upper gate electrode portion having an areal overlap with the second trench isolation structure 8 has a uniform thickness that equals the first thickness t1.

In one embodiment, the semiconductor structure comprises additional third field effect transistors that are located adjacent to the third field effect transistor, wherein the third gate electrode (251F, 252F) extends over active regions of the additional third field effect transistors and functions as a common gate electrode (251F, 252F) for each of the third field effect transistor and the additional third field effect transistor, and wherein a minimum thickness of the common gate electrode (251F, 252F) is greater than a maximum thickness of the second electrode of the second field effect transistor.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A semiconductor structure, comprising:
a first field effect transistor comprising a first active region and a first gate electrode that comprises a first semiconductor gate electrode portion;
a first trench isolation structure laterally surrounding the first active region;
a second field effect transistor comprising a second active region and a second gate electrode that comprises a stack of a lower semiconductor gate electrode portion and an upper semiconductor gate electrode portion;
a second trench isolation structure laterally surrounding the second active region; and
at least one dielectric material layer overlying the first field effect transistor and the second field effect transistor, wherein:
the first semiconductor gate electrode portion contacts sidewall surface segments of the first trench isolation structure and comprises a top surface contacting the at least one dielectric material layer;
the lower semiconductor gate electrode portion has a same material composition and a same thickness as the first semiconductor gate electrode portion, and contacts sidewall surface segments of the second trench isolation structure; and
the upper semiconductor gate electrode portion comprises a bottom surface contacting the lower semiconductor gate electrode and top surface segments of the second shallow trench isolation structure.

2. The semiconductor structure of claim 1, wherein the first gate electrode does not include any additional semiconductor gate electrode portion which contacts the first semiconductor gate electrode portion, and the first gate electrode lacks an interface between two semiconductor gate portions.

3. The semiconductor structure of claim 1, wherein:
the first active region comprises a first source region and a first drain region that are laterally spaced from each other by a first channel along a first channel direction;
the first gate electrode laterally extends along a first gate electrode direction that is perpendicular to the first channel direction;
the second active region comprises a second source region and a second drain region that are laterally spaced from each other by a second channel along a second channel direction; and
the second gate electrode laterally extends along a second gate electrode direction that is perpendicular to the second channel direction.

4. The semiconductor structure of claim 3, wherein a maximum lateral dimension of the first gate electrode along the first gate electrode direction equals a lateral dimension of a top surface of the first active region along the first gate electrode direction.

5. The semiconductor structure of claim 4, wherein a maximum lateral dimension of the lower semiconductor gate electrode along the second gate electrode direction equals a lateral dimension of a top surface of the second active region along the second gate electrode direction.

6. The semiconductor structure of claim 5, wherein a lateral dimension of upper semiconductor gate electrode portion along the second gate electrode direction is greater than the third lateral dimension.

7. The semiconductor structure of claim 3, wherein the upper semiconductor gate electrode portion and the lower semiconductor gate electrode have a same width along the second channel direction.

8. The semiconductor structure of claim 3, wherein:
the first field effect transistor comprises a first gate dielectric overlying the first active region and underlying the first gate electrode, and two first dielectric gate spacers contacting a respective sidewall of the first gate electrode; and
a lateral dimension of the first gate dielectric along the first channel direction equals a width of the first gate electrode along the first channel direction.

9. The semiconductor structure of claim 8, wherein:
the second field effect transistor comprises a second gate dielectric overlying the second active region and underlying the lower semiconductor gate electrode portion, and two second dielectric gate spacers contacting a respective sidewall of the lower semiconductor gate electrode portion;
the second gate dielectric is thicker than the first gate dielectric; and
a lateral dimension of the second gate dielectric along the second channel direction equals a width of the second gate electrode along the second channel direction.

10. The semiconductor structure of claim 8, wherein the two first dielectric gate spacers are not in direct contact with each other, and have a maximum height that is less than a sum of a thickness of the first gate dielectric and a thickness of the first gate electrode.

11. The semiconductor structure of claim 3, wherein each sidewall of the first semiconductor gate electrode portion that contacts the sidewall surface segments of the first trench isolation structure has a respective taper angle relative to a vertical plane that is perpendicular to the first gate electrode direction.

12. The semiconductor structure of claim 3, wherein the first gate electrode has a variable lateral dimension along the first gate electrode direction that decreases with a vertical distance from a horizontal plane including a top surface of the first active region.

13. The semiconductor structure of claim 12, wherein the lower semiconductor gate electrode portion has a variable lateral dimension along the second gate electrode direction that decreases with a vertical distance from a horizontal plane including a top surface of the second active region.

14. The semiconductor structure of claim 13, wherein the upper semiconductor gate electrode portion has a uniform lateral dimension along the second gate electrode direction that is invariant with the vertical distance from the horizontal plane including the top surface of the second active region.

15. The semiconductor structure of claim 1, further comprising:
a first gate metal-semiconductor alloy region in contact with a top surface segment of the first semiconductor gate electrode portion; and
a second gate metal-semiconductor alloy region in contact with a top surface segment of the upper semiconductor gate electrode portion, wherein the lower semiconductor gate electrode portion is not in direct contact with any metal-semiconductor alloy material.

16. A method of forming a semiconductor structure, comprising:
forming a first patterned stack including a first gate dielectric layer and a first gate semiconductor material portion, and a second patterned stack including a second gate dielectric layer and a second gate semiconductor material portion over a semiconductor substrate, wherein the first gate semiconductor material portion and the second gate semiconductor material portion comprise patterned portions of a first semiconductor material layer;
forming shallow trench isolation structures around the first patterned stack and the second patterned stack, and into an upper portion of the semiconductor substrate;
forming a dielectric capping layer directly on the first gate semiconductor material portion;
forming a second semiconductor material layer directly on the second gate semiconductor material portion;
patterning the second semiconductor material layer, the dielectric capping layer, the first gate dielectric layer, and the second gate dielectric layer to form a first gate electrode comprising a portion of the first gate semiconductor material portion and a second gate electrode comprising a portion of the second gate semiconductor material portion and a portion of the second semiconductor material layer;
forming a first field effect transistor by forming a first source region and a first drain region in portions of the semiconductor substrate adjacent to the first gate electrode; and
forming a second field effect transistor by forming a second source region and a second drain region in portions of the semiconductor substrate adjacent to the second gate electrode.

17. The method of claim 16, wherein:
the first patterned stack further comprises a first hardmask plate overlying the first gate semiconductor material portion;
the second patterned stack further comprises a second hardmask plate overlying the second gate semiconductor material portion;
a top surface of the shallow trench isolation structures are formed within a horizontal plane including top surfaces of the first hardmask plate and the second hardmask plate; and
the method further comprises removing the first hardmask plate and the second hardmask plate prior to formation of the dielectric capping layer.

18. The method of claim 16, wherein:
the dielectric capping layer is formed on a top surface of the first gate semiconductor material portion and on a top surface of the second gate semiconductor material portion;
the method further comprises removing a portion of the dielectric capping layer from above the top surface of the second gate semiconductor material portion; and
the second semiconductor material layer is formed directly on the top surface of the second gate semiconductor material portion.

19. The method of claim 16, further comprising:
forming a dielectric cover layer over the second semiconductor material layer and the dielectric capping layer; and
patterning the dielectric cover layer with a gate pattern into dielectric gate mask portions, wherein the gate pattern is subsequently transferred through the second semiconductor material layer, the dielectric capping layer, the first gate dielectric layer, and the second gate dielectric layer.

20. The method of claim 16, further comprising:
forming first dielectric gate spacers on sidewalls of the first gate electrode; and
forming second dielectric gate spacers on sidewalls of the second gate electrode, wherein the second dielectric gate spacers contact a remaining portion of the second gate semiconductor material portion and does not contact any remaining portion of the second semiconductor material layer.
